(19) United States
(12) Patent Application Publication
(10) Pub. No.: US 2025/0284199 A1
(43) Pub. Date: Sep. 11, 2025

(54) PATTERNING PROCESS AND RESIST MATERIAL

(71) Applicant: SHIN-ETSU CHEMICAL CO., LTD., Tokyo (JP)

(72) Inventors: Jun HATAKEYAMA, Joetsu-shi (JP); Yutaro OTOMO, Joetsu-shi (JP)

(73) Assignee: SHIN-ETSU CHEMICAL CO., LTD., Tokyo (JP)

(21) Appl. No.: 19/069,642

(22) Filed: Mar. 4, 2025

(30) Foreign Application Priority Data
Mar. 8, 2024 (JP) 2024-036350

(51) Int. Cl. G03F 7/38; C08F 220/18; C08F 220/20; G03F 7/004

(52) U.S. Cl. CPC G03F 7/38; C08F 220/18; C08F 220/20; G03F 7/0045

(57) ABSTRACT

The present invention is a patterning process including: providing a resist material containing a polymer in which a carboxy group bonded to a polymer main chain is protected with an acid-labile group; forming a resist film by using the resist material; and subjecting the resist film to exposure and heating, and then to development by dry etching to form a pattern, where the polymer has one or both of repeating units represented by the following general formulae (a1) and (a2). This can provide a patterning process according to which a fine pattern can be formed with a high aspect ratio and without pattern collapse occurring.

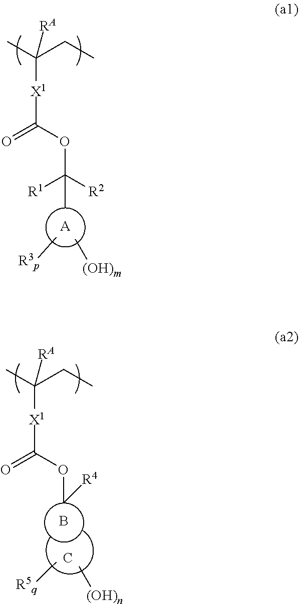

### TECHNICAL FIELD

The present invention relates to: a patterning process; and a resist material.

### BACKGROUND ART

As LSIs advance toward higher integration and higher processing speed, miniaturization of pattern rule is progressing rapidly. This is because the spread of high-speed communication of 5 G and artificial intelligence (AI) has progressed, and high-performance devices for processing these are needed. As a cutting-edge technology for miniaturization, 5-nm node and 3-nm node devices have been mass-produced by extreme ultraviolet ray (EUV) lithography at a wavelength of 13.5 nm. Furthermore, studies are also in progress on employing EUV lithography in next-generation 2-nm node and the following-generation 14-Å node devices. IMEC in Belgium has announced the development of devices of 2 Å.

As the miniaturization progresses, image blurs due to acid diffusion become a problem. To ensure resolution for fine patterns with dimensional sizes of 45 nm and smaller, there is a proposal that it is important to not only improve dissolution contrast as previously reported, but also control acid diffusion (Non Patent Document 1). Nevertheless, since chemically-amplified resist materials enhance the sensitivity and contrast through acid diffusion, an attempt to minimize acid diffusion by reducing the temperature and/or time of post-exposure baking (PEB) results in significant reductions of sensitivity and contrast.

A triangular tradeoff relationship among sensitivity, resolution, and edge roughness (LWR) has been pointed out. Specifically, resolution improvement requires suppression of acid diffusion, whereas shortening acid diffusion distance results in the reduction of sensitivity.

The addition of an acid generator capable of generating a bulky acid is effective in suppressing acid diffusion. Hence, it has been proposed to incorporate in a polymer a repeating unit derived from an onium salt having a polymerizable unsaturated bond. In this case, the polymer also functions as an acid generator (polymer-bound acid generator). Patent Document 1 proposes a sulfonium and iodonium salt having a polymerizable unsaturated bond that generates a particular sulfonic acid. Patent Document 2 proposes a sulfonium salt having a sulfonic acid moiety directly bonded to the main chain.

It is reported that pattern collapse determines the resolution limit of a resist (Non Patent Document 1). Patterns collapse due to the stress applied to the pattern during spin-drying after rinsing in aqueous alkaline development. To reduce the stress during spin-drying, it is effective to reduce the surface tension of the rinsing liquid, and rinsing liquids containing a surfactant is used for this purpose, but this is not sufficient for line patterns having dimensions with a pattern pitch of 20 nm or less. The use of rinsing with carbon dioxide in a supercritical state, where the surface tension is 0, has been considered, but a special chamber is necessary for creating a high-pressure supercritical state, and this is not practical from the viewpoint of improving throughput. There has been proposed a method of filling spaces between patterns with a water-soluble silicon-containing rinsing liquid and performing dry etching with oxygen gas, but there is a problem that image reversal occurs.

There has been proposed a patterning process in which exposed portions are opened by performing dry etching on a resist pattern in which the exposed portions have shrunk due to deprotection of acid-labile groups by exposure and PEB (Patent Document 3). If the shrinkage amount of an exposed portion is large, there are problems that a two-dimensional pattern having an L-shape or the like becomes deformed or that the cross-sectional shape of a line becomes triangular.

### CITATION LIST

### Patent Literature

Patent Document 1: JP 2006-045311 A
Patent Document 2: JP 2006-178317 A
Patent Document 3: JP 2023-157346 A

### Non Patent Literature

Non Patent Document 1: SPIE Vol. 6153 p 61531C-1 (2006)

### SUMMARY OF INVENTION

### Technical Problem

As stated above, as LSIs advance toward higher integration and higher processing speed, miniaturization of pattern rule is progressing, and in this situation, there have been demands for a patterning process in which pattern collapse and pattern deformation do not occur.

The present invention has been made in view of the above circumstances. An object of the present invention is to provide a patterning process according to which a fine pattern can be formed with a high aspect ratio and without pattern collapse occurring.

### Solution to Problem

To achieve the object, the present invention provides a patterning process comprising:
providing a resist material containing a polymer in which a carboxy group bonded to a polymer main chain is protected with an acid-labile group;
forming a resist film by using the resist material; and
subjecting the resist film to exposure and heating, and then to development by dry etching to form a pattern,
wherein the polymer has one or both of repeating units represented by the following general formulae (a1) and (a2),

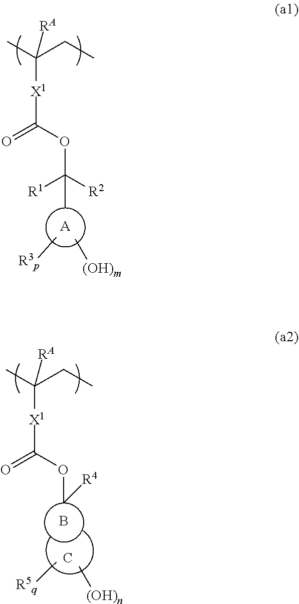

wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

According to the inventive patterning process described above, a fine pattern can be formed with a high aspect ratio without pattern collapse occurring.

In this case, the resist material can further contain an acid generator, a resist material containing a polymer having a repeating unit-b having an acid-generating moiety in addition to the one or both of the repeating units can be used, and both can be combined.

In the present invention, a suitable acid-generating function in the resist material can be achieved by incorporating an acid generator into the resist material (external addition), by using a polymer incorporating an acid-generating moiety (polymer-bound acid generator) (internal addition), or by using a combination of these.

When the polymer incorporating the repeating unit-b, having the acid-generating moiety, is used, the repeating unit-b having the acid-generating moiety preferably is at least one of repeating units selected from repeating units represented by the following formulae (b1) to (b5),

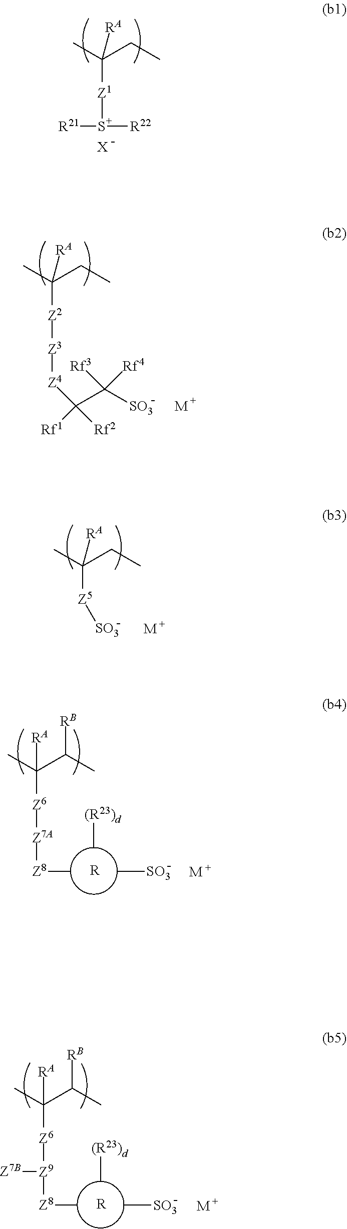

wherein each R^{A} independently represents a hydrogen atom or a methyl group; each RB independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

In the present invention, by using a polymer incorporating a repeating unit-b having such an acid-generating moiety, a fine pattern with a high aspect ratio can be formed more favorably without pattern collapse.

In this case, the repeating unit-b having the acid-generating moiety can be at least one repeating unit selected from repeating units represented by the formulae (b2) to (b5) in which the Z³, the Z^{7A}, the Z^{7B}, or the M⁺ in the formula contains one or more iodine atoms.

By using such a repeating unit containing an iodine atom, more suitable pattern formation is possible.

In the present invention, the exposure can be performed with an extreme ultraviolet ray having a wavelength of 3 to 15 nm or an electron beam with an acceleration voltage of 1 to 150 kV.

In the present invention, a fine pattern with a high aspect ratio can be formed more favorably without pattern collapse by using such high-energy beams.

The present invention also provides a resist material for patterning by dry etching, the resist material comprising a polymer having one or both of repeating units represented by the following general formulae (a1) and (a2),

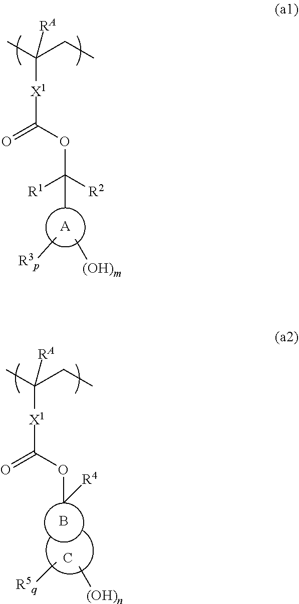

wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

Such a resist material can be used suitably in the inventive patterning process.

### Advantageous Effects of Invention

In the inventive patterning process, when an acid is generated in a resist film by exposure, the acid-labile group having a phenolic group in the polymer undergoes deprotection and generates a carboxy group. When a positive resist material is used, exposed portions, where carboxy groups have been generated, are opened by dry etching to form a positive pattern. Due to radicals generated in the dry etching chamber, the etching rate in exposed portions is enhanced by main-chain decomposition and the generation of carbonic acid, and in unexposed portions, etching rate is decreased by phenolic groups absorbing radicals. Positive patterns are formed by the difference in etching rate between exposed portions and unexposed portions being large. Development by dry etching makes it possible to form a fine pattern with a high aspect ratio, since pattern collapse due to capillary force does not occur.

### DESCRIPTION OF EMBODIMENTS

As stated above, as LSIs advance toward higher integration and higher processing speed, miniaturization of pattern rule is progressing, and in this situation, there have been demands for a patterning process in which pattern collapse and pattern deformation do not occur.

To achieve the object, the present inventors have earnestly studied, and found out that, by using a resist material containing, as a base, a polymer having a repeating unit in which a carboxy group is protected with an acid-labile group having a phenolic group, unexposed portions have phenolic groups and exposed portions generate carboxy groups by deprotection, and when this is dry etched, the etching rate in the unexposed portions is decreased by radicals generated in the etching chamber being absorbed by phenol and the etching rate in the exposed portions is increased along with decarboxylation and main-chain decomposition, thus increasing the selectivity of the etching rate between the exposed portions and the unexposed portions without relying on shrinkage of the film in the exposed portions and making it possible to form a fine pattern with a high aspect ratio. Thus, the present invention has been completed.

That is, the present invention is a patterning process comprising:
providing a resist material containing a polymer (base polymer) in which a carboxy group bonded to a polymer main chain is protected with an acid-labile group;
forming a resist film by using the resist material; and
subjecting the resist film to exposure and heating, and then to development by dry etching to form a pattern,
wherein the polymer has a particular repeating unit, described later. Incidentally, in the following, a base polymer may also be referred to as a base resin.

Hereinafter, the present invention will be described in detail, but the present invention is not limited thereto. In the present description, the recitations of numerical ranges by endpoints include all numbers subsumed within that range.

### [Patterning Process]

The inventive patterning process includes the following steps (i) to (iv):
(i) providing a resist material containing a polymer in which a carboxy group bonded to a polymer main chain is protected with an acid-labile group;
(ii) forming a resist film by using the resist material and exposing the resist film;
(iii) heating (baking) the exposed resist film; and
(iv) subjecting the heated resist film to development by dry etching to form a pattern,
where the polymer has one or both of repeating units represented by the following general formulae (a1) and (a2).

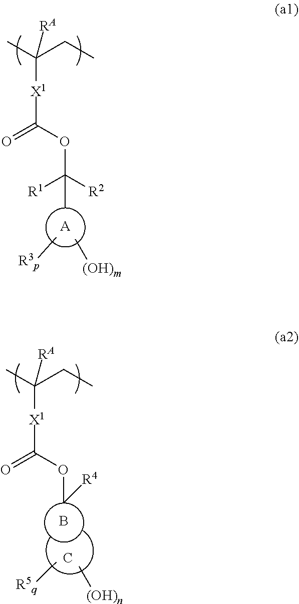

In the formulae, each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

[Step (i)]

Step (i) is a step of providing a resist material containing a polymer (base resin) in which a carboxy group bonded to a polymer main chain is protected with an acid-labile group. Details of the resist material will be described later.

[Step (ii)]

Step (ii) is a step of forming a resist film by using the resist material and exposing the resist film. The resist film can be formed, for example, by applying the resist material containing the base resin onto a substrate and performing a heat treatment.

Specifically, for example, the resist material is applied onto a substrate for manufacturing an integrated circuit or a layer to be processed on the substrate (Si, SiO₂, SiN, SiON, TiN, WSi, BPSG, SOG, organic antireflective film, etc.), or a substrate for manufacturing a mask circuit or a layer to be processed on the substrate (Cr, Cro, CrON, MoSiz, SiO₂, Ru, Ta, TaB, TaBN, TaBO, etc.) by an appropriate coating process, such as spin coating, roll coating, flow coating, dip coating, spray coating, or doctor coating, so that the coating film has a thickness of 0.1 to 2.0 μm. The resultant is prebaked on a hot plate at 60 to 150° C. for 10 seconds to 30 minutes, preferably at 80 to 120° C. for 30 seconds to 20 minutes to form a resist film.

Then, the resist film is exposed to be the target pattern via a predetermined mask or directly with a high-energy beam, such as ultraviolet ray, deep ultraviolet ray, electron beam (EB) with an acceleration voltage of 1 to 150 kV, extreme ultraviolet ray (EUV) having a wavelength of 3 to 15 nm, X-ray, soft X-ray, excimer laser, y-ray, or synchrotron radiation.

In the inventive patterning process, it is particularly preferable to perform the exposure with an extreme ultraviolet ray having a wavelength of 3 to 15 nm or with an electron beam with an acceleration voltage of 1 to 150 kV.

The exposure dose is preferably about 1 to 300 mJ/cm², particularly 10 to 200 mJ/cm², or about 1 to 500 μC/cm², particularly 5 to 400 μc/cm².

[Step (iii)]

Step (iii) is a step of baking (PEB) the resist film at 30 to 170° C. after the exposure. The PEB temperature is preferably 40 to 160° C., more preferably 50 to 150° C., and the treatment time is preferably 10 seconds to 30 minutes, more preferably 10 seconds to 20 minutes.

In the inventive patterning process, the heating in the PEB after the exposure can be performed, not only with a hot plate, but also by irradiation with infrared rays or a laser, hot-air blowing, or a method of inserting the wafer into an atmosphere having a temperature for baking.

Currently, most methods for heating a wafer are methods using a hot plate. By placing the silicon wafer on a hot plate, the resist film is heated by heat transfer from the wafer. The temperature at which to heat the resist film is adjusted by controlling the temperature of the hot plate.

[Step (iv)]

Step (iv) is a step of subjecting the resist film to development by dry etching after the baking. As the dry etching gas, it is possible to use a mixed gas in which a gas of oxygen, hydrogen, ammonia, fluorocarbon, chlorine, or bromine is diluted with nitrogen, argon, helium, carbon dioxide, carbon monoxide, sulfur dioxide, etc.

### [Resist Material]

As described above, the resist film is formed using a resist material containing, as a base, a polymer having a repeating unit in which a carboxy group is substituted with an acid-labile group having a phenolic group.

The base polymer contained in the resist material used in the present invention has one or both of the above-described repeating units represented by the general formulae (a1) and (a2) (these repeating units are also referred to as repeating units-a).

The repeating unit constituting the main chain of the base polymer has a carboxy group, and the carboxy group is protected (substituted) with an acid-labile group. The acid-labile group has a phenolic group. The resist film is formed in a state where the carboxy group bonded to the base polymer main chain is protected with the acid-labile group. Then, by exposing the resist film, deprotection is performed by the action of an acid.

The group that substitutes the carboxy group of the repeating unit, that is, the acid-labile group having the phenolic group, is represented by the following formula (a11) or the following formula (a22).

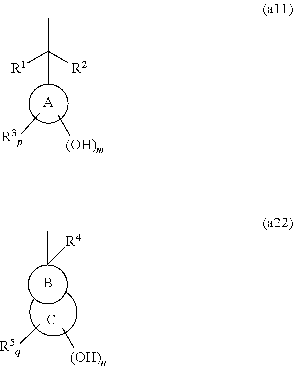

In the formulae, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

Examples of a monomer to give the repeating unit represented by the formula (a1) (hereinafter, also referred to as repeating unit-a1) include ones shown below, but are not limited thereto. Note that, in the following formulae, R^{A} is as defined above.

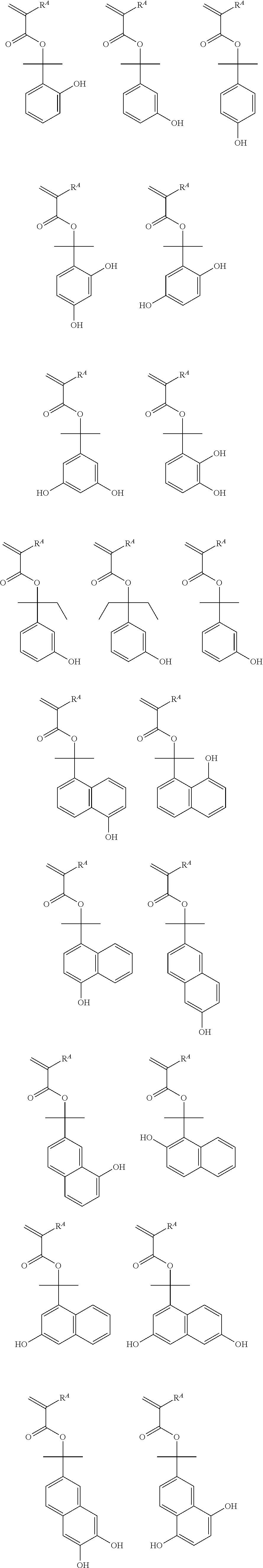

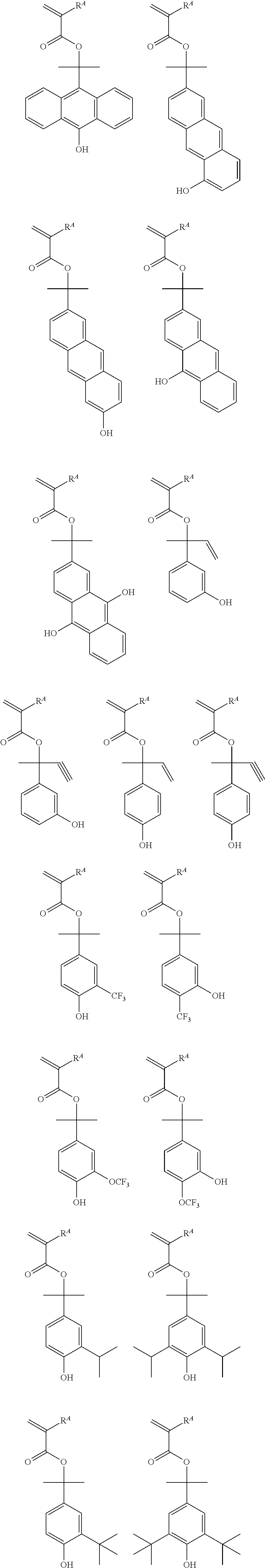

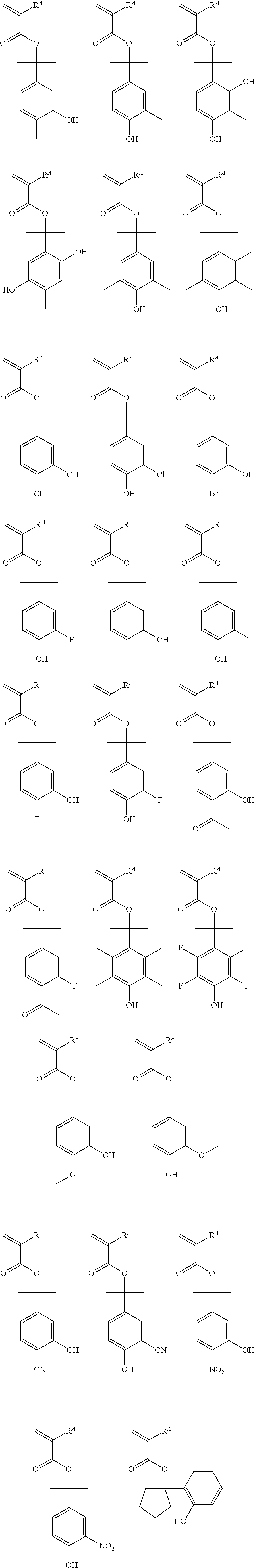

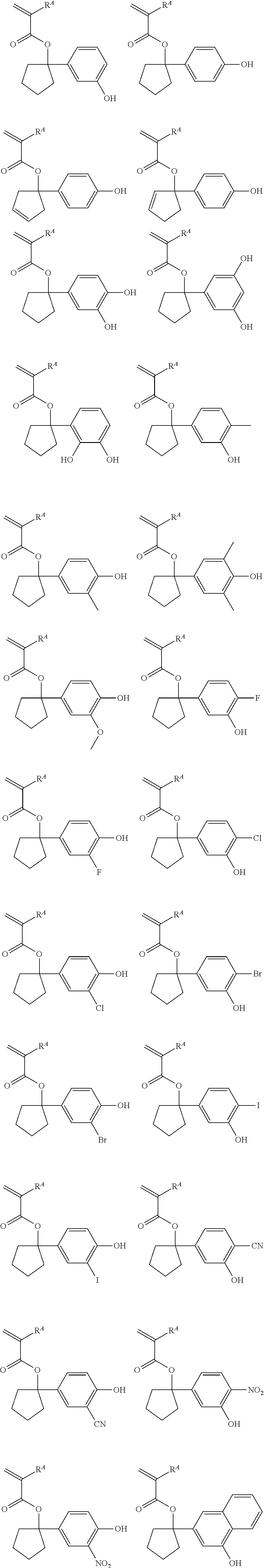

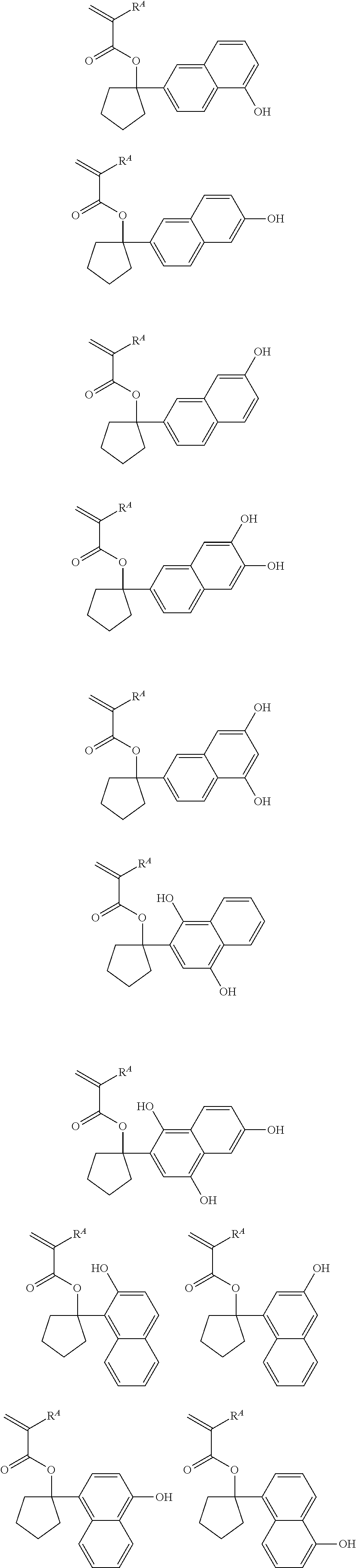

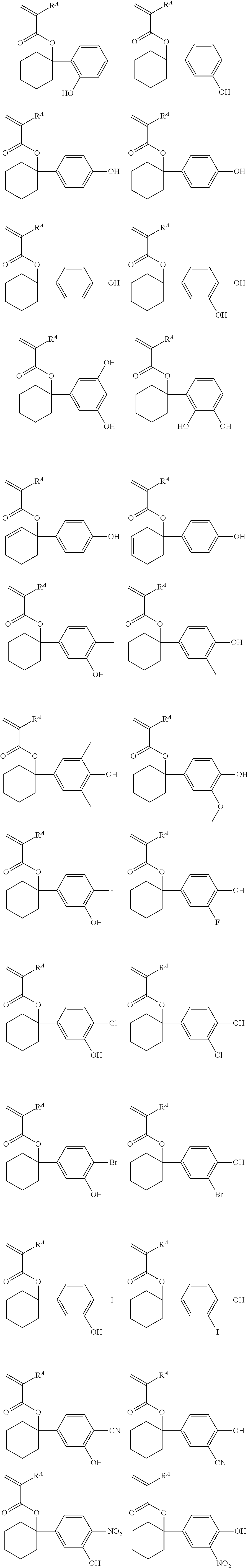

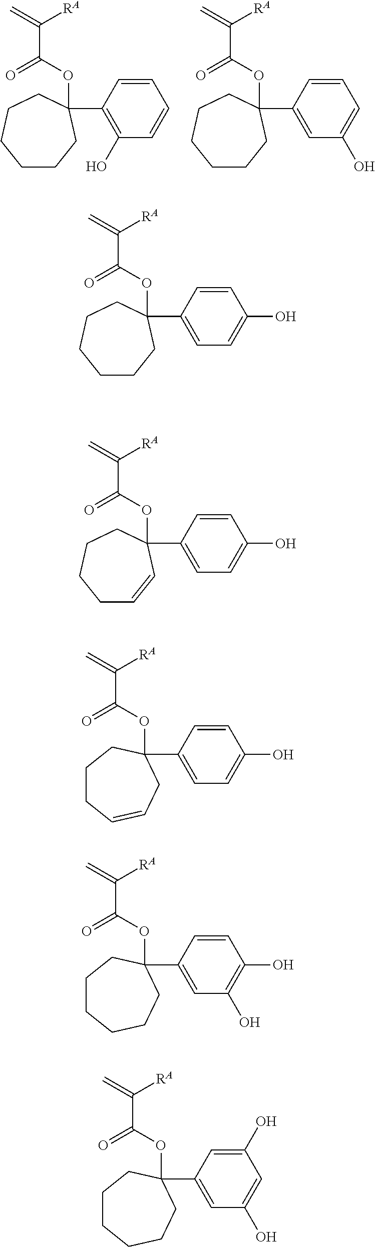

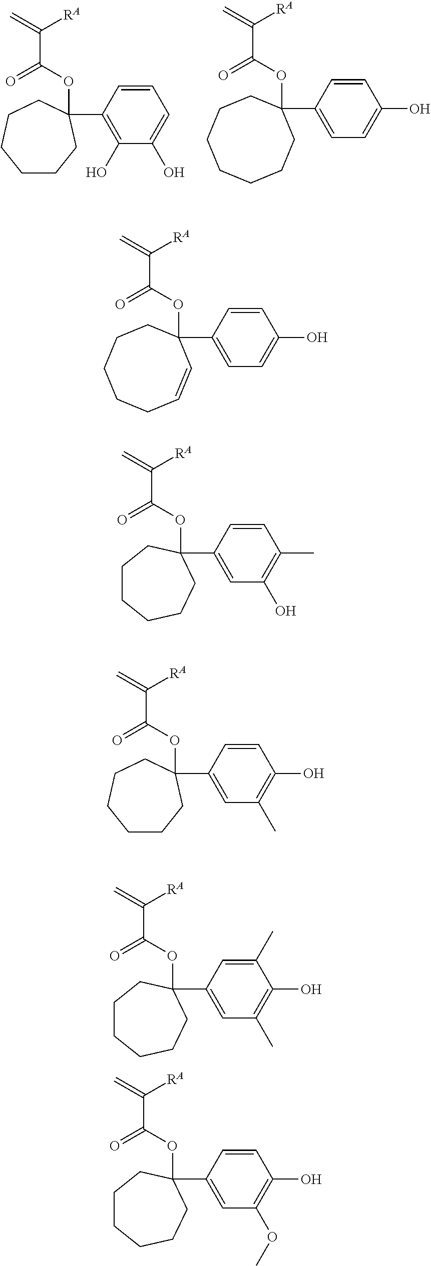

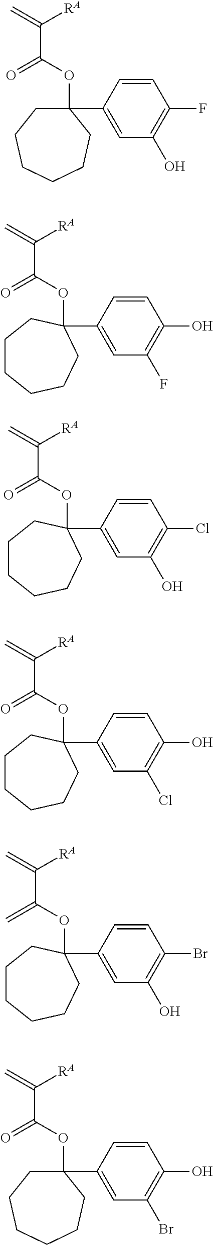

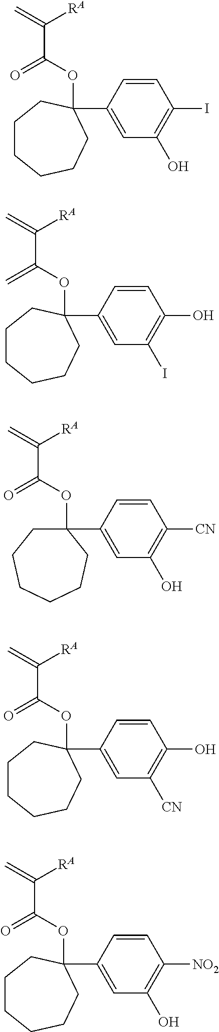

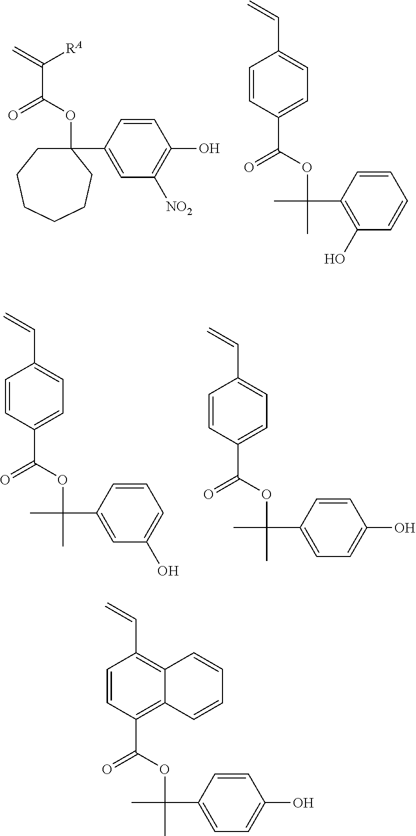

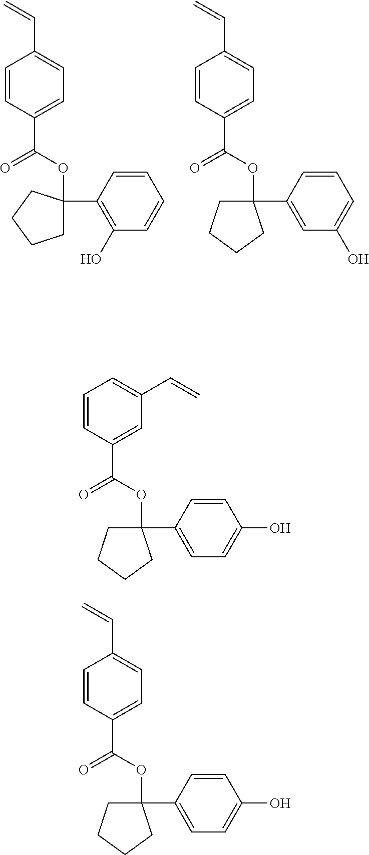

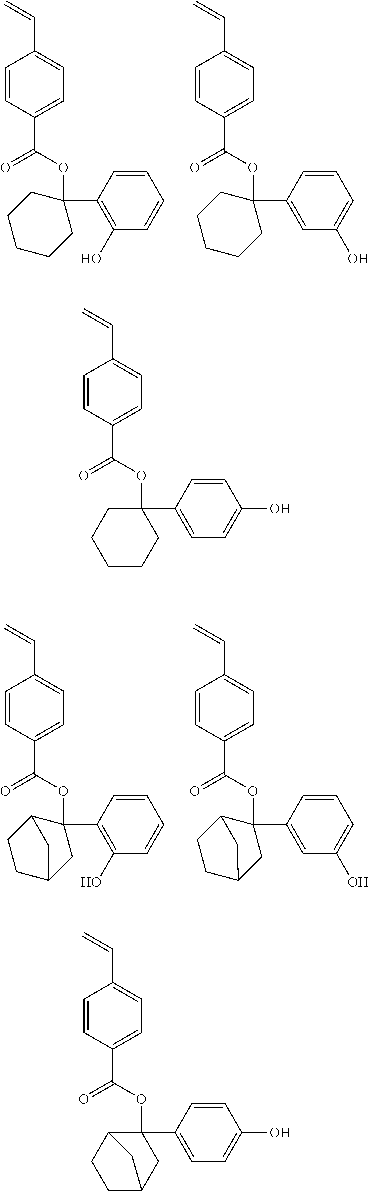

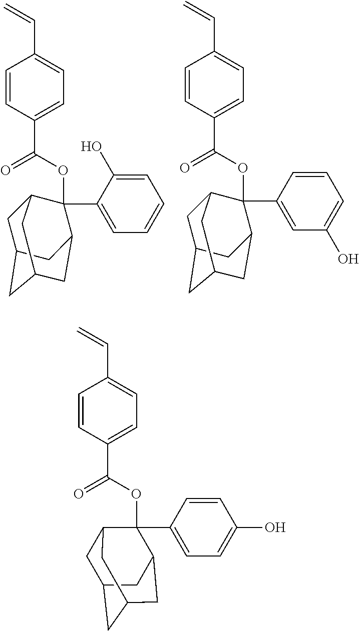

In the formulae, a vinyl group on an aromatic ring may be substituted with an isopropenyl group.

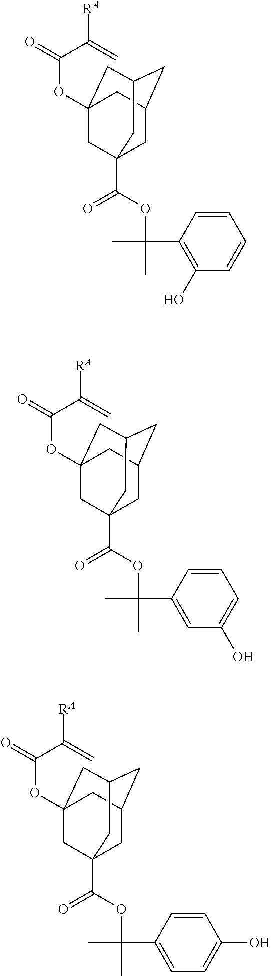

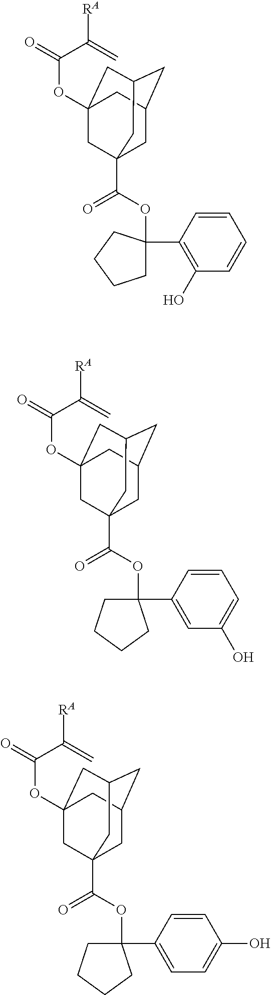

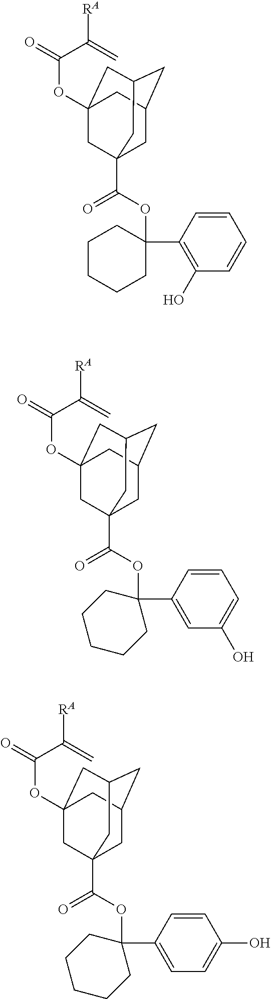

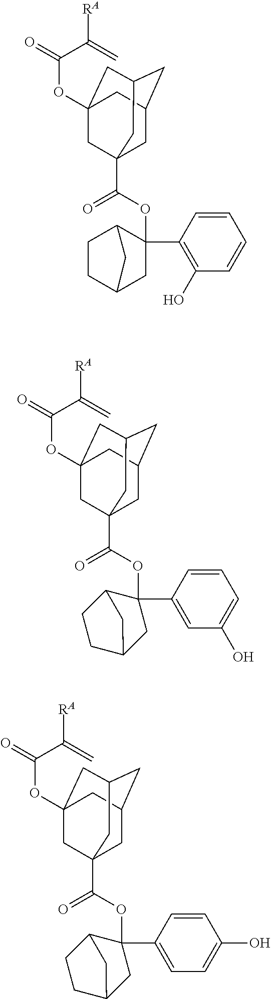

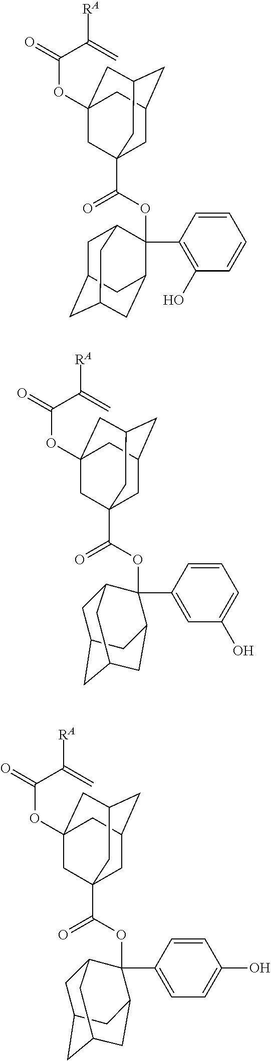

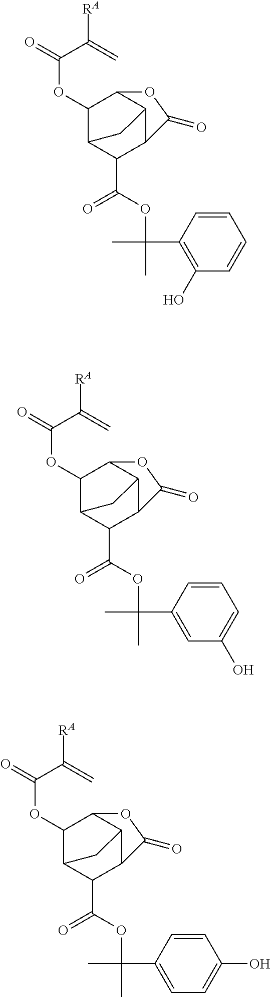

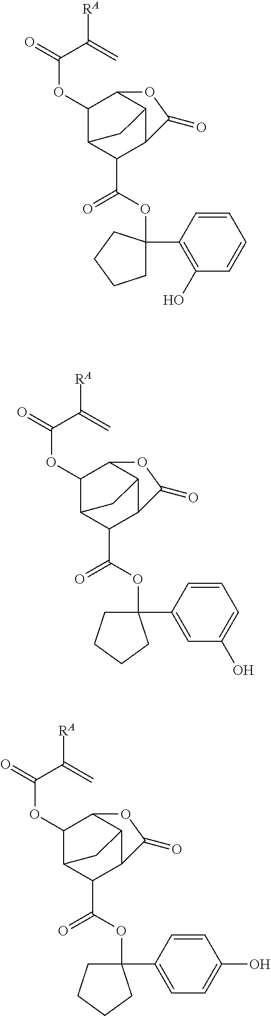

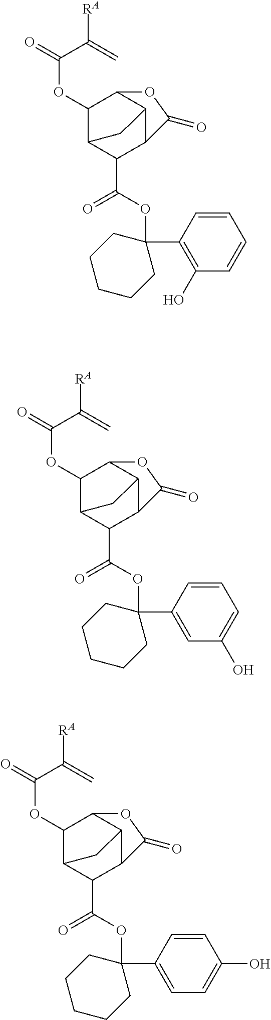

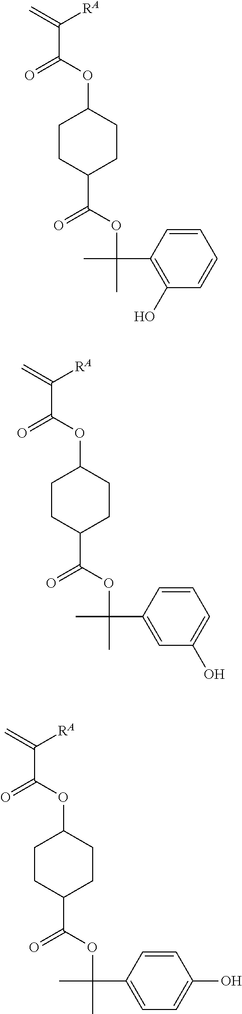

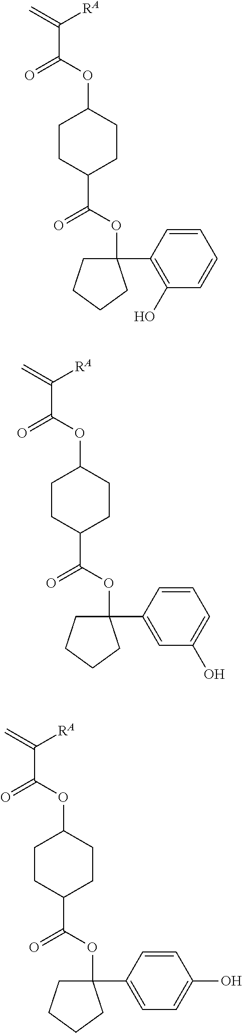

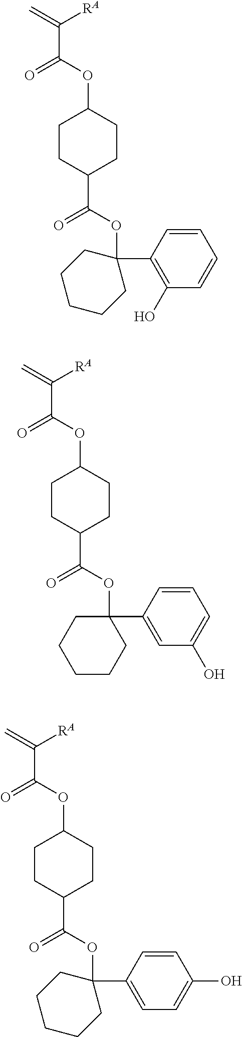

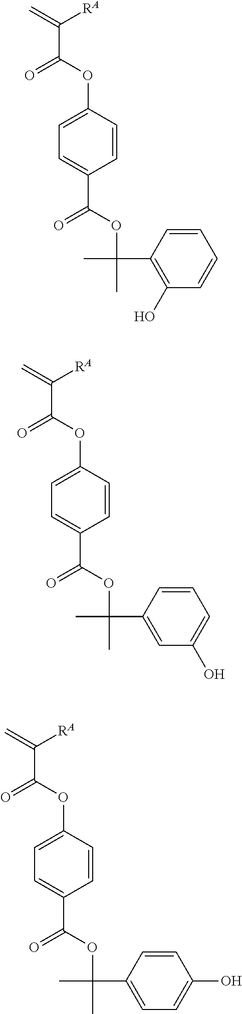

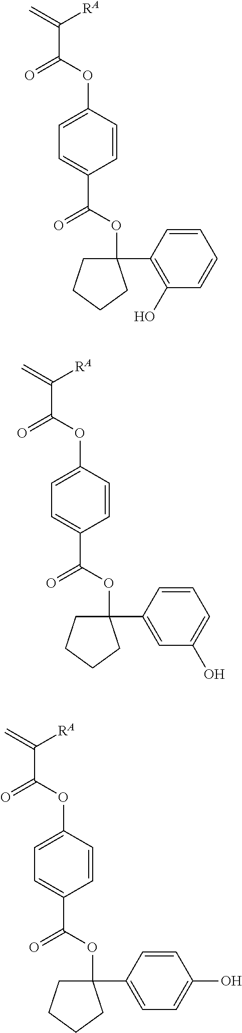

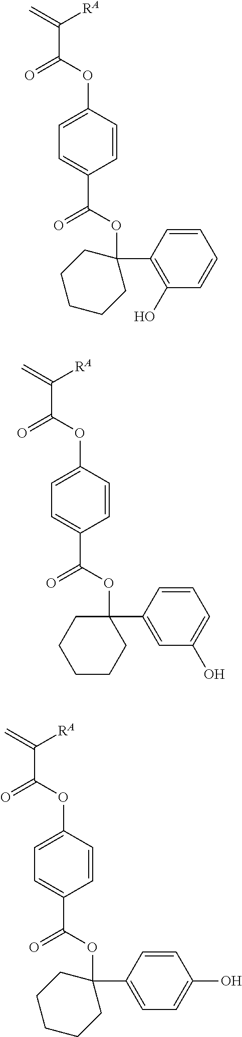

Examples of a monomer to give the repeating unit represented by the formula (a2) (hereinafter, also referred to as repeating unit-a2) include ones shown below, but are not limited thereto. Note that, in the following formulae, R^{A} is as defined above.

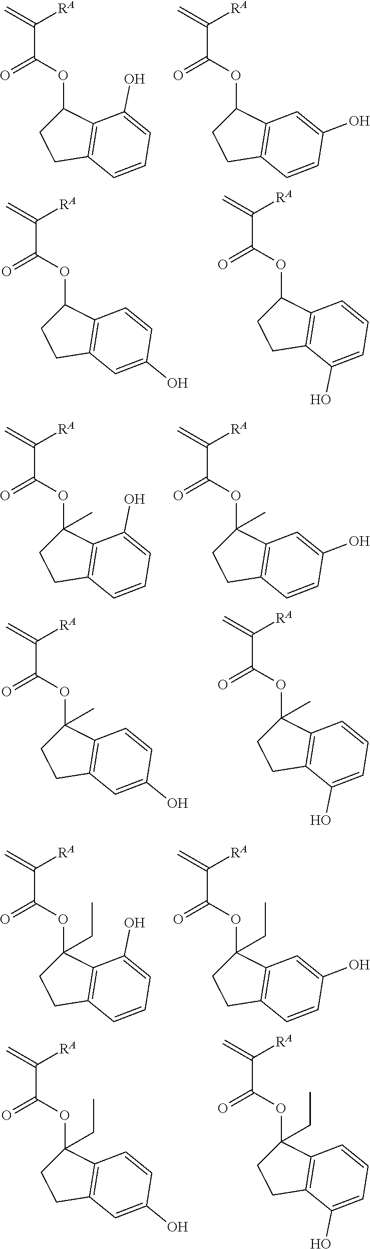

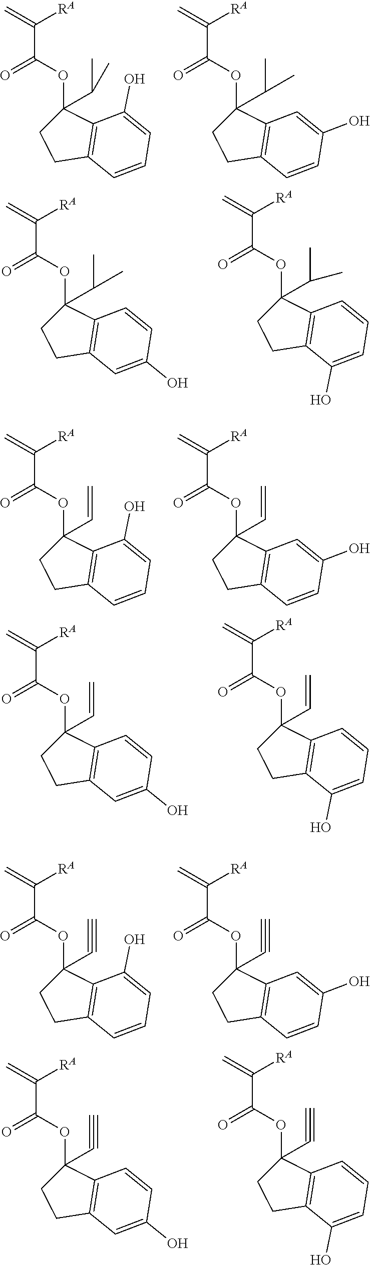

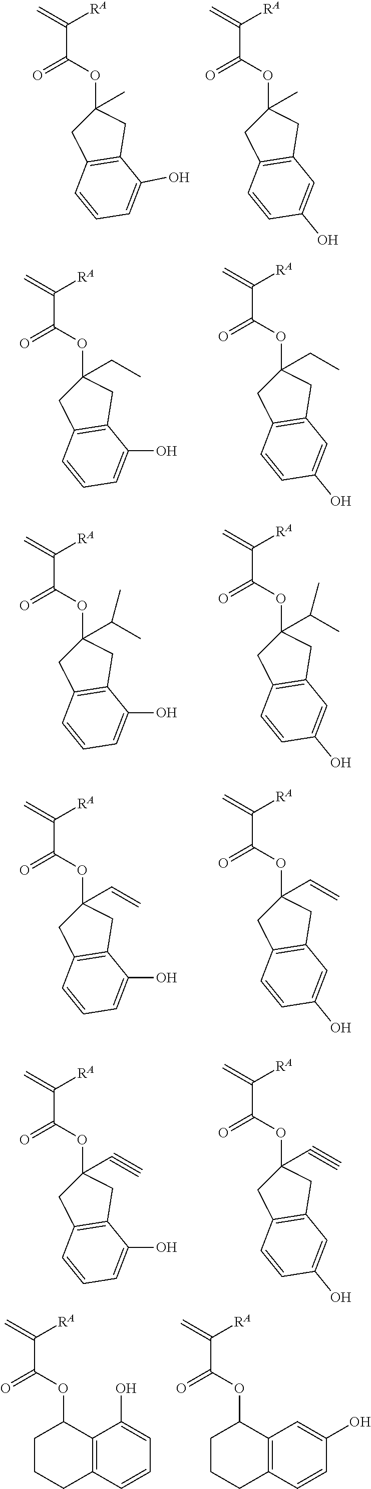

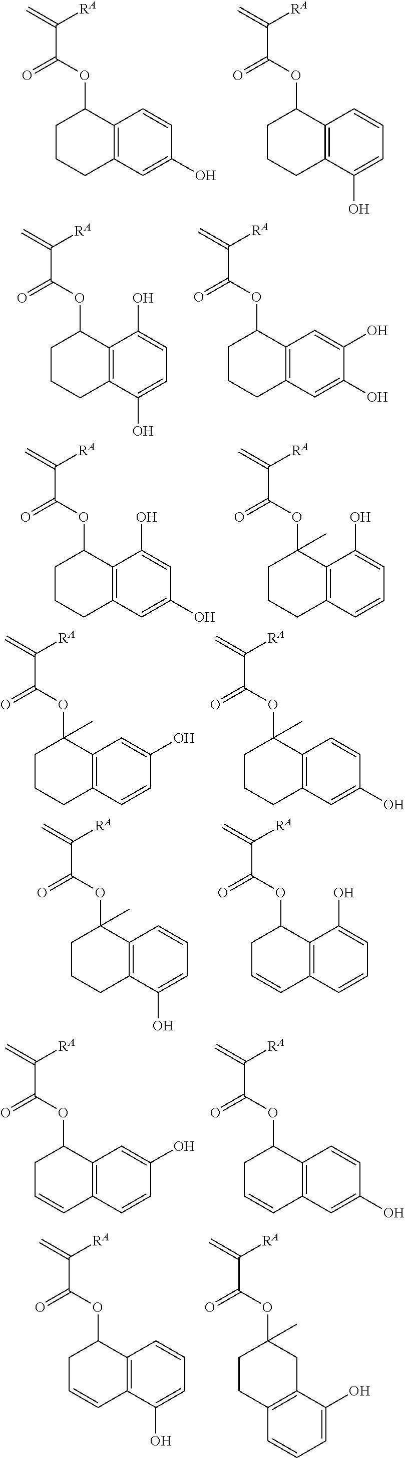

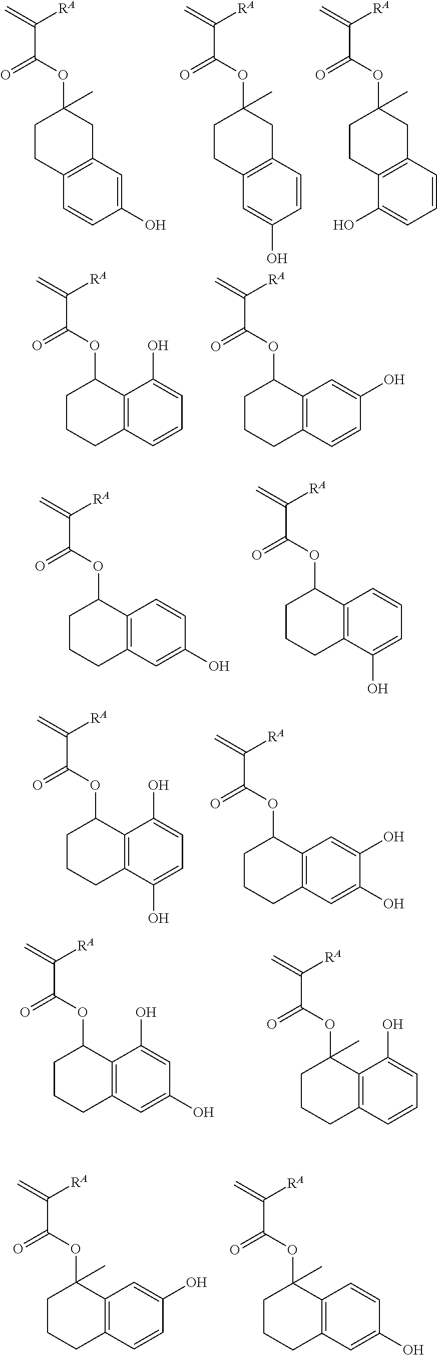

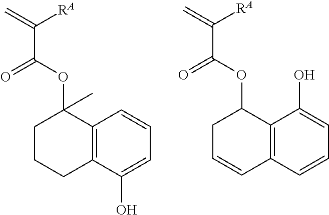

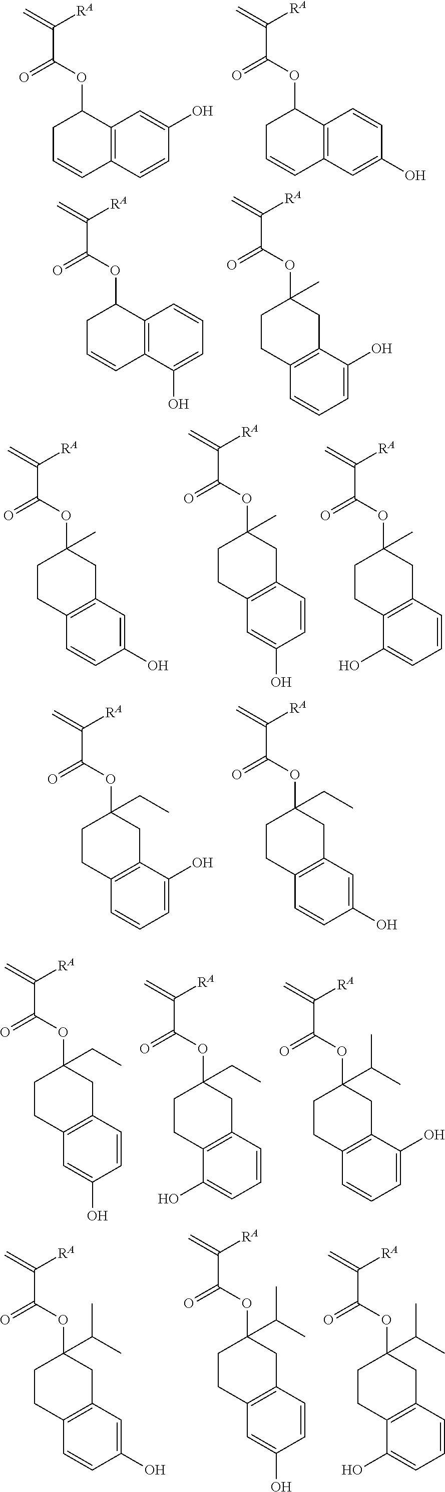

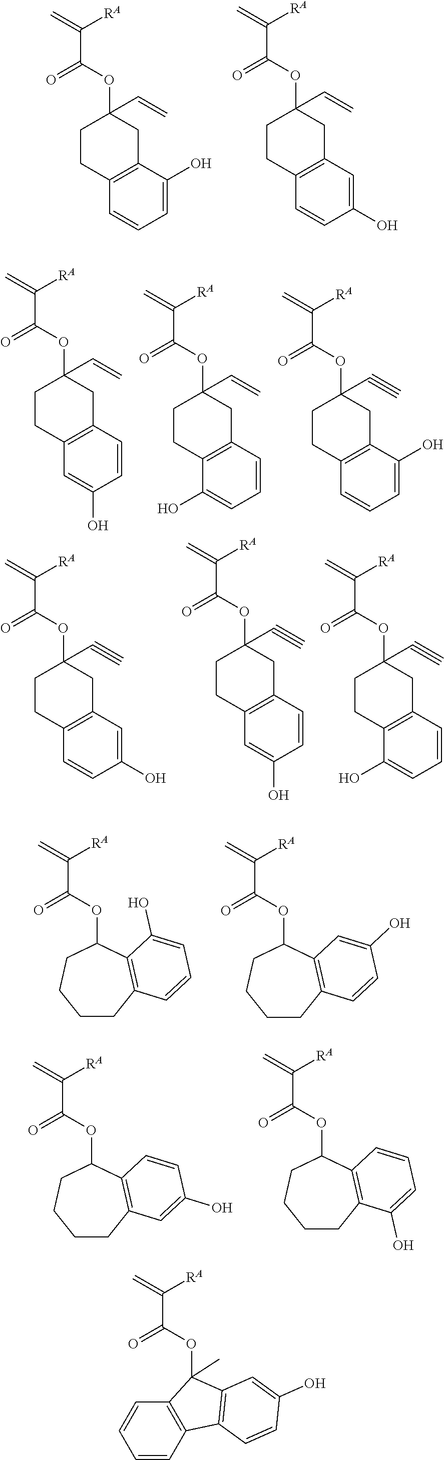

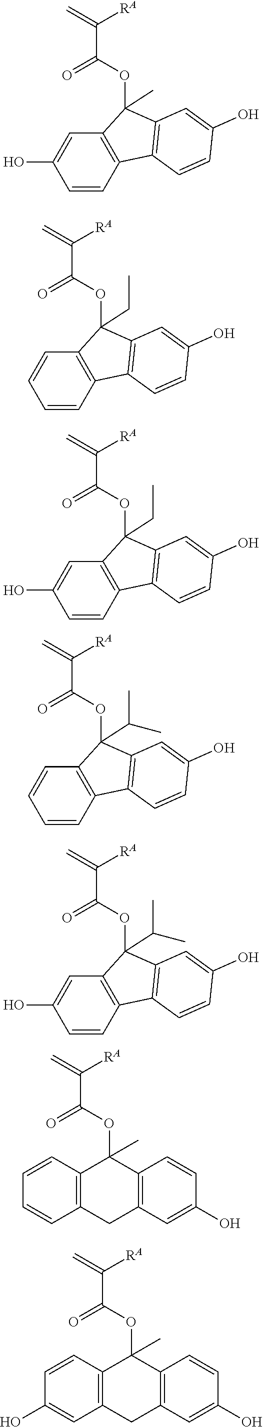

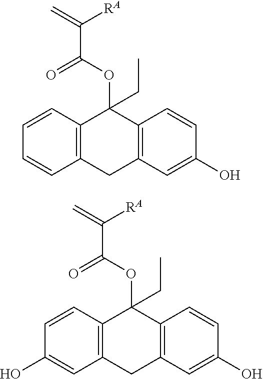

A feature of the present invention is that a repeating unit having an acid-labile group with a phenolic hydroxy group represented by the general formula (a1) or (a2) is contained, and a repeating unit having a conventional acid-labile group, not containing a phenolic hydroxy group, may also be copolymerized.

Examples of such repeating units-ax of the conventional type respectively include those represented by the following formulae (ax1) and (ax2) (also referred to as repeating unit-ax1 and repeating unit-ax2 respectively. The same is true hereinafter.).

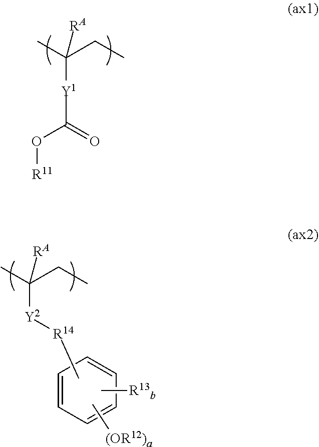

In the formulae (ax1) and (ax2), each R^{A} independently represent a hydrogen atom or a methyl group. Y¹ represents a single bond, a phenylene group, a naphthylene group, or a linking group having 1 to 12 carbon atoms, having an ester bond, an ether bond, or a lactone ring, and optionally having a halogen atom, a nitro group, a hydroxy group, an alkoxy group, an acyloxy group, or an alkoxycarbonyloxy group. Y² represents a single bond, an ester bond, or an amide bond. R¹¹ and R¹² each represent an acid-labile group. R¹³ represents a fluorine atom, a trifluoromethyl group, a cyano group, or an alkyl group having 1 to 6 carbon atoms. R¹⁴ represents a single bond or a linear or branched alkanediyl group having 1 to 6 carbon atoms, part of the carbon atoms optionally being substituted with an ether bond or an ester bond. “a” represents 1 or 2. “b” represents an integer of 0 to 4.

Examples of a monomer to give the repeating unit-ax1 include ones shown below, but are not limited thereto. Note that, in the following formulae, R^{A} and R¹¹ are as defined above.

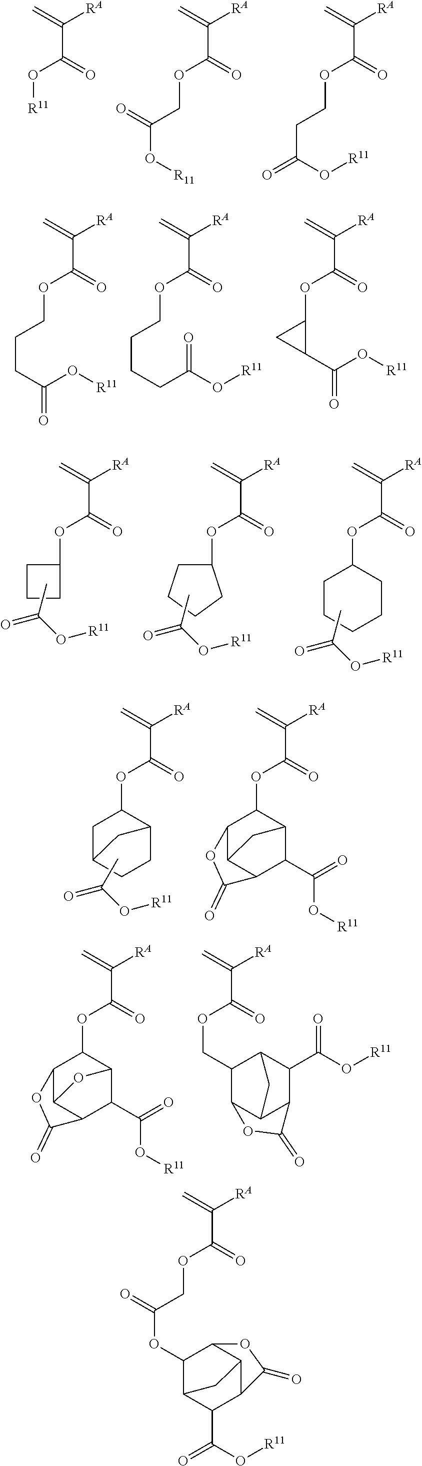

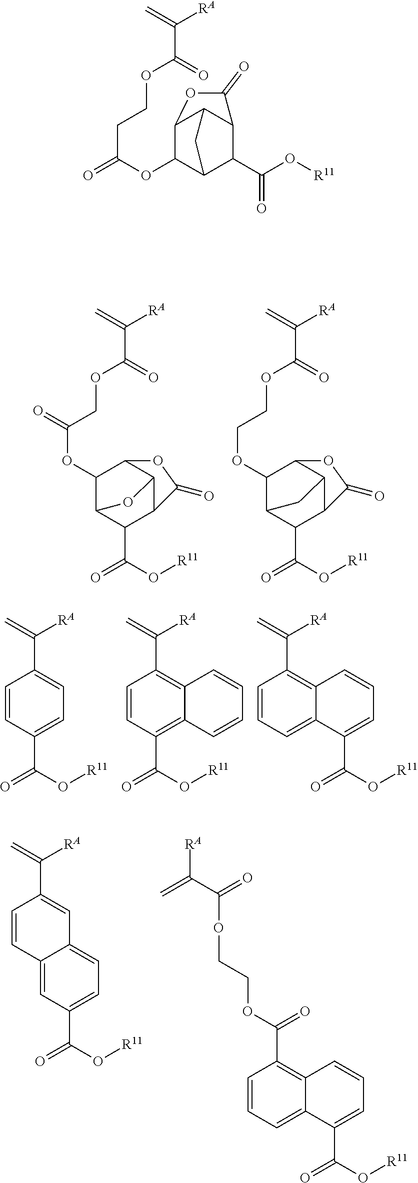

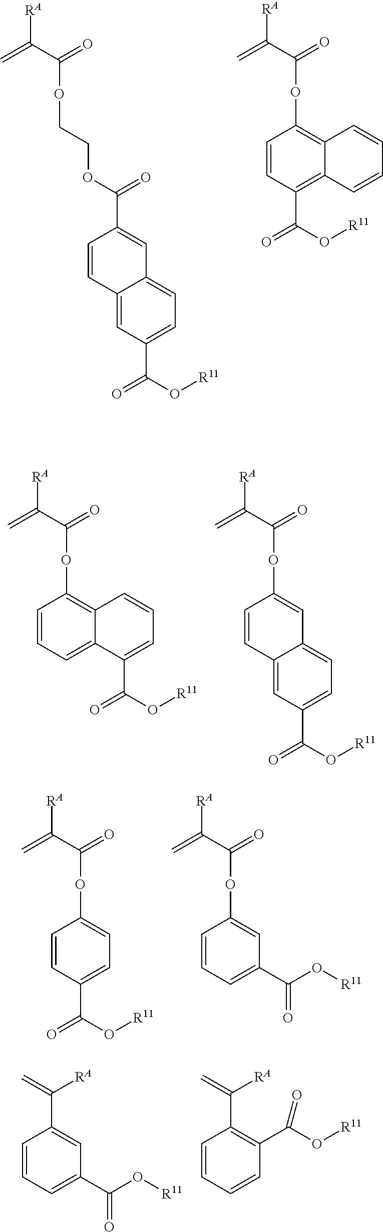

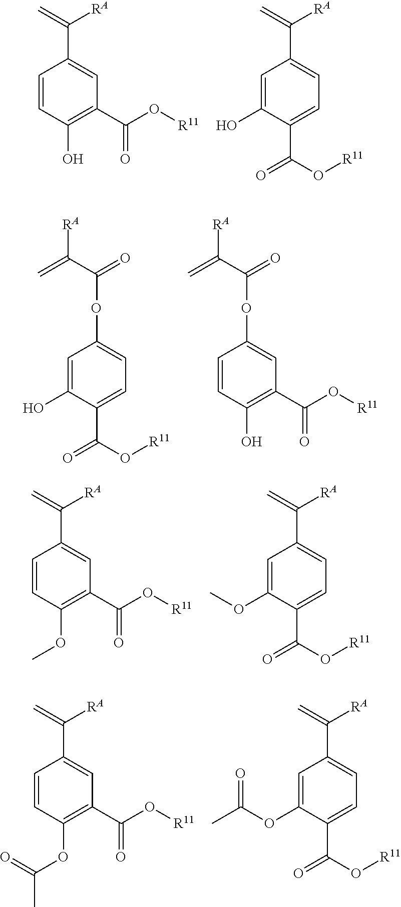

Examples of a monomer to give the repeating unit-ax2 include ones shown below, but are not limited thereto. Note that, in the following formulae, R^{A} and R¹² are as defined above.

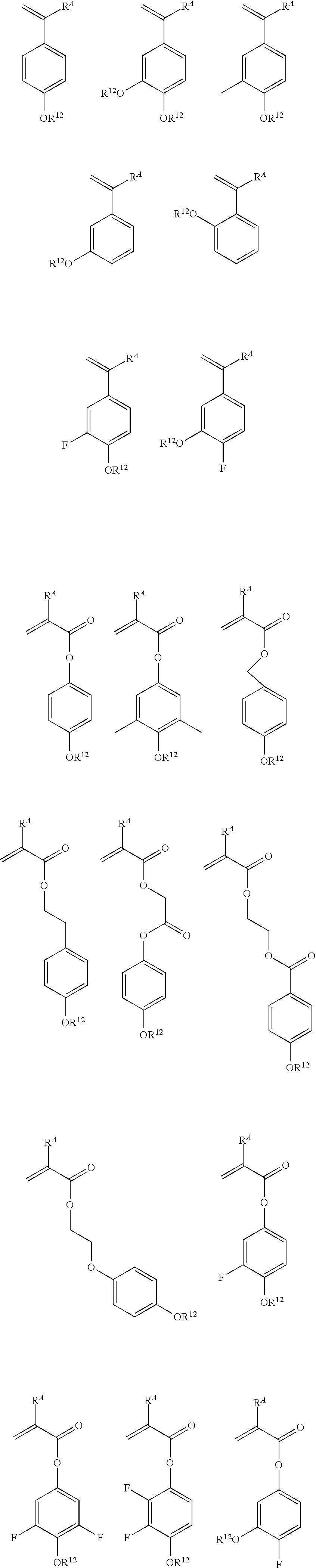

Various acid-labile groups can be selected as the acid-labile groups shown by R¹¹ or R¹². Examples thereof include ones shown by the following formulae (AL-1) to (AL-3).

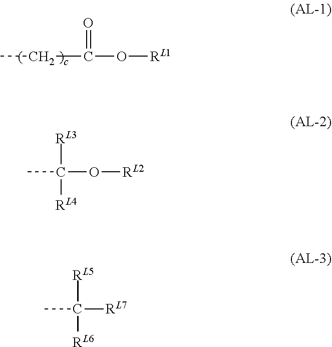

In the formulae, a broken line represents an attachment point.

In the formula (AL-1), “c” represents an integer of 0 to 6. R^{L1} represents: a tertiary hydrocarbyl group having 4 to 20 carbon atoms, preferably 4 to 15 carbon atoms; a trihydrocarbylsilyl group in which hydrocarbyl groups are each a saturated hydrocarbyl group having 1 to 6 carbon atoms; a saturated hydrocarbyl group having 4 to 20 carbon atoms containing a carbonyl group, an ether bond, or an ester bond; or a group shown by the formula (AL-3).

The tertiary hydrocarbyl group shown by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, a 2-methyl-2-adamantyl group, etc. Examples of the trialkylsilyl group include a trimethylsilyl group, a triethylsilyl group, a dimethyl-tert-butylsilyl group, etc. The saturated hydrocarbyl group containing a carbonyl group, an ether bond, or an ester bond may be linear, branched, or cyclic, and is preferably cyclic. Specific examples thereof include a 3-oxocyclohexyl group, a 4-methyl-2-oxooxan-4-yl group, a 5-methyl-2-oxooxolan-5-yl group, a 2-tetrahydropyranyl group, a 2-tetrahydrofuranyl group, etc.

Examples of the acid-labile group shown by the formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1, 1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, a 2-tetrahydrofuranyloxycarbonylmethyl group, etc.

Other examples of the acid-labile group shown by the formula (AL-1) include groups shown by the following formulae (AL-1)-1 to (AL-1)-10.

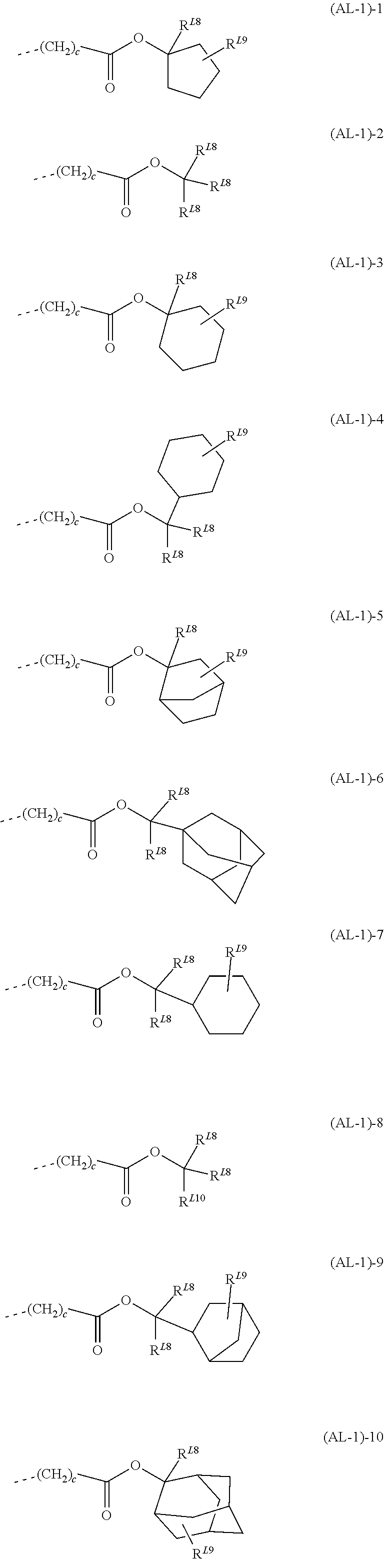

In the formulae, a broken line represents an attachment point.

In the formulae (AL-1)-1 to (AL-1)-10, “c” is as defined above. Each R^{L8} independently represents a saturated hydrocarbyl group having 1 to 10 carbon atoms or an aryl group having 6 to 20 carbon atoms. R^{L9} represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl groups may be linear, branched, or cyclic.

In the formula (AL-2), R^{L2} and R^{L3} each independently represent a hydrogen atom or a saturated hydrocarbyl group having 1 to 18 carbon atoms, preferably 1 to 10 carbon atoms. The saturated hydrocarbyl group may be linear, branched, or cyclic. Specific examples thereof include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, etc.

In the formula (AL-2), R^{L4} represents a hydrocarbyl group having 1 to 18 carbon atoms, preferably 1 to 10 carbon atoms, and optionally contains a heteroatom. The hydrocarbyl group may be saturated or unsaturated, and may be linear, branched, or cyclic. Examples of the hydrocarbyl group include saturated hydrocarbyl groups each having 1 to 18 carbon atoms, etc., and some of hydrogen atoms thereof may be substituted with a hydroxy group, an alkoxy group, an oxo group, an amino group, an alkylamino group, or the like. Examples of such substituted saturated hydrocarbyl groups include ones shown below, etc.

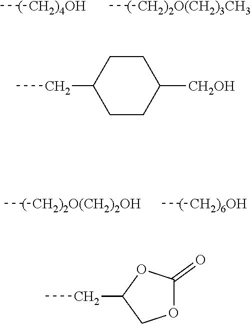

In the formulae, a broken line represents an attachment point.

R^{L2} and R^{L3}, R^{L2} and R^{L4}, or R^{L3} and R^{L4} optionally bond with each other to form a ring together with a carbon atom bonded therewith, or together with the carbon atom and an oxygen atom. In this case, R^{L2} and R^{L3}, R^{L2} and R^{L4}, or R^{L3} and R^{L4}, involved in the ring formation, each independently represent an alkanediyl group having 1 to 18 carbon atoms, preferably 1 to 10 carbon atoms. The number of carbon atoms in the ring obtained by bonding these is preferably 3 to 10, more preferably 4 to 10.

Examples of the linear and branched acid-labile groups shown by the formula (AL-2) include ones shown by the following formulae (AL-2)-1 to (AL-2)-69, but are not limited thereto. Note that, in the following formulae, each broken line represents an attachment point.

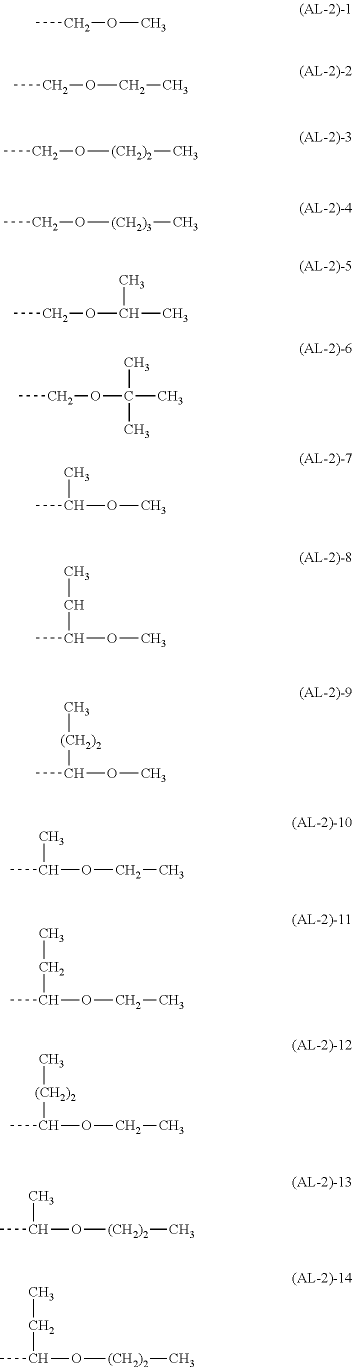

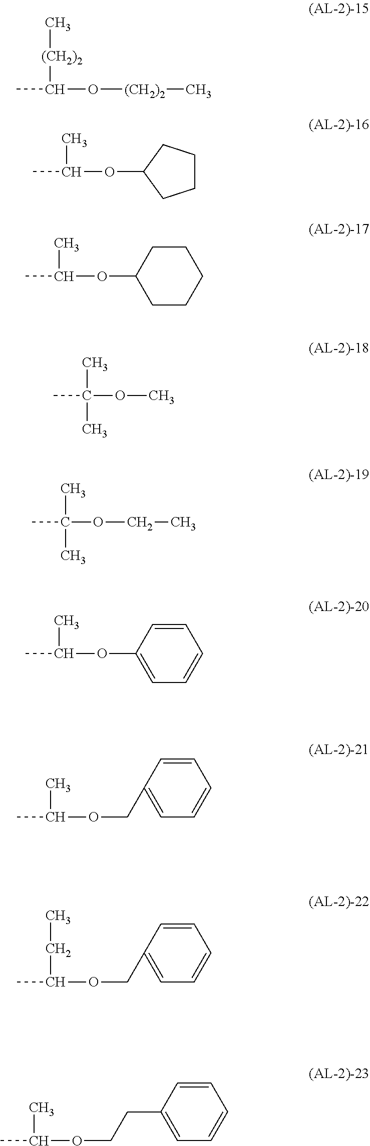

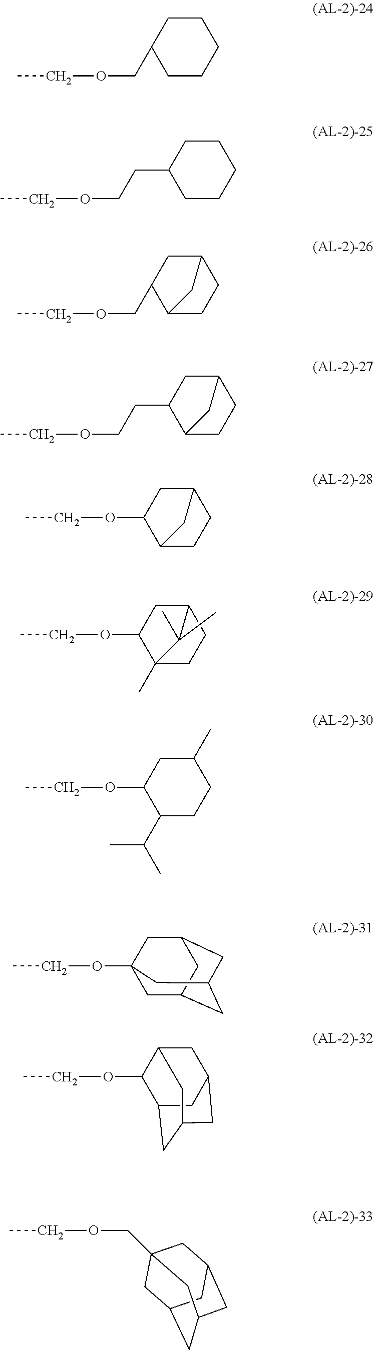

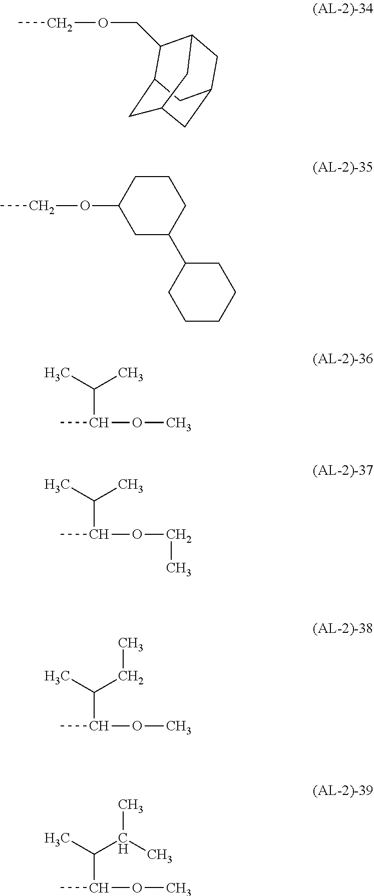

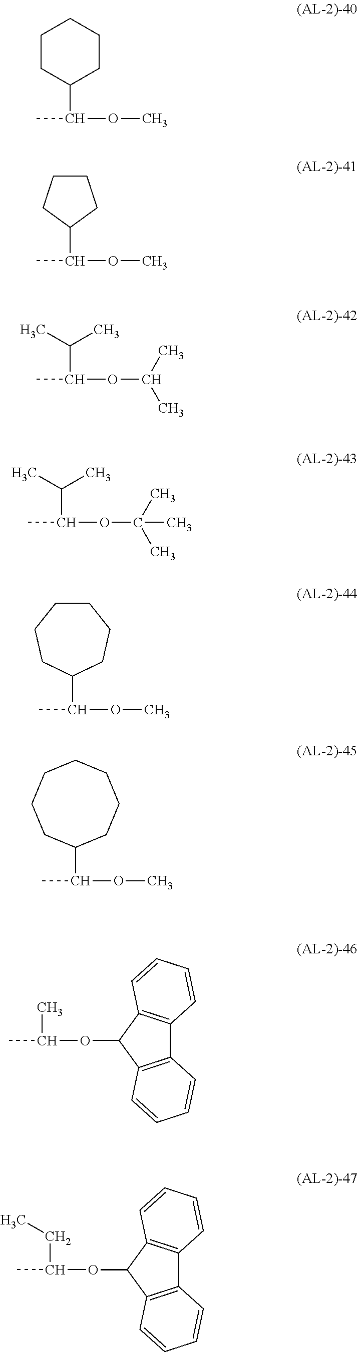

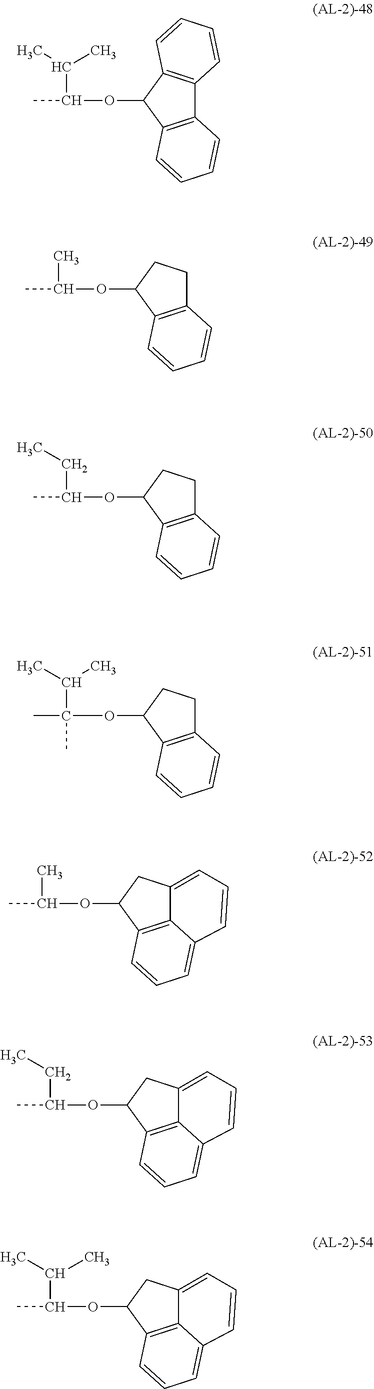

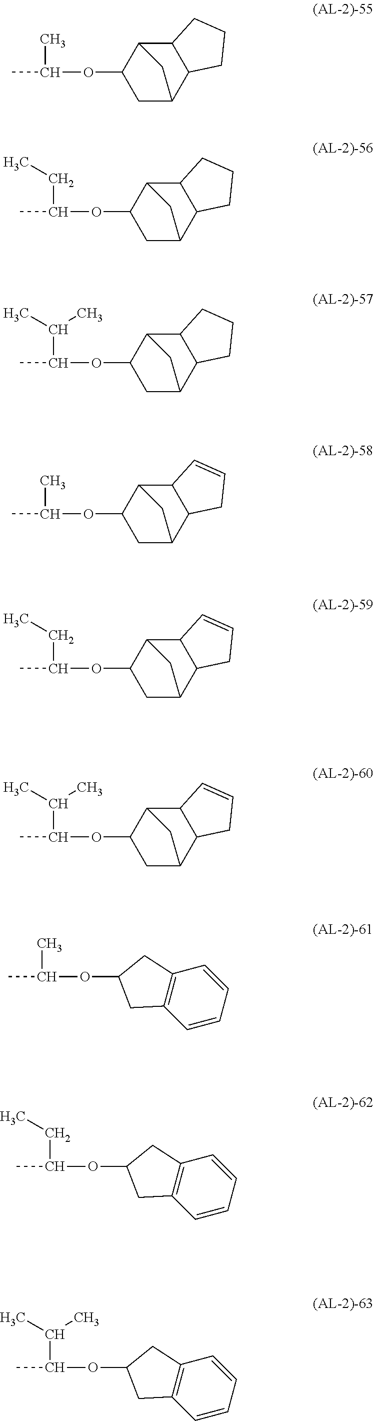

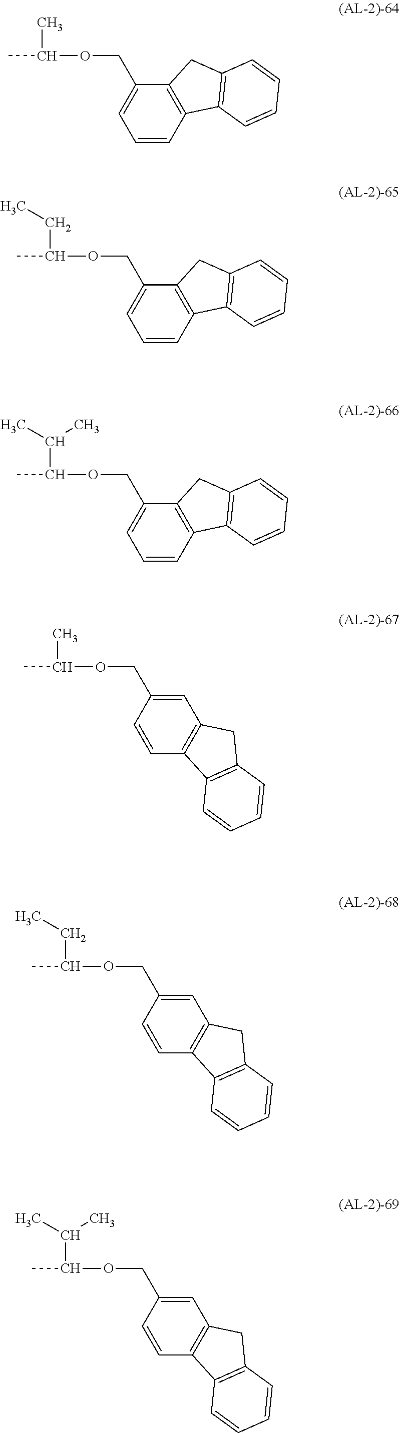

Examples of the cyclic acid-labile group shown by the formula (AL-2) include a tetrahydrofuran-2-yl group, a 2-methyltetrahydrofuran-2-yl group, a tetrahydropyran-2-yl group, a 2-methyltetrahydropyran-2-yl group, etc.

In addition, the examples of the acid-labile groups include groups shown by the following formula (AL-2a) or (AL-2b). The acid-labile group may crosslink the base polymer intermolecularly or intramolecularly.

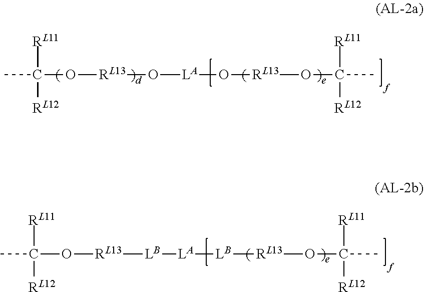

In the formulae, a broken line represents an attachment point.

In the formulae (AL-2a) and (AL-2b), R^{L11} and R^{L12} each independently represent a hydrogen atom or a saturated hydrocarbyl group having 1 to 8 carbon atoms. The saturated hydrocarbyl group may be linear, branched, or cyclic. Alternatively, R^{L11} and R^{L12} may bond with each other to form a ring together with a carbon atom bonded therewith. In this case, R^{L11} and R^{L12} each independently represent an alkanediyl group having 1 to 8 carbon atoms. Each R^{L13} independently represents a saturated hydrocarbylene group having 1 to 10 carbon atoms. The saturated hydrocarbylene group may be linear, branched, or cyclic. “d” and “e” each independently represent an integer of 0 to 10, preferably an integer of 0 to 5. “f” represents an integer of 1 to 7, preferably an integer of 1 to 3.

In the formula (AL-2a) or (AL-2b), L^{A} represents an aliphatic saturated hydrocarbon group having a valency of (f+1) with 1 to 50 carbon atoms, an alicyclic saturated hydrocarbon group having a valency of (f+1) with 3 to 50 carbon atoms, an aromatic hydrocarbon group having a valency of (f+1) with 6 to 50 carbon atoms, or a heterocyclic group having a valency of (f+1) with 3 to 50 carbon atoms. Some of the carbon atoms of these groups may be substituted with a heteroatom-containing group, and some hydrogen atoms bonded to the carbon atoms of these groups may be substituted with a hydroxy group, a carboxy group, an acyl group, or a fluorine atom. L^{A} is preferably an arylene group having 6 to 30 carbon atoms, a saturated hydrocarbon group, such as a saturated hydrocarbylene group, a trivalent saturated hydrocarbon group, and a tetravalent saturated hydrocarbon group each of which have 1 to 20 carbon atoms, or the like. The saturated hydrocarbon groups may be linear, branched, or cyclic. L^{B} represents —C(═O)—O—, —NH—C(═O)—O—, or —NH—C(═O)—NH—.

Examples of the crosslinking acetal groups shown by the formulae (AL-2a) and (AL-2b) include groups shown by the following formulae (AL-2)-70 to (AL-2)-77, etc.

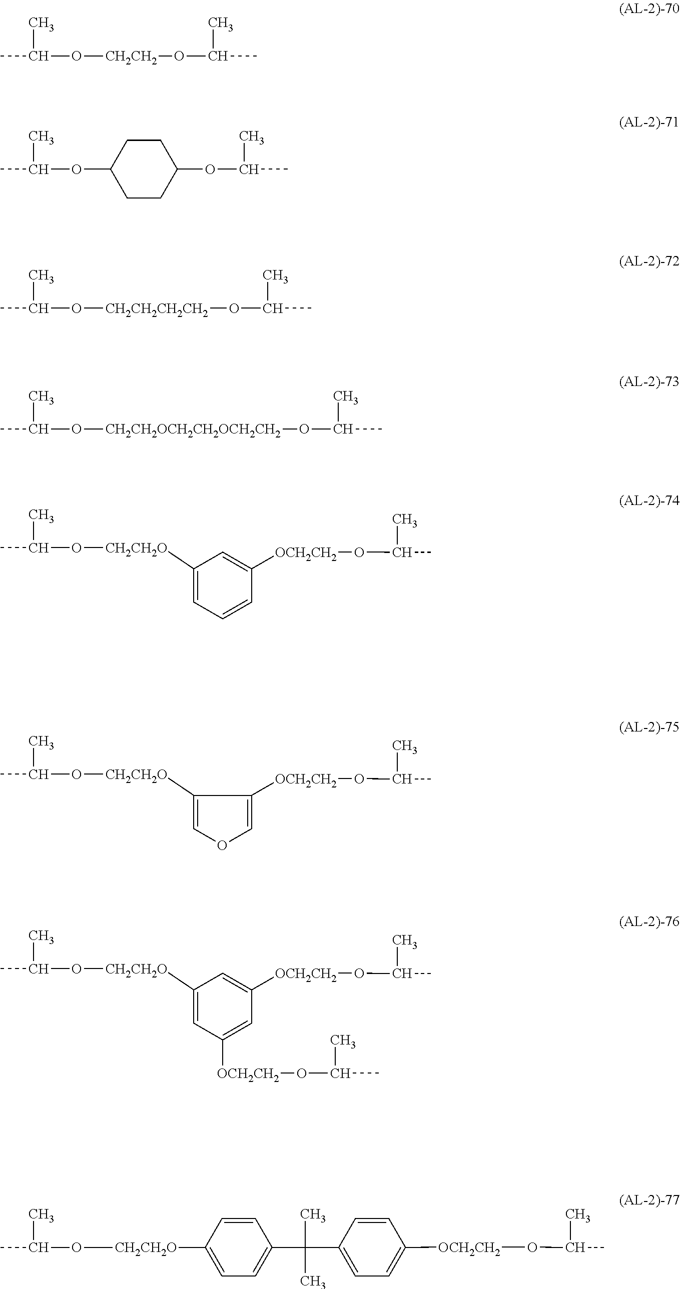

In the formulae, a broken line represents an attachment point.

In the formula (AL-3), R, R, and R each independently represent a hydrocarbyl group having 1 to 20 carbon atoms, and optionally contain a heteroatom, such as an oxygen atom, a sulfur atom, a nitrogen atom, and a fluorine atom. The hydrocarbyl group may be saturated or unsaturated, and may be linear, branched, or cyclic. Specific examples thereof include alkyl groups having 1 to 20 carbon atoms, cyclic saturated hydrocarbyl groups having 3 to 20 carbon atoms, alkenyl groups having 2 to 20 carbon atoms, cyclic unsaturated hydrocarbyl groups having 3 to 20 carbon atoms, aryl groups having 6 to 10 carbon atoms, etc. Alternatively, R^{L5} and R^{L6}, R^{L5} and R^{L7}, or R^{L6} and R^{L7}, may bond with each other to form an alicyclic group having 3 to 20 carbon atoms, together with a carbon atom bonded therewith.

Examples of the group shown by the formula (AL-3) include a tert-butyl group, a 1,1-diethylpropyl group, a 1-ethylnorbornyl group, a 1-methylcyclopentyl group, a 1-isopropylcyclopentyl group, a 1-ethylcyclopentyl group, a 1-methylcyclohexyl group, a 2-(2-methyl) adamantyl group, a 2-(2-ethyl) adamantyl group, a tert-pentyl group, etc.

The examples of the group shown by the formula (AL-3) also include groups shown by the following formulae (AL-3)-1 to (AL-3)-19.

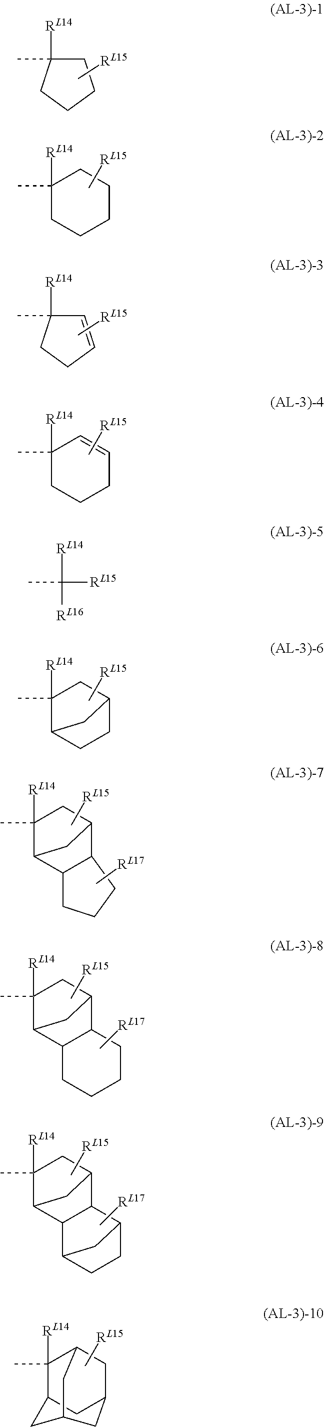

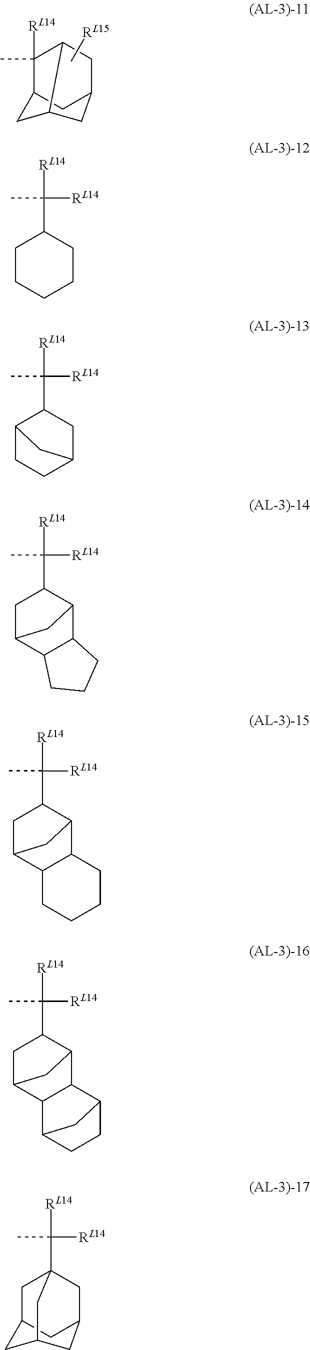

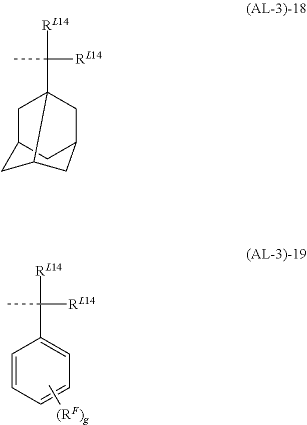

In the formulae, a broken line represents an attachment point.

In the formulae (AL-3)-1 to (AL-3)-19, each R^{L14} independently represents a hydrogen atom, a saturated hydrocarbyl group having 1 to 8 carbon atoms, or an aryl group having 6 to 20 carbon atoms. R^{L15} and R^{L17} each independently represent a hydrogen atom or a saturated hydrocarbyl group having 1 to 20 carbon atoms. R^{L16} represents an aryl group having 6 to 20 carbon atoms. The saturated hydrocarbyl groups may be linear, branched, or cyclic. The aryl groups are preferably a phenyl group or the like. RE represents a fluorine atom or a trifluoromethyl group. “g” represents an integer of 1 to 5.

Examples of the acid-labile group further include groups shown by the following formula (AL-3)-20 or (AL-3)-21. The acid-labile group may crosslink the polymer intramolecularly or intermolecularly.

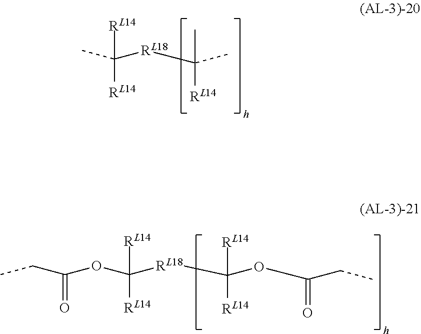

In the formulae, a broken line represents an attachment point.

In the formulae (AL-3)-20 and (AL-3)-21, R^{L14} is as defined above. R^{L18} represents a saturated hydrocarbylene group having a valency of (h+1) and having 1 to 20 carbon atoms or represents an arylene group having a valency of (h+1) and having 6 to 20 carbon atoms, and optionally contains a heteroatom such as an oxygen atom, a sulfur atom, or a nitrogen atom. The saturated hydrocarbylene group may be linear, branched, or cyclic. “h” represents an integer of 1 to 3.

Examples of a monomer to give the repeating unit containing the acid-labile group shown by the formula (AL-3) include (meth)acrylate having an exo-form structure shown by the following formula (AL-3)-22.

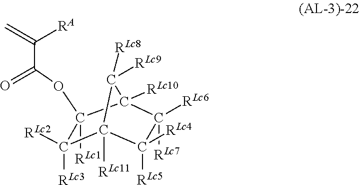

In the formula (AL-3)-22, R^{A} is as defined above. R^{Lc1} represents a saturated hydrocarbyl group having 1 to 8 carbon atoms or an aryl group having 6 to 20 carbon atoms and optionally containing a substituent. The saturated hydrocarbyl group may be linear, branched, or cyclic. R^{Lc2} to R^{Lc11} each independently represent a hydrogen atom or a hydrocarbyl group having 1 to 15 carbon atoms and optionally containing a heteroatom. Examples of the heteroatom include an oxygen atom, etc. Examples of the hydrocarbyl group include alkyl groups having 1 to 15 carbon atoms, aryl groups having 6 to 15 carbon atoms, etc. R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10} may bond with each other to form a ring together with a carbon atom bonded therewith. In this case, a group involved in the bonding is a hydrocarbylene group having 1 to 15 carbon atoms and optionally containing a heteroatom. Alternatively, R^{Lc2} and R^{Lc11}, R^{Lc8} and R^{Lc11}, or R^{Lc4} and R^{Lc6}, all pairs of which are bonded to carbon atoms next to each other, may directly bond with each other to form a double bond. Note that the formula also represents an enantiomer.

Examples of the monomer shown by the formula (AL-3)-22 to give the repeating unit include ones disclosed in JP 2000-327633 A, etc. Specific examples thereof include ones shown below, but are not limited thereto. Note that, in the following formulae, R^{A} is as defined above.

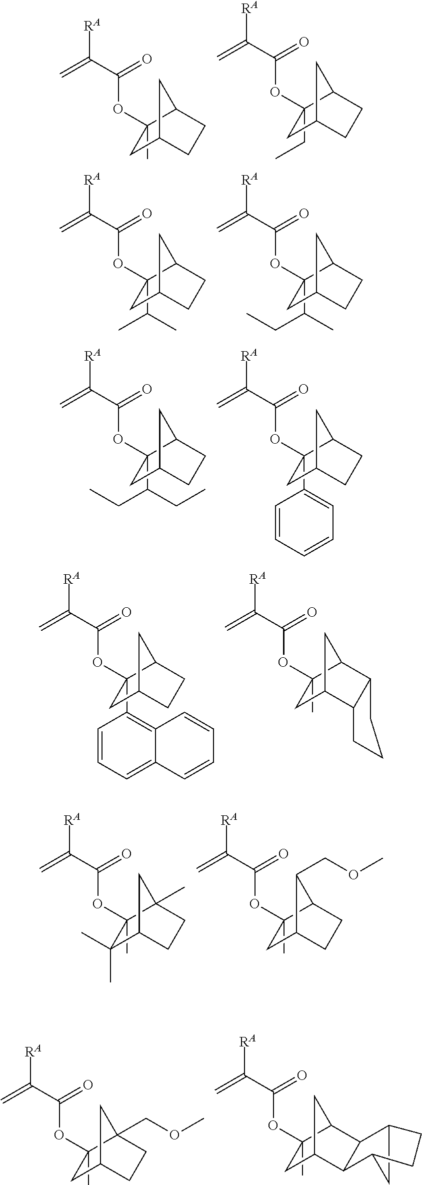

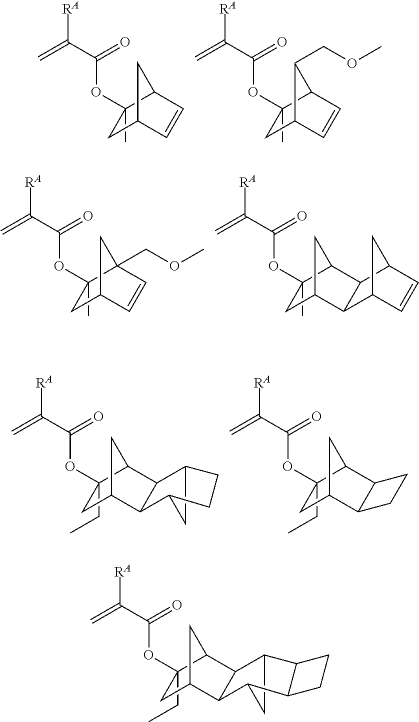

Other examples of the monomer to give the repeating unit containing the acid-labile group shown by the formula (AL-3) include (meth)acrylate containing a furandiyl group, a tetrahydrofurandiyl group, or an oxanorbornanediyl group, as shown by the following formula (AL-3)-23.

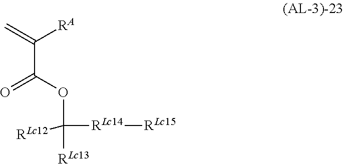

In the formula (AL-3)-23, R^{A} is as defined above. R^{Lc12} and R^{Lc13} each independently represent a hydrocarbyl group having 1 to 10 carbon atoms. R^{Lc12} and R^{Lc13} may bond with each other to form an alicyclic group together with a carbon atom bonded therewith. R^{Lc14} represents a furandiyl group, a tetrahydrofurandiyl group, or an oxanorbornanediyl group. R^{Lc15} represents a hydrogen atom, or a hydrocarbyl group having 1 to 10 carbon atoms and optionally containing a heteroatom. The hydrocarbyl groups may be linear, branched, or cyclic. Specific examples thereof include a saturated hydrocarbyl group having 1 to 10 carbon atoms, etc.

Examples of the monomer shown by the formula (AL-3)-23 to give the repeating unit include ones shown below, but are not limited thereto. Note that, in the following formulae, R^{A} is as defined above, Ac represents an acetyl group, and Me represents a methyl group.

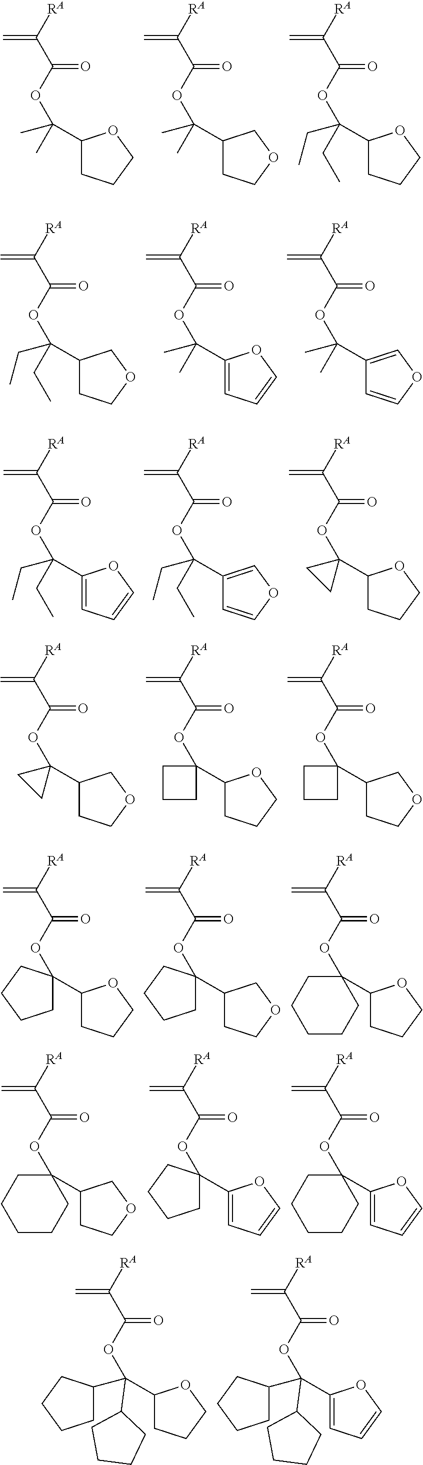

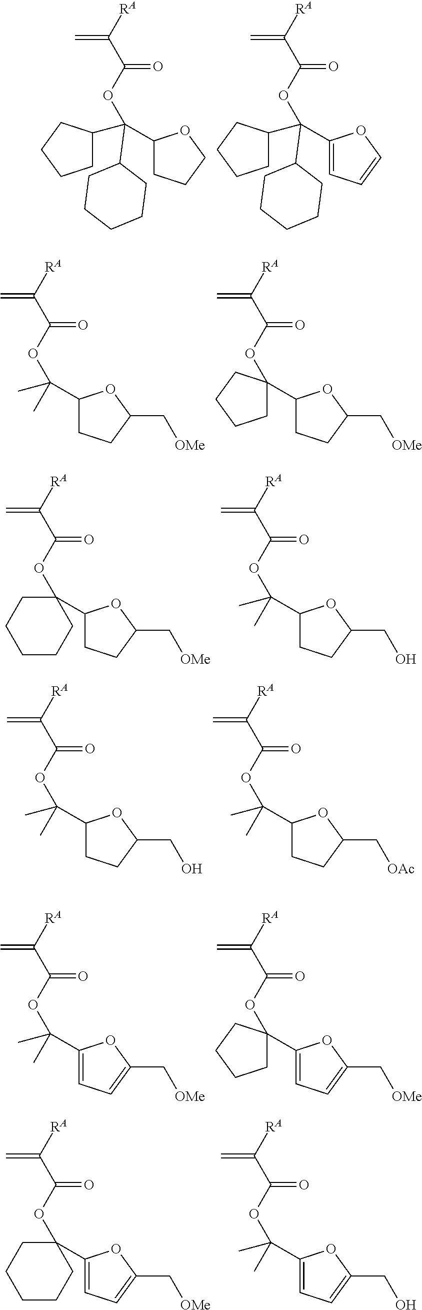

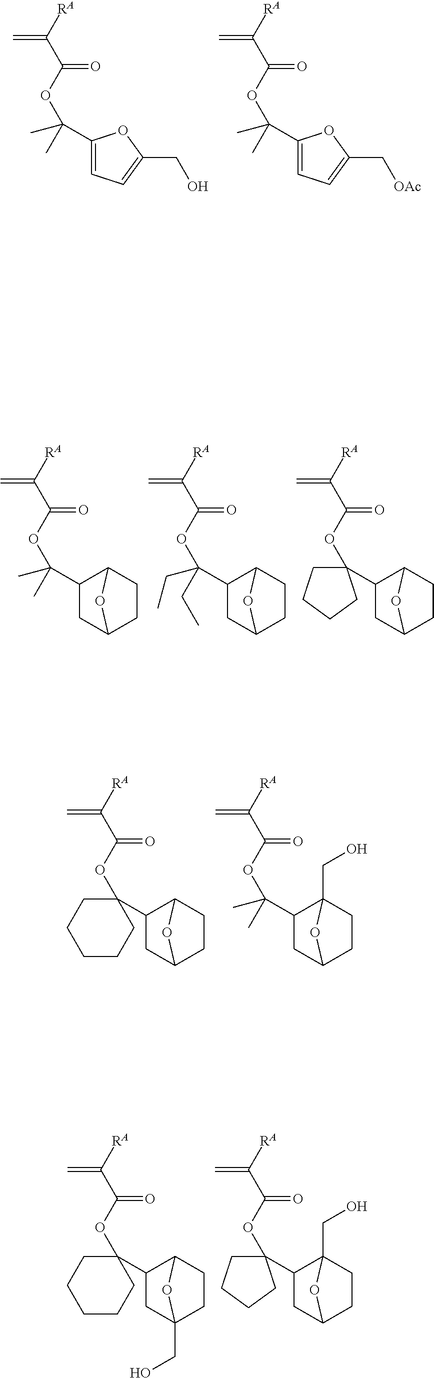

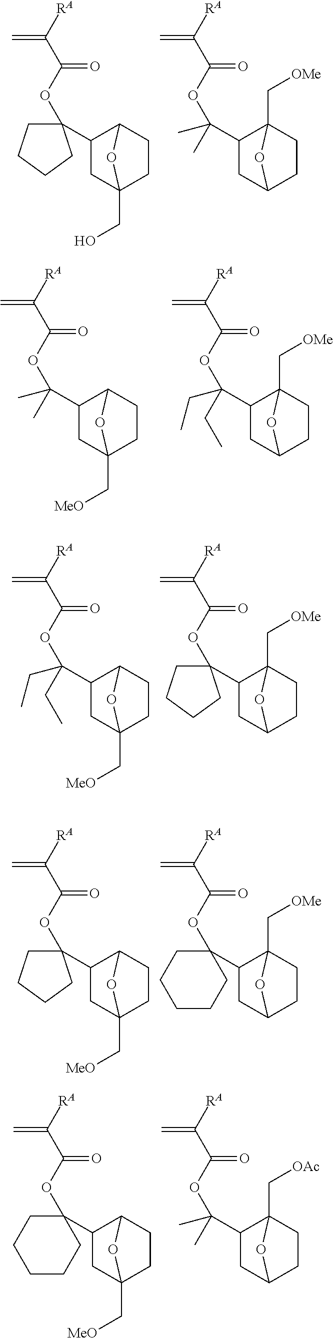

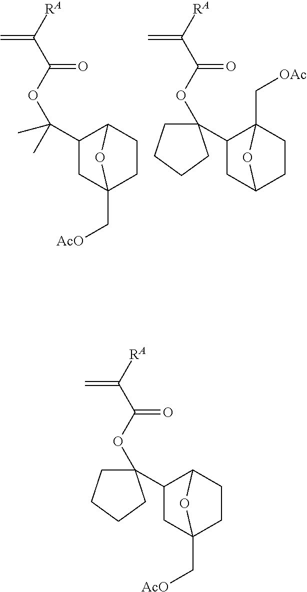

The base polymer preferably further contains a repeating unit-b having at least one acid-generating moiety selected from repeating units represented by the following formulae (b1) to (b5).

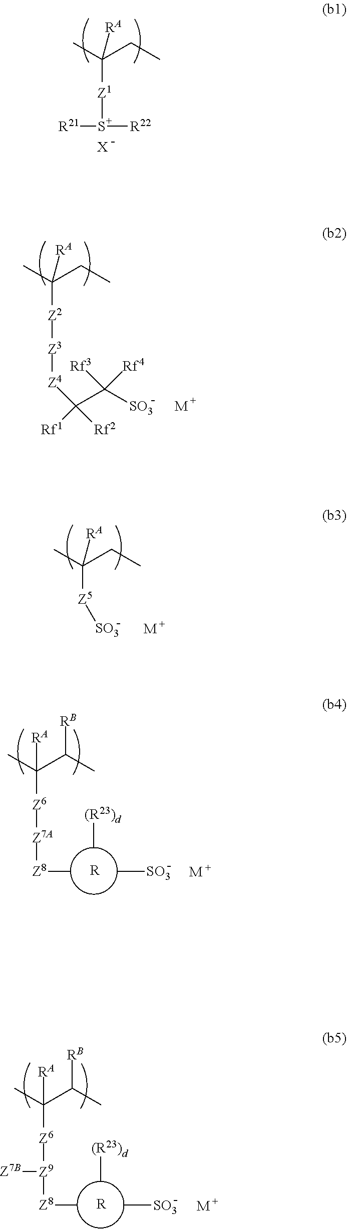

In the formulae, each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; 25 represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z⁷⁸ represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

Examples of a monomer to give the repeating unit-b1 include ones shown below, but are not limited thereto. Note that, in the following formulae, R^{A} is as defined above.

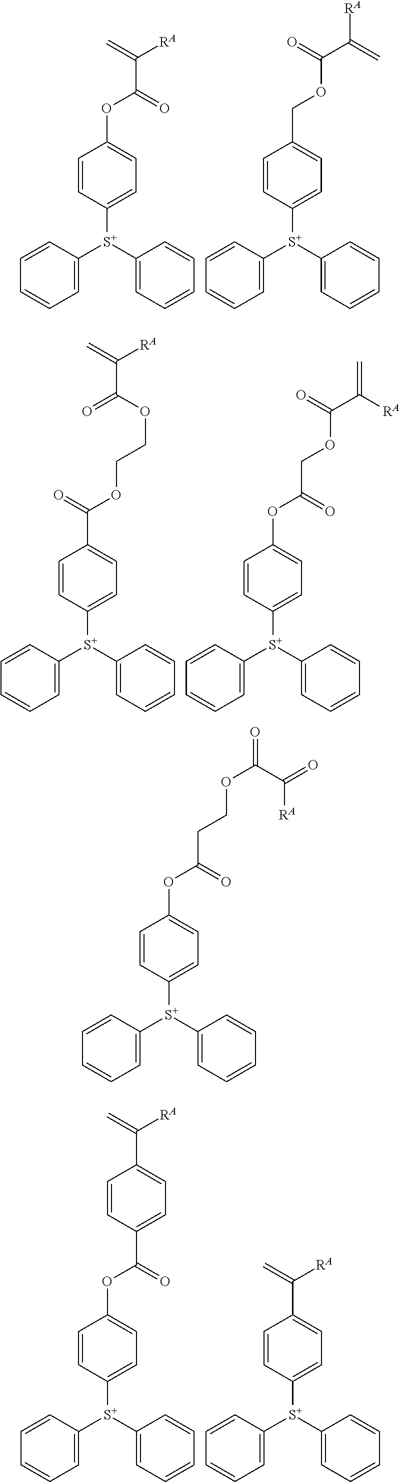

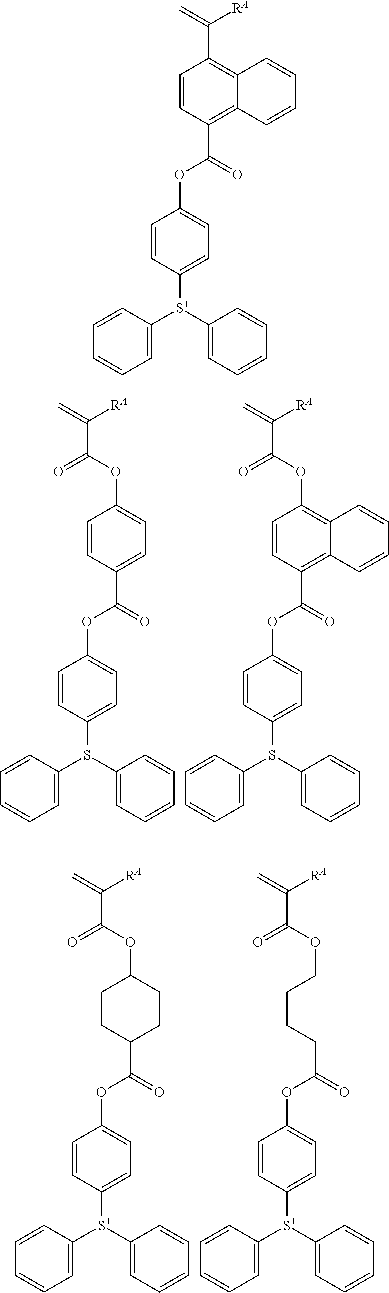

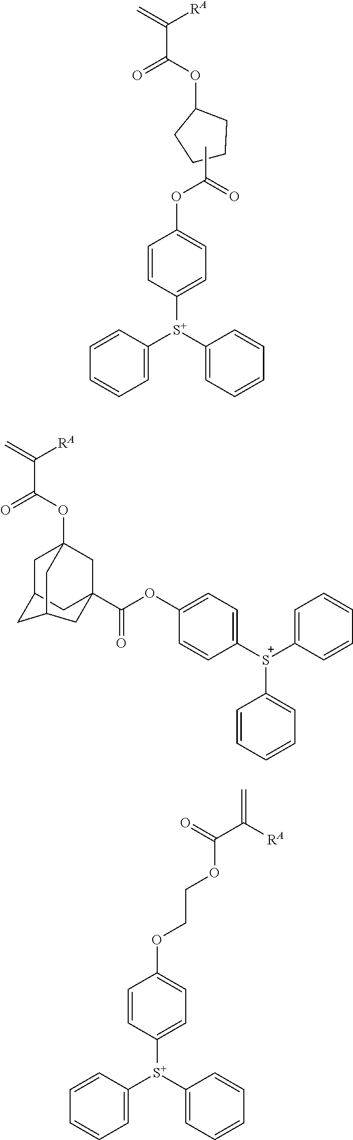

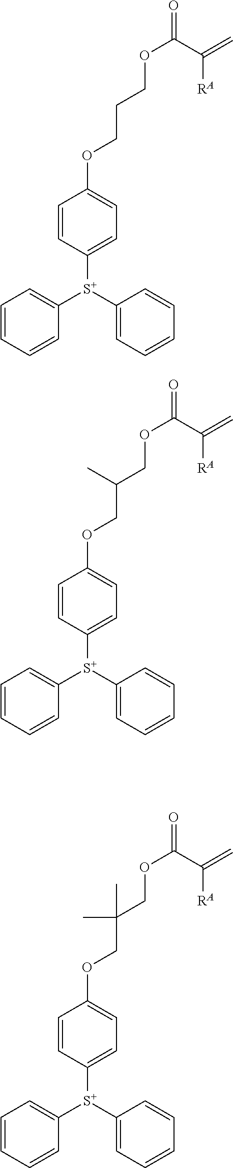

In the formula (b1), X⁻ represents a non-nucleophilic counter ion. Examples of the non-nucleophilic counter ion include halide ions, such as chloride and bromide ions; fluoroalkylsulfonate ions, such as triflate, 1, 1, 1-trifluoroethanesulfonate, and nonafluorobutanesulfonate ions; arylsulfonate ions, such as tosylate, benzenesulfonate, 4-fluorobenzenesulfonate, and 1, 2, 3, 4, 5-pentafluorobenzenesulfonate ions; alkylsulfonate ions, such as mesylate and butanesulfonate ions; imidic acid ions, such as bis(trifluoromethylsulfonyl)imide, bis(perfluoroethylsulfonyl)imide and bis(perfluorobutylsulfonyl)imide ions; and methide acid ions such as tris (trifluoromethylsulfonyl) methide and tris (perfluoroethylsulfonyl) methide ions.

Examples of the non-nucleophilic counter ion further include: sulfonate ions represented by the following formula (b1-1), having a substituting fluorine atom at α position; sulfonate ions represented by the following formula (b1-2), having a substituting fluorine atom at α position and having a substituting trifluoromethyl group at β position; etc.

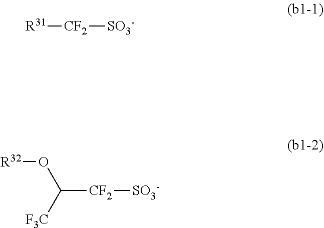

In the formula (b1-1), R³¹ represents a hydrogen atom, an alkyl group having 1 to 20 carbon atoms, an alkenyl group having 2 to 20 carbon atoms, or an aryl group having 6 to 20 carbon atoms, and optionally contains an ether bond, an ester bond, a carbonyl group, a lactone ring, or a fluorine atom. The alkyl group and the alkenyl group may be linear, branched, or cyclic.

In the formula (b1-2), R³² represents a hydrogen atom, an alkyl group having 1 to 30 carbon atoms, an acyl group having 2 to 30 carbon atoms, an alkenyl group having 2 to 20 carbon atoms, an aryl group having 6 to 20 carbon atoms, or an aryloxy group having 6 to 20 carbon atoms, and optionally contains an ether bond, an ester bond, a carbonyl group, or a lactone ring. The alkyl group, acyl group, and alkenyl group may be linear, branched, or cyclic.

Examples of the non-nucleophilic counter ion also include an anion containing bromine or iodine, represented by the following formula (b1-3).

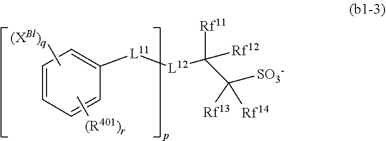

Specific examples of the anion shown in the formula (b1-3) include the following.

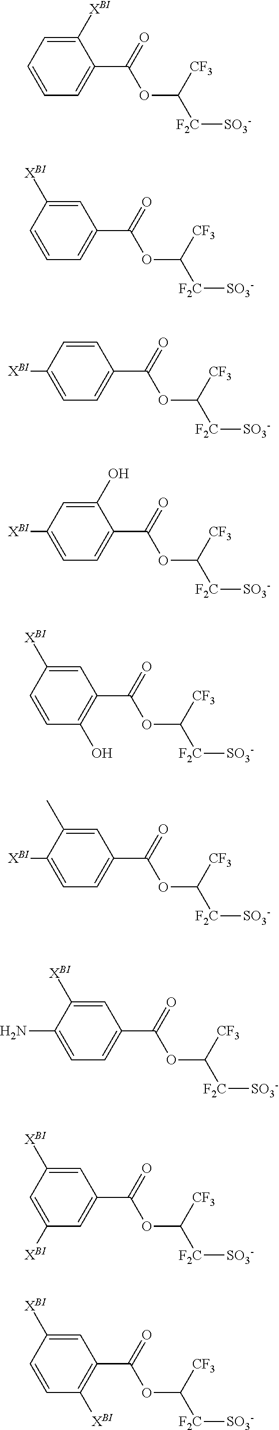

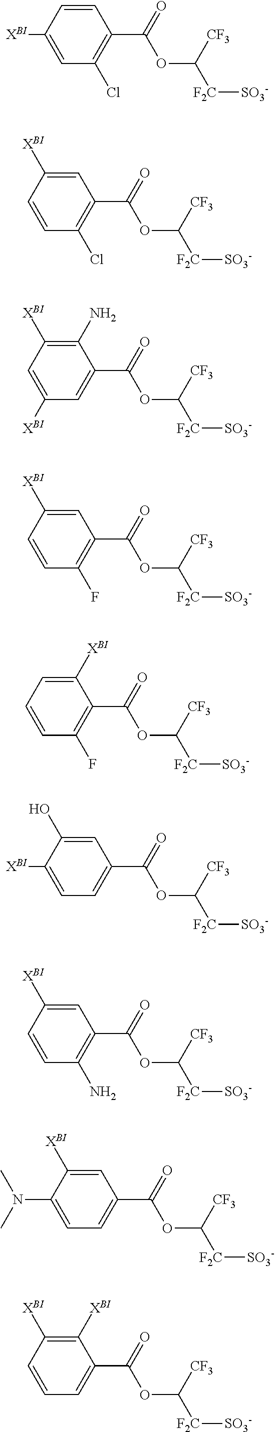

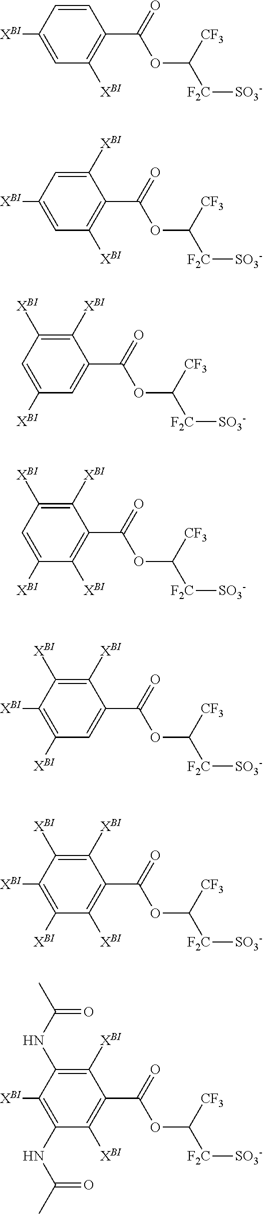

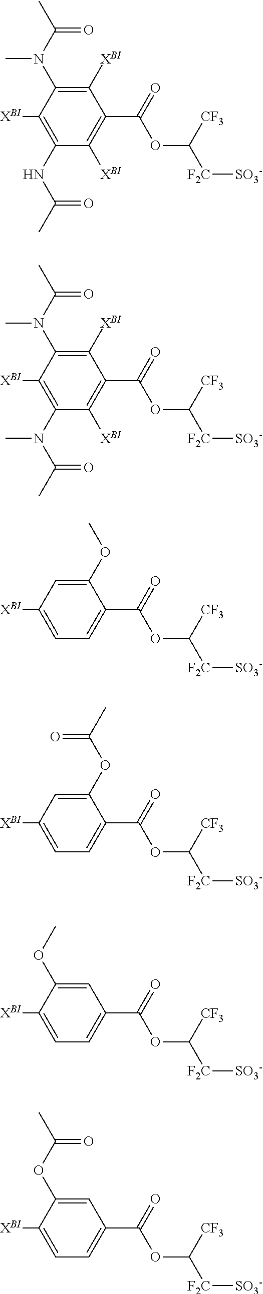

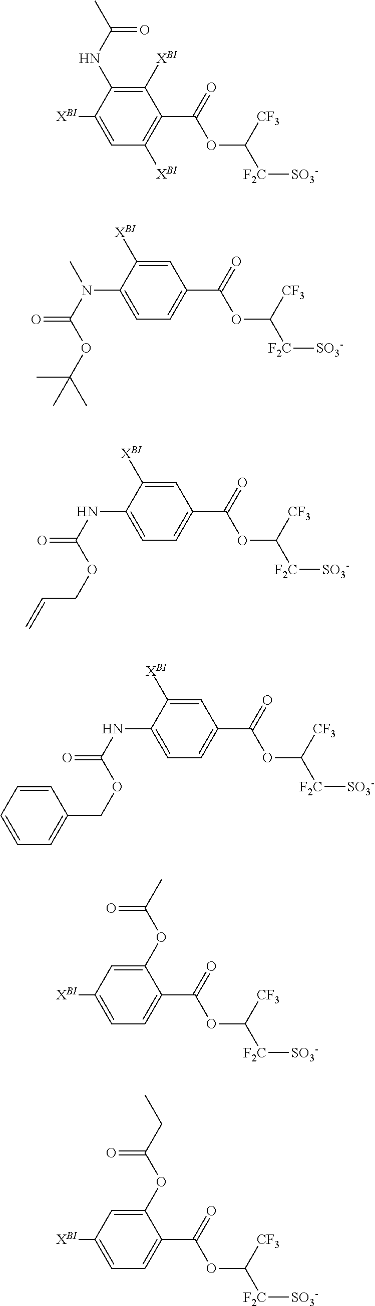

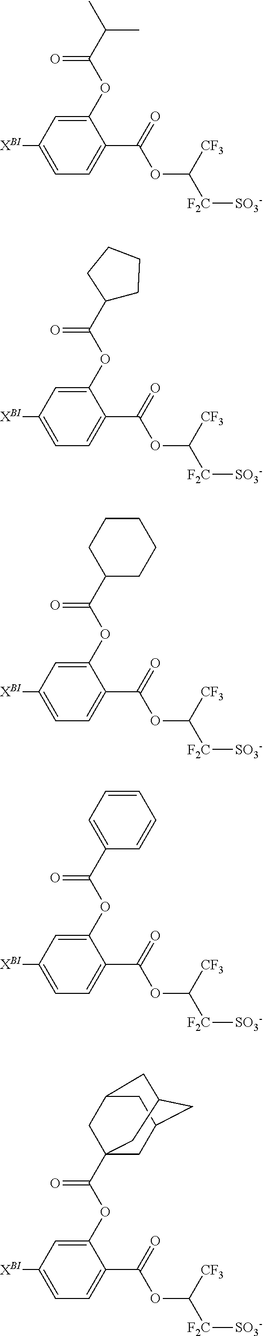

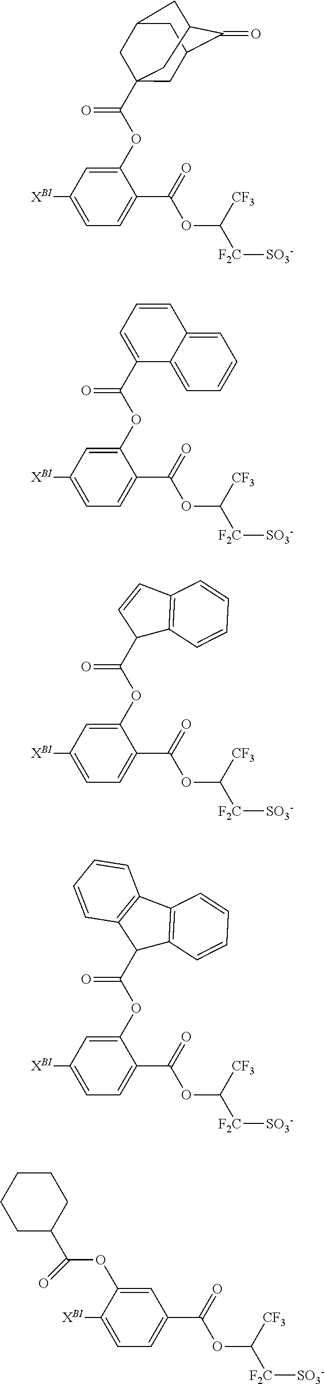

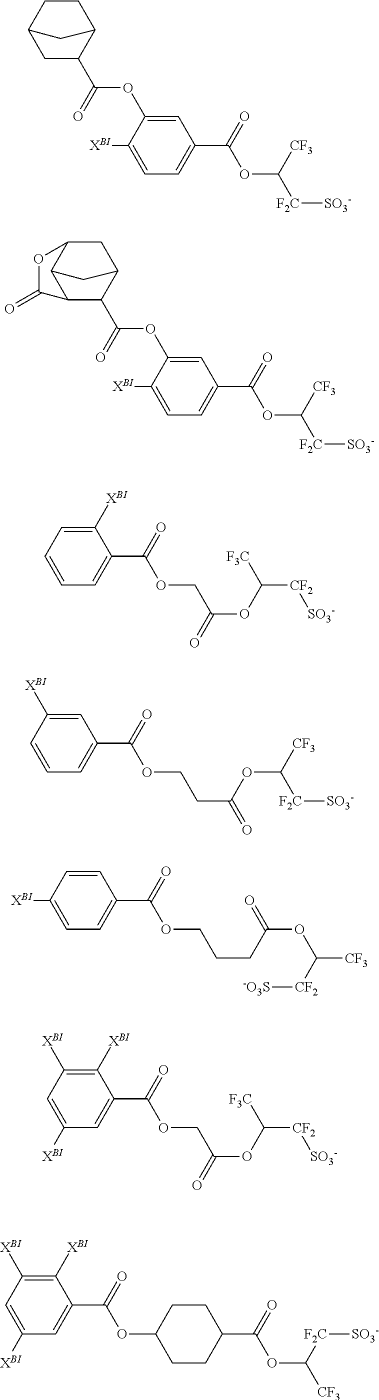

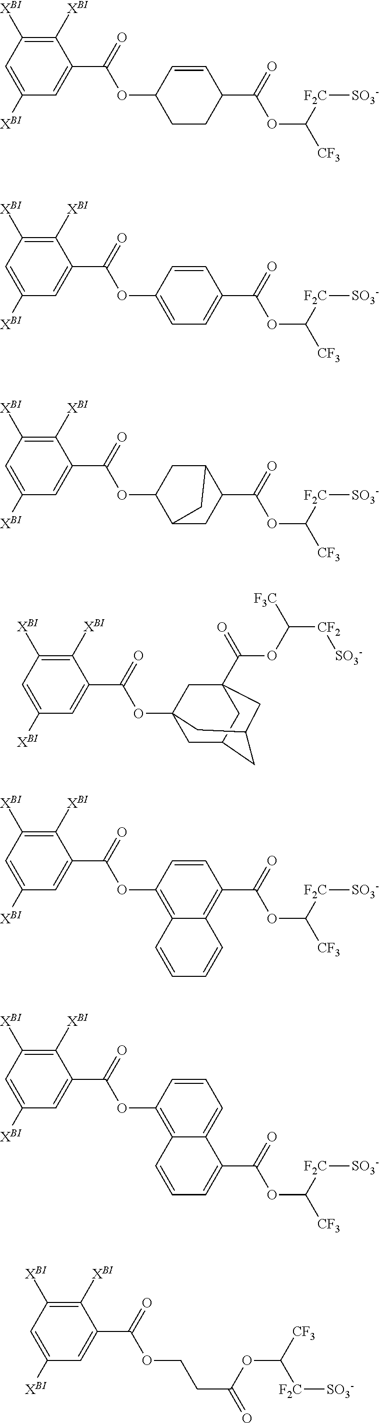

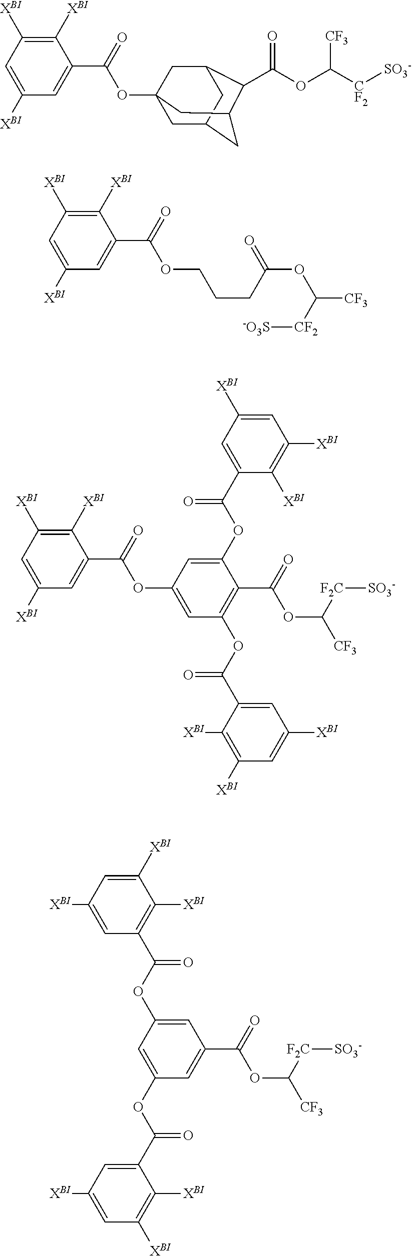

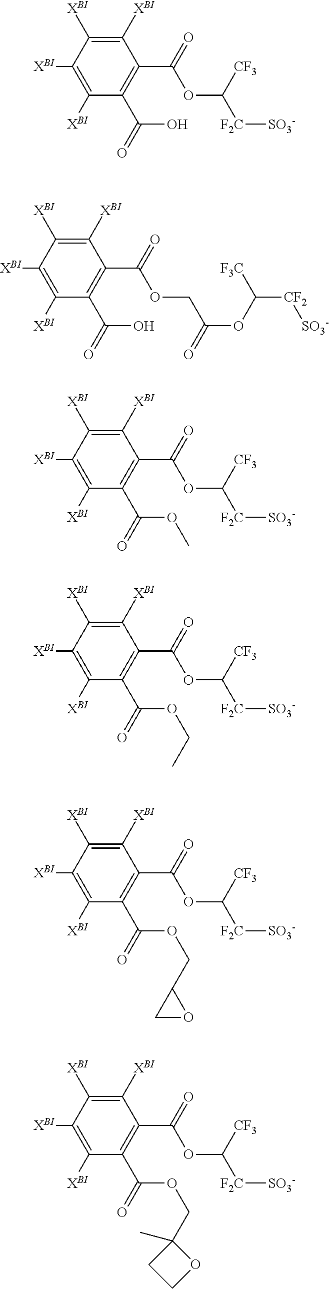

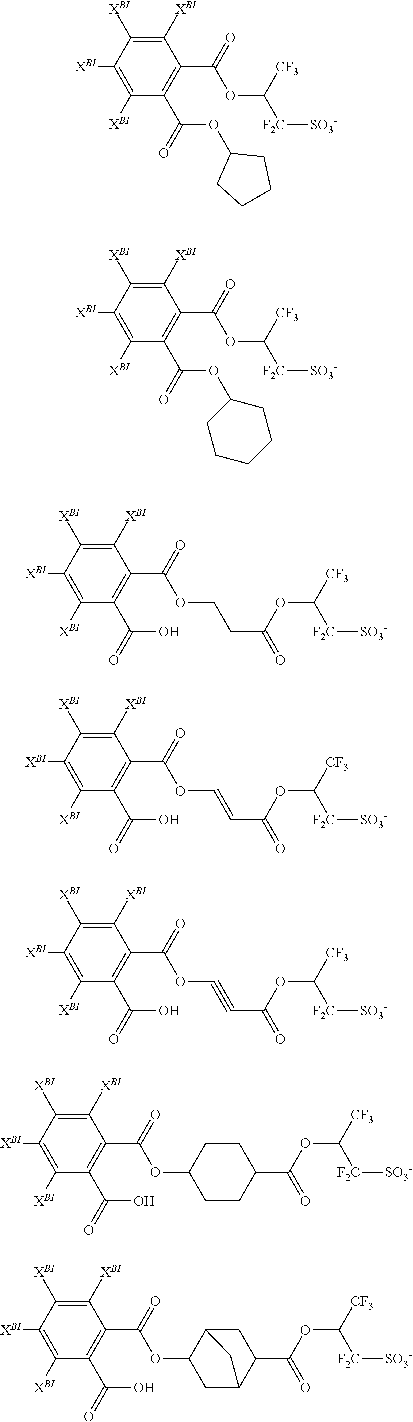

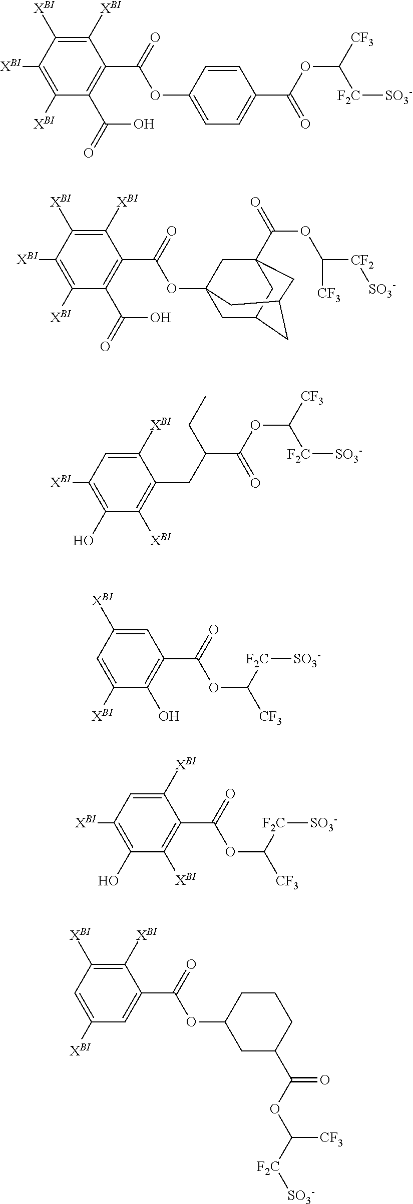

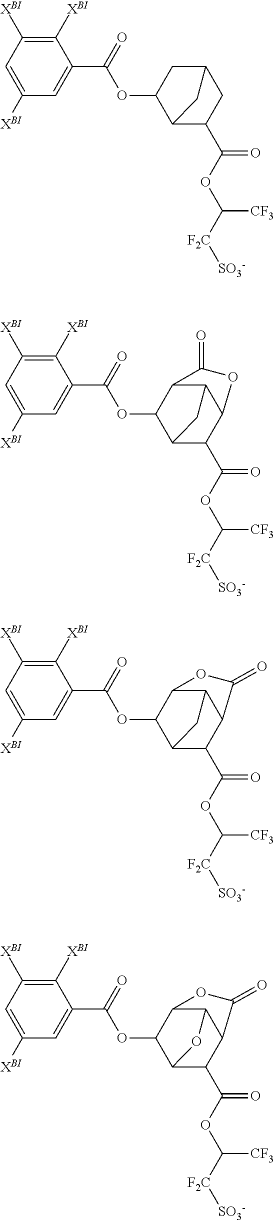

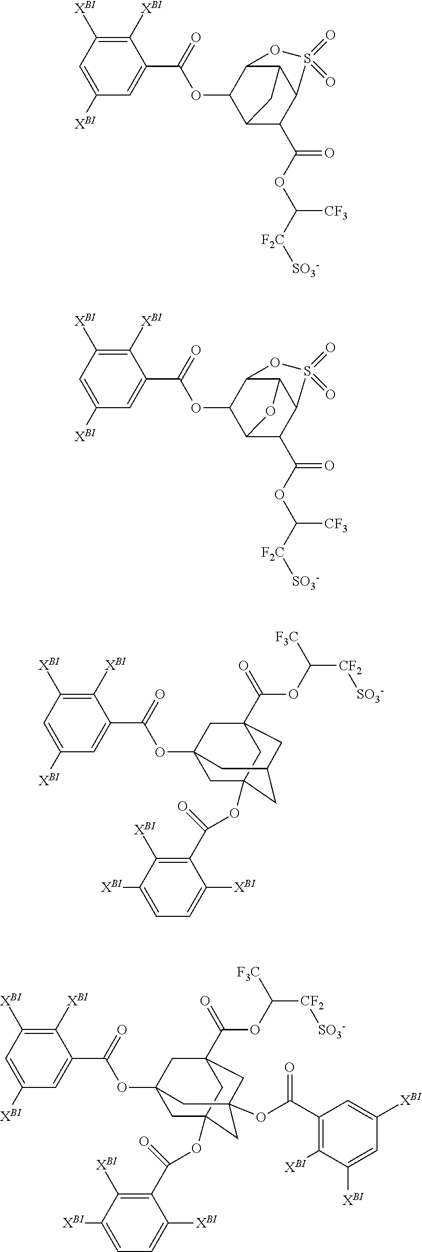

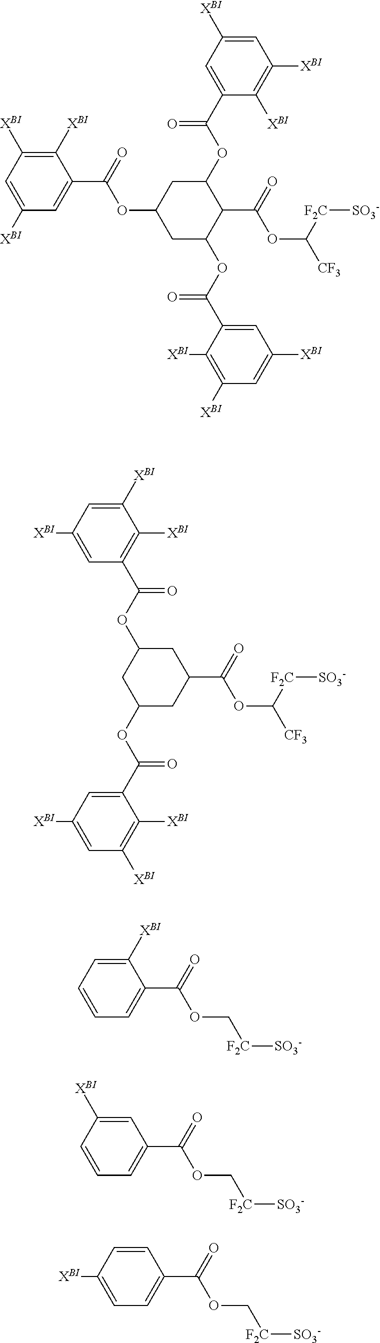

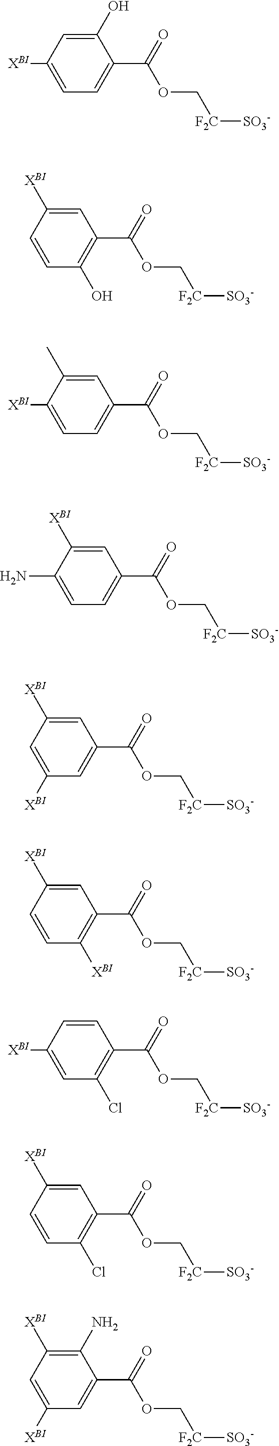

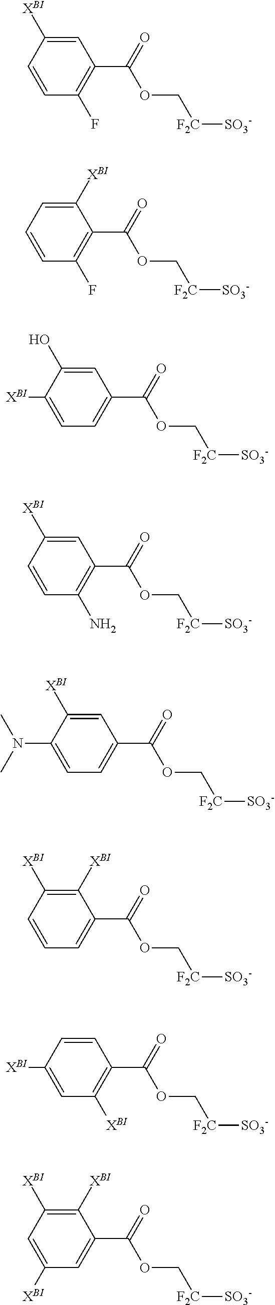

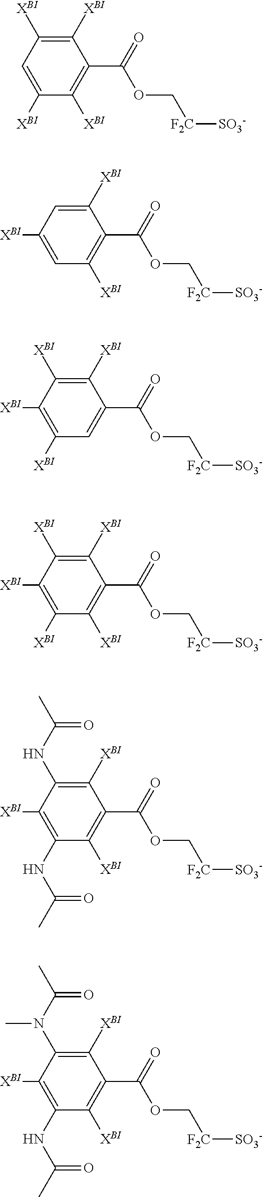

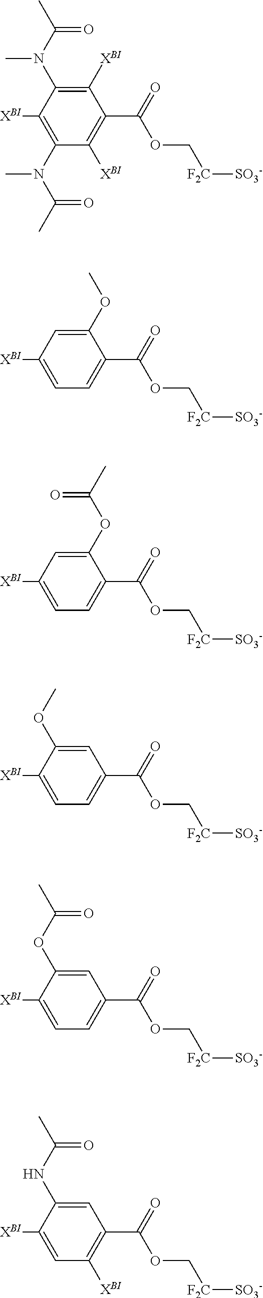

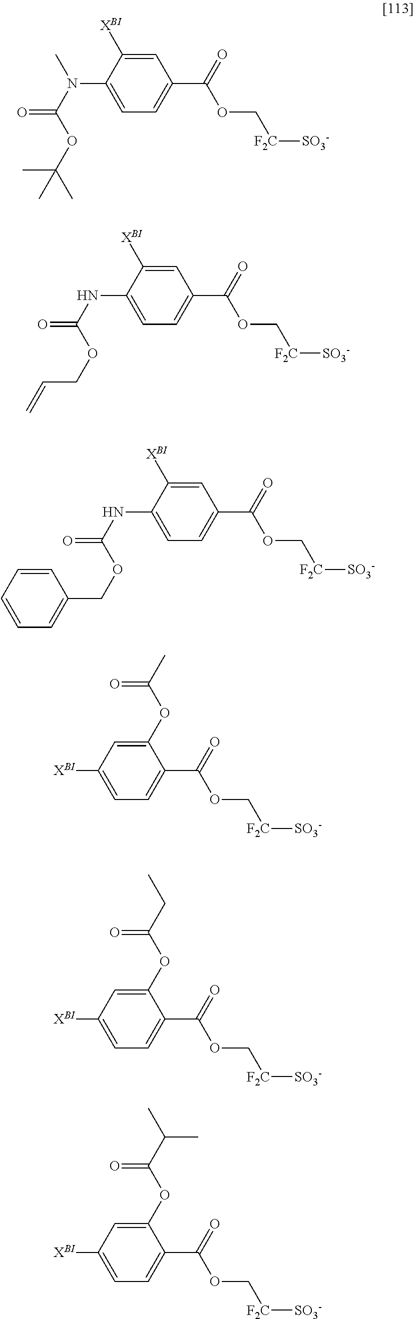

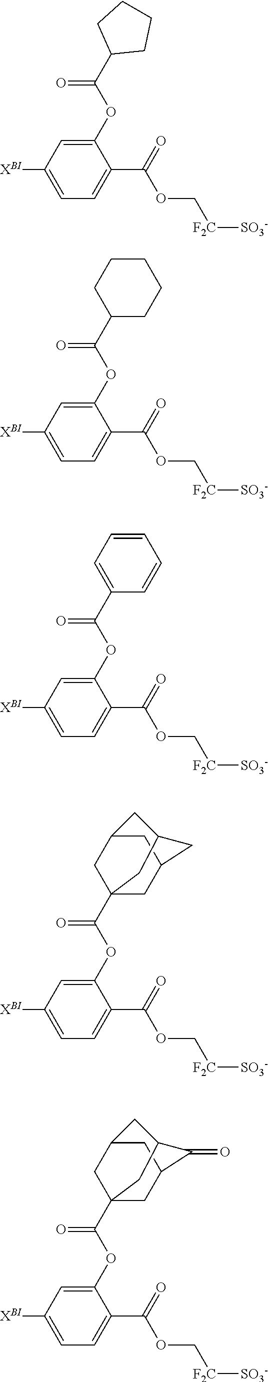

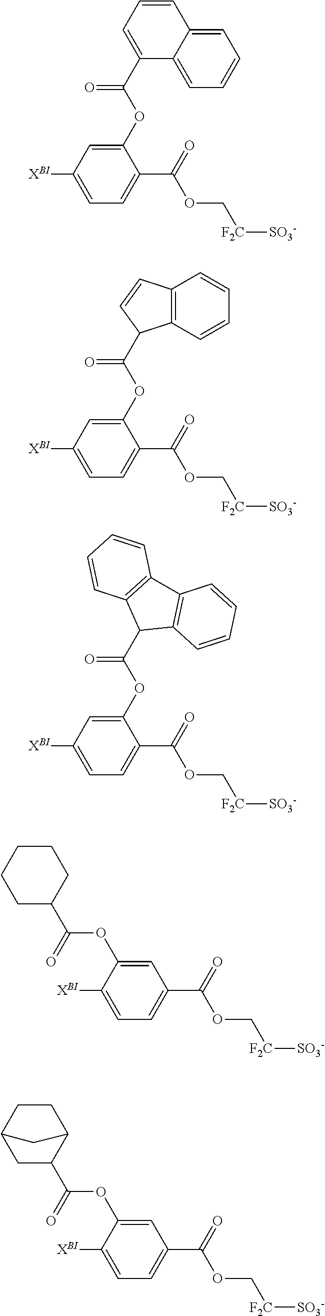

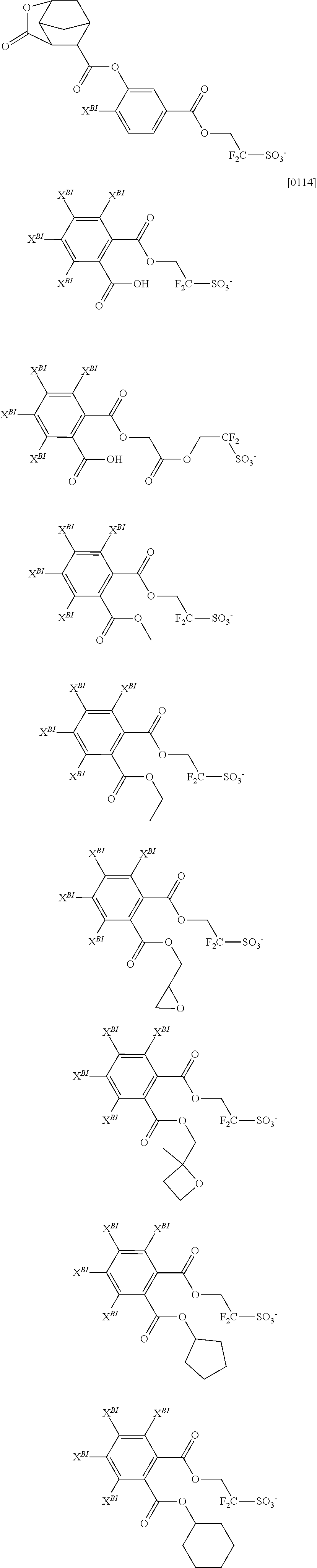

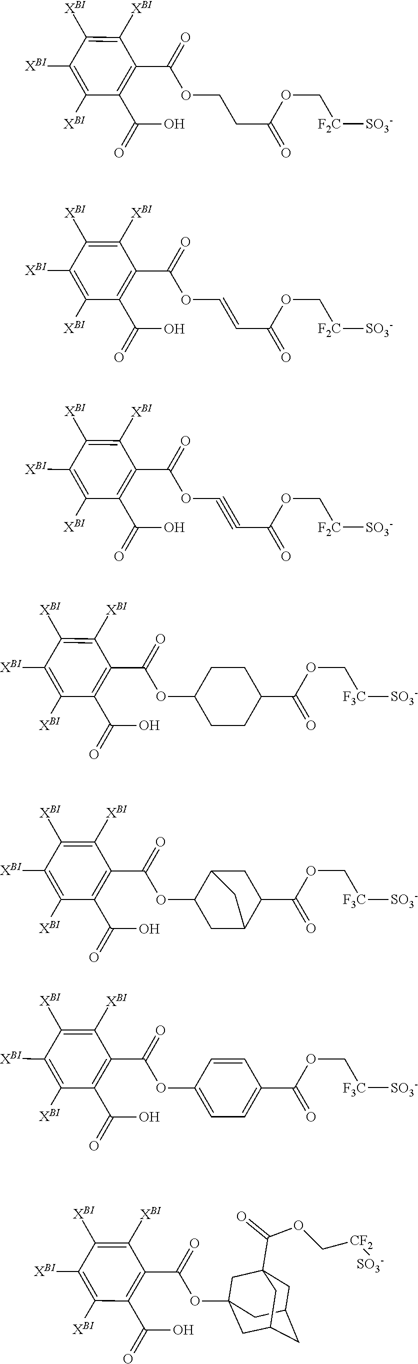

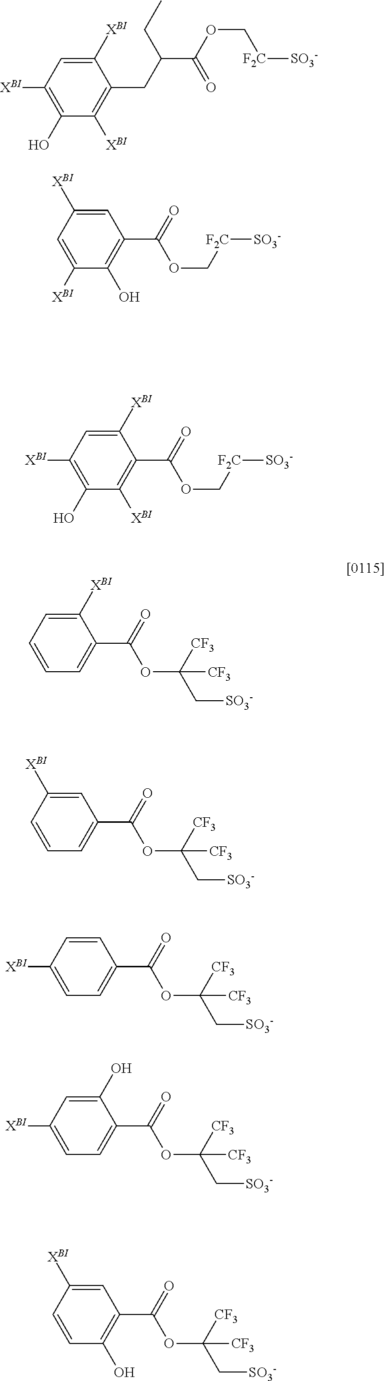

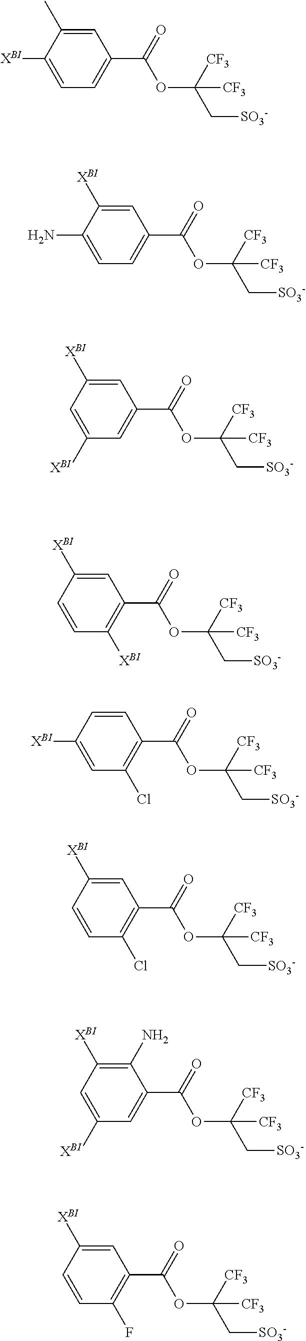

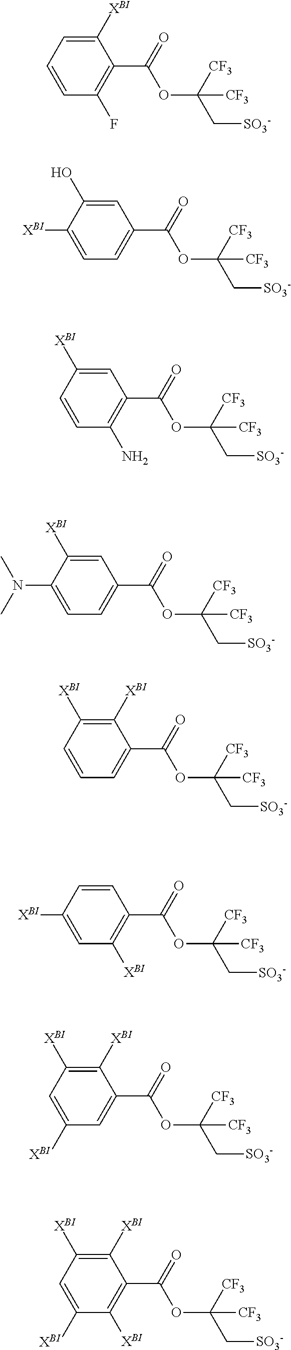

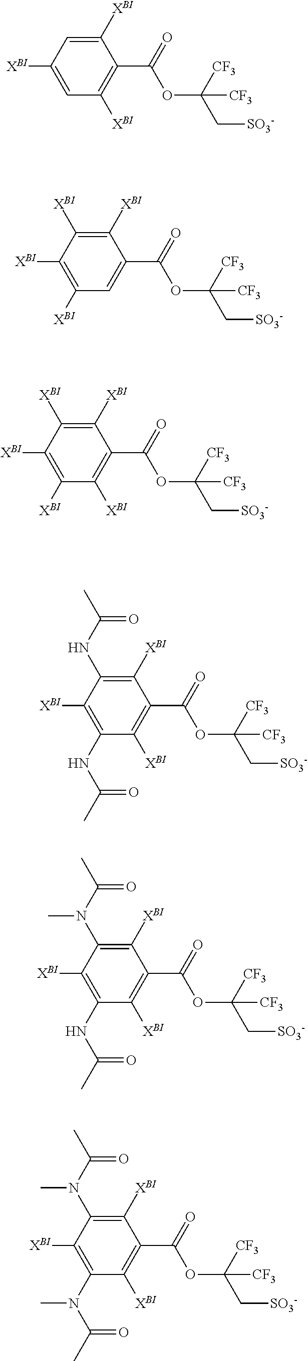

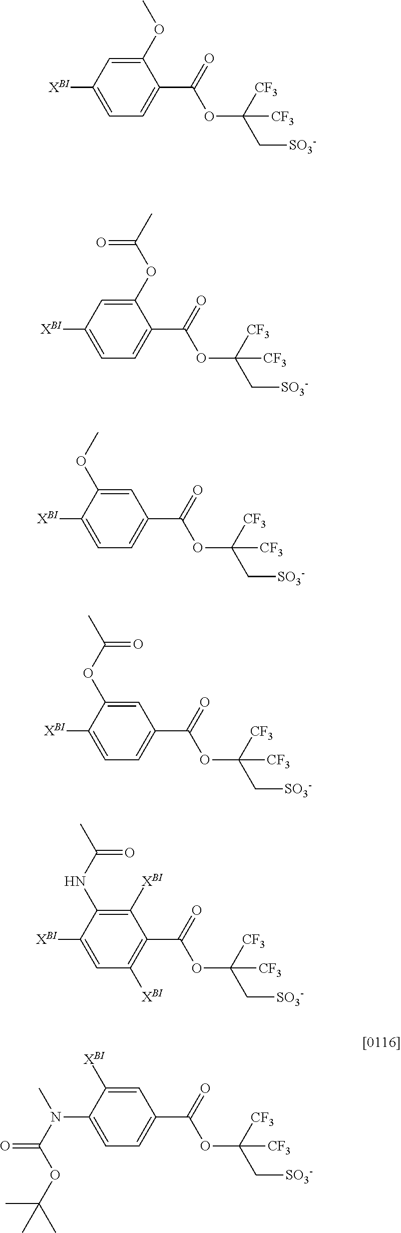

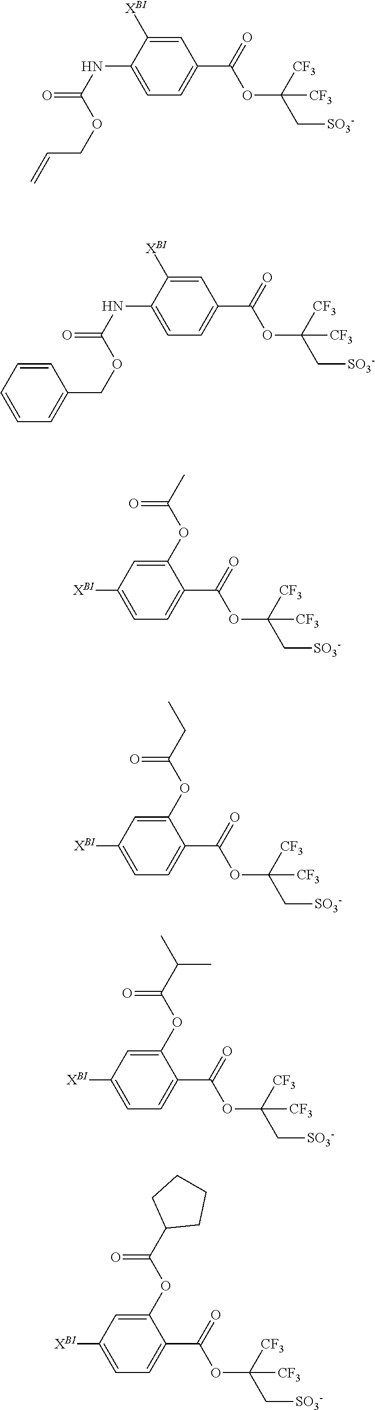

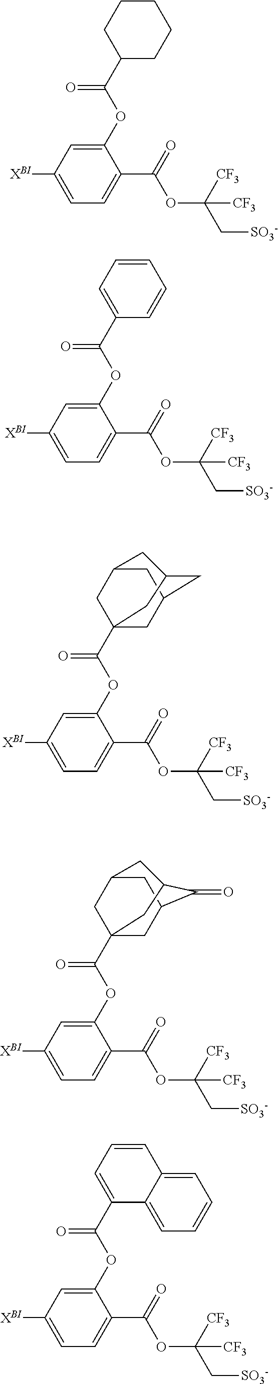

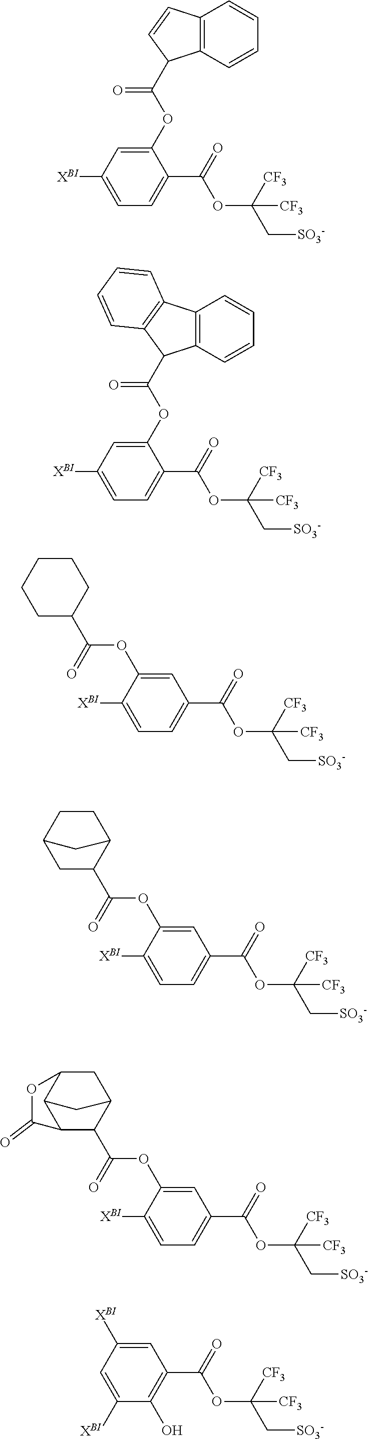

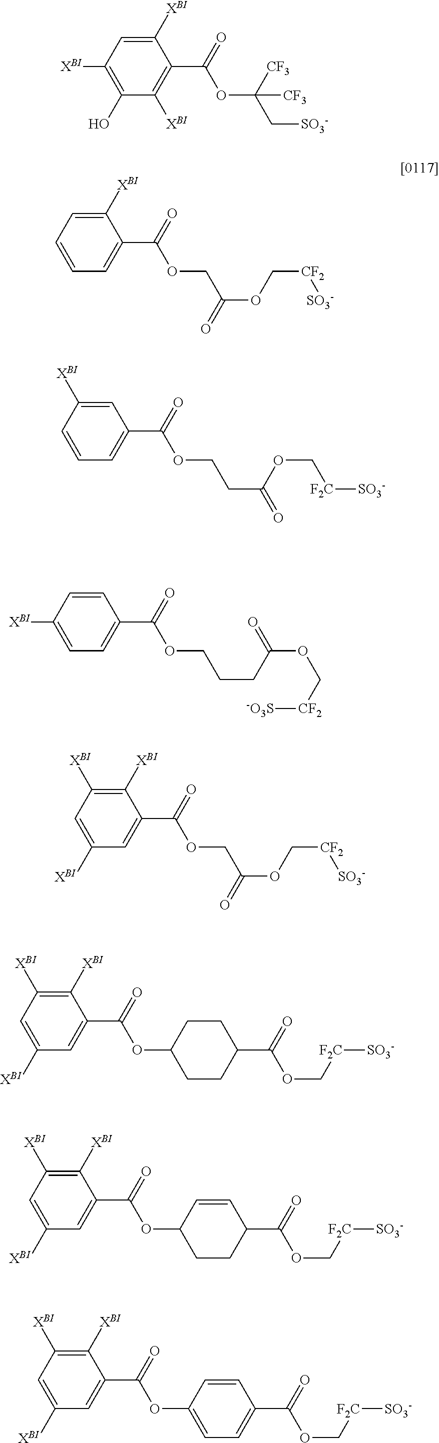

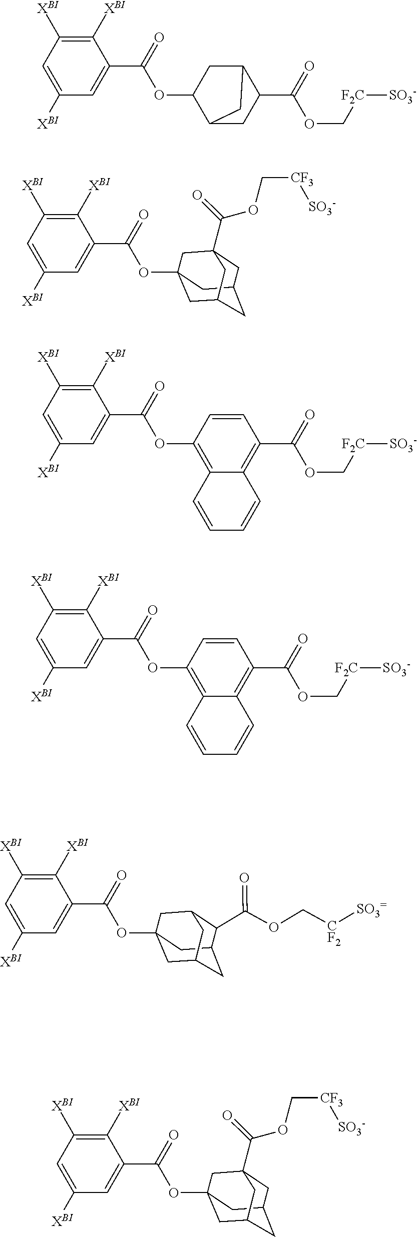

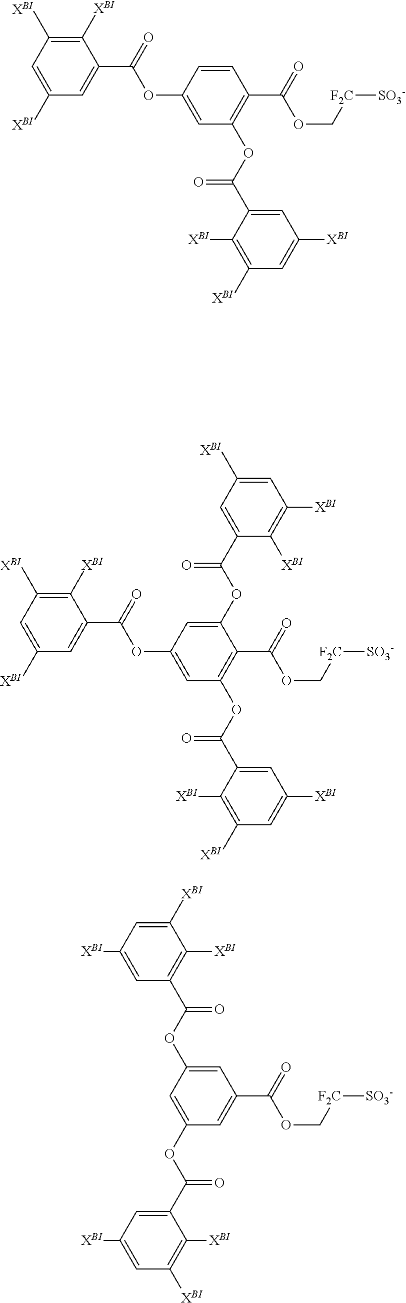

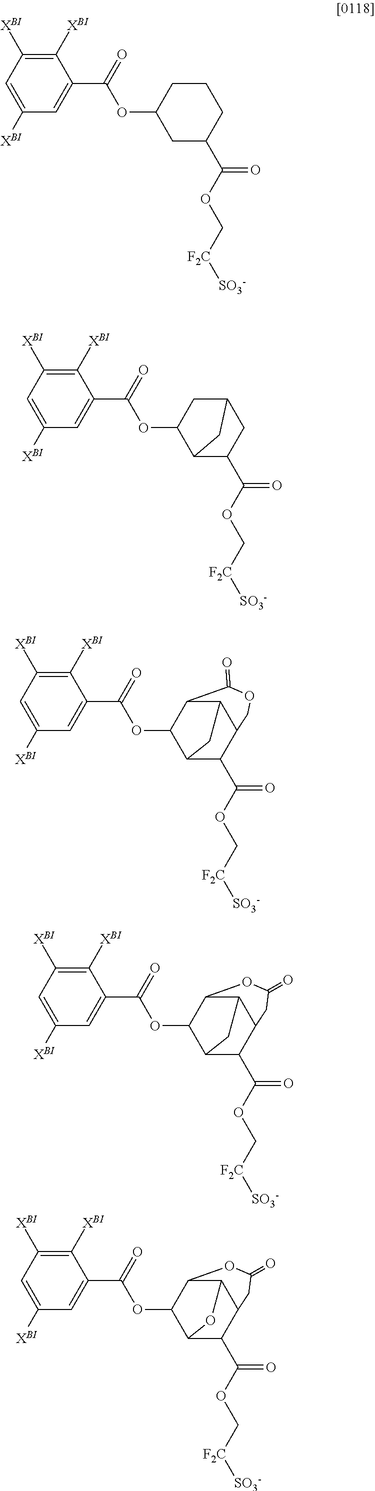

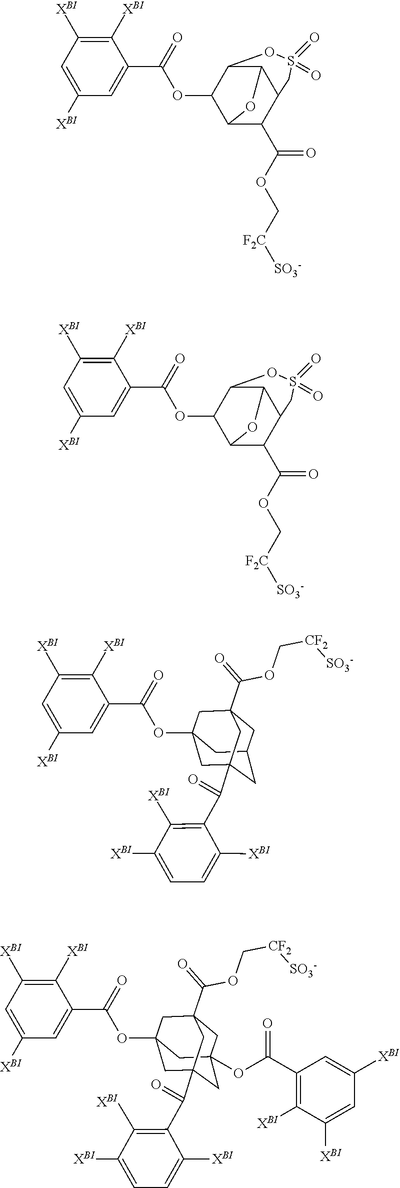

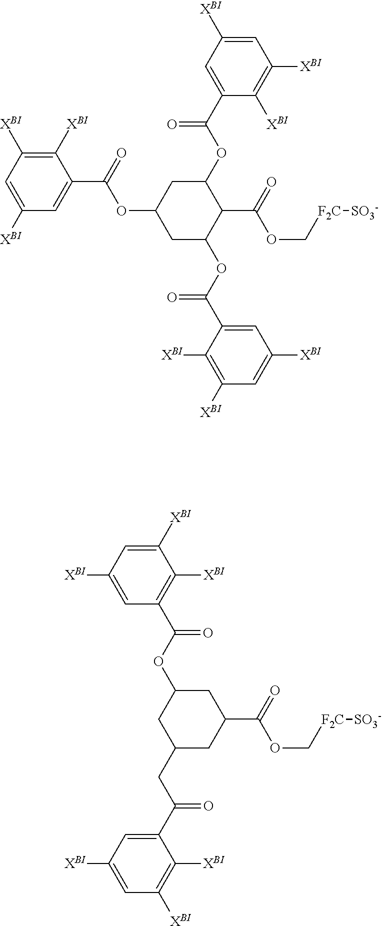

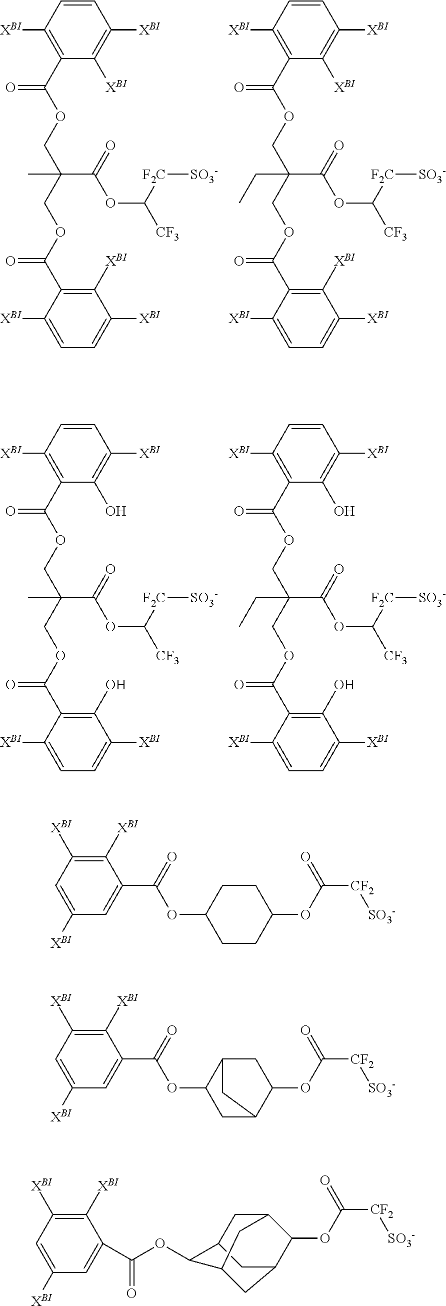

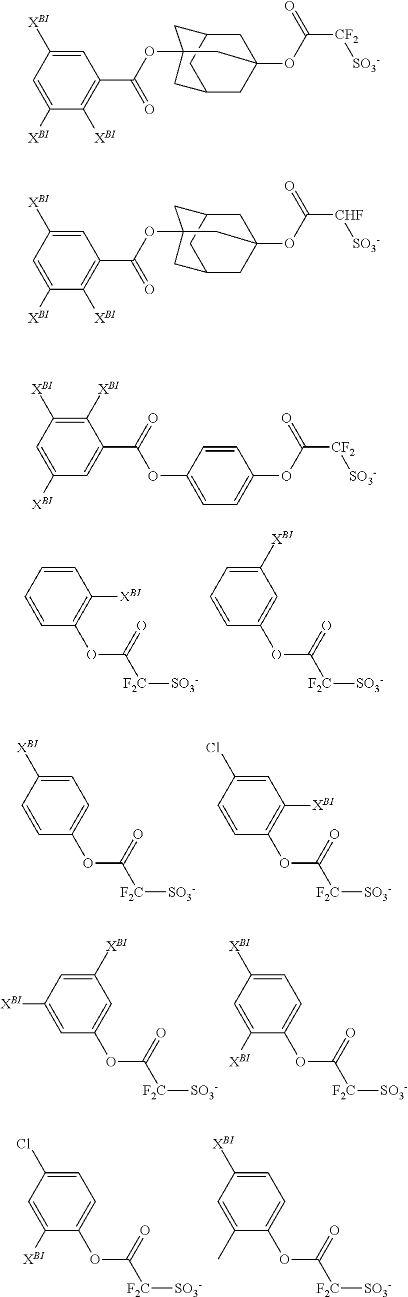

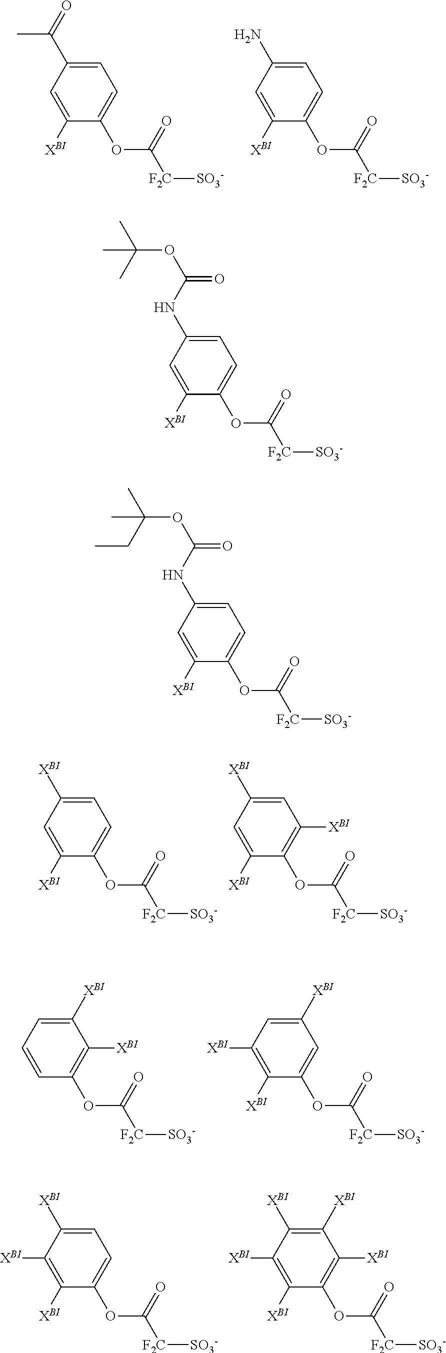

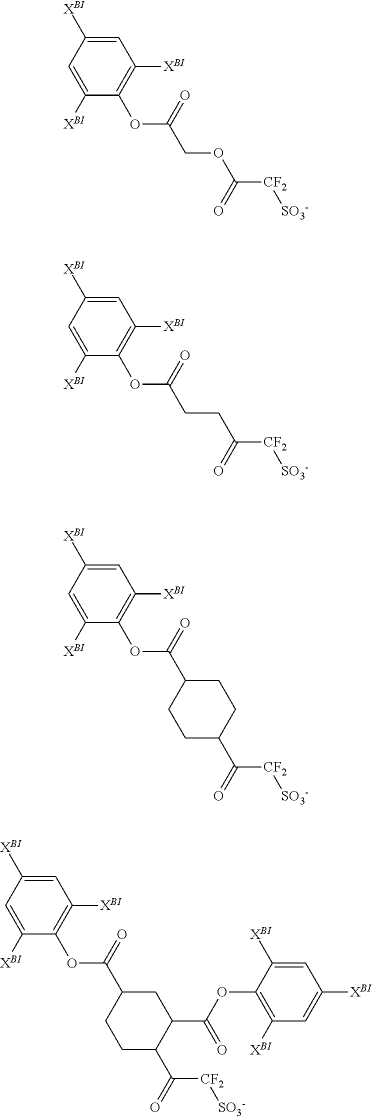

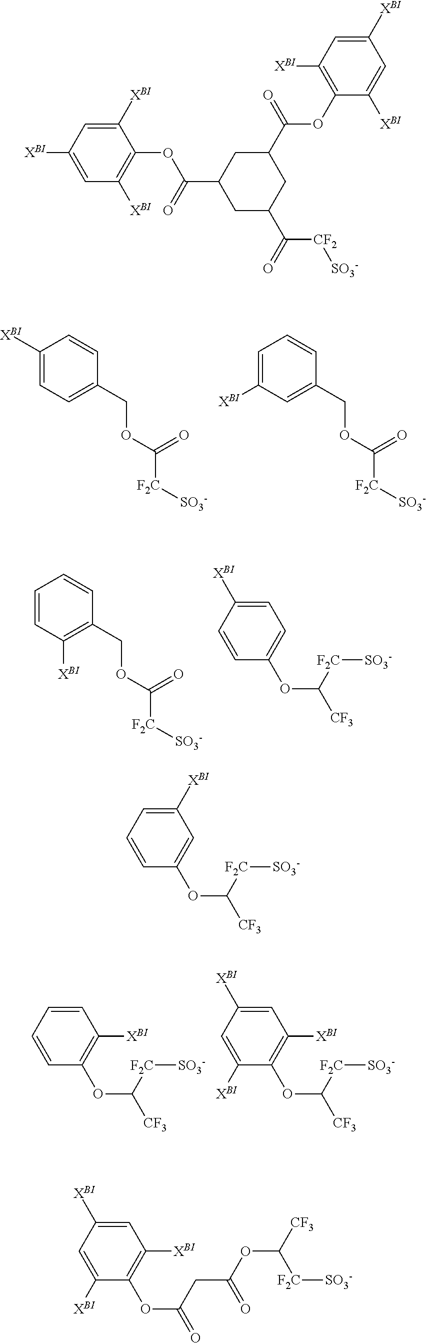

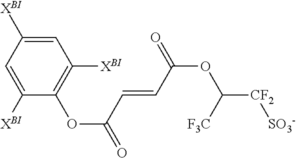

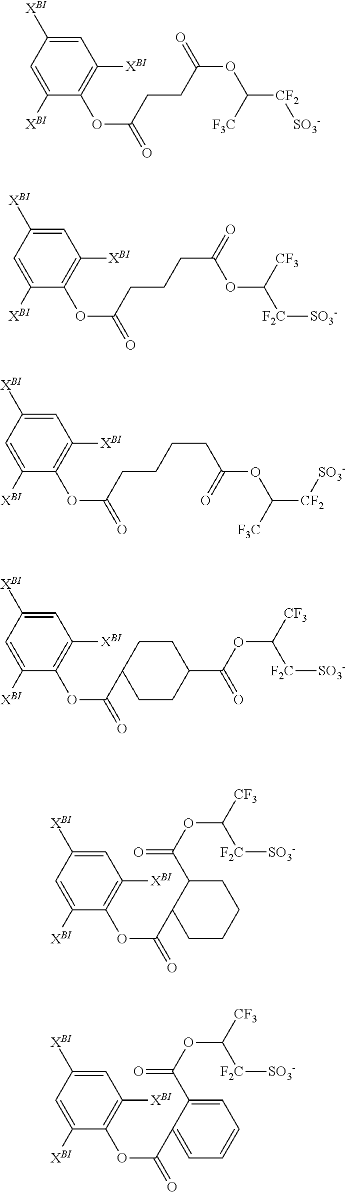

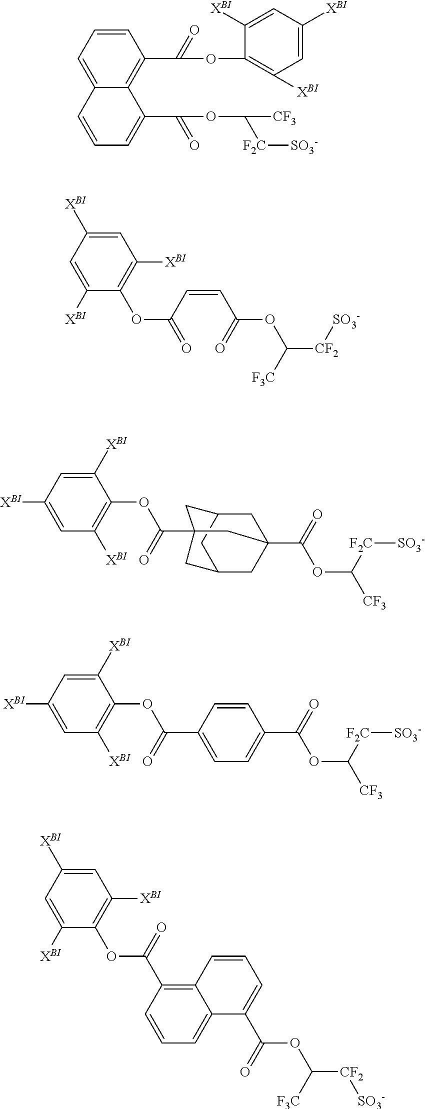

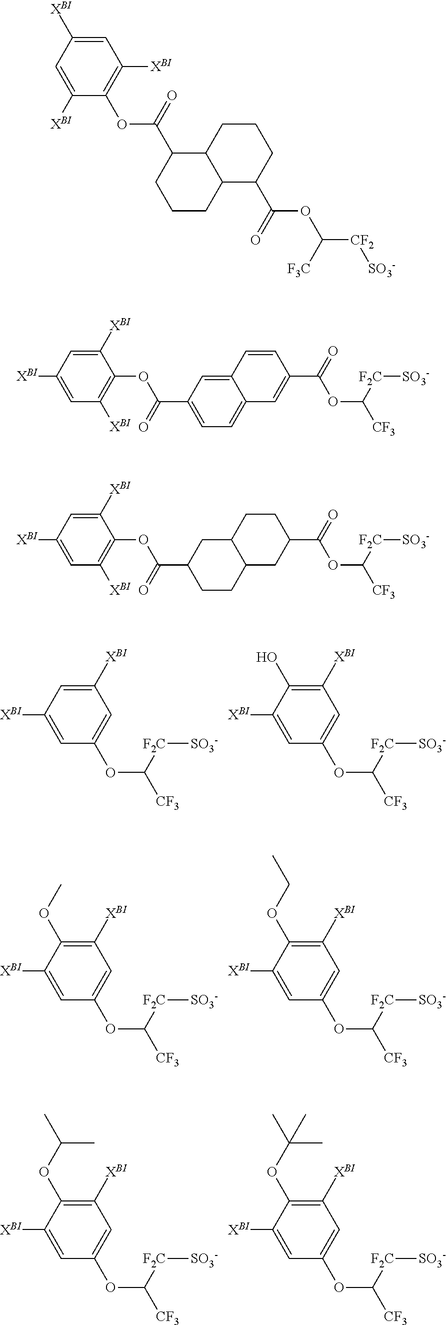

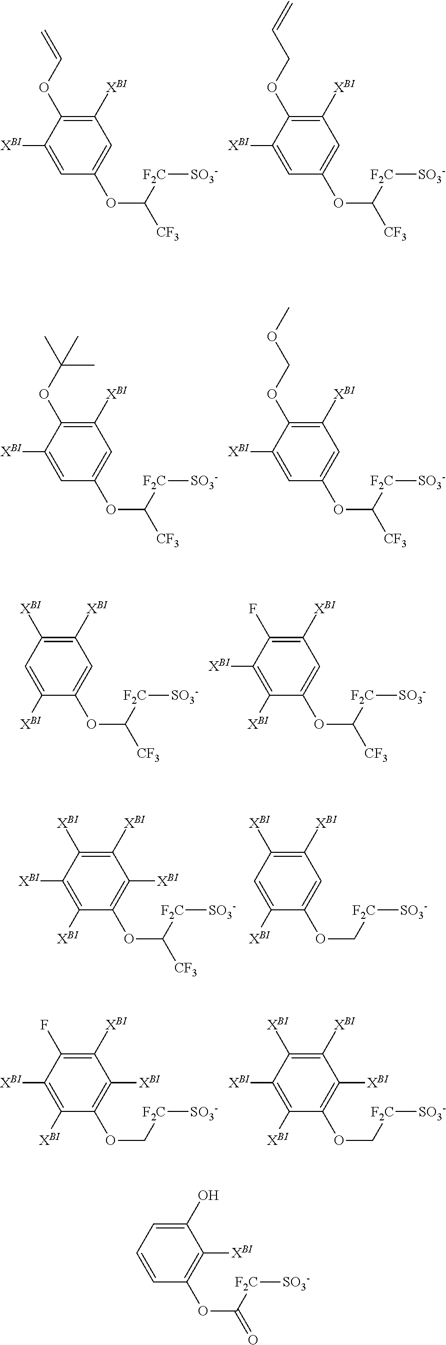

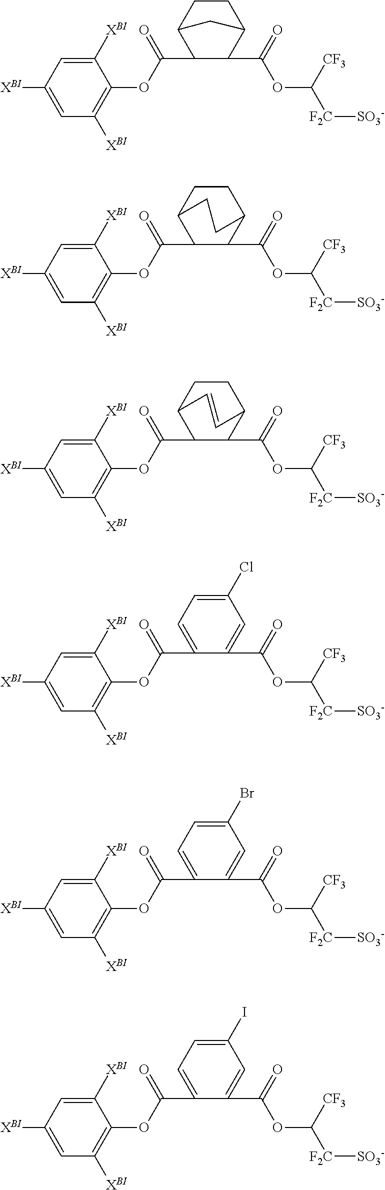

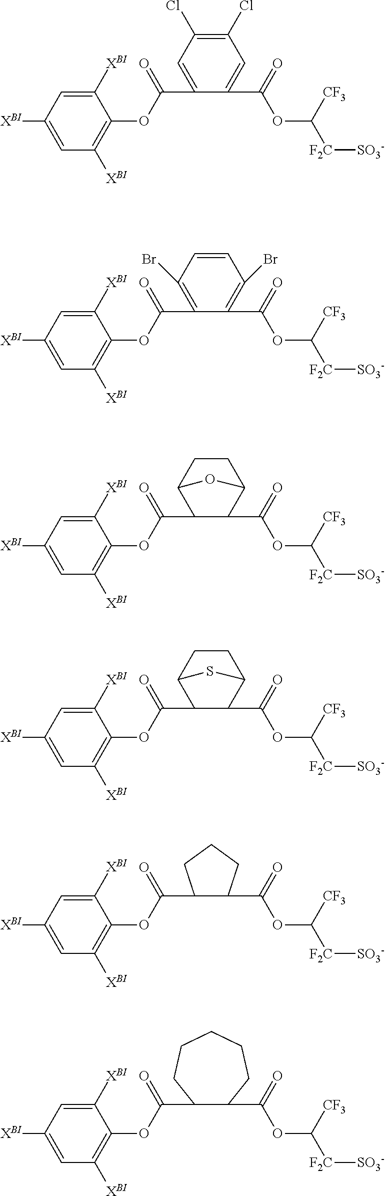

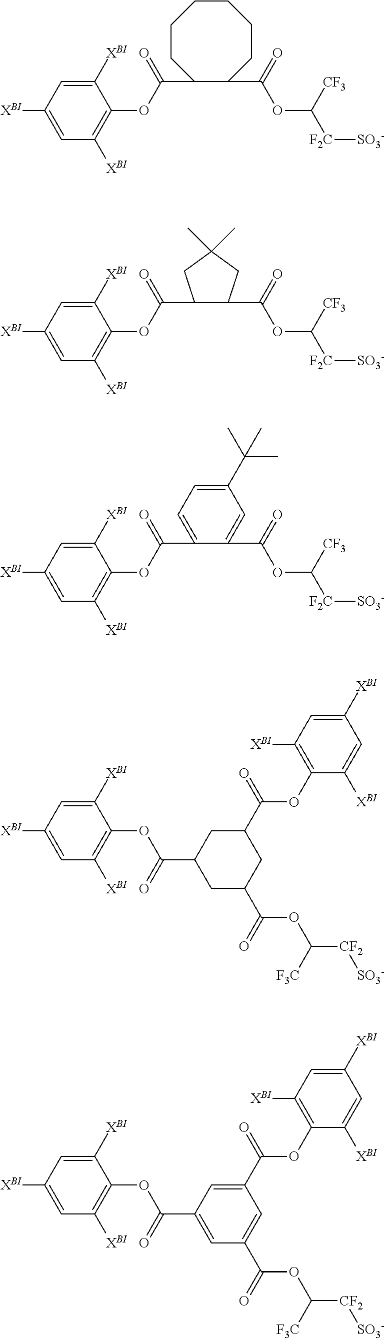

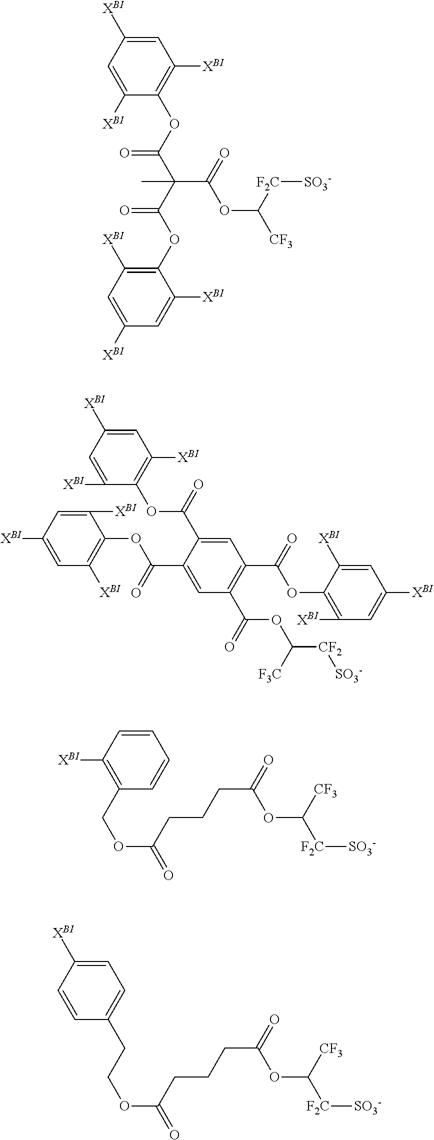

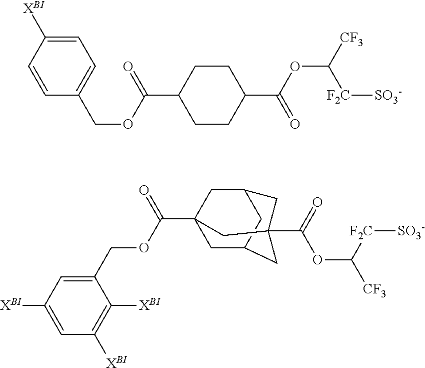

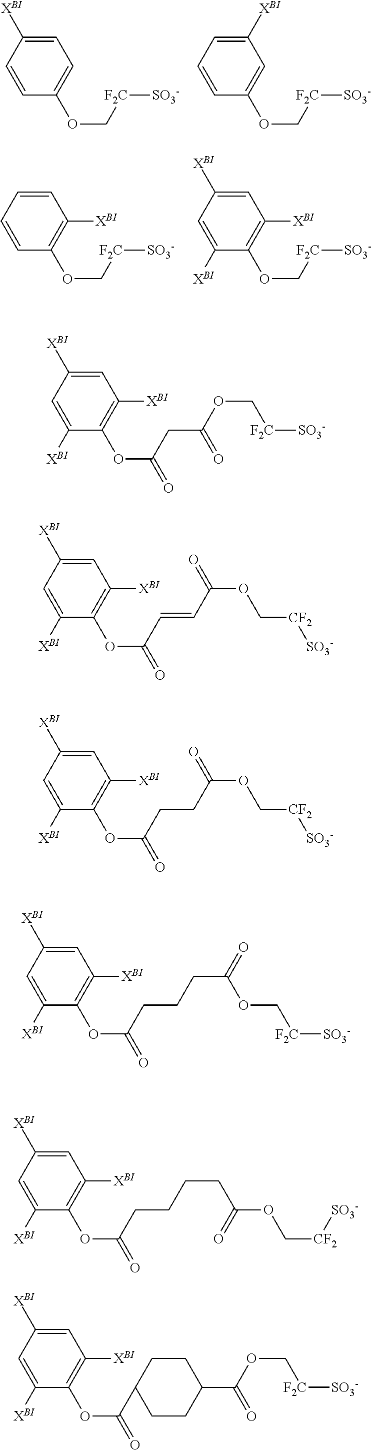

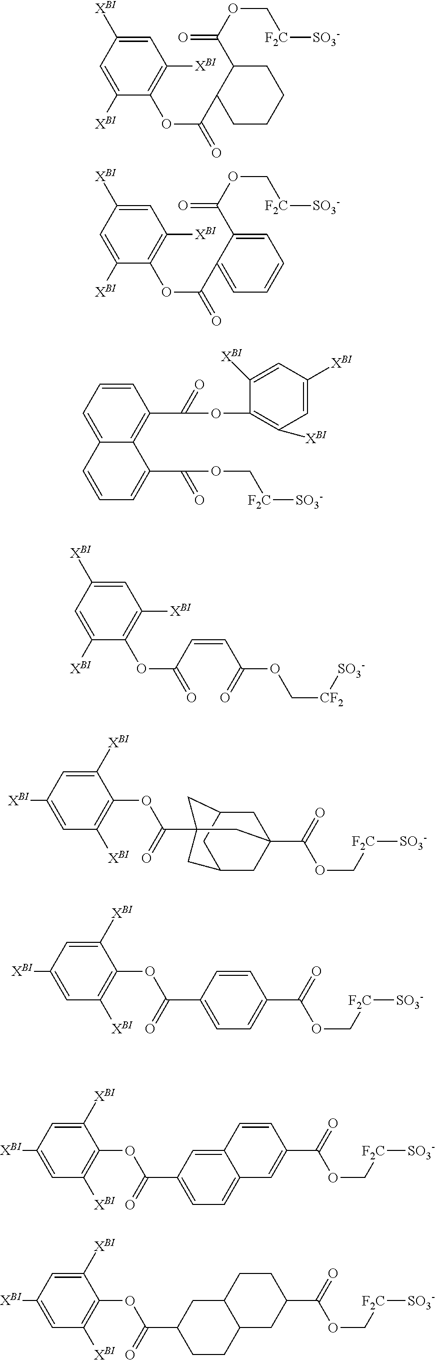

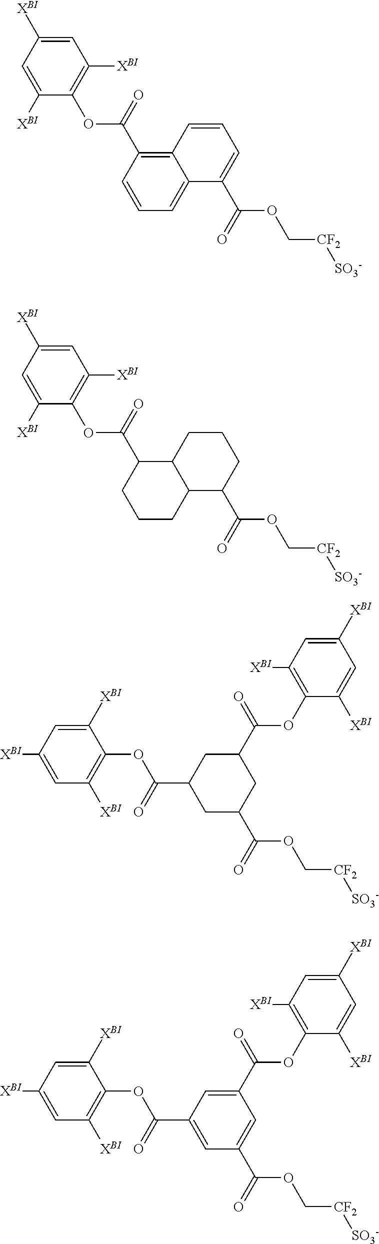

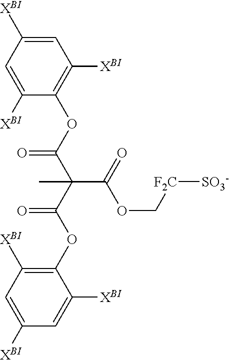

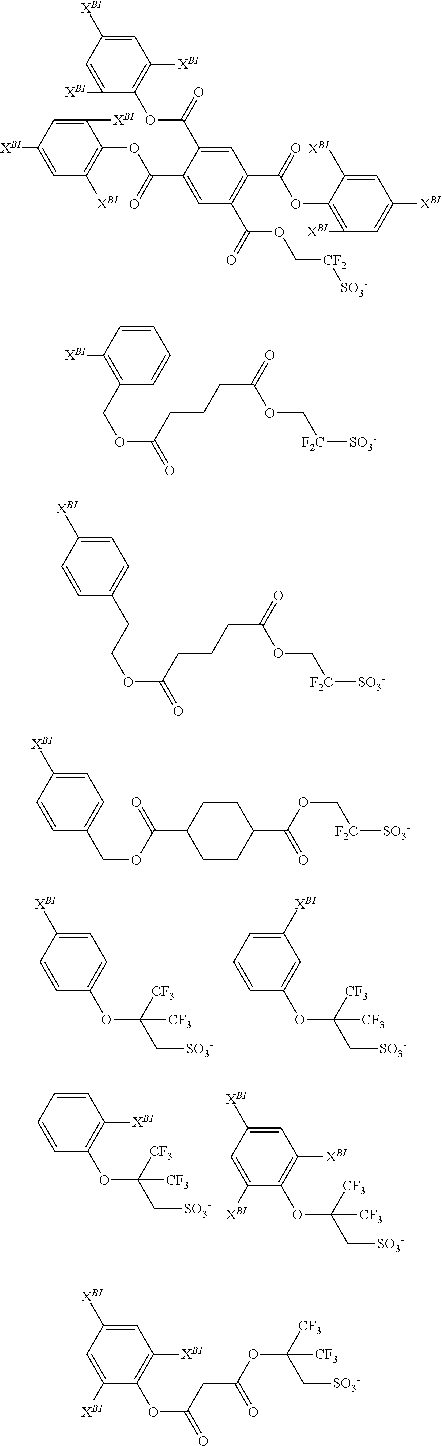

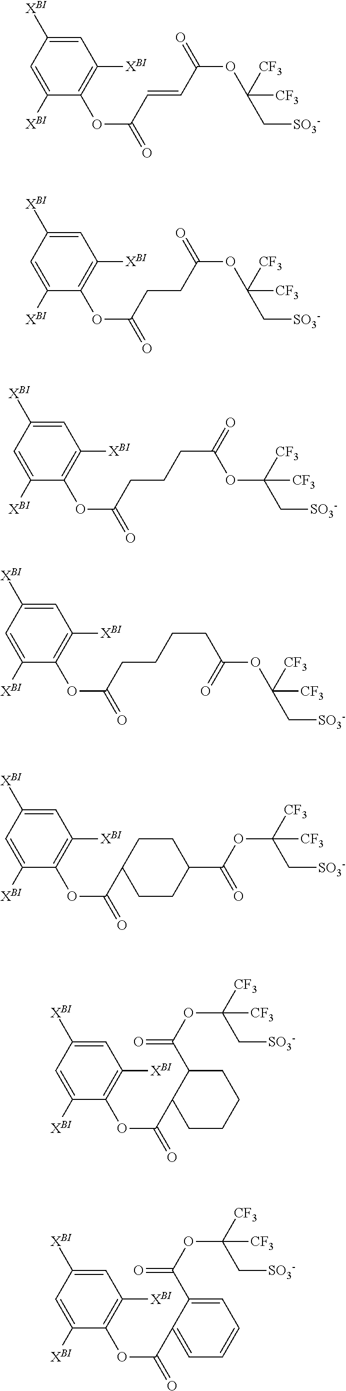

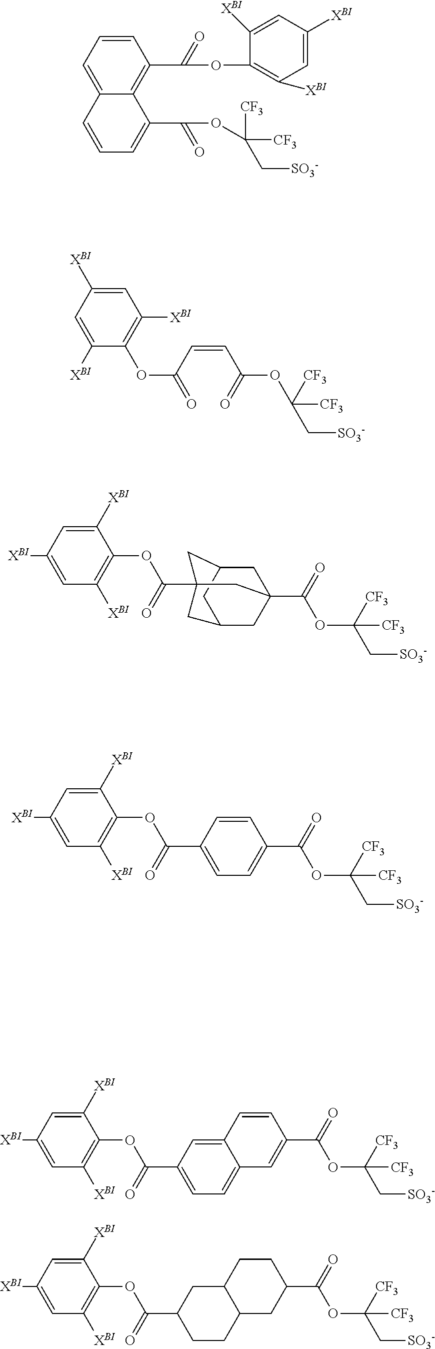

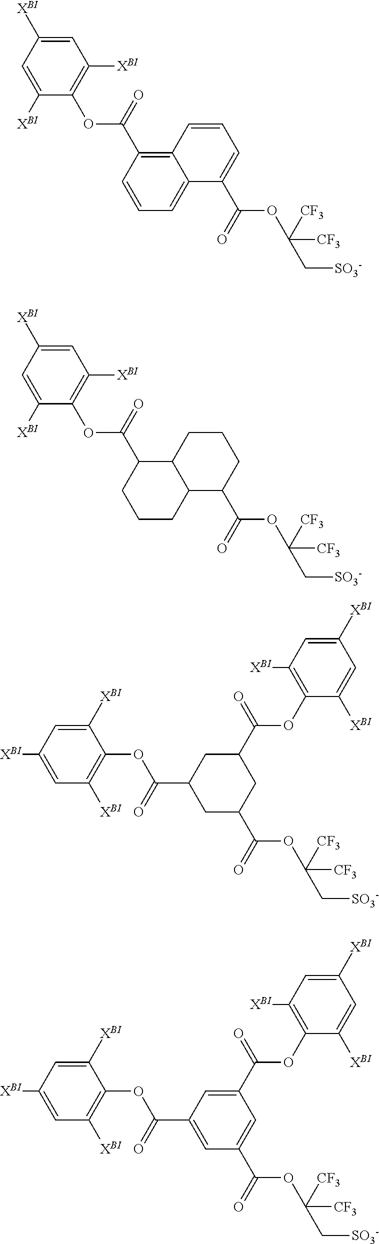

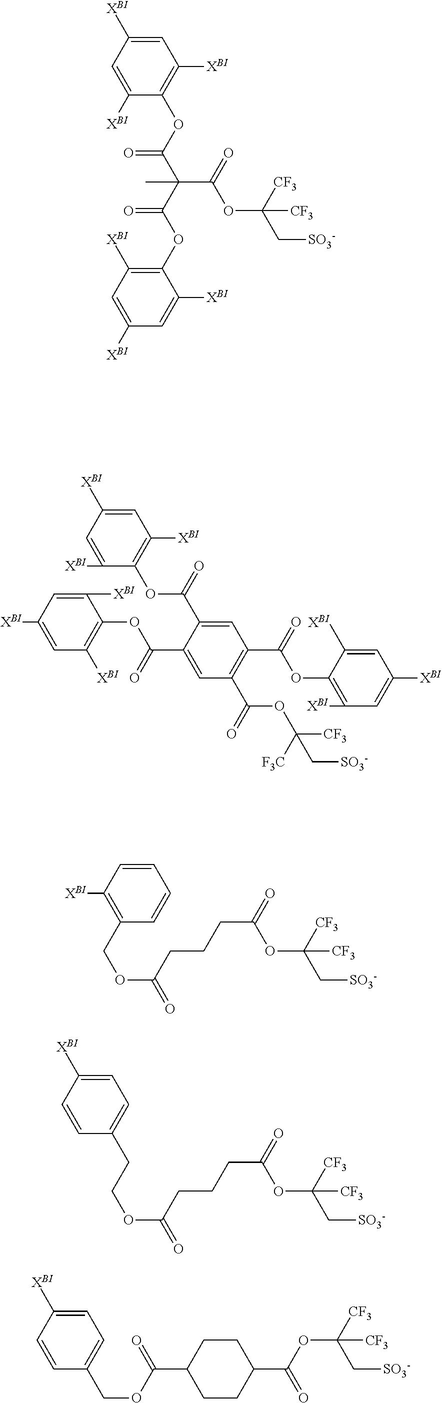

In the above, X^{BI} represents a bromine atom or an iodine atom.

Examples of an anion of a monomer to give the repeating unit-b2 include those shown below, but are not limited thereto. Note that, in the following formulae, R is as defined above.

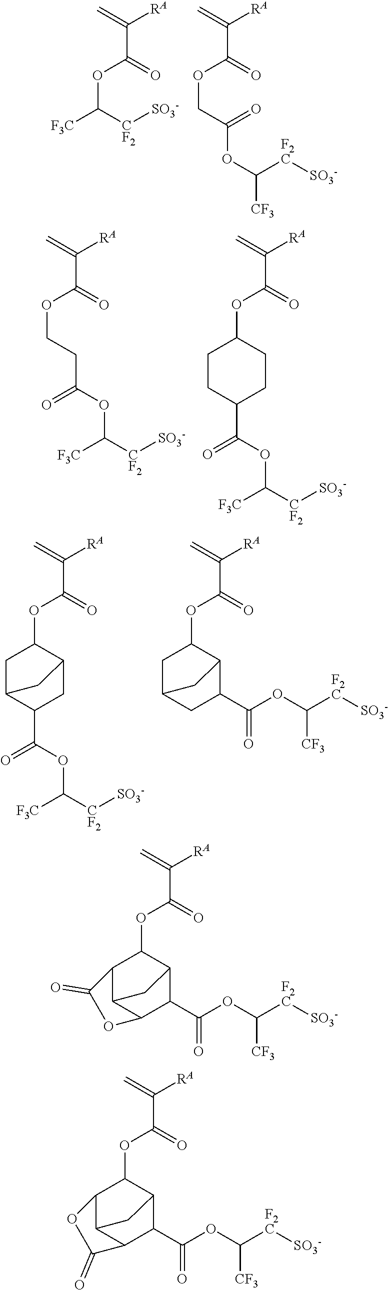

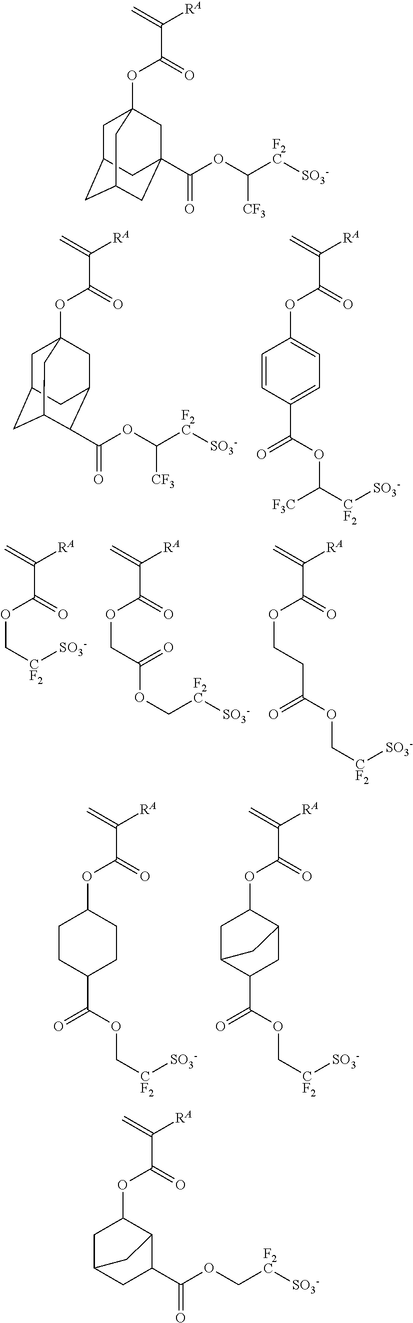

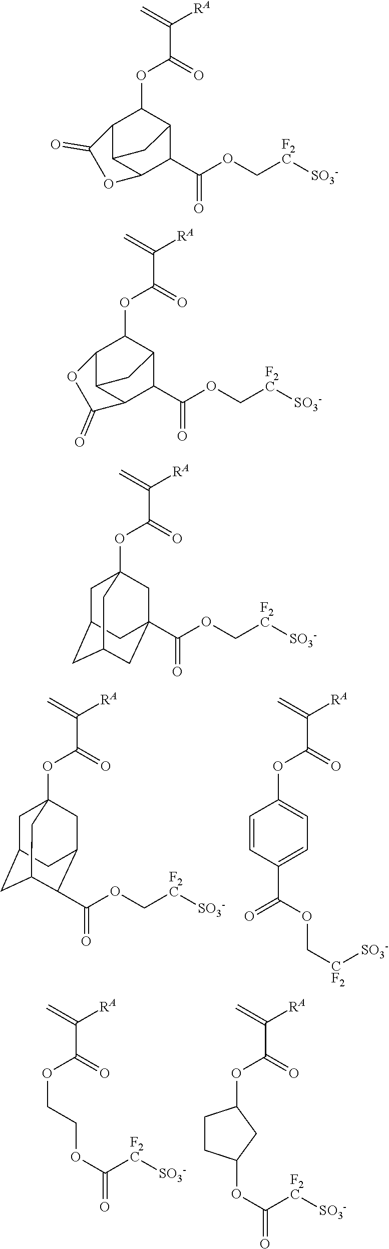

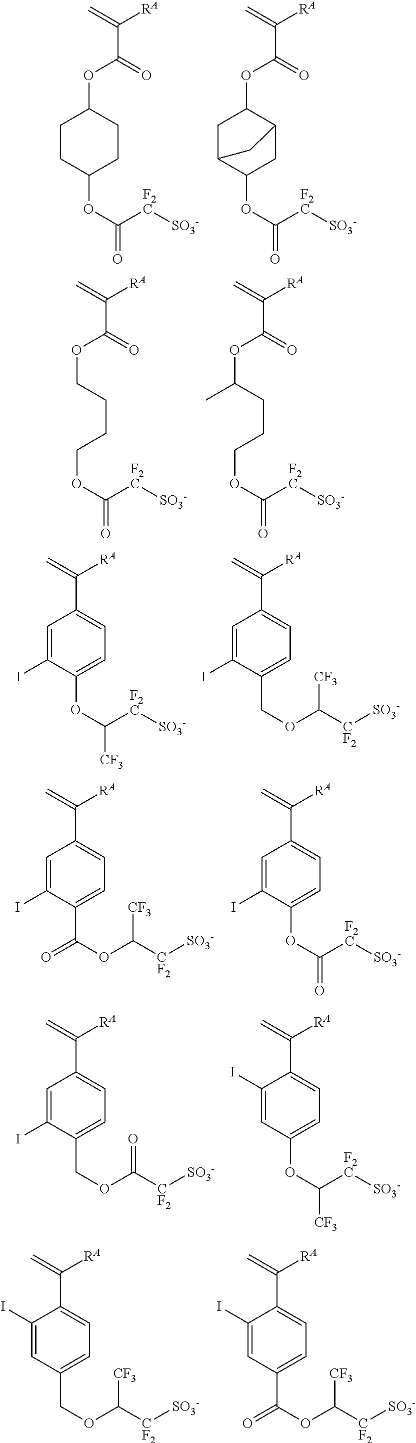

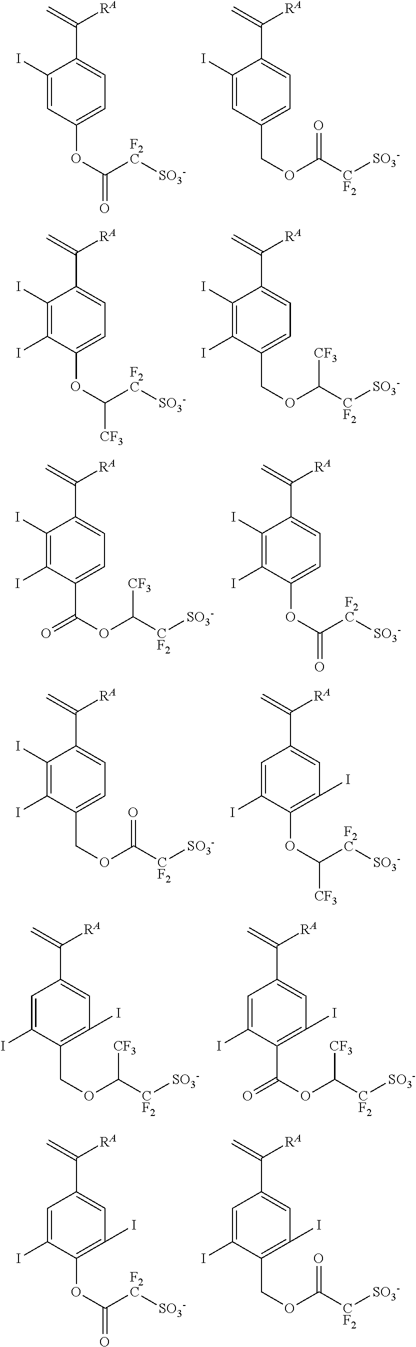

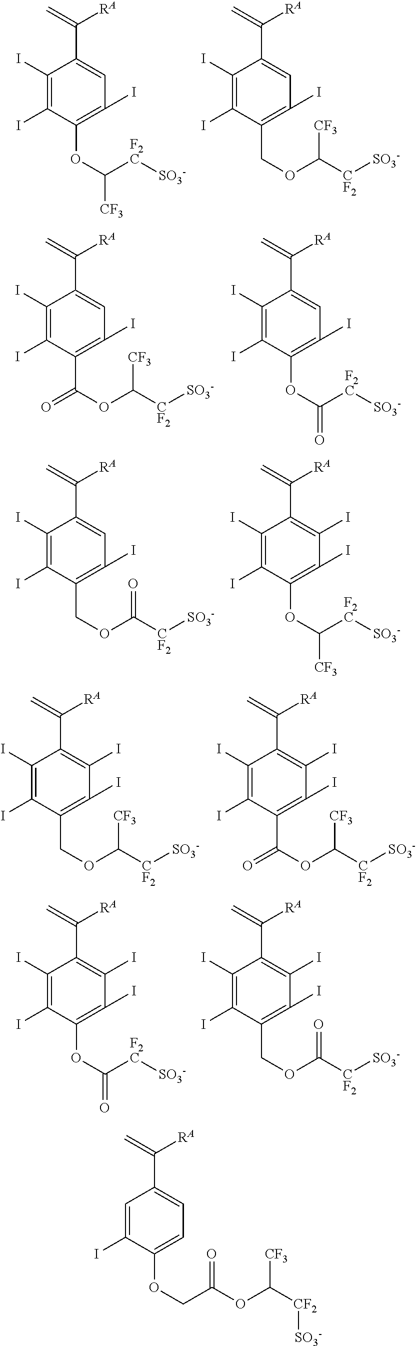

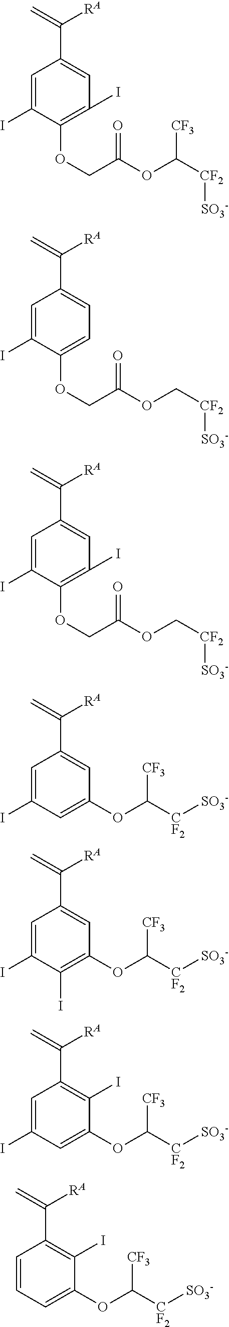

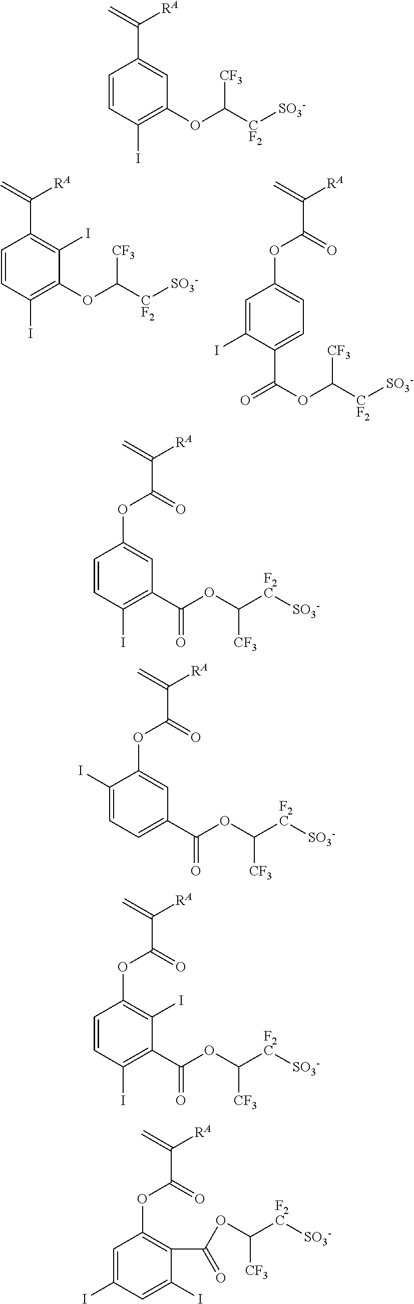

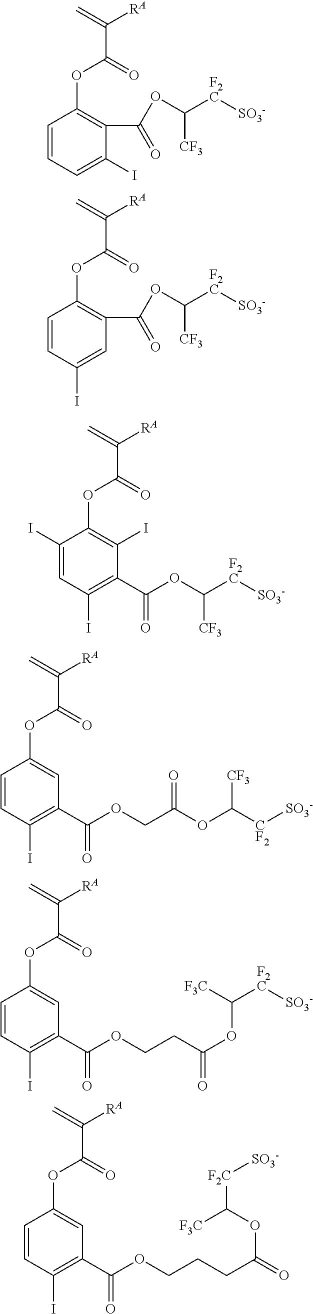

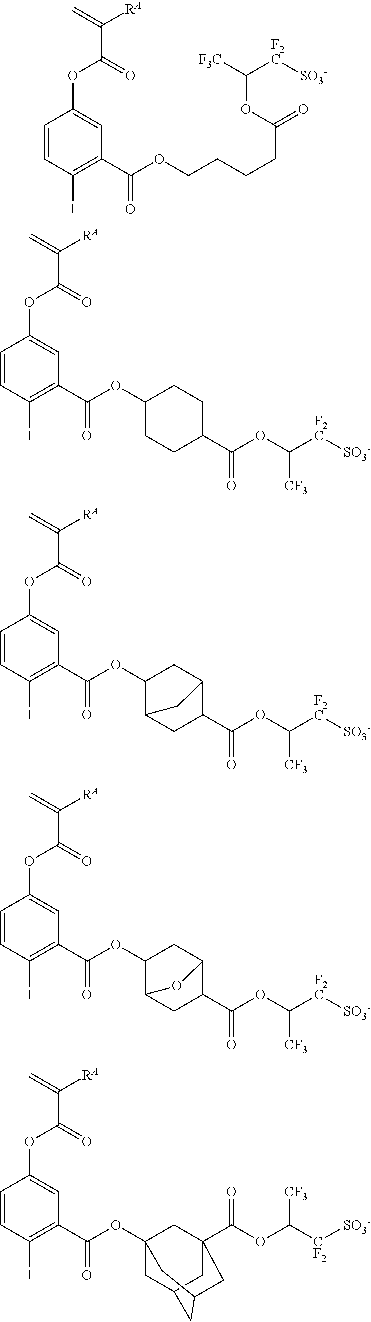

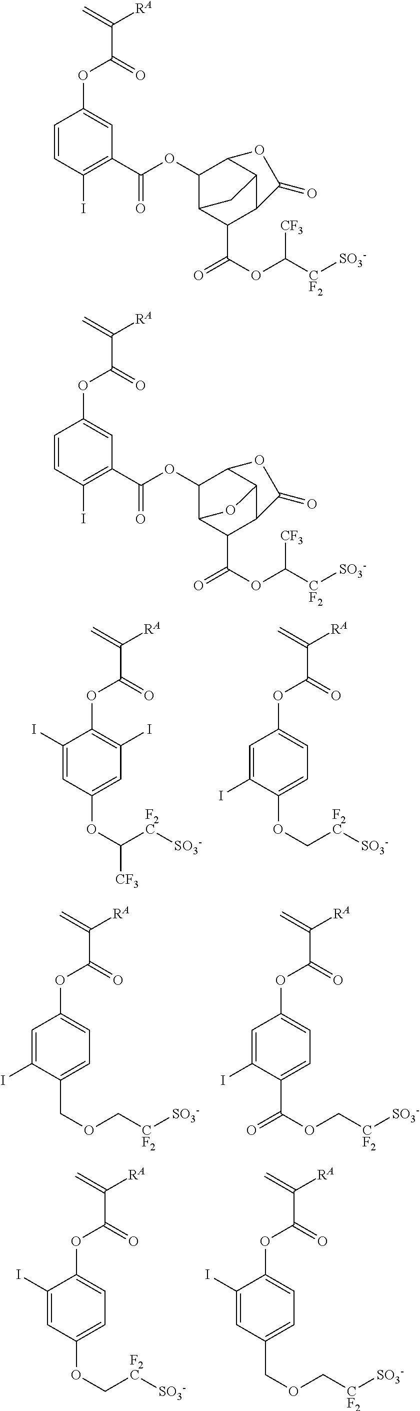

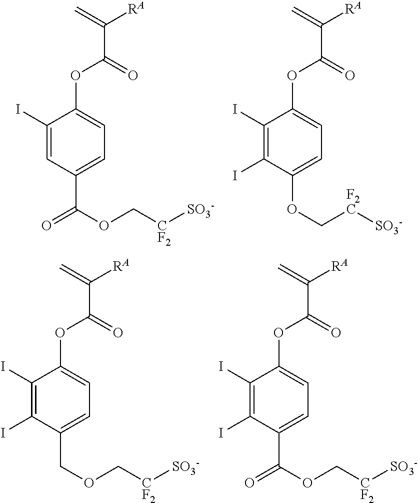

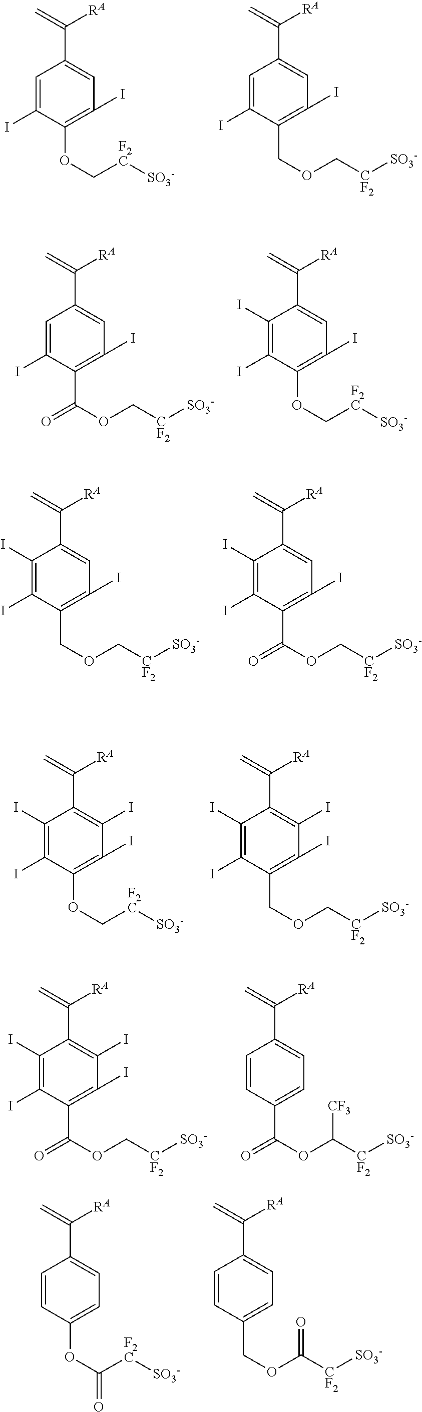

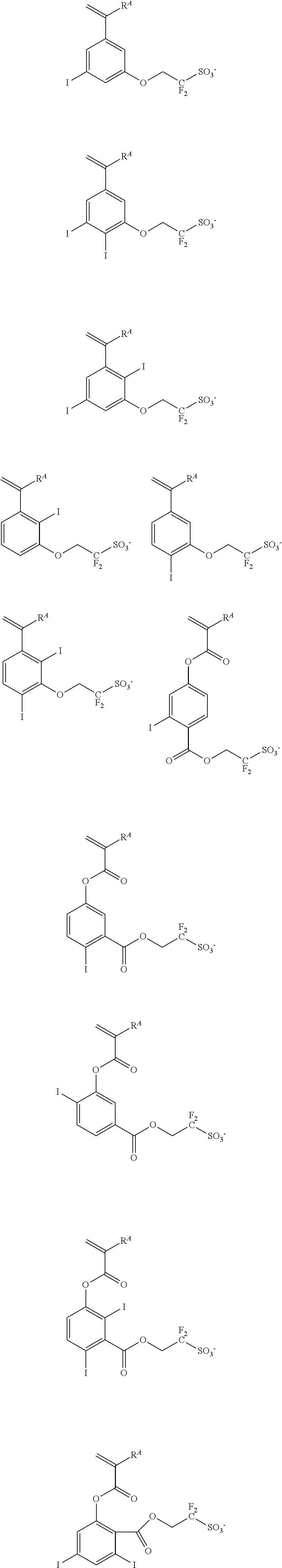

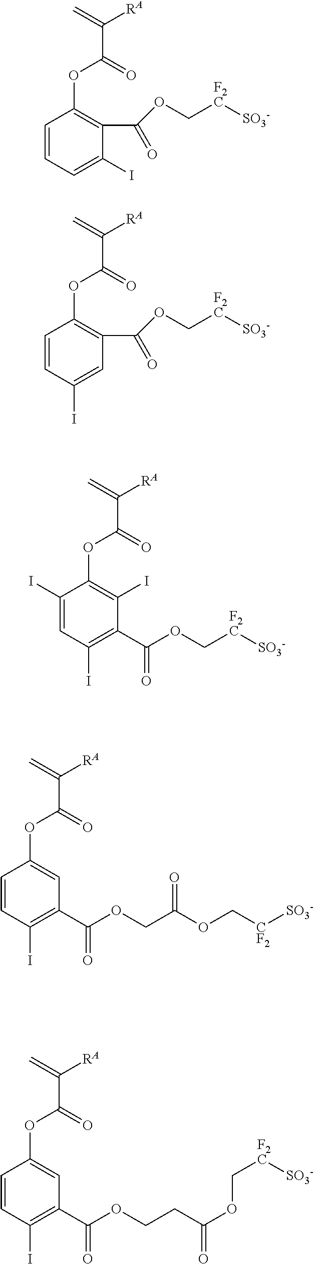

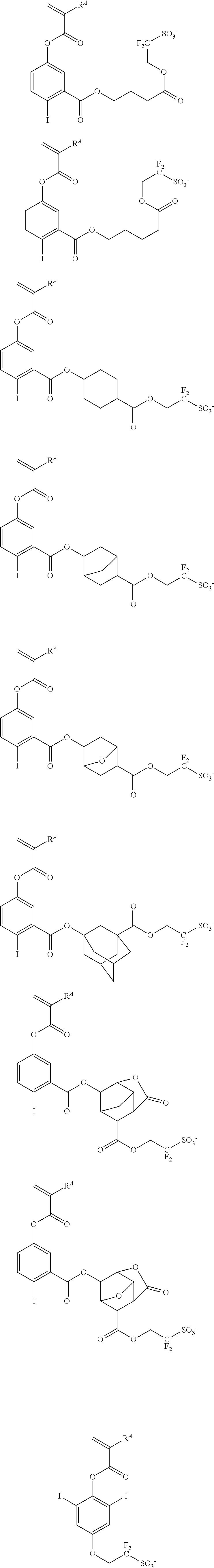

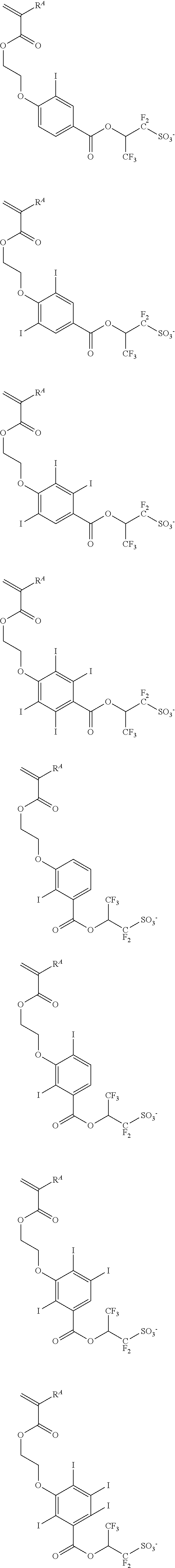

Examples of an anion of a monomer to give the repeating unit-b3 include those shown below, but are not limited thereto. Note that, in the following formulae, R^{A} is as defined above.

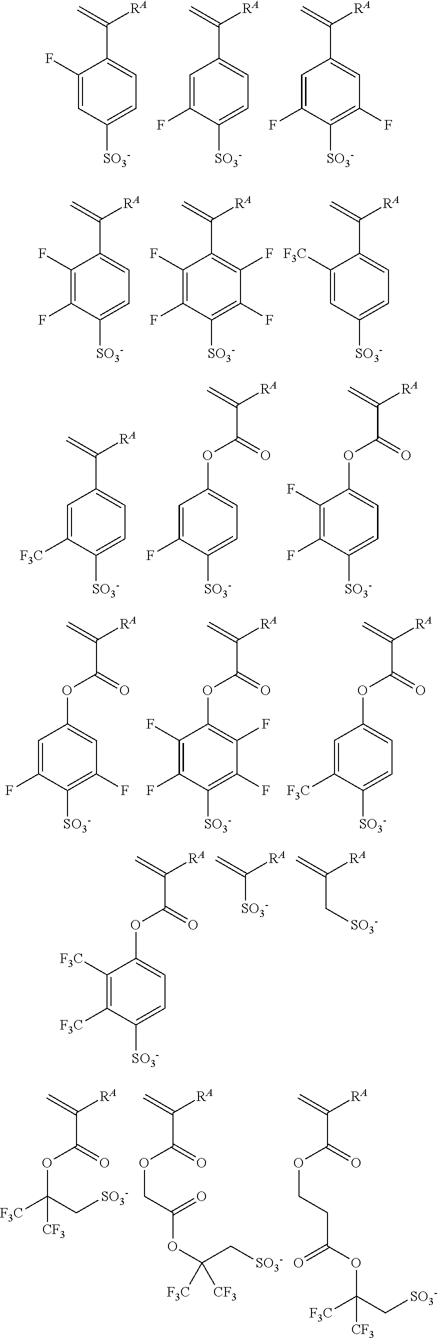

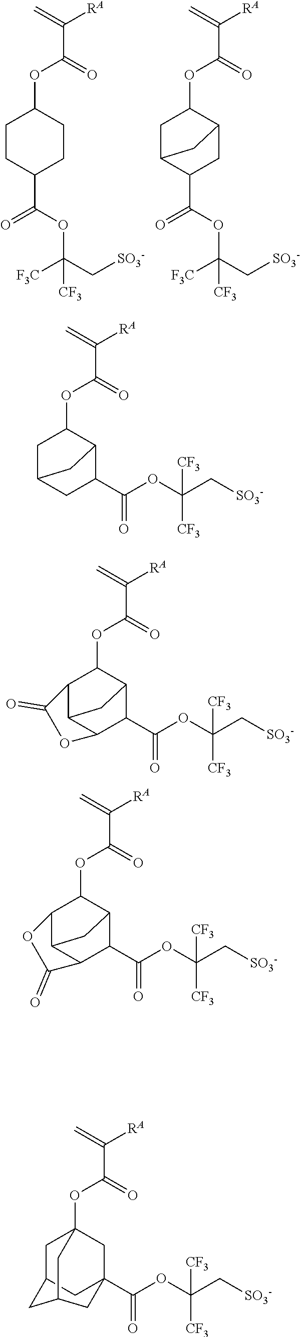

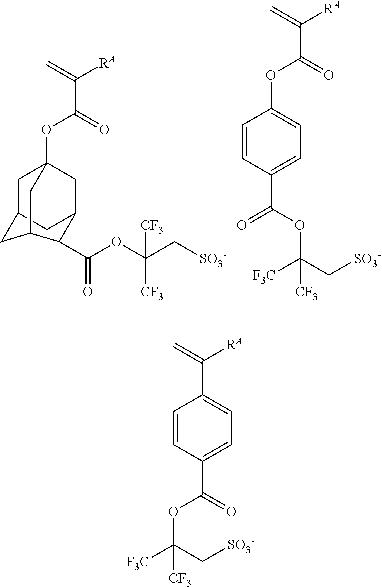

Specific examples of anions of the repeating units-b4 and -b5 include those shown below, but are not limited thereto. Note that, in the following formulae, X^{BI} represents an iodine atom or a bromine atom.

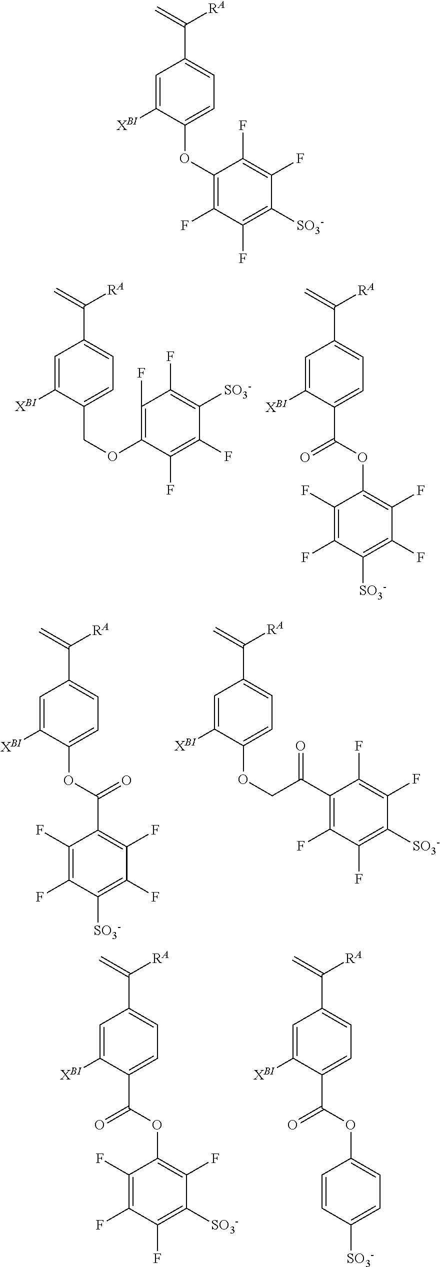

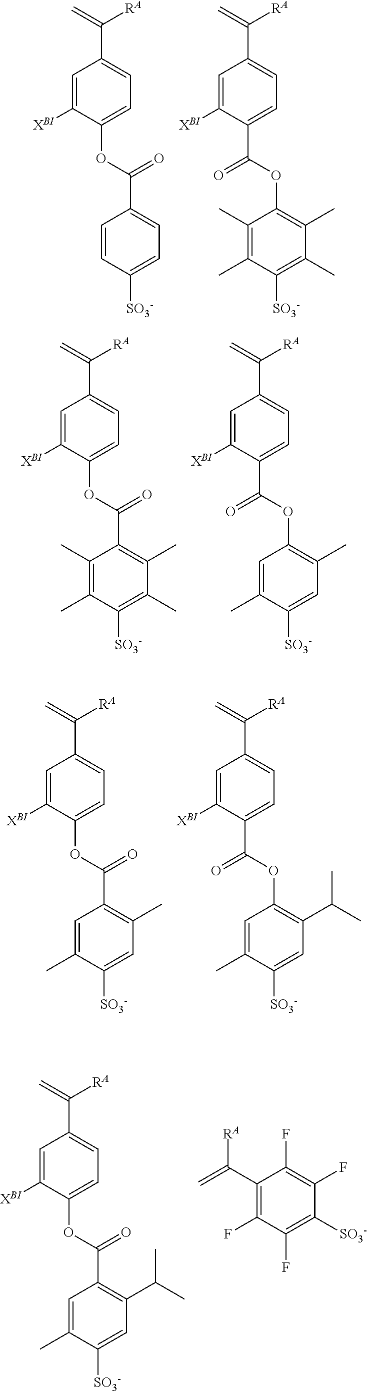

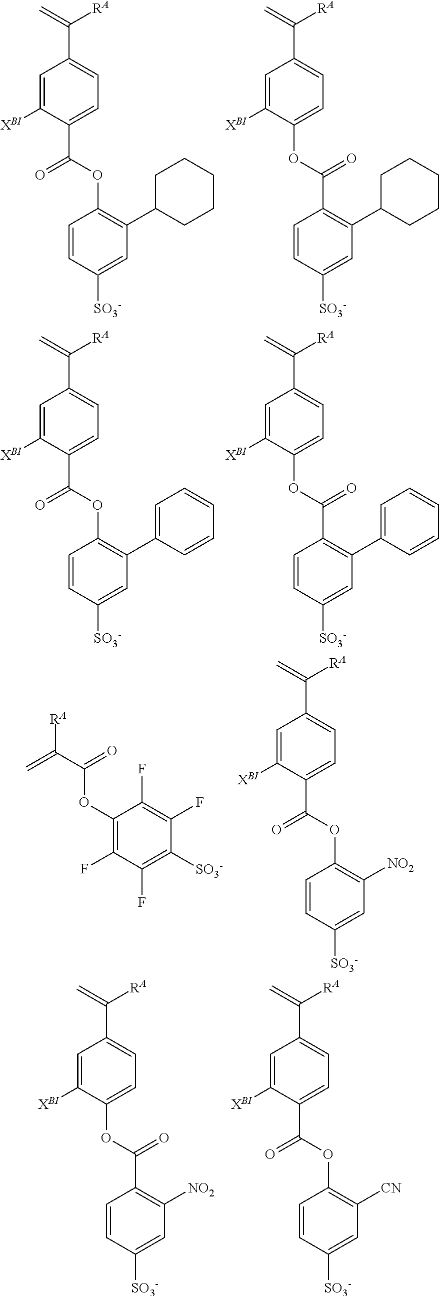

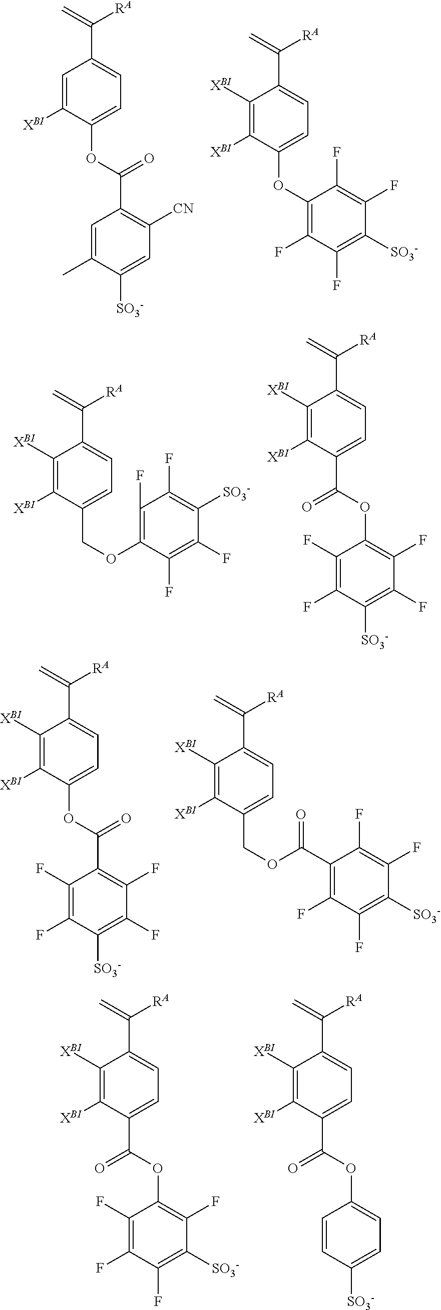

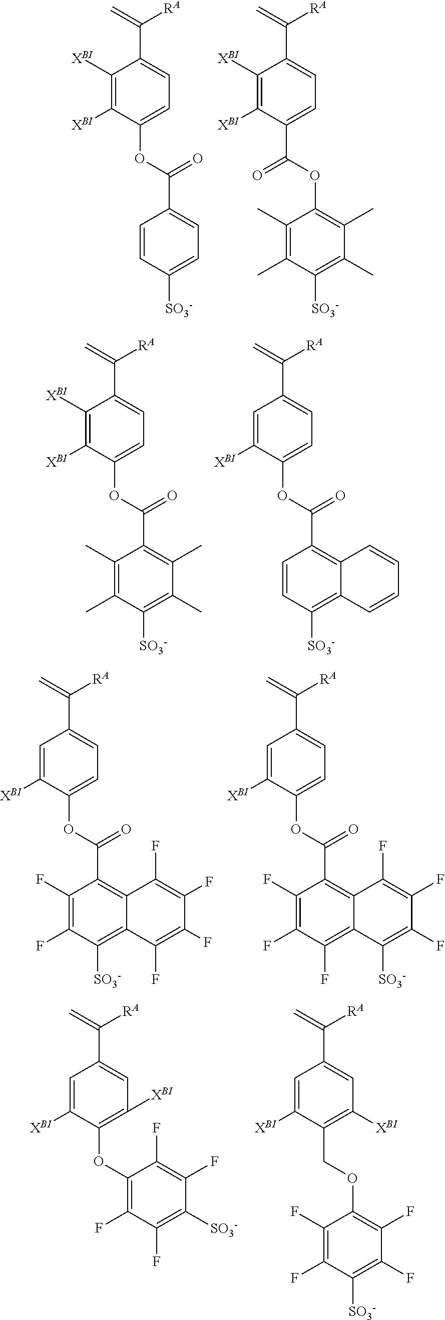

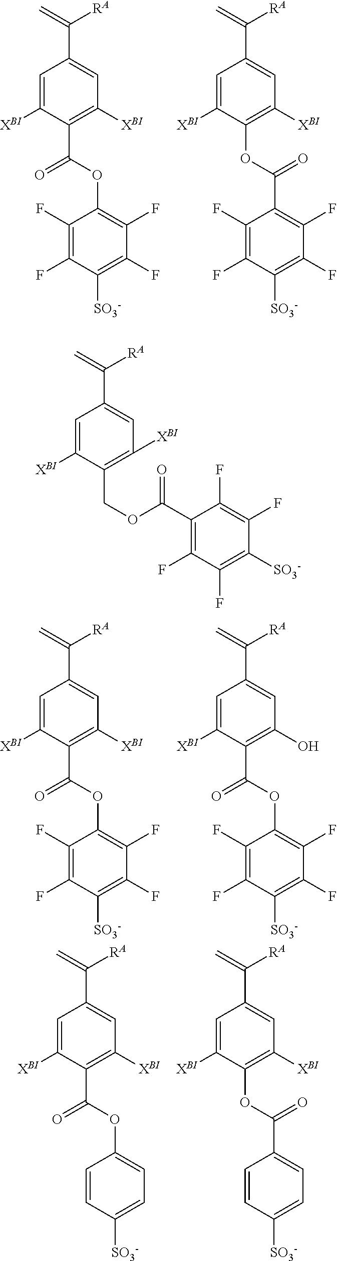

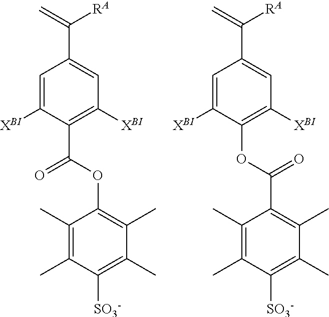

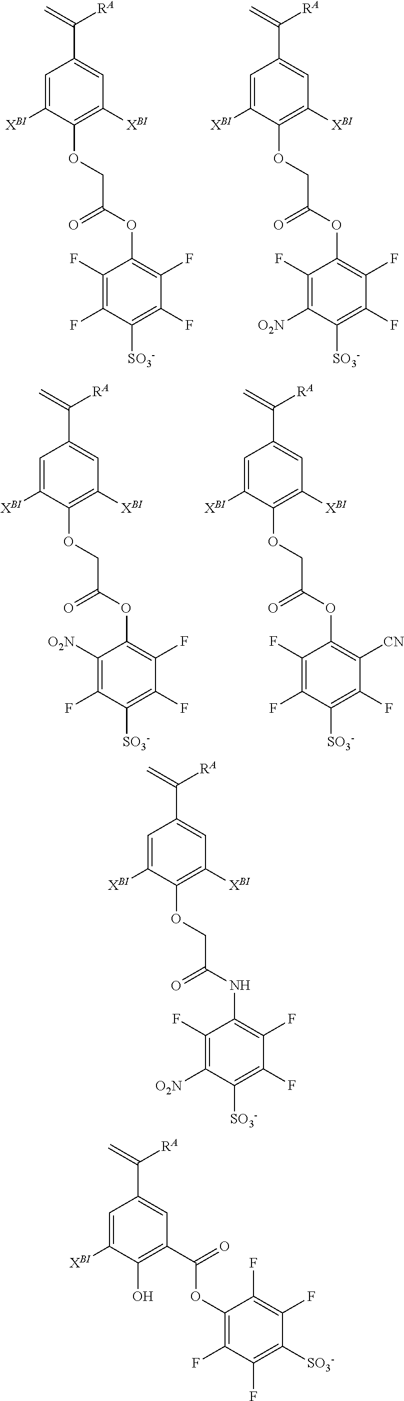

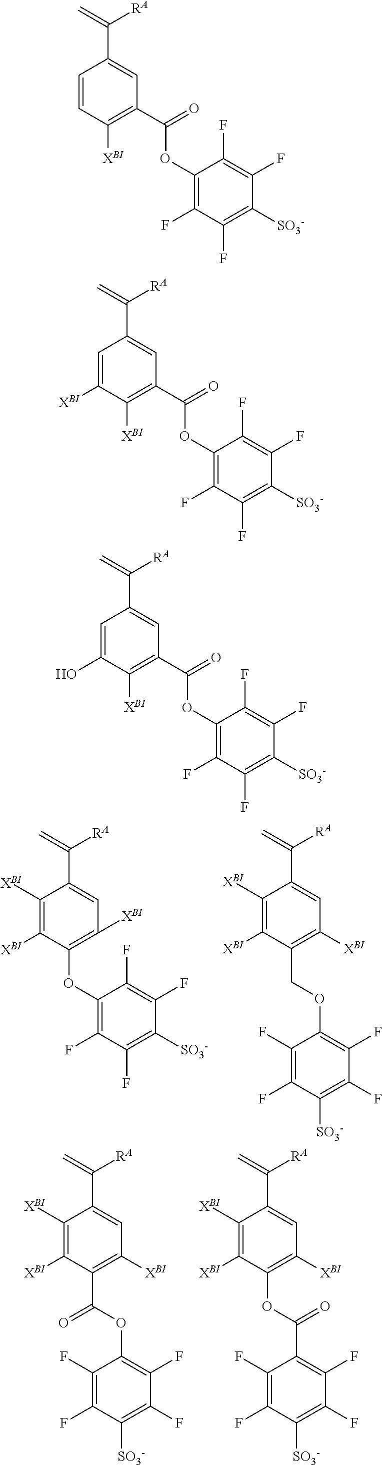

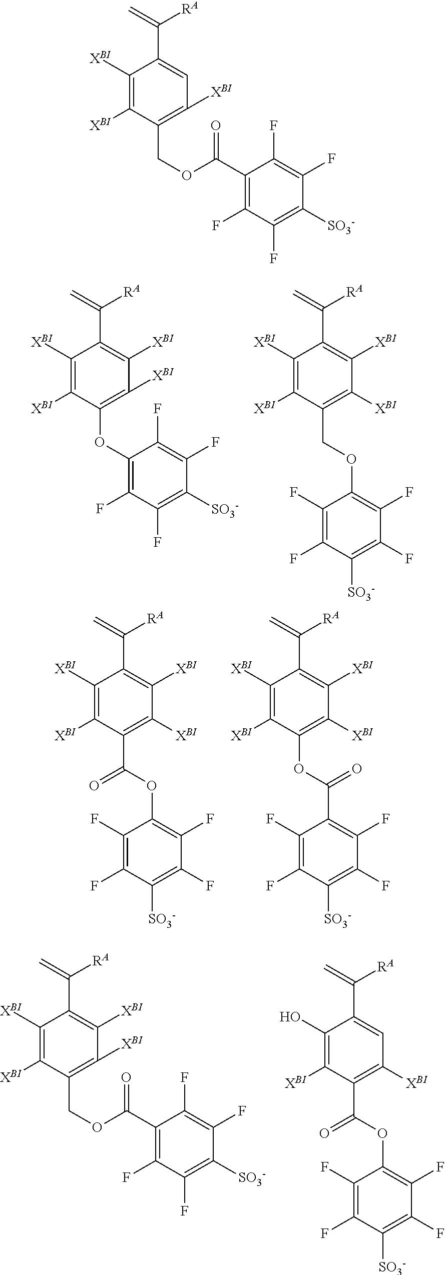

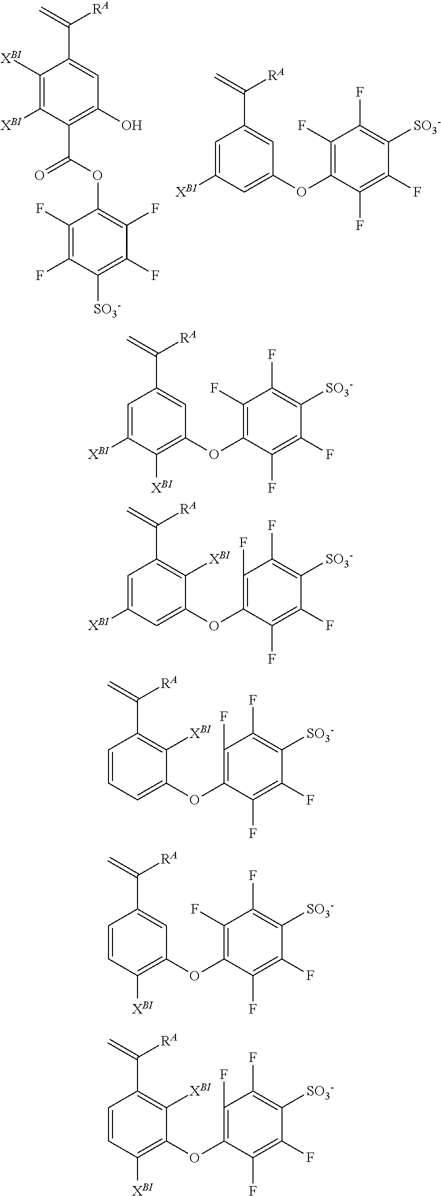

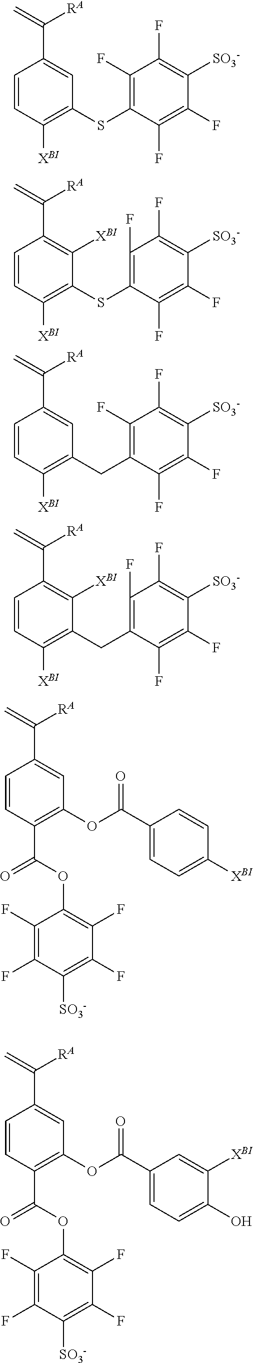

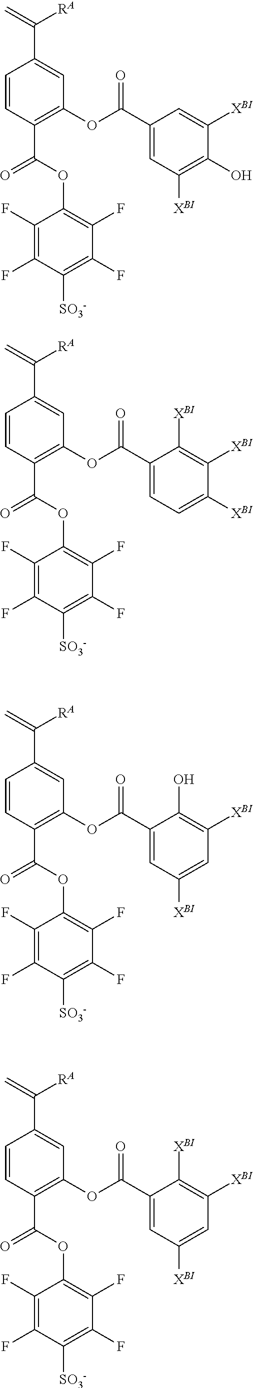

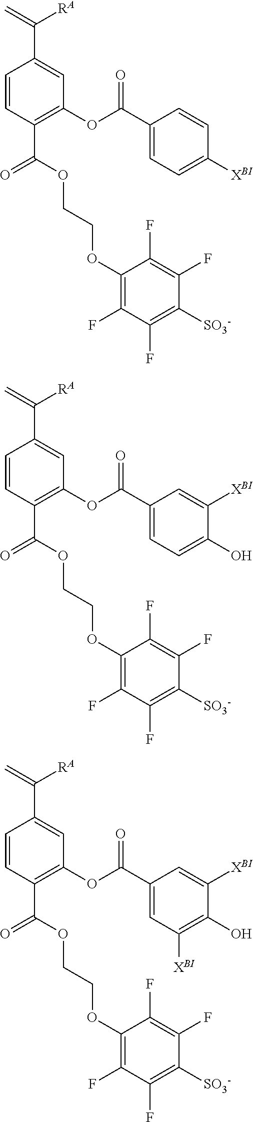

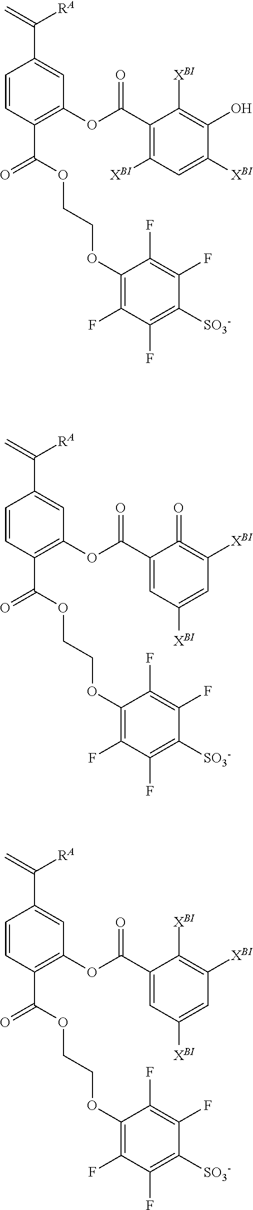

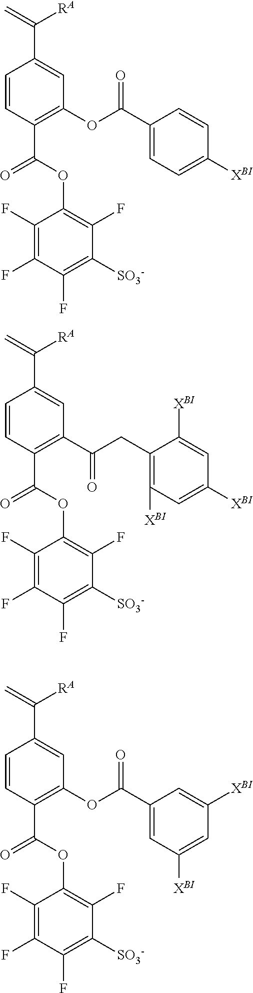

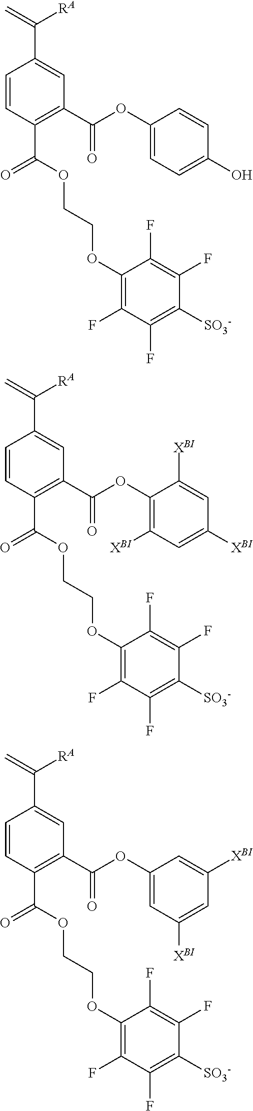

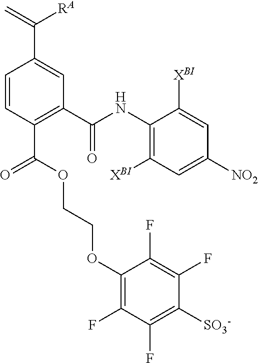

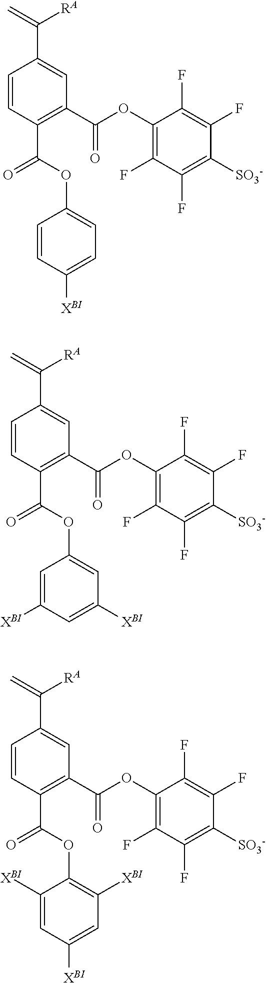

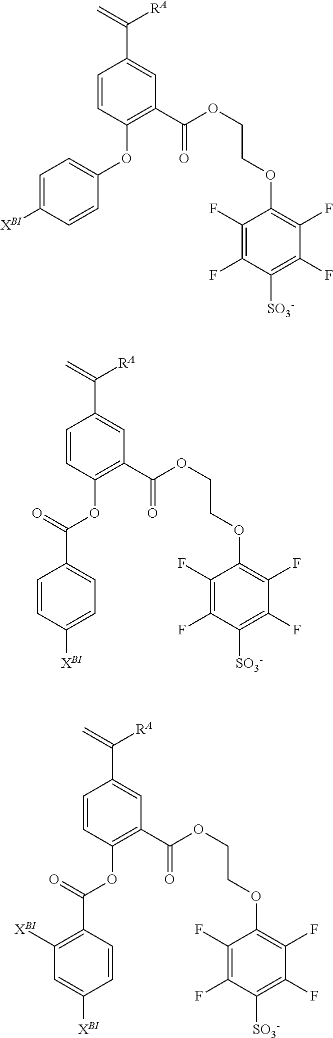

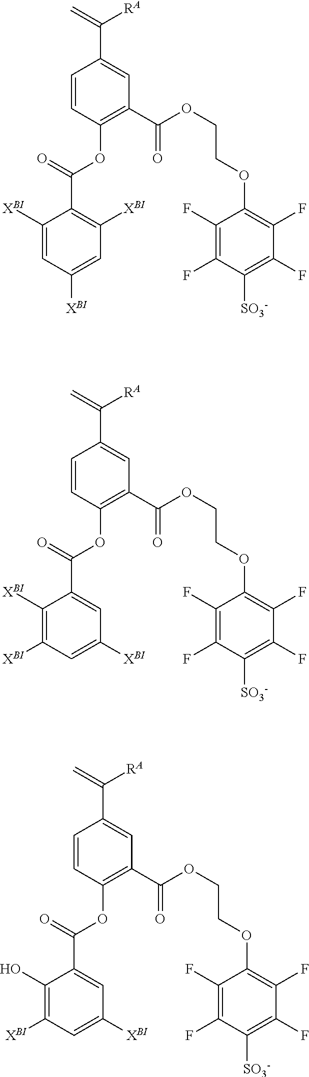

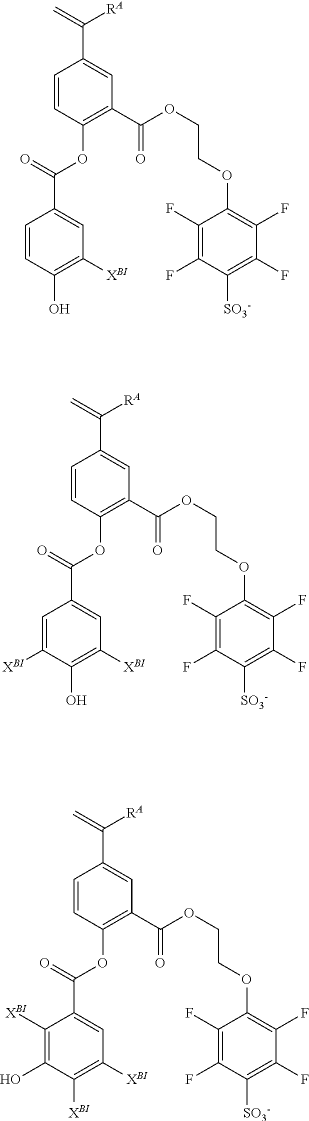

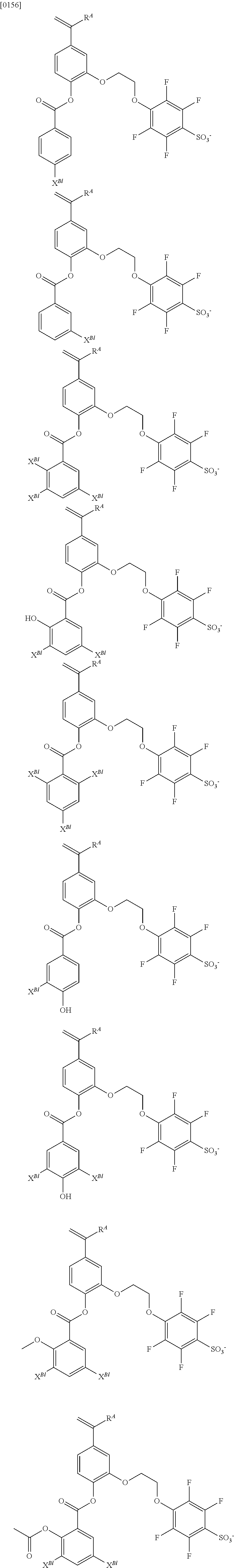

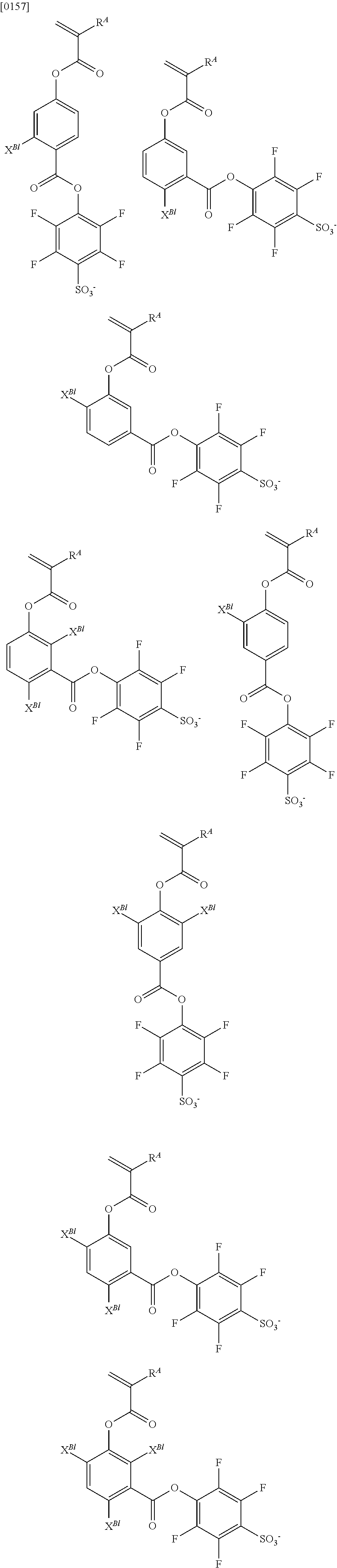

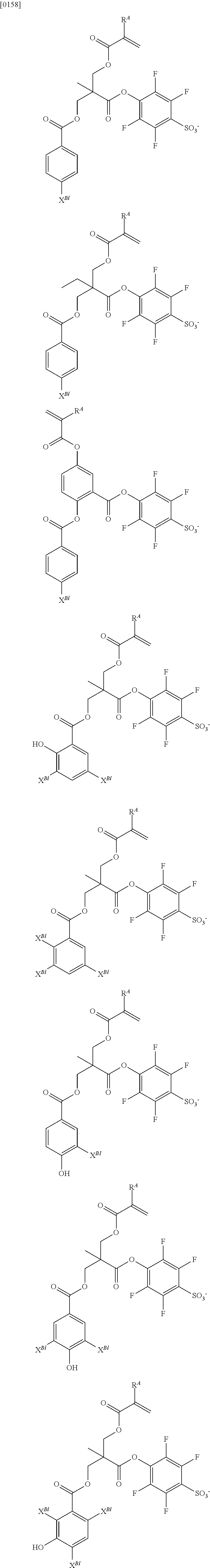

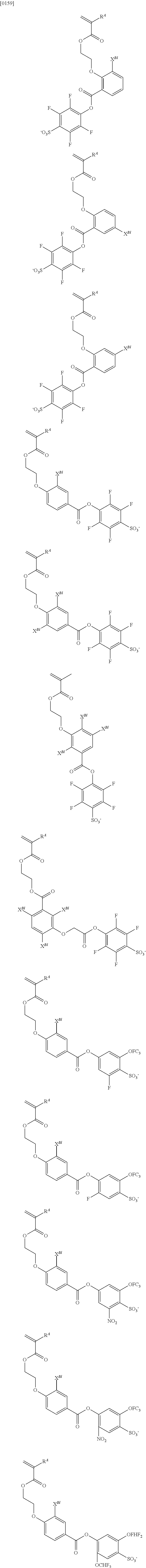

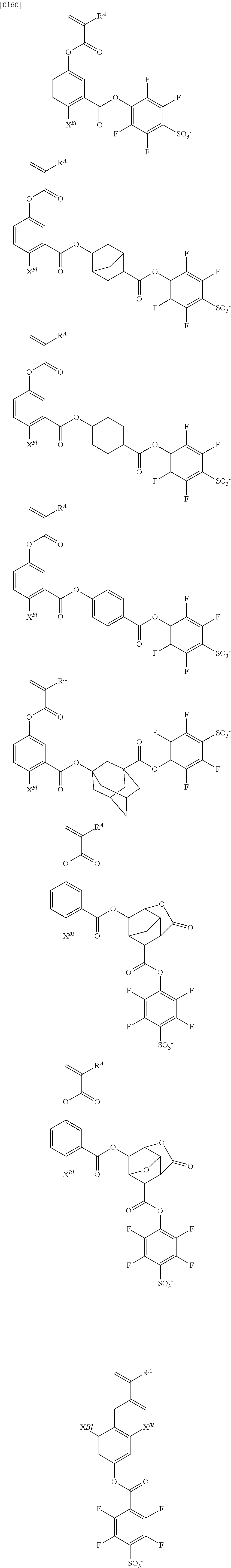

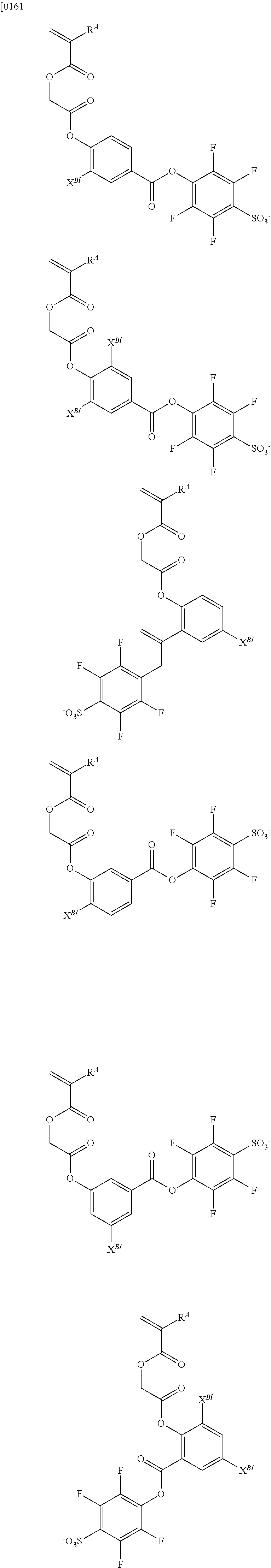

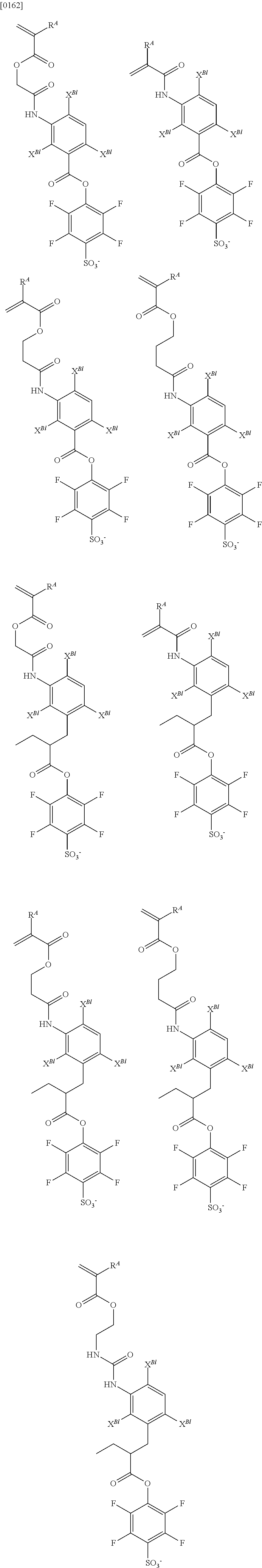

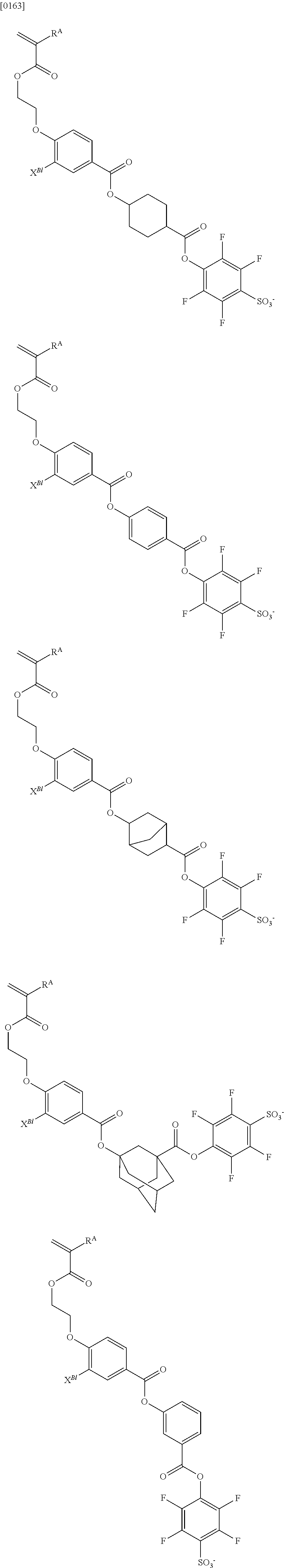

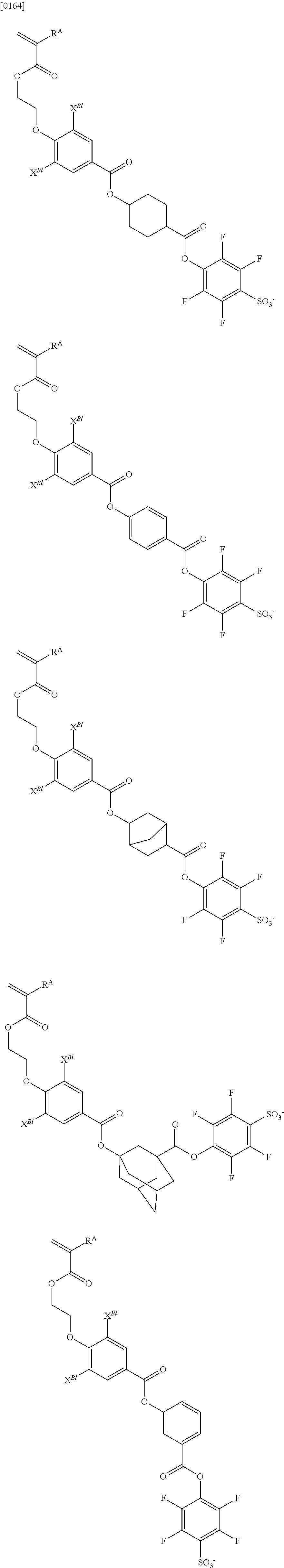

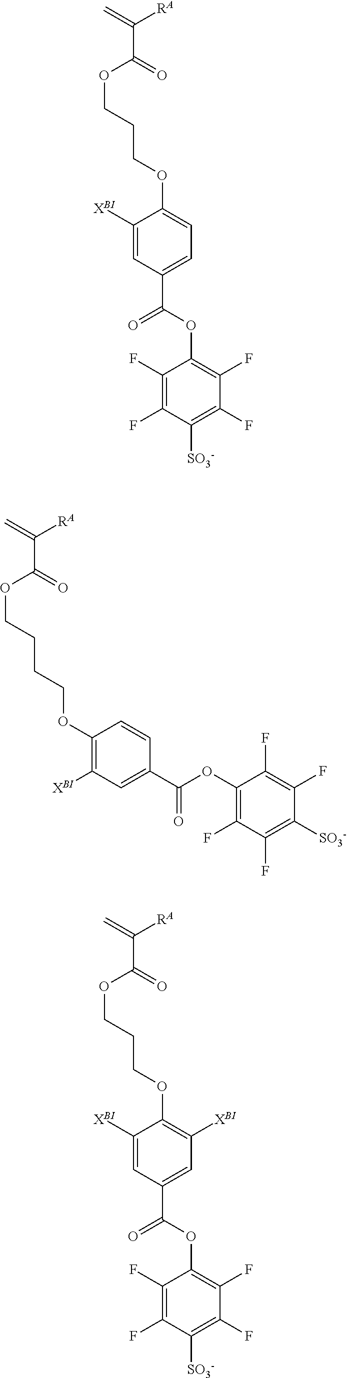

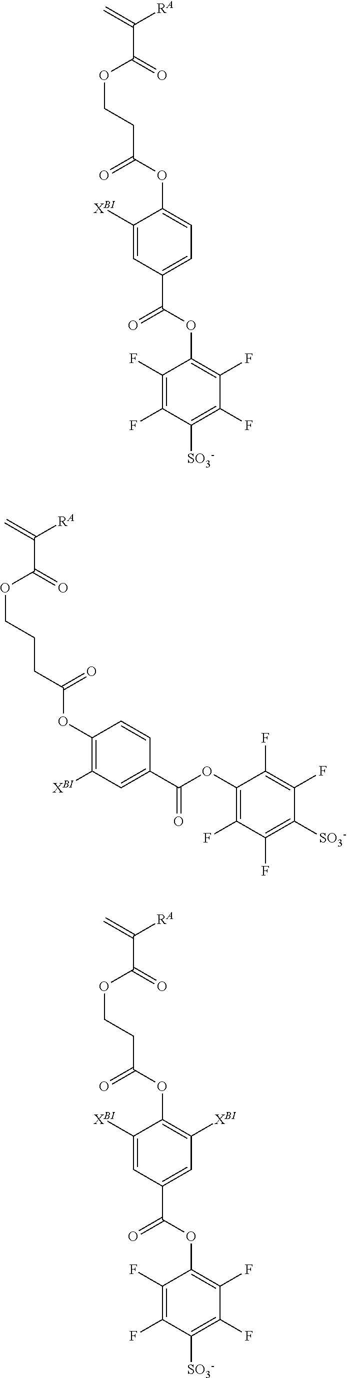

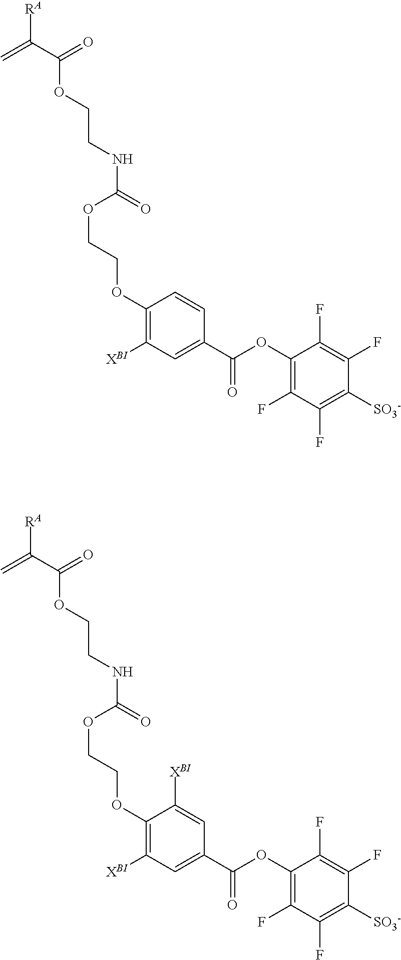

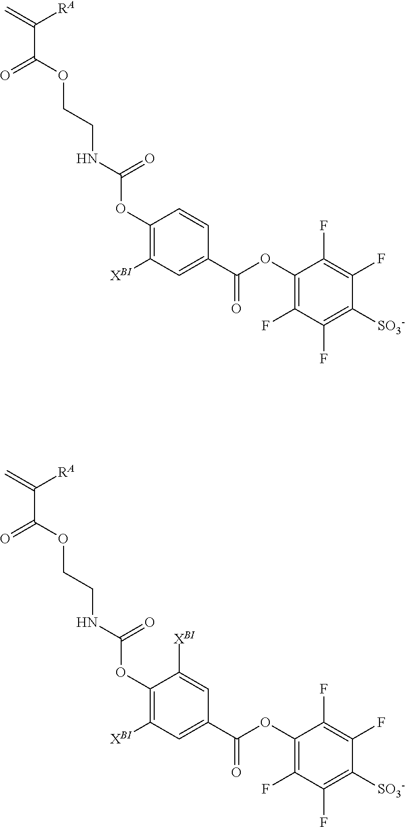

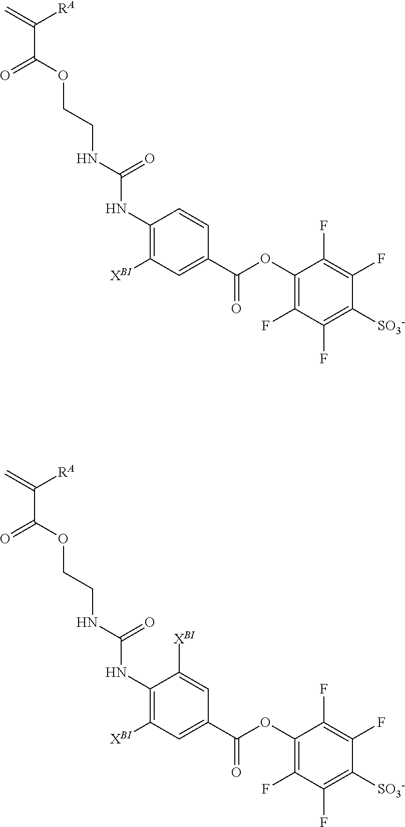

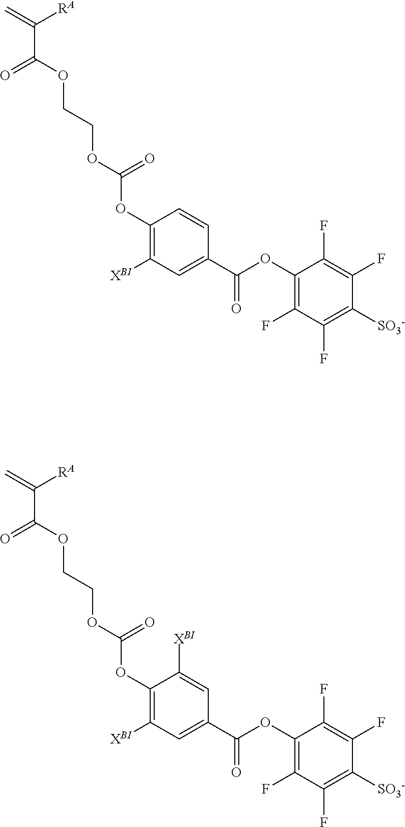

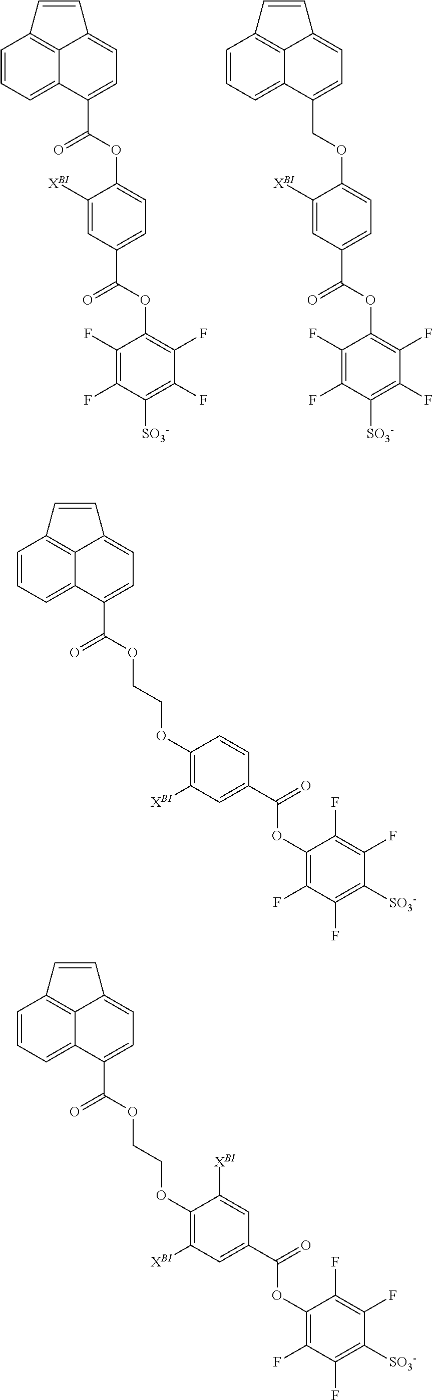

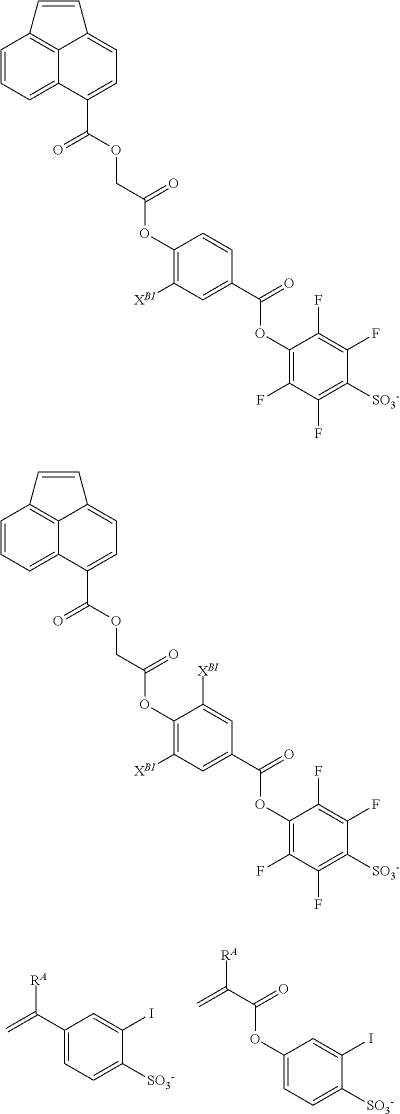

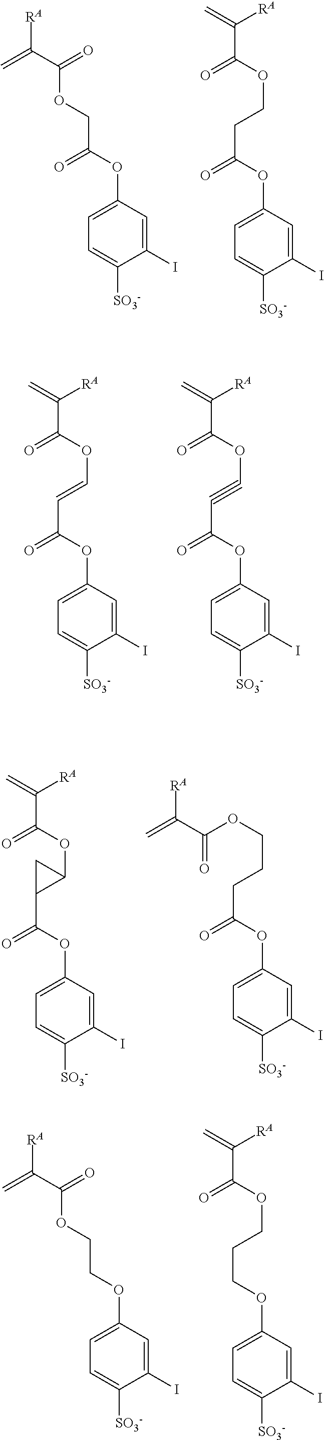

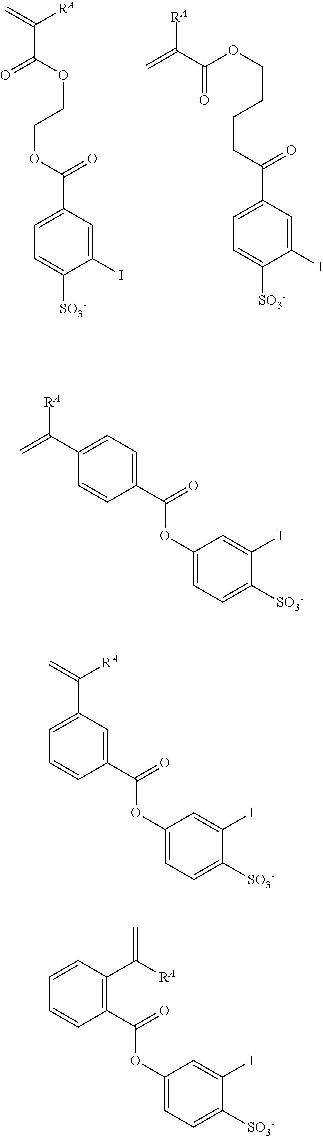

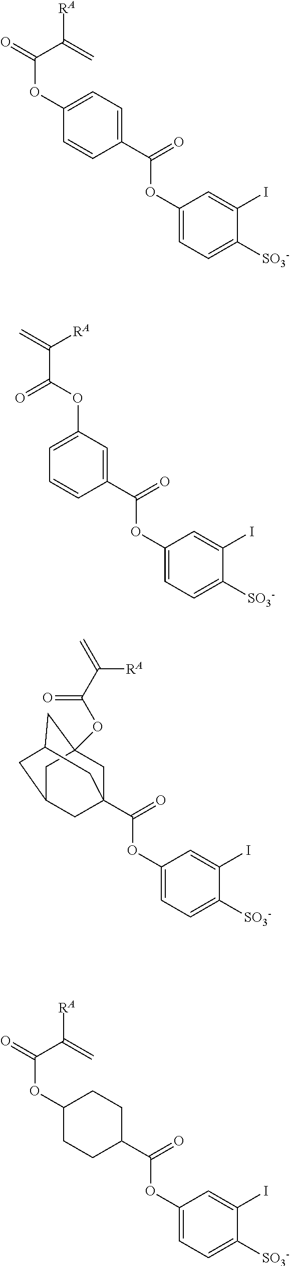

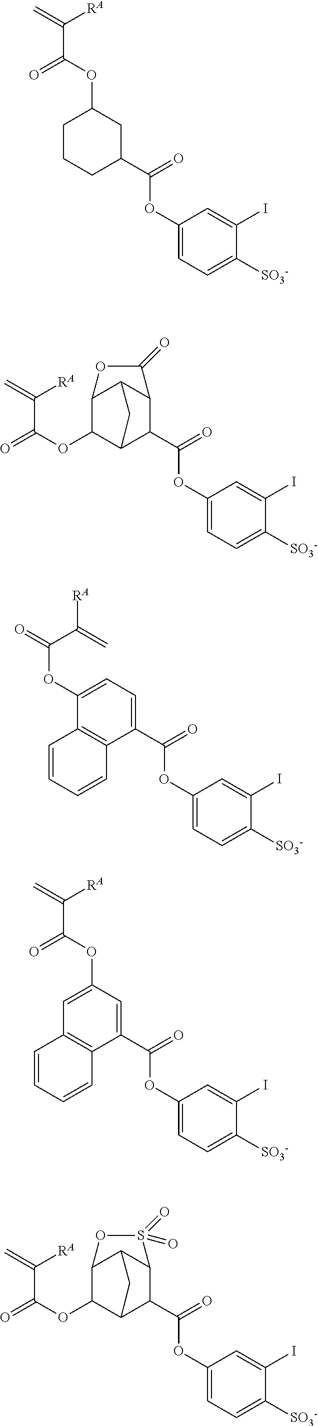

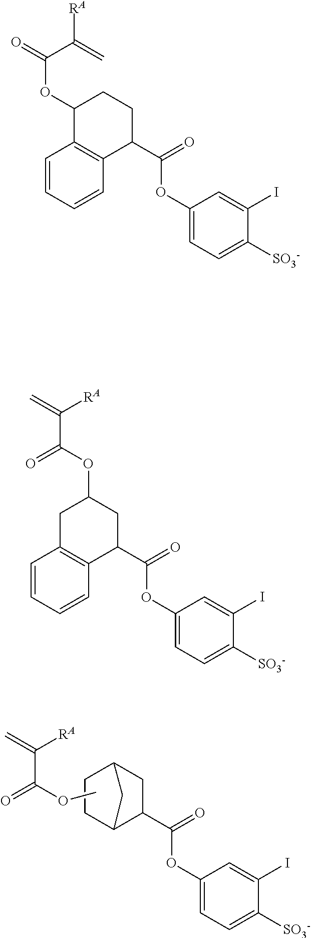

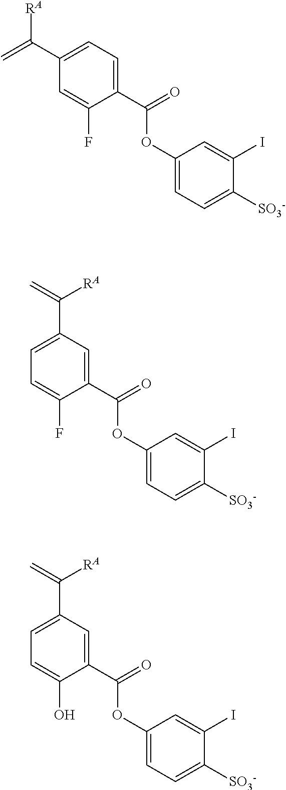

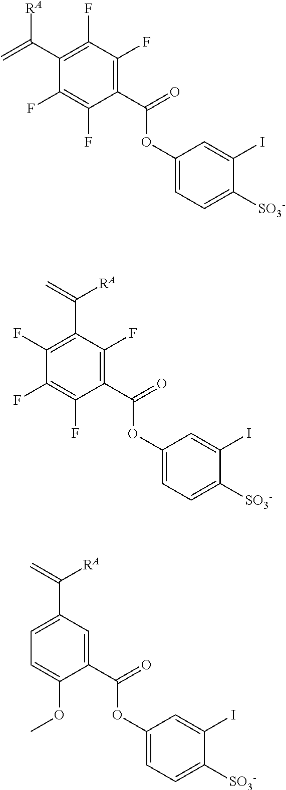

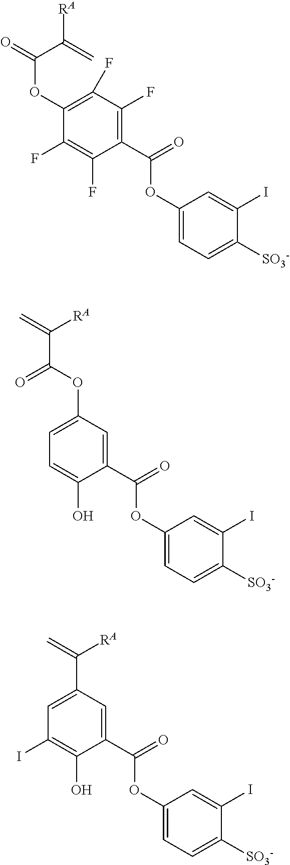

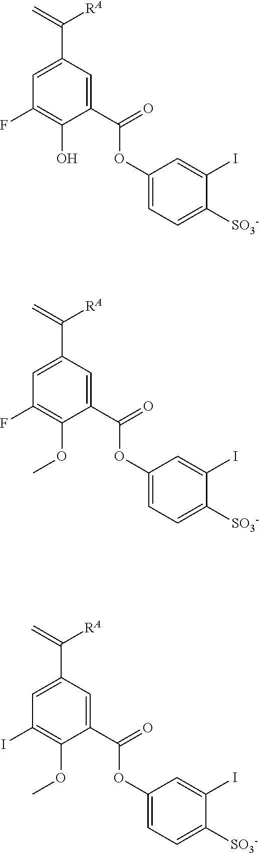

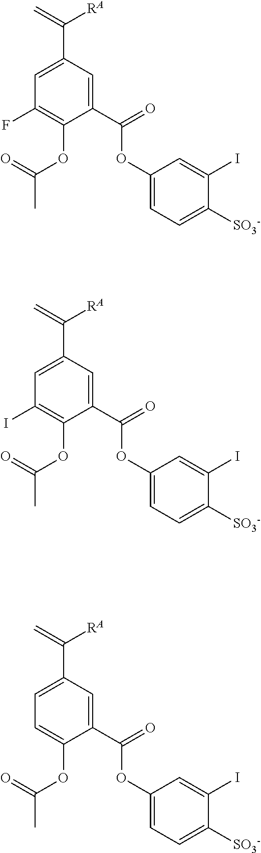

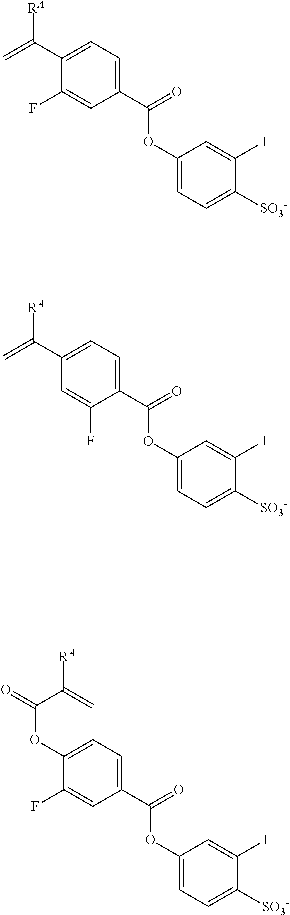

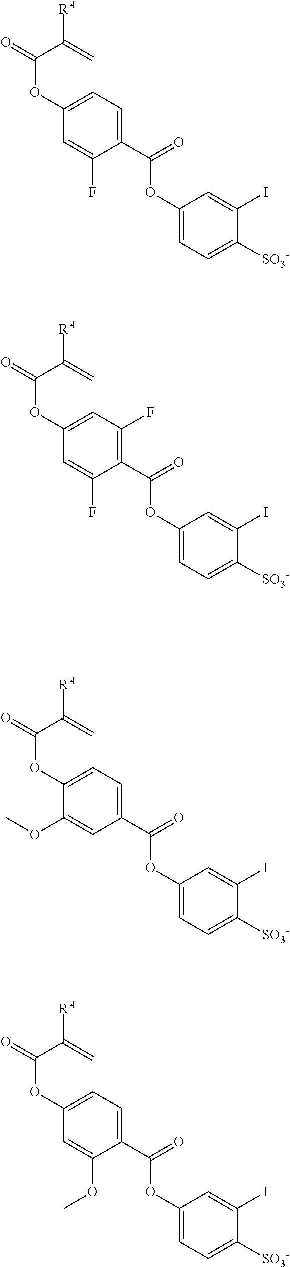

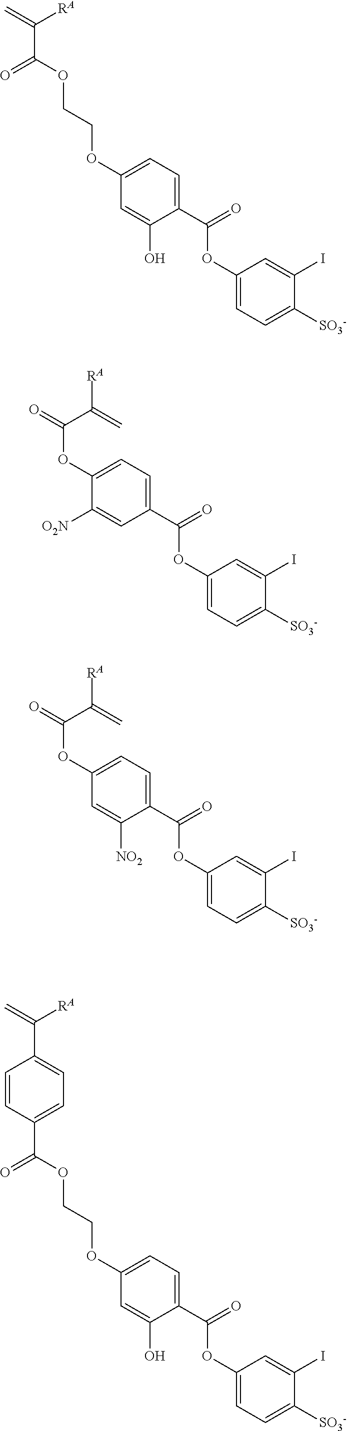

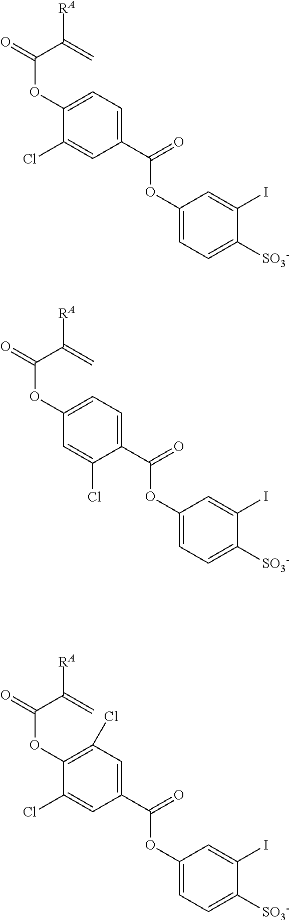

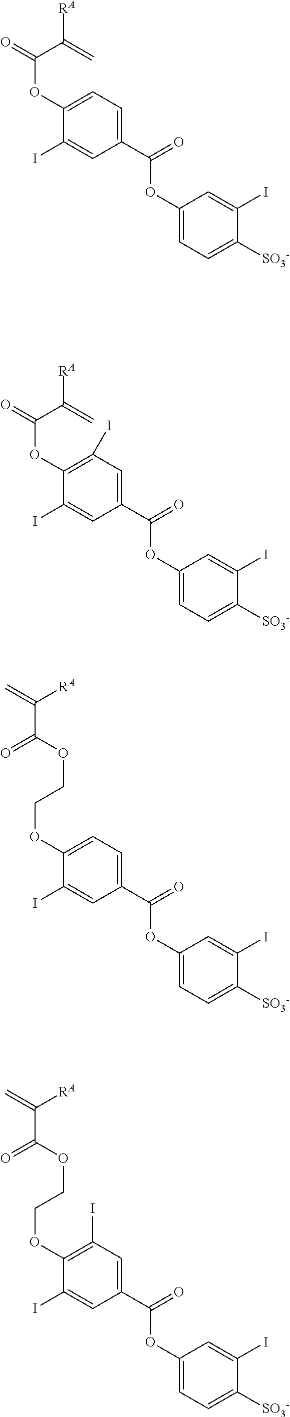

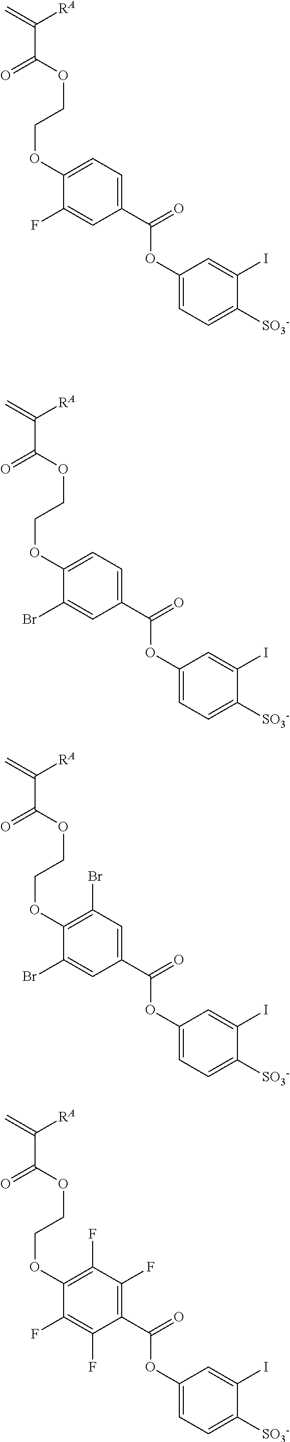

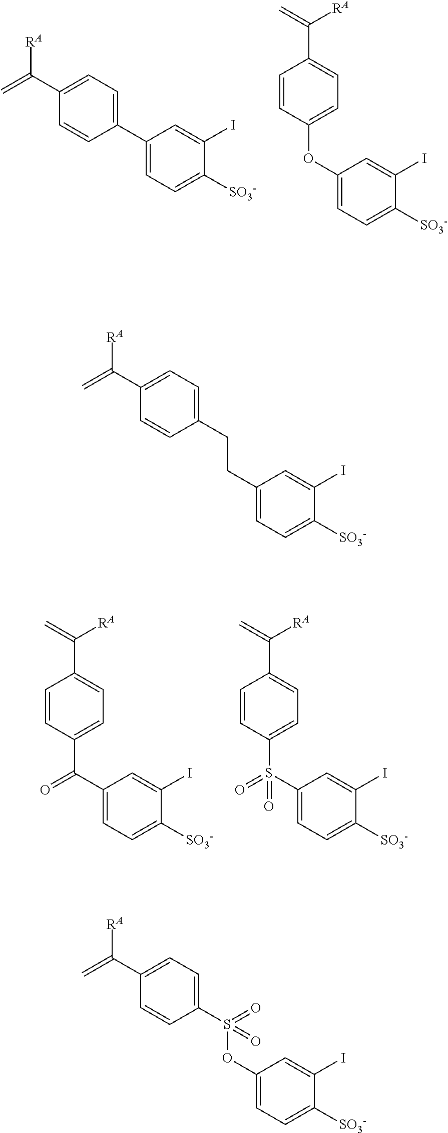

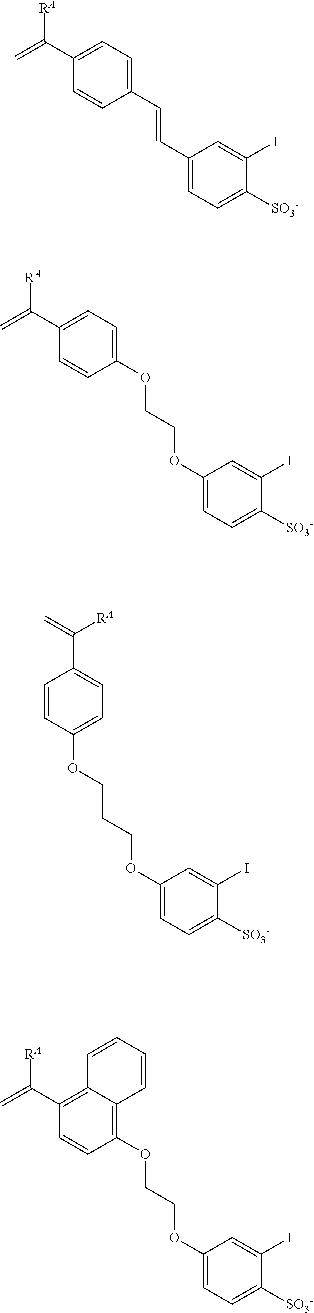

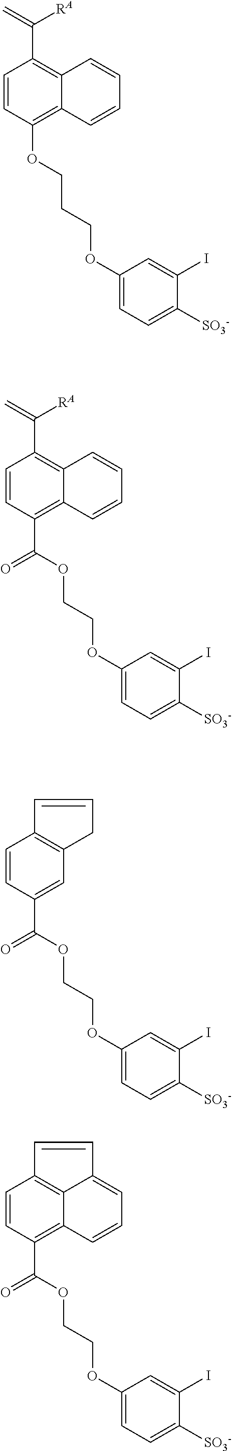

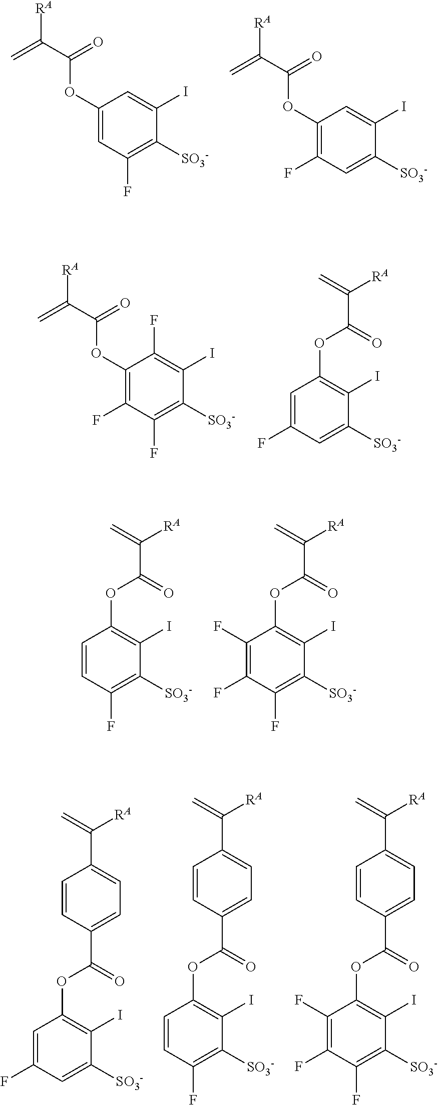

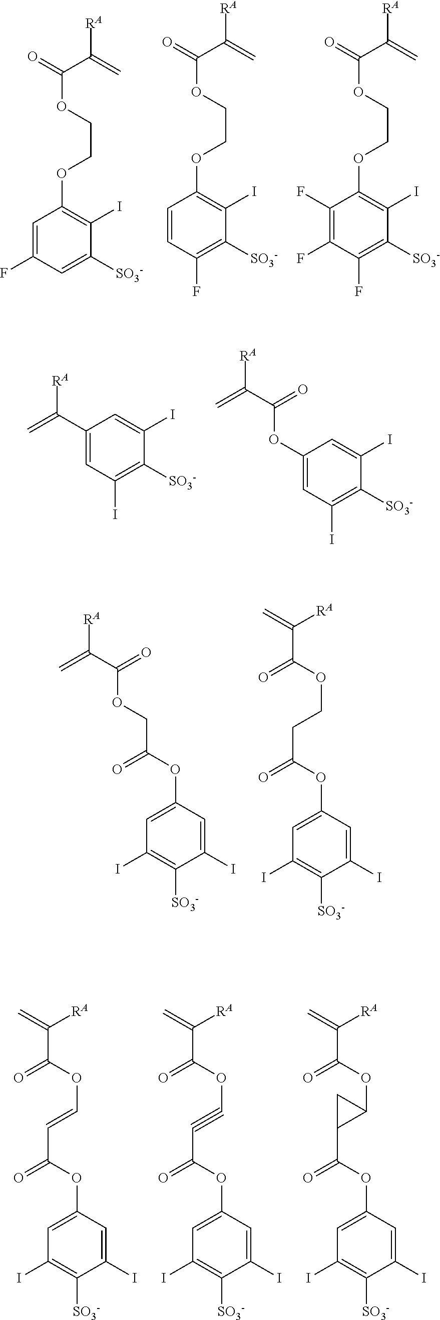

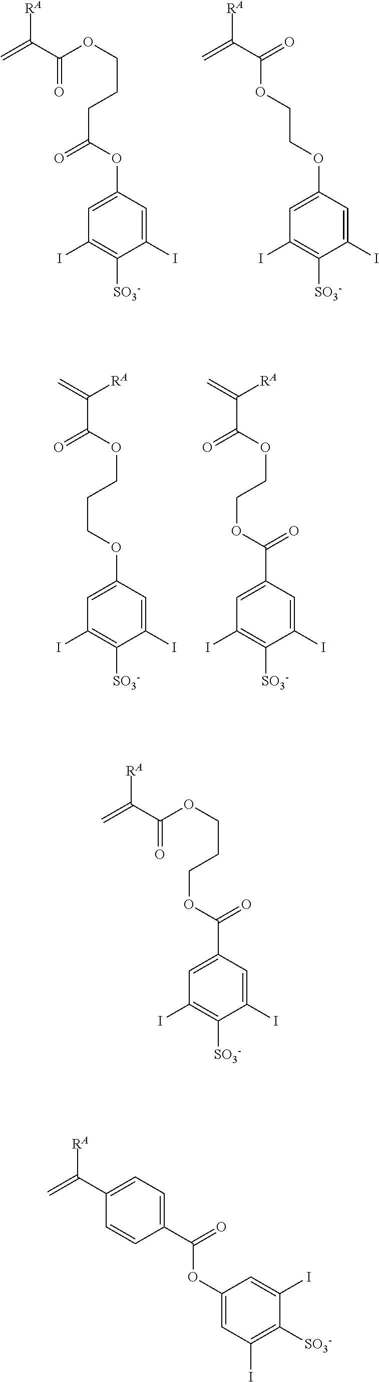

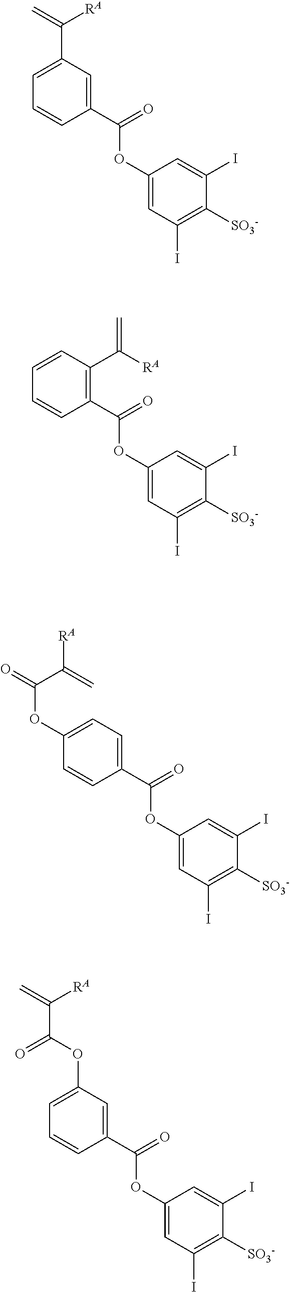

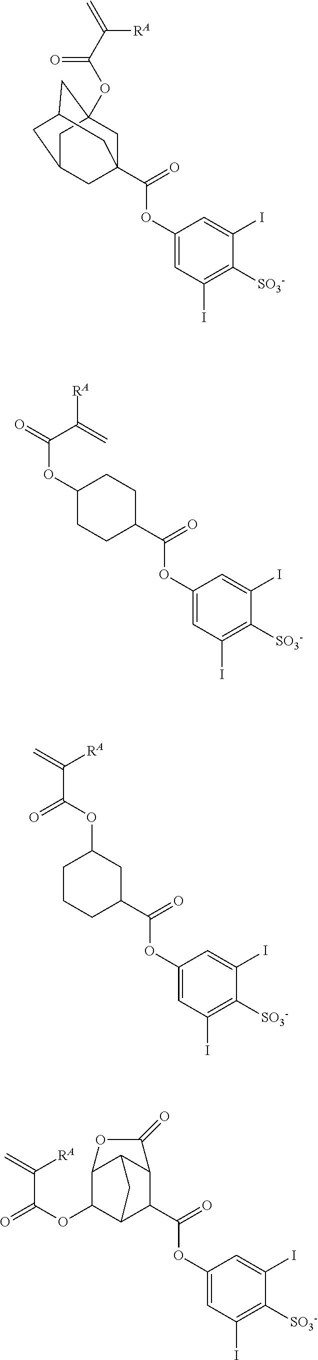

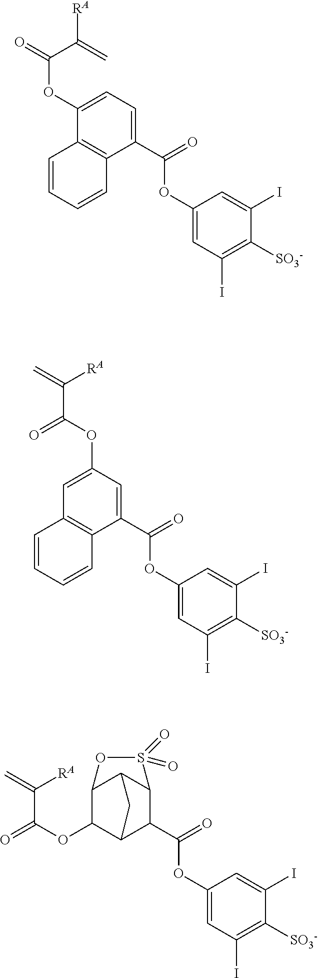

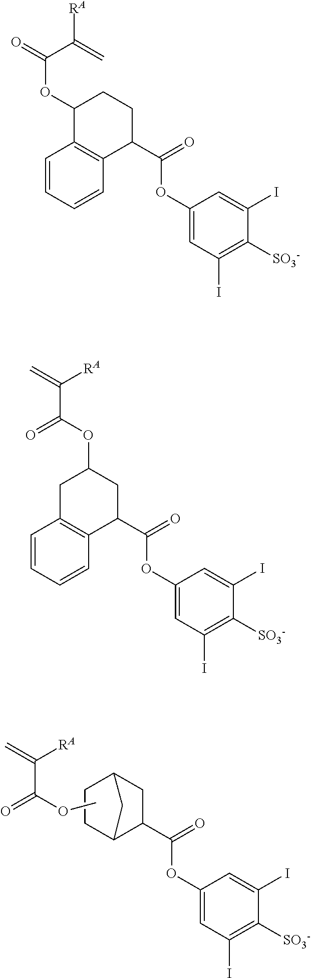

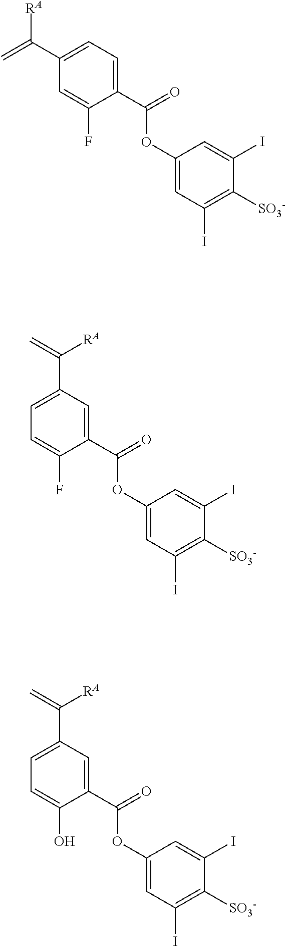

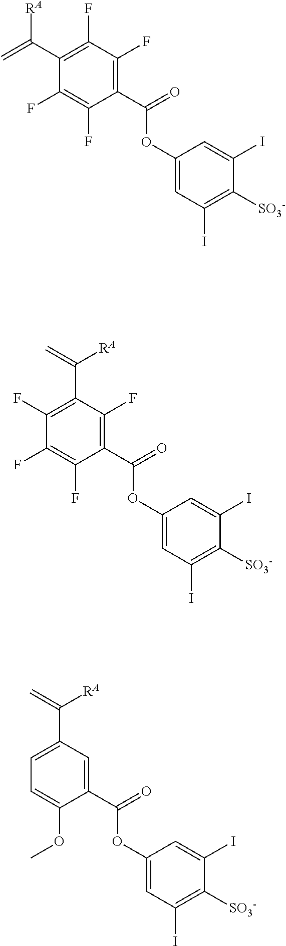

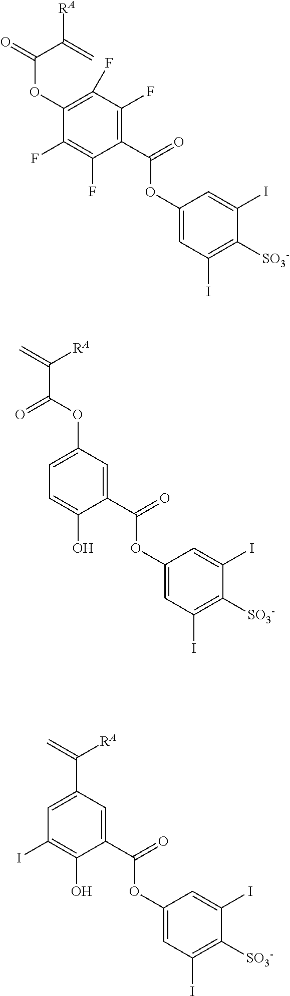

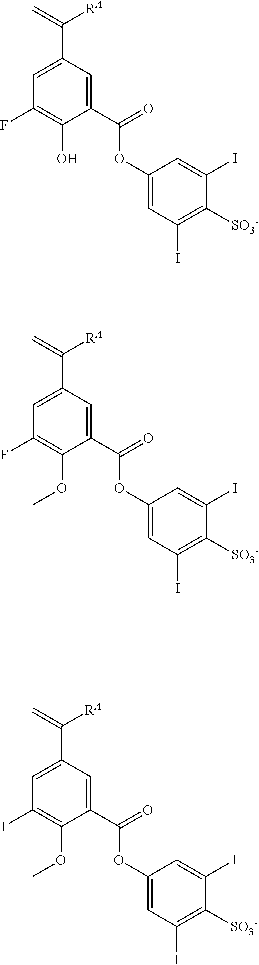

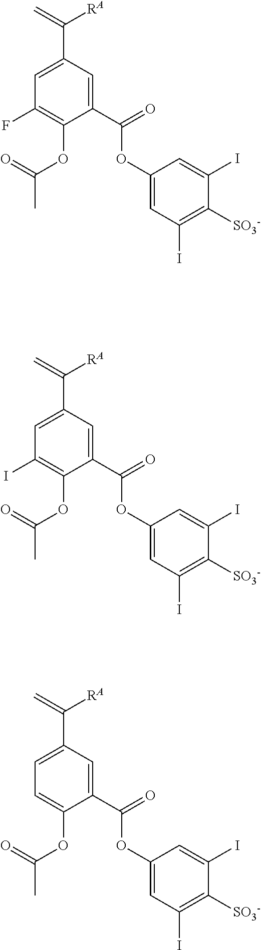

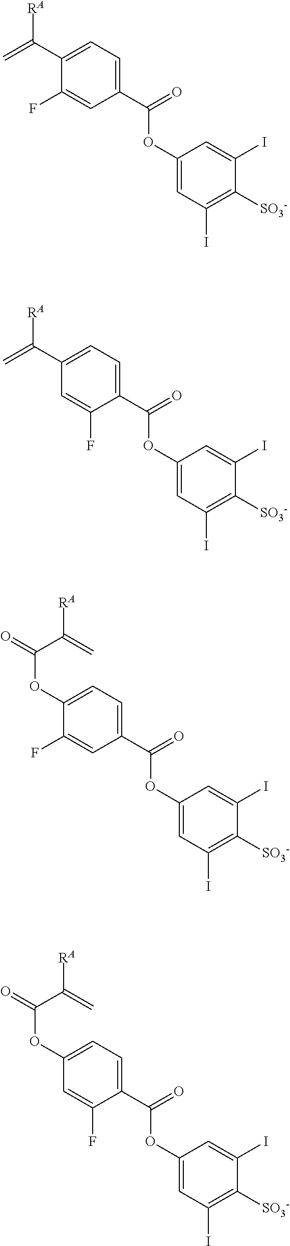

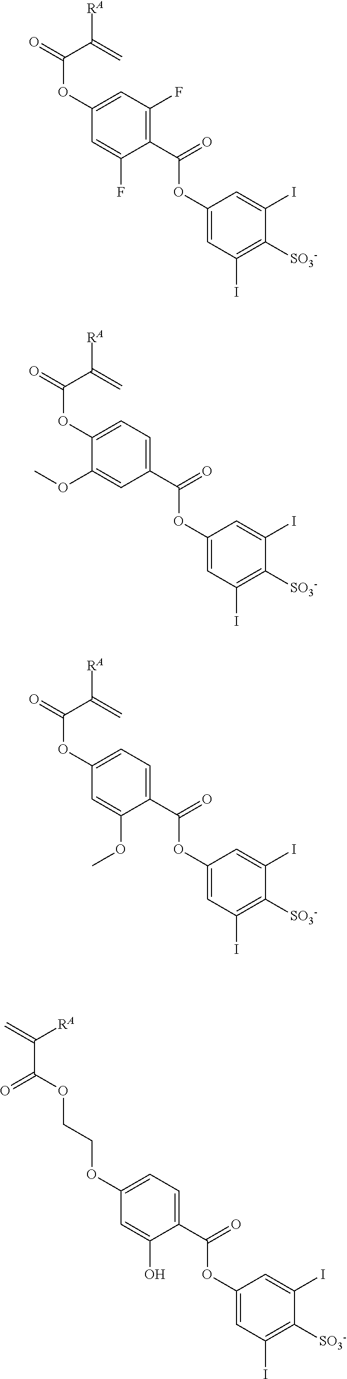

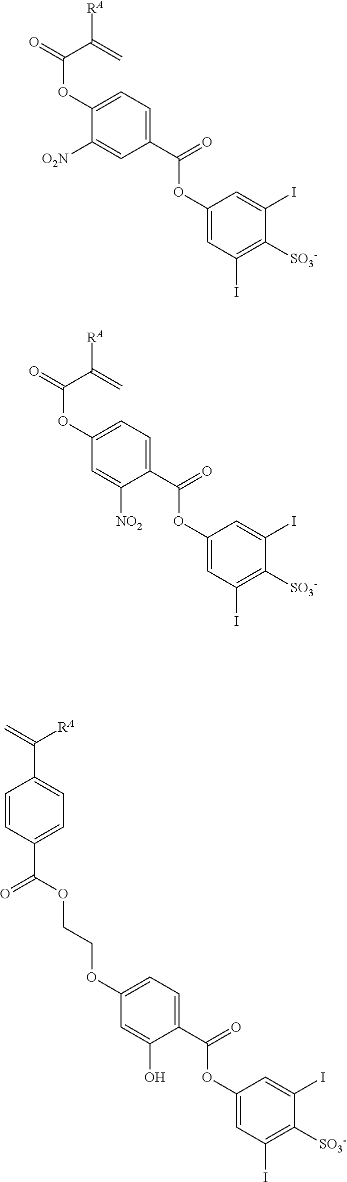

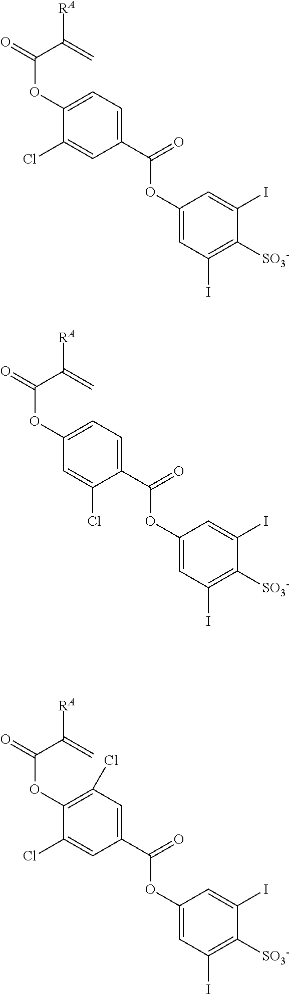

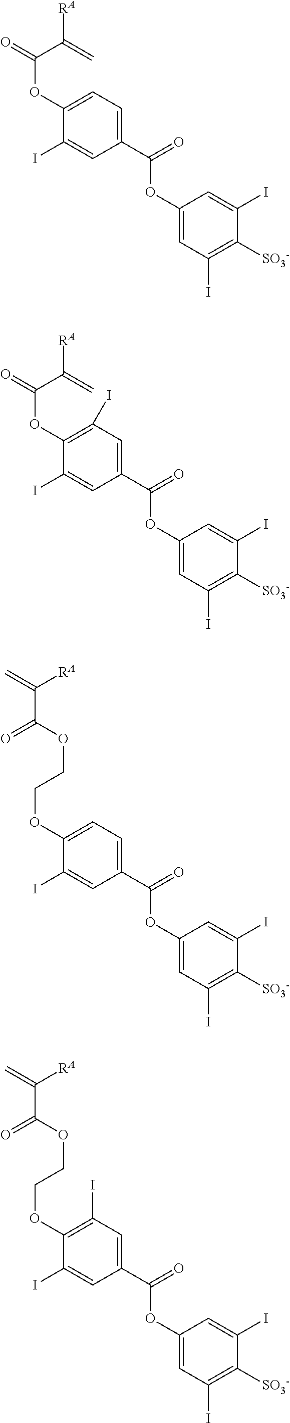

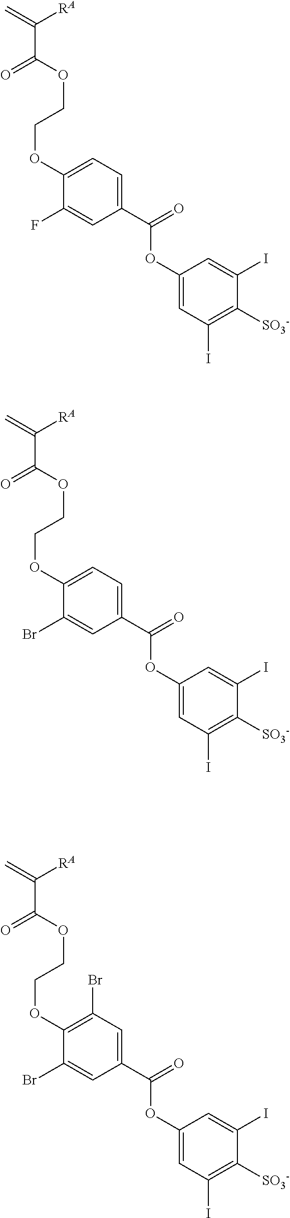

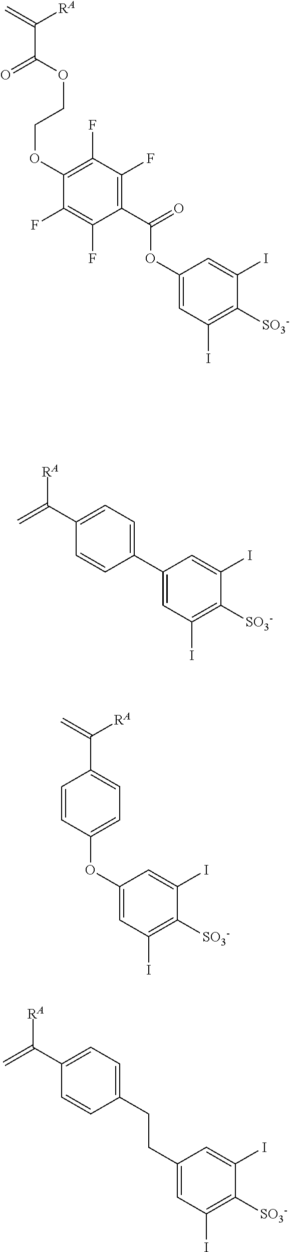

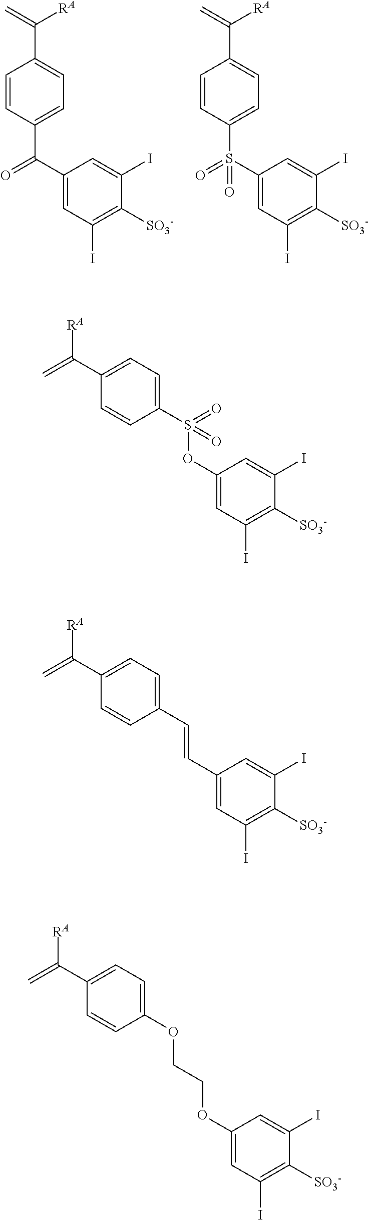

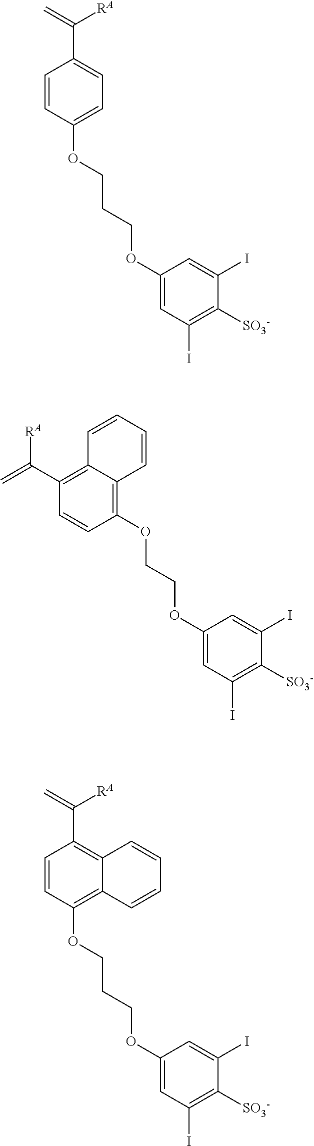

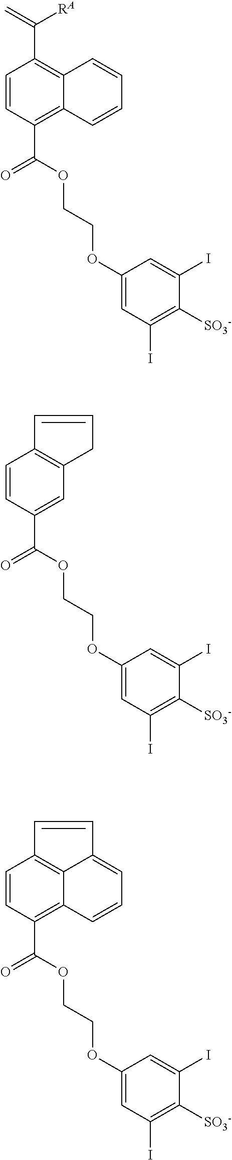

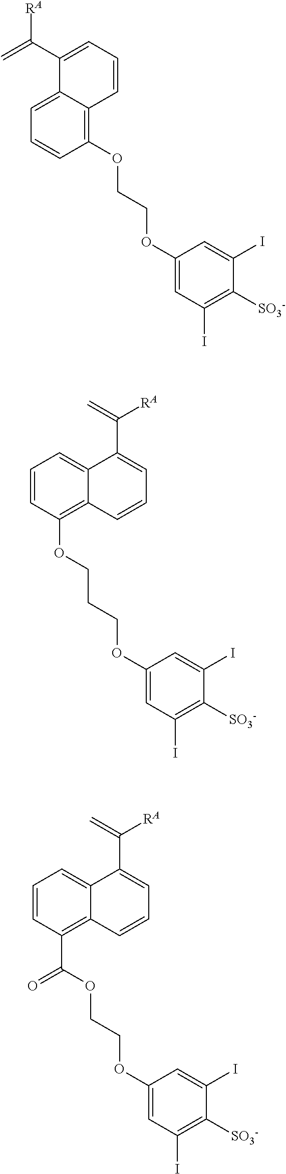

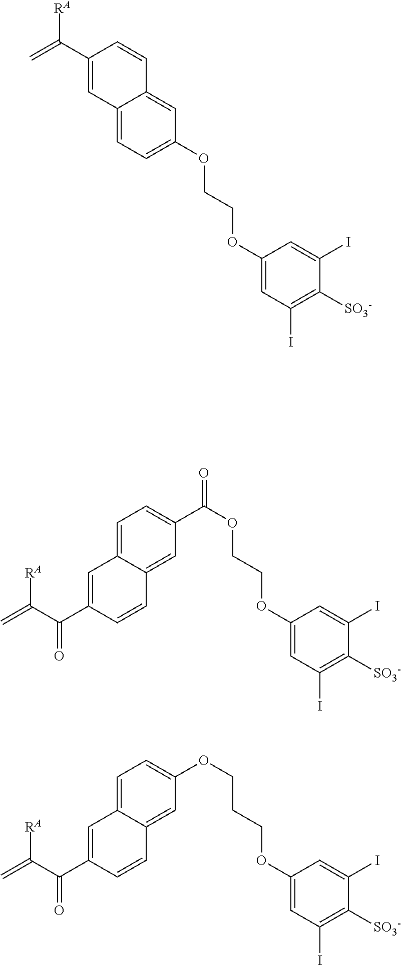

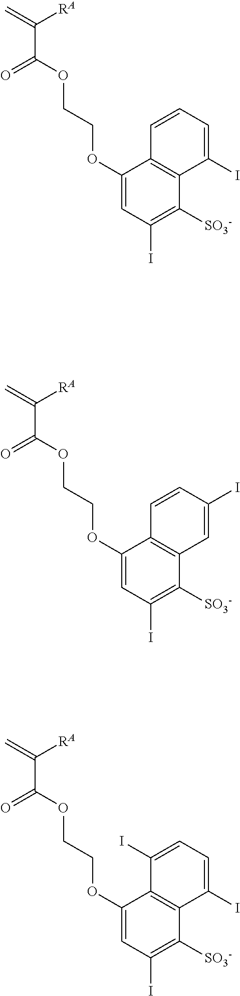

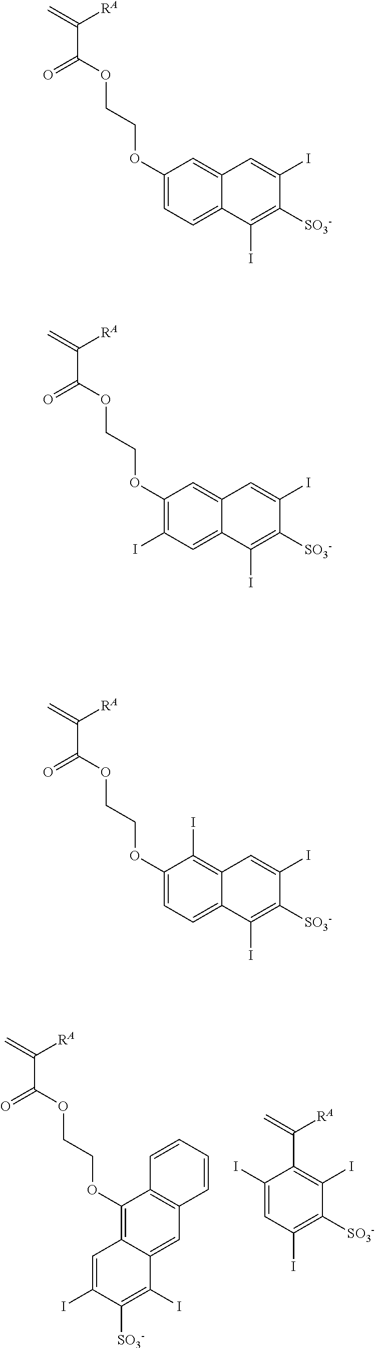

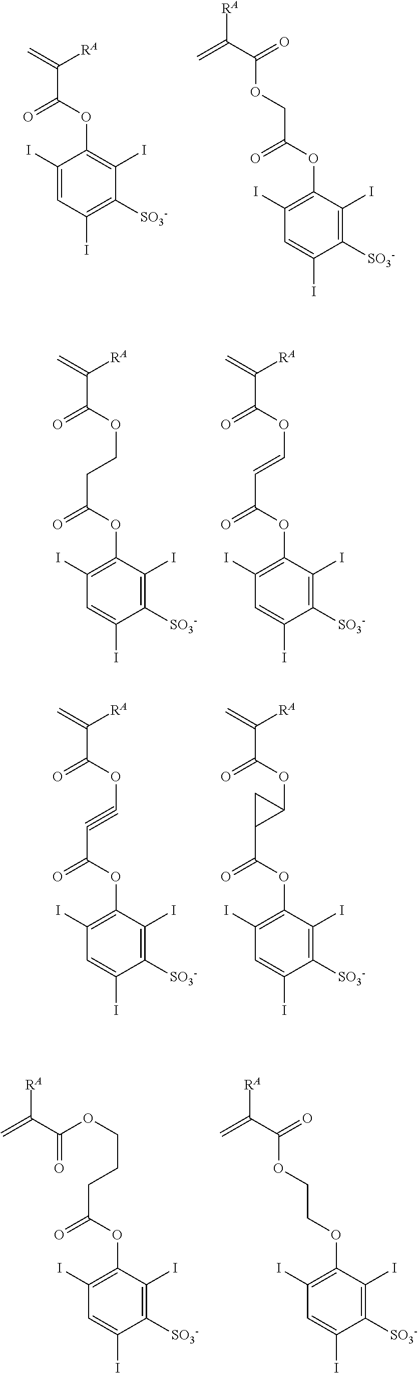

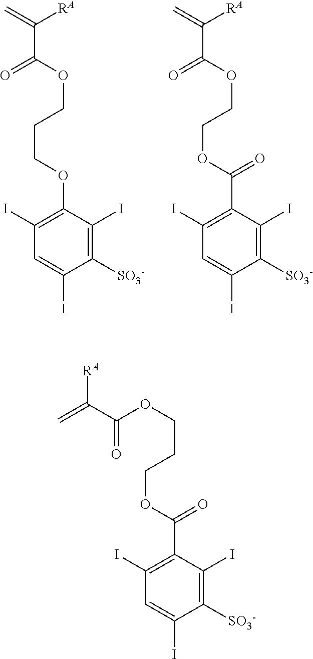

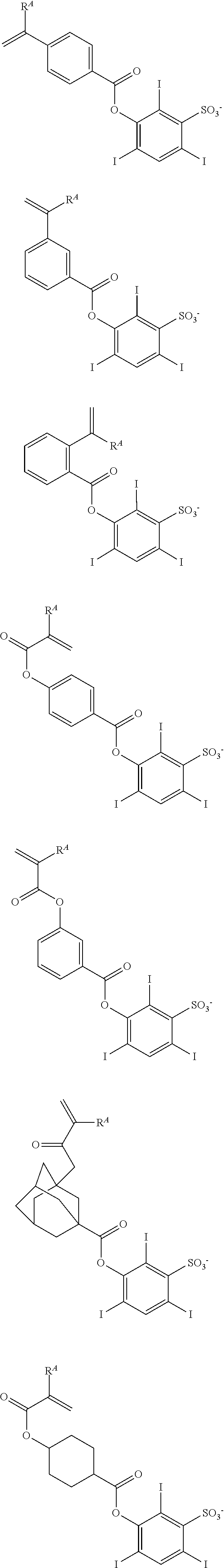

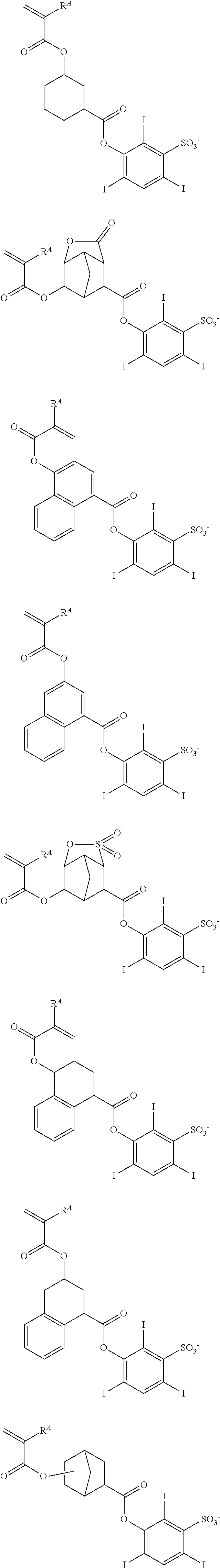

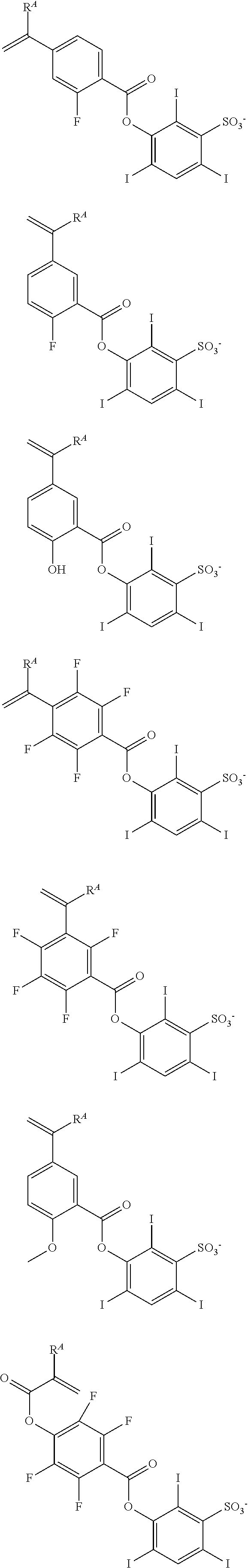

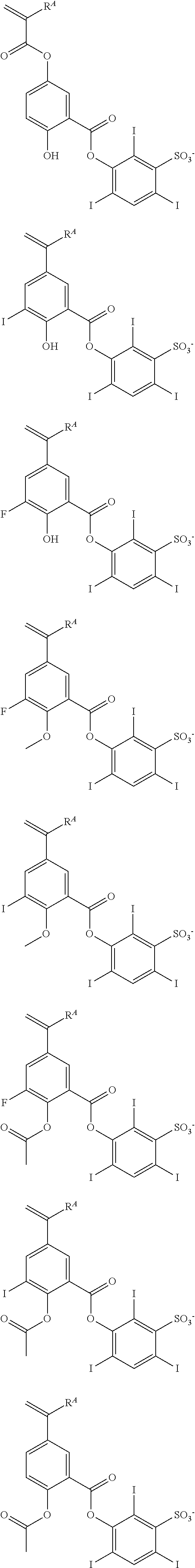

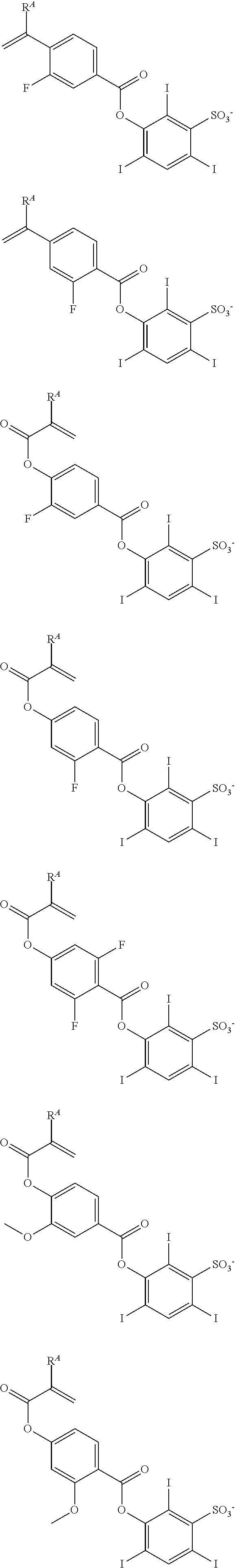

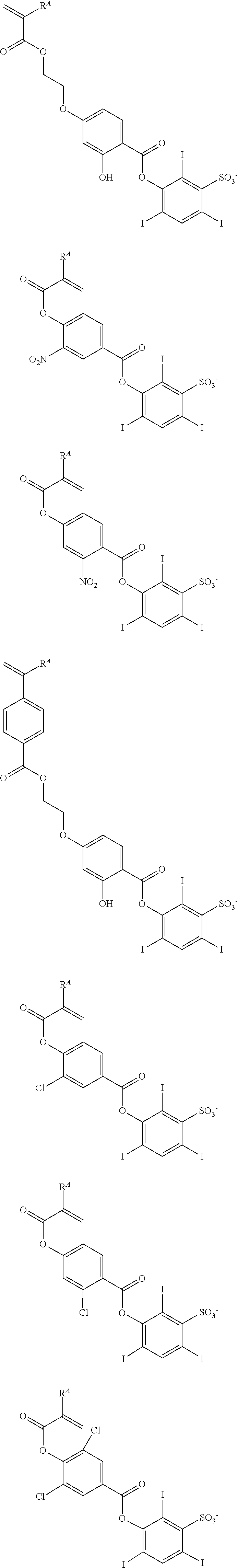

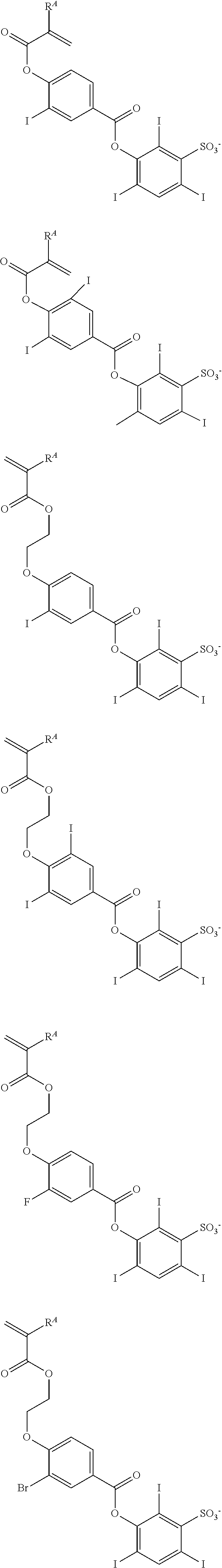

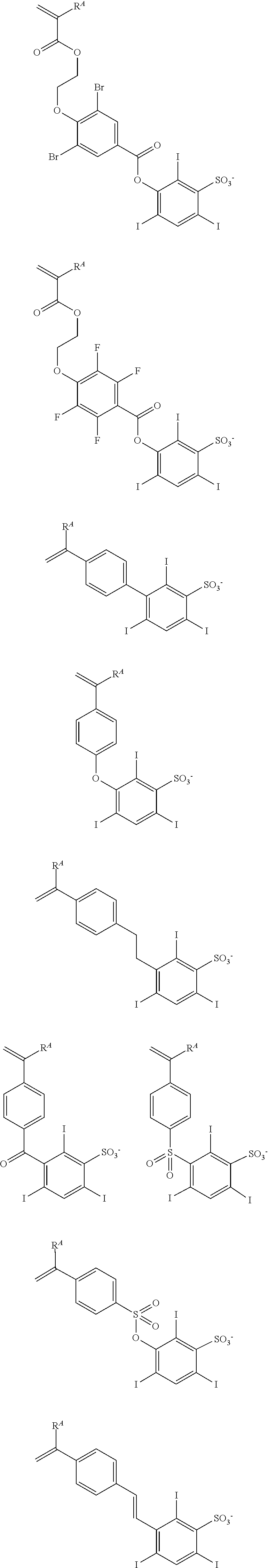

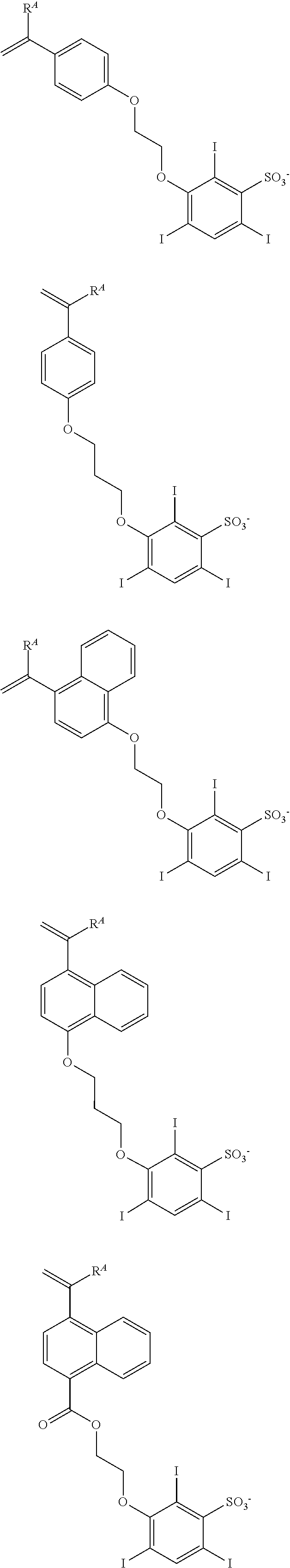

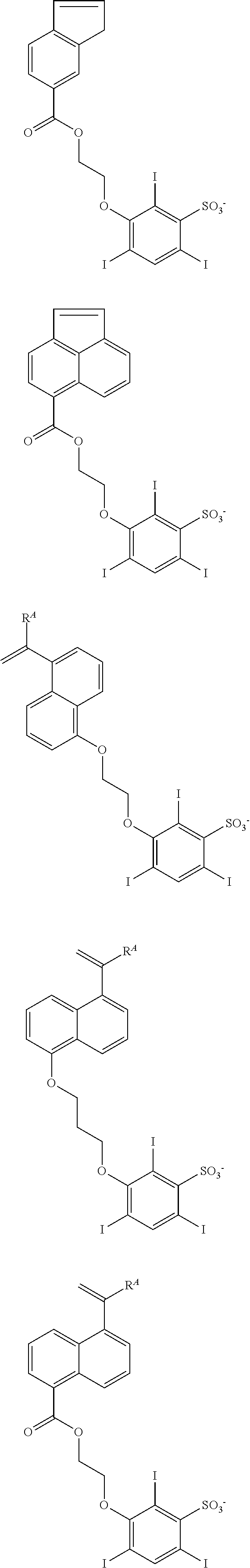

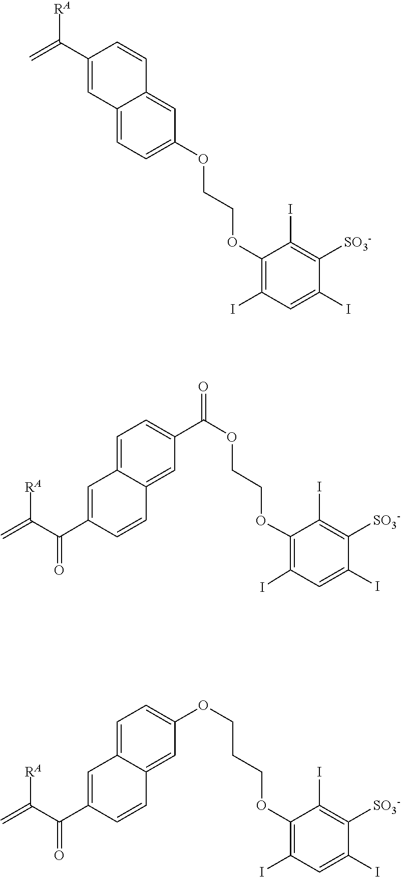

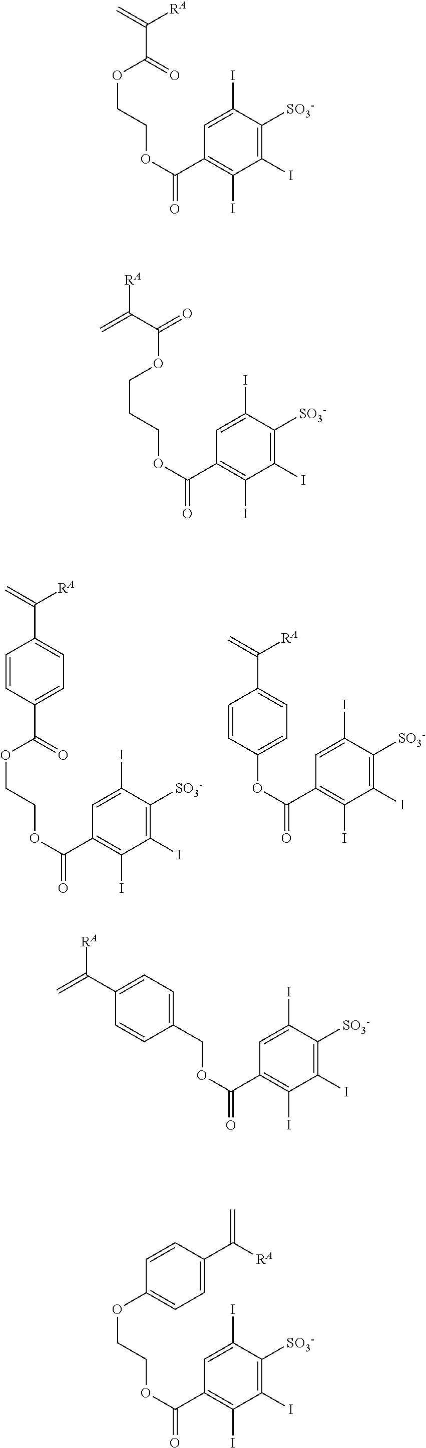

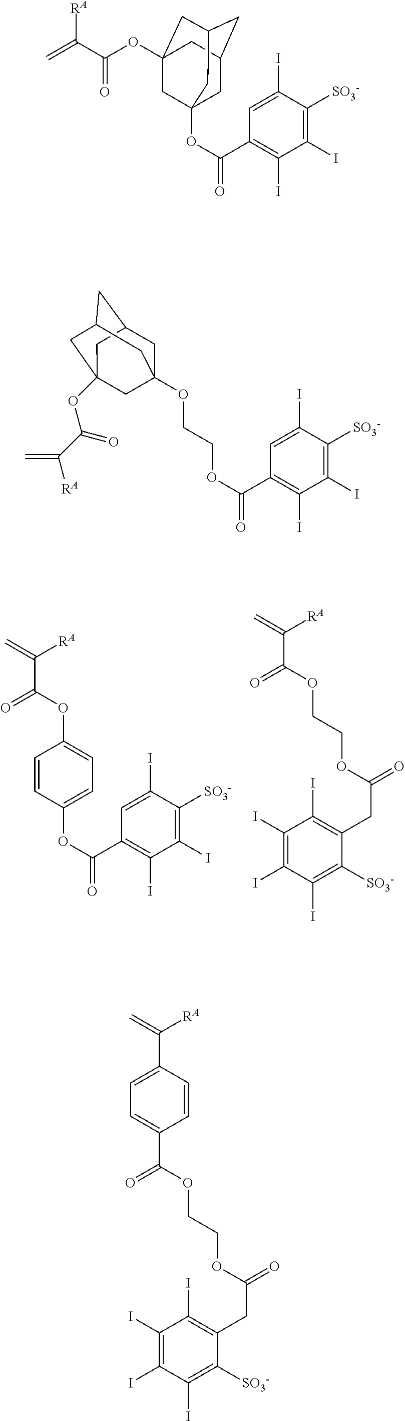

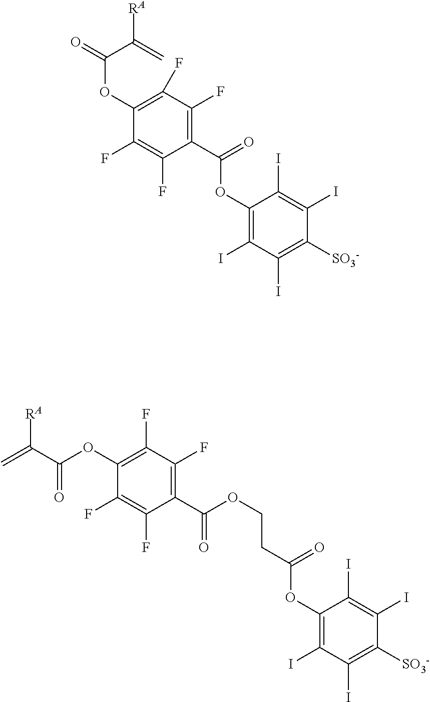

In the base polymer which contains the repeating unit-b having the acid-generating moiety selected from repeating units represented by the formulae (b2) to (b5), it is preferable that the Z³, the Z^{7A}, the Z^{7B}, or the M⁺ in the above formulae (b2) to (b5) contain one or more iodine atoms. By using such a repeating unit containing an iodine atom, more suitable pattern formation can be achieved.

The base polymer may further contain a repeating unit-c containing an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

Examples of a monomer to give the repeating unit-c include ones shown below, but are not limited thereto. Note that, in the following formulae, R^{A} is as defined above.

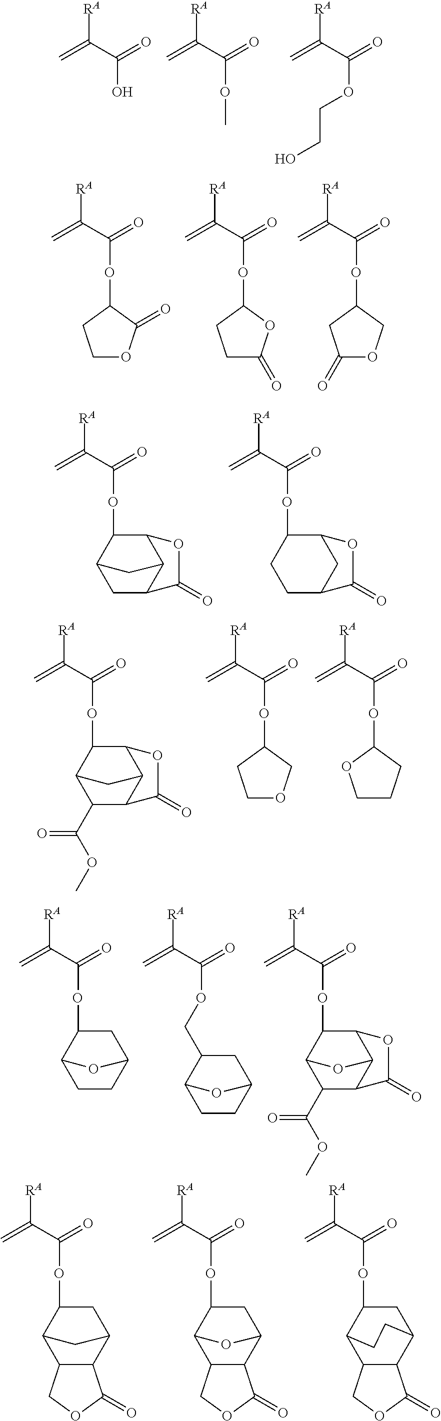

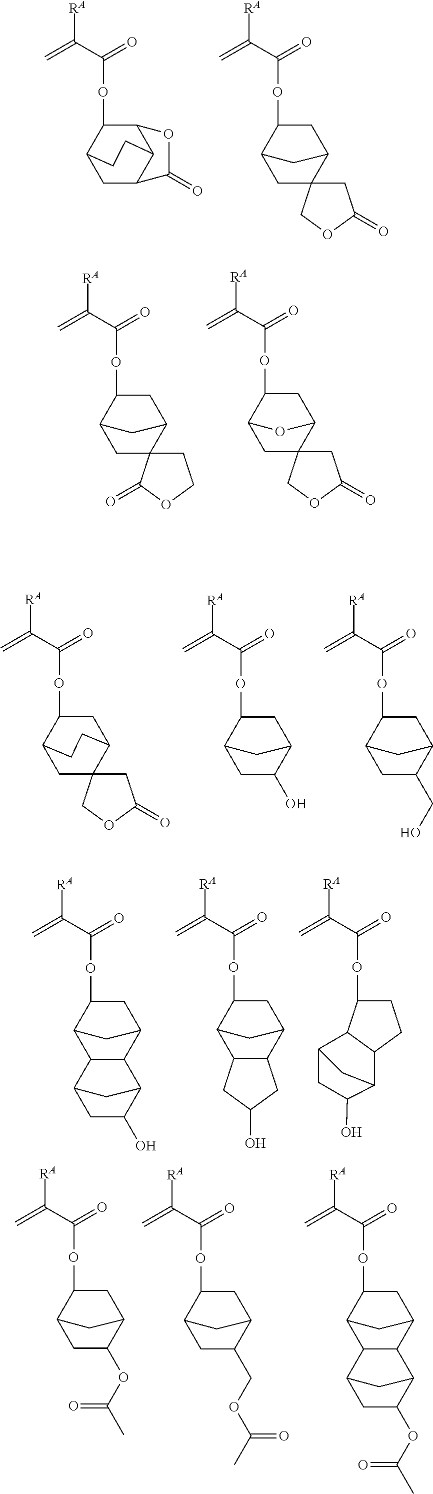

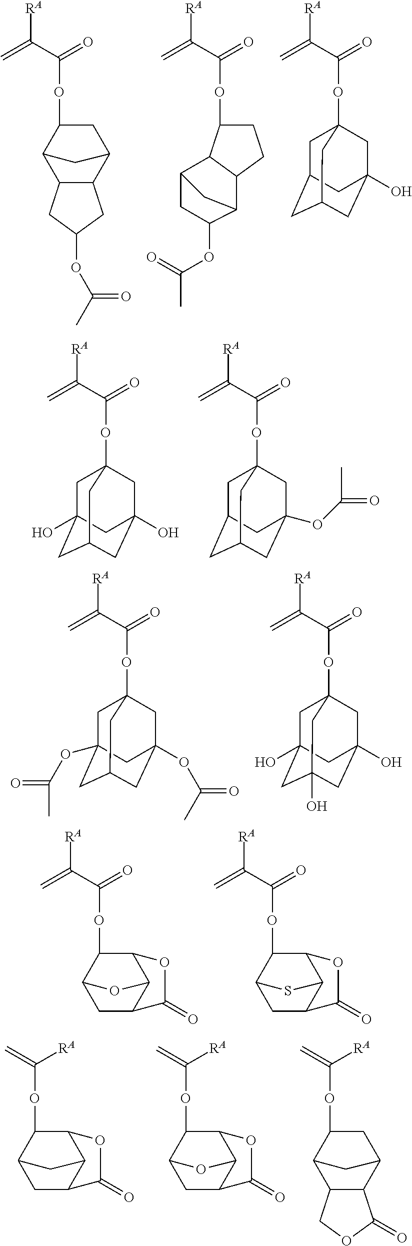

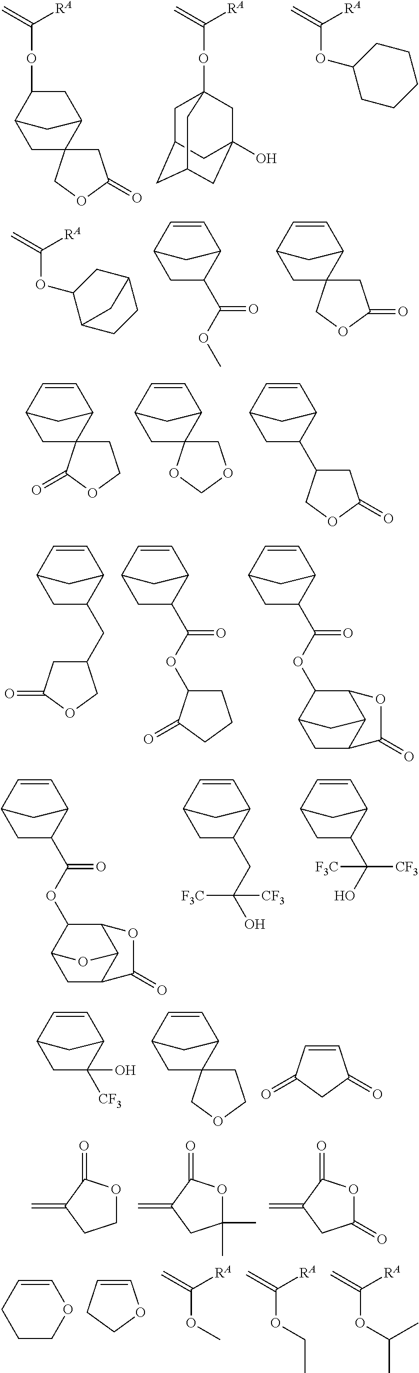

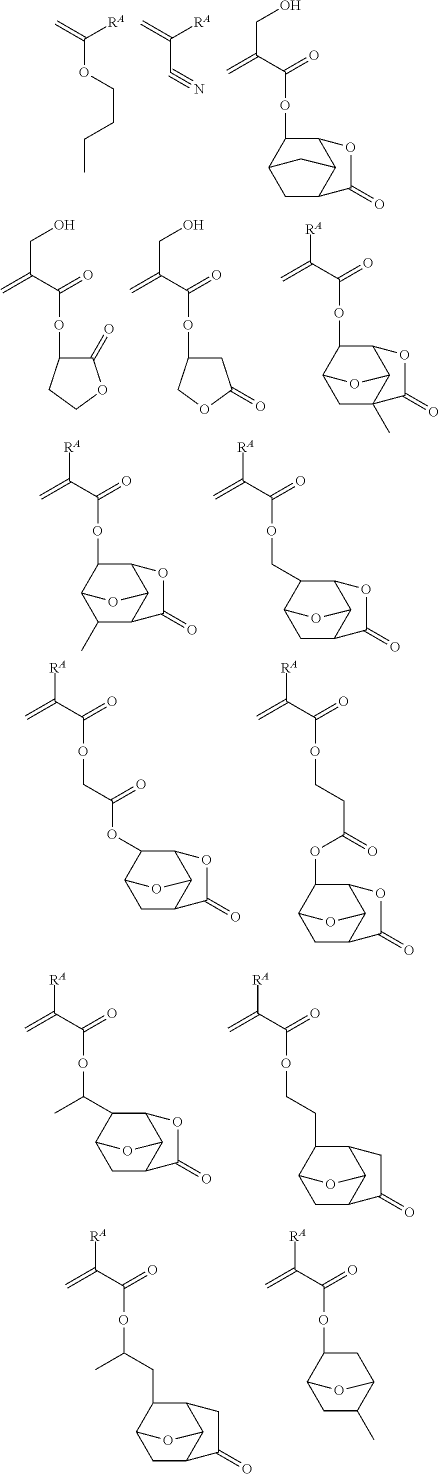

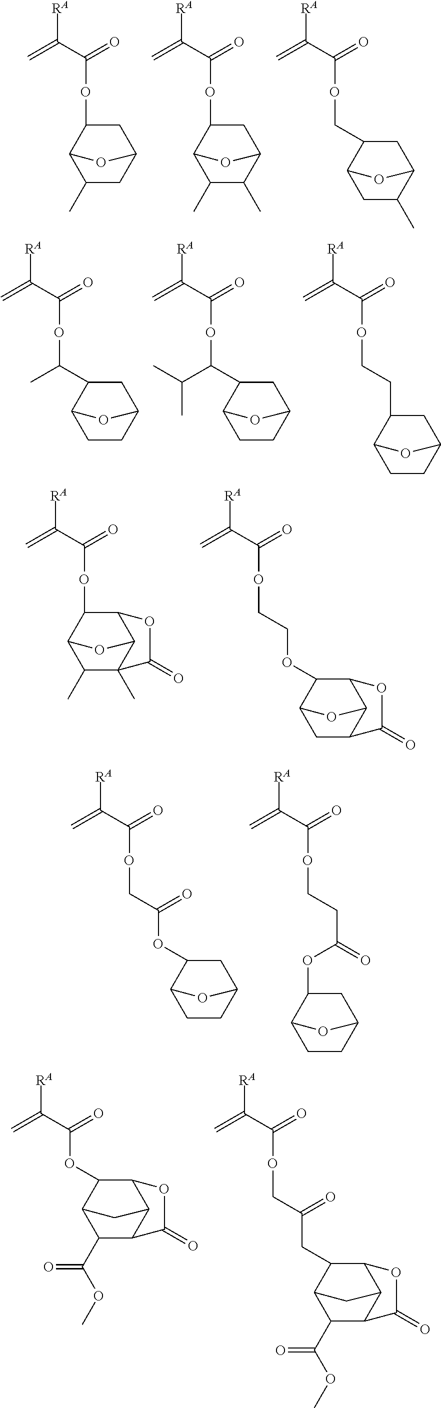

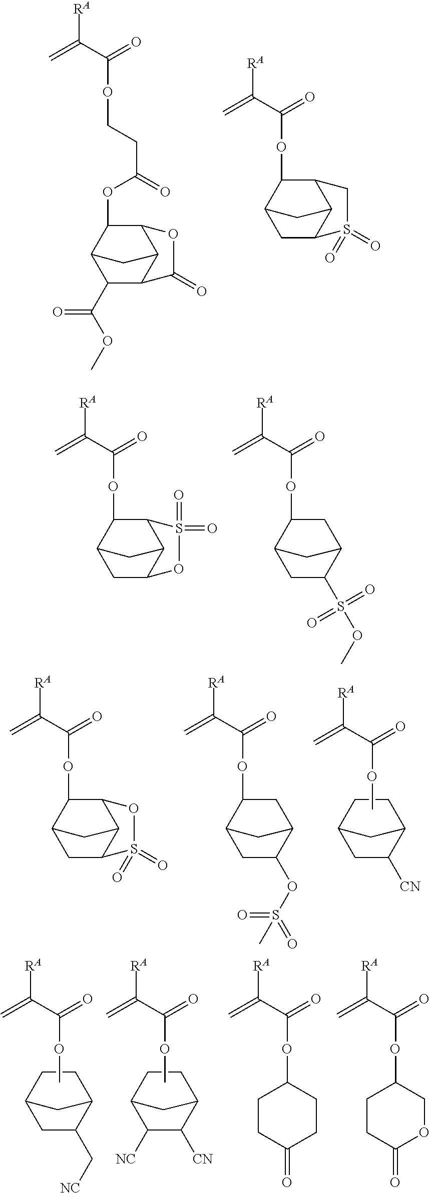

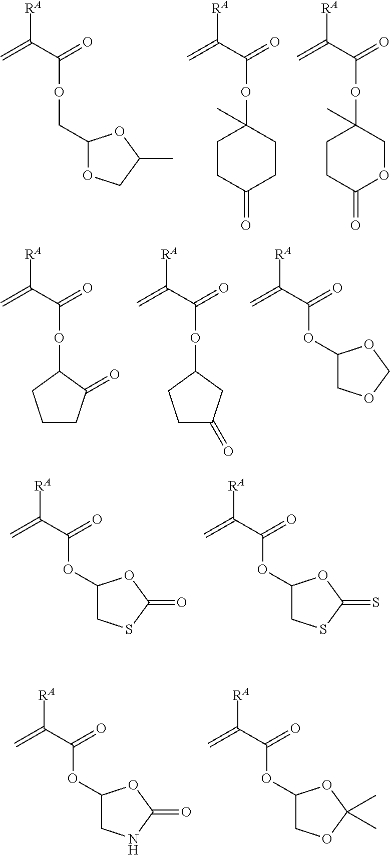

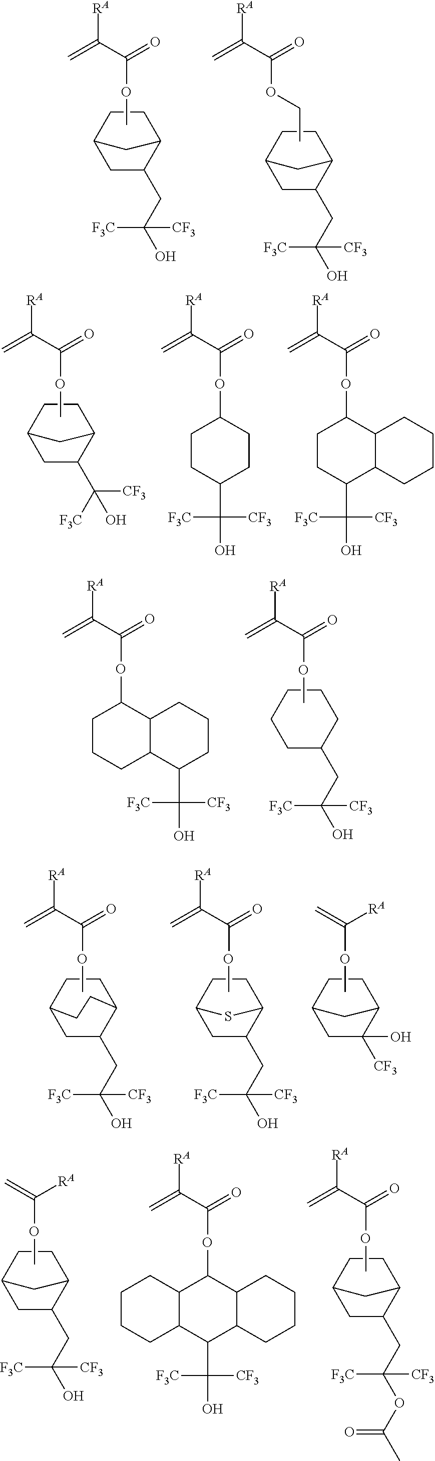

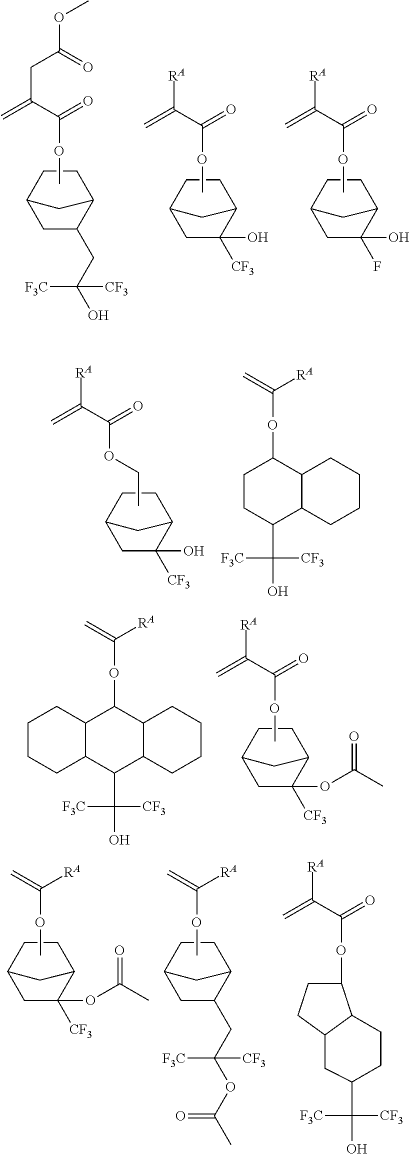

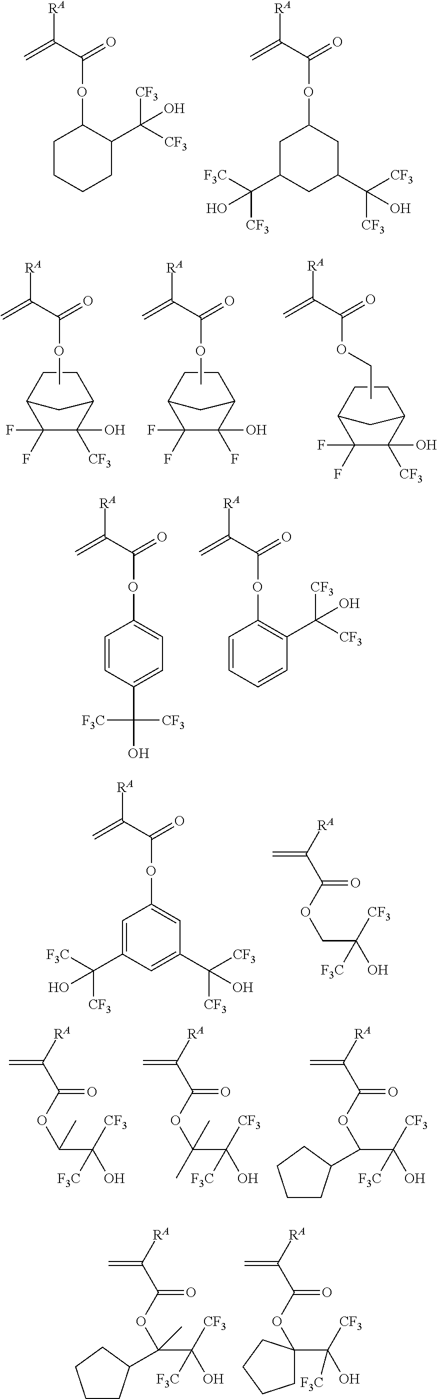

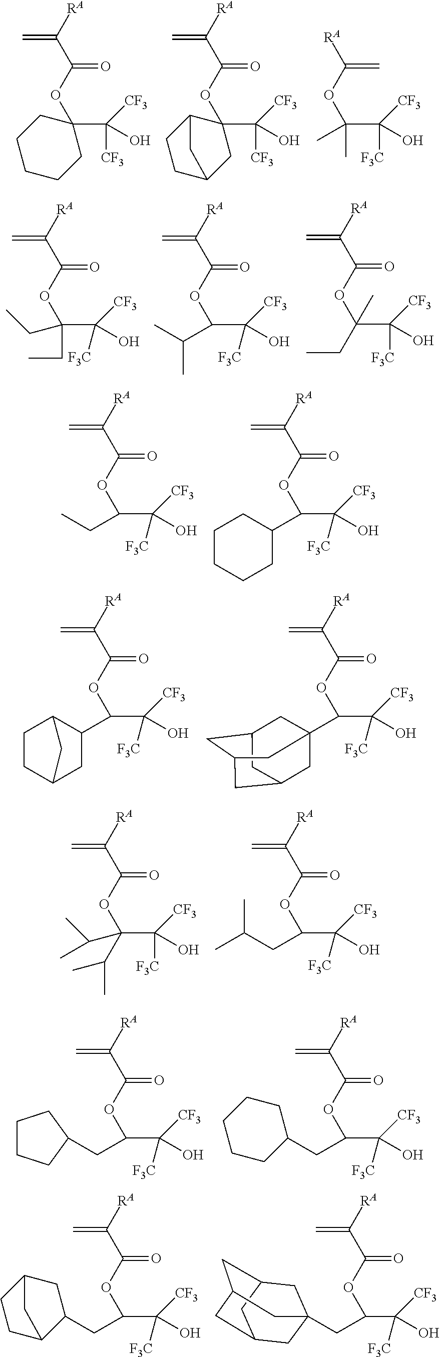

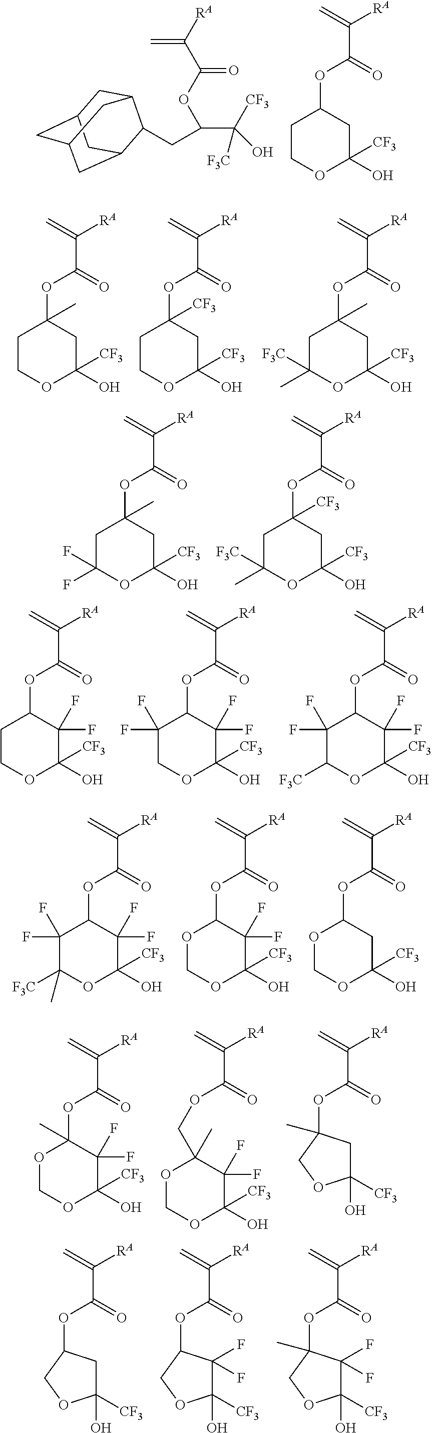

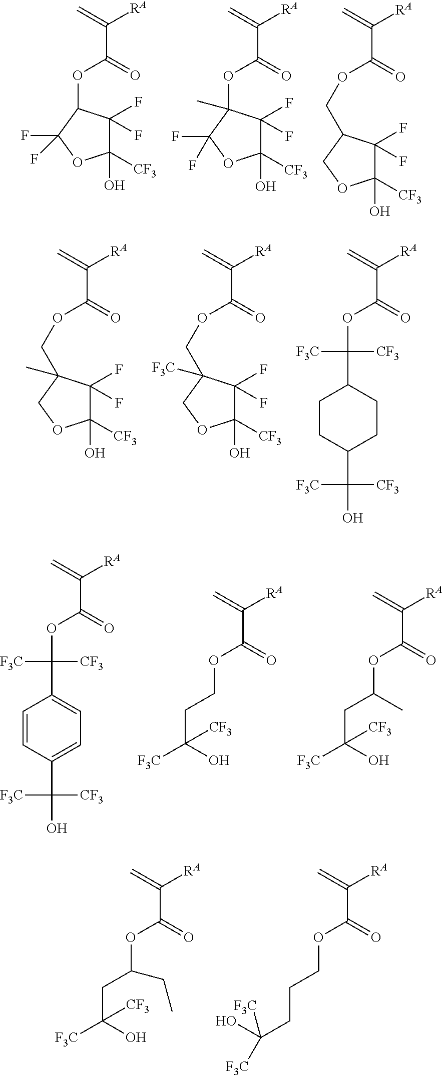

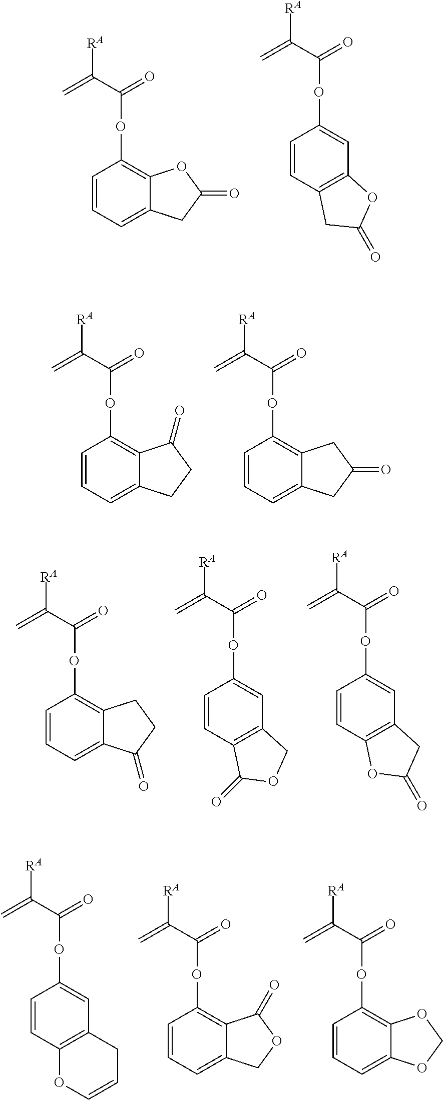

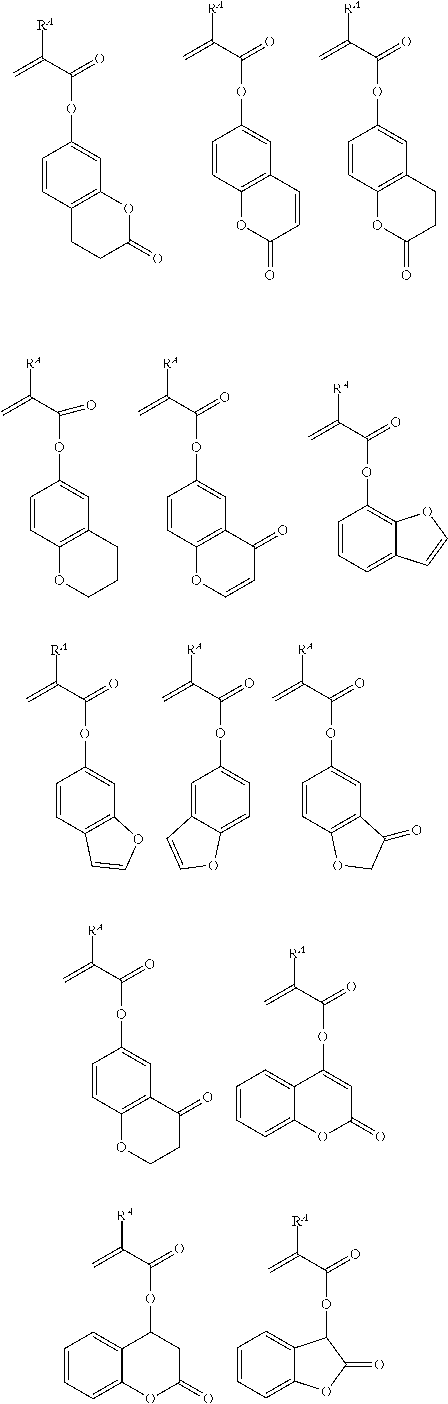

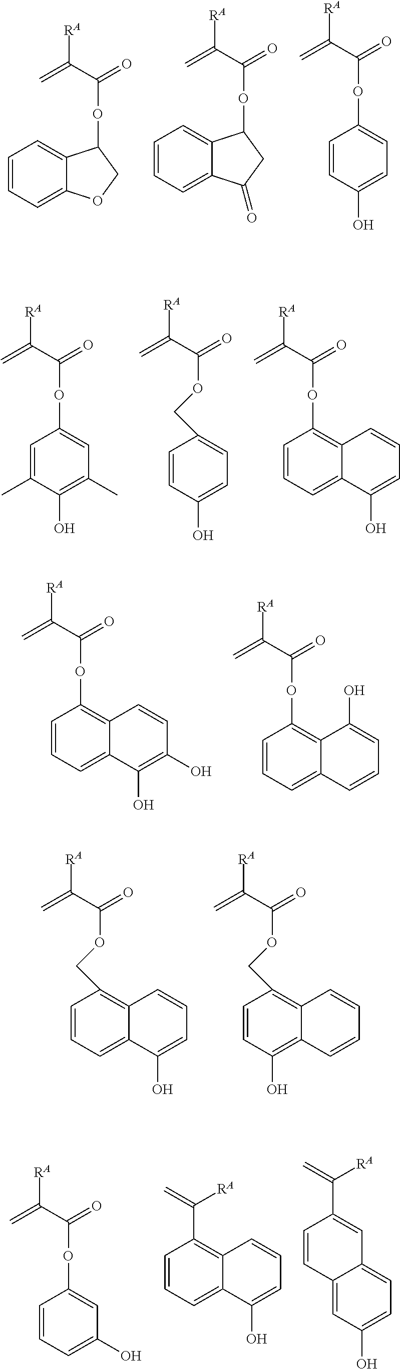

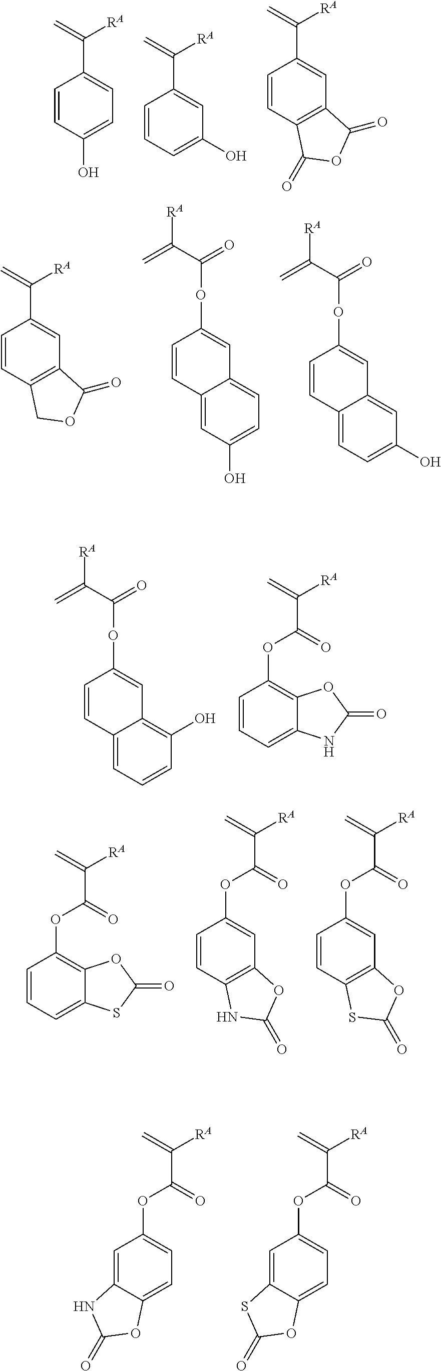

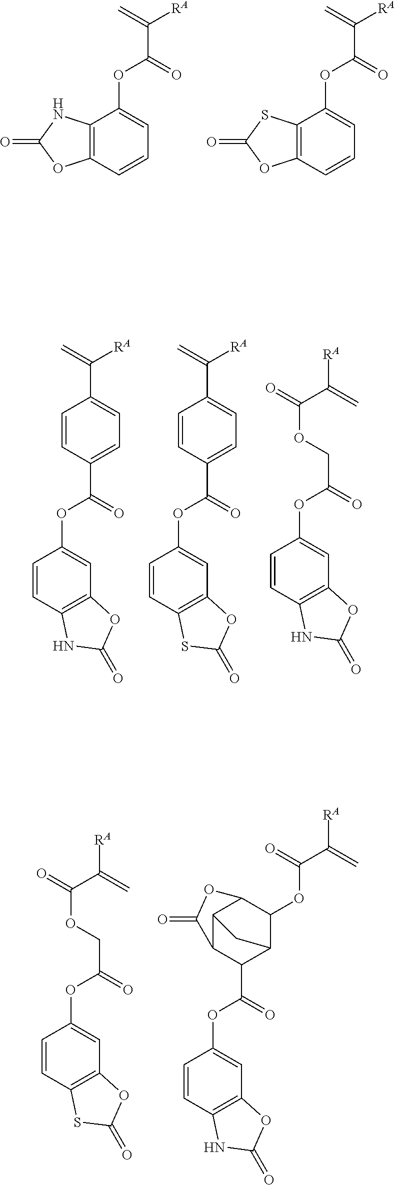

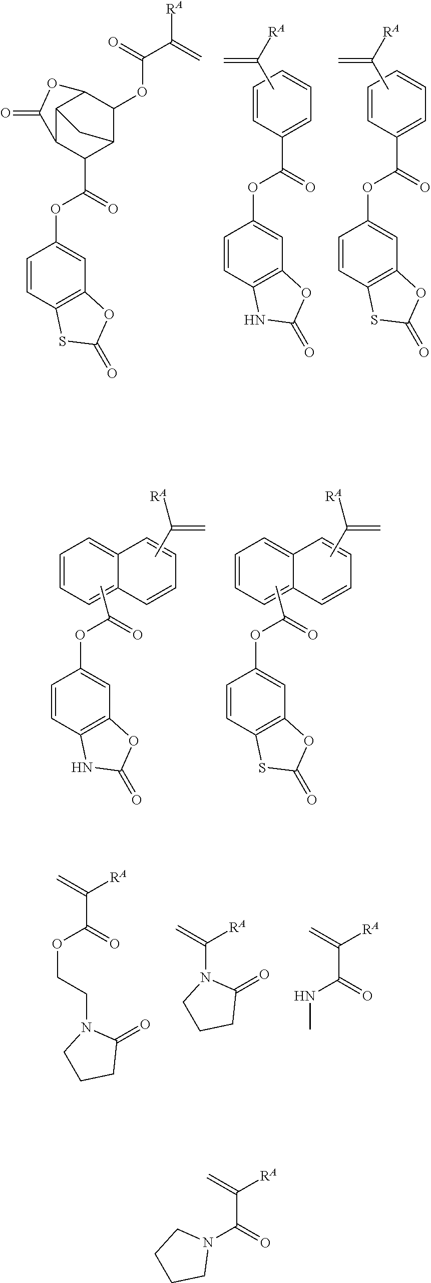

The base polymer may further contain a repeating unit-d not containing an amino group and containing an iodine atom. Examples of a monomer to give the repeating unit-d include ones shown below, but are not limited thereto. Note that, in the following formulae, R^{A} is as defined above.

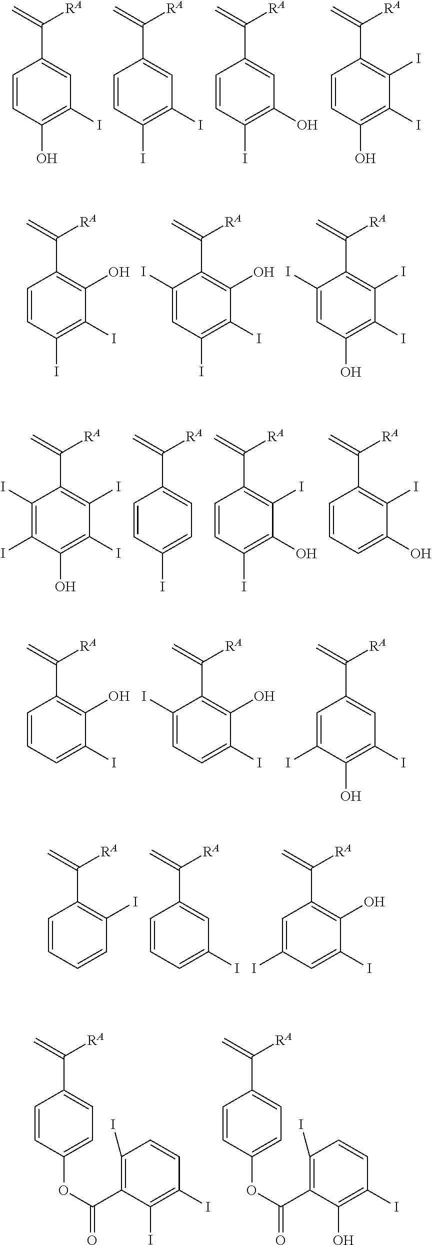

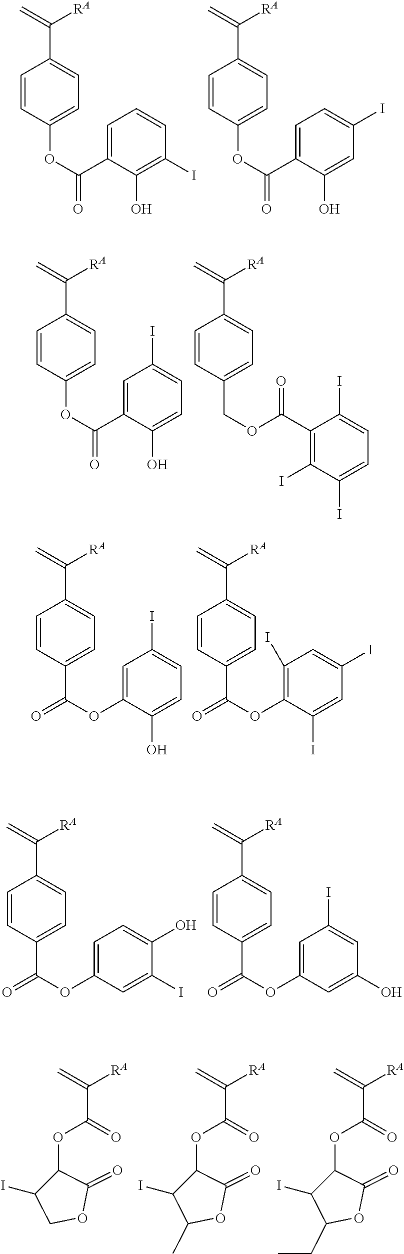

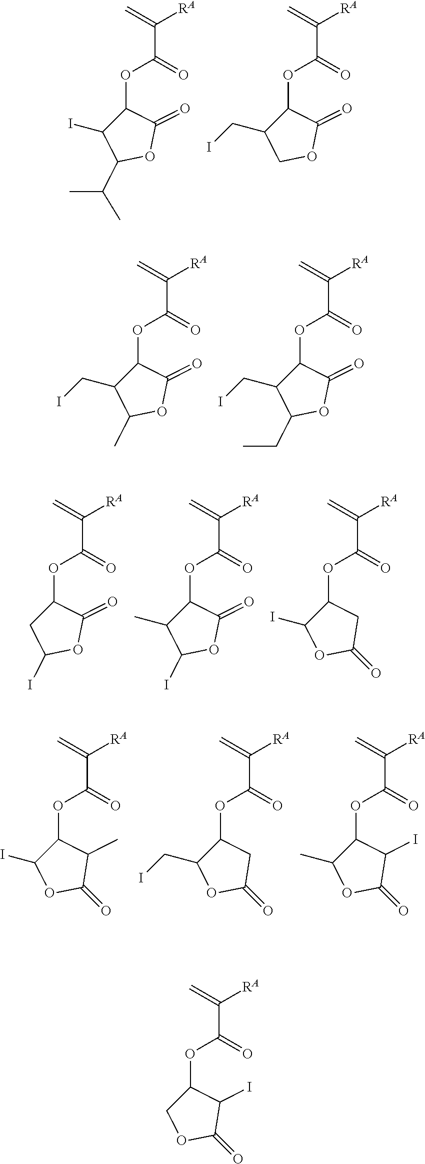

The base polymer may contain a repeating unit-e different from the above-described repeating units. Examples of the repeating unit-e include ones derived from styrene, vinylnaphthalene, indene, acenaphthylene, coumarin, coumarone, etc.

In the base polymer, the content ratios (molar fraction) of the repeating units-a1, -a2, -b1, -b2, -b3, -b4, -b5, -c, -d, and -e relative to all the repeating units are preferably 0≤a1≤1.0, 0≤a2≤1.0, 0<a1+a2≤1.0, 0≤b1≤0.5, 0≤b2≤0.5, 0≤b3≤0.5, 0≤b4≤0.5, 0≤b5≤0.5, 0≤b1+b2+b3+b4+b5≤0.5, 0≤c≤0.8, 0≤d≤0.5, and 0≤e≤0.5, provided that a1+a2+b1+b2+b3+b4+b5+c+d+e=1.0. In the present description, the recitations of numerical ranges by endpoints include all numbers subsumed within that range.

The base polymer may be synthesized, for example, by subjecting the monomers to give the repeating units described above to heat polymerization in an organic solvent to which a radical polymerization initiator has been added.

Examples of the organic solvent used in the polymerization include toluene, benzene, tetrahydrofuran (THF), diethyl ether, dioxane, propylene glycol monomethyl ether, γ-butyrolactone, mixed solvents thereof, etc. Examples of the polymerization initiator include 2,2′-azobisisobutyronitrile (AIBN), 2,2′-azobis(2, 4-dimethylvaleronitrile), dimethyl-2,2-azobis(2-methylpropionate), benzoyl peroxide, lauroyl peroxide, etc. The temperature during the polymerization is preferably 50 to 80° C. The reaction time is preferably 2 to 100 hours, more preferably 5 to 20 hours.

In the case where the monomer containing a hydroxy group is copolymerized, the process may include: substituting the hydroxy group with an acetal group susceptible to deprotection with acid, such as an ethoxyethoxy group, prior to the polymerization; and the deprotection with weak acid and water after the polymerization. Alternatively, the process may include: substituting the hydroxy group with an acetyl group, a formyl group, a pivaloyl group, or the like; and performing alkaline hydrolysis after the polymerization.

In a case where hydroxystyrene or hydroxyvinylnaphthalene is copolymerized, at first, acetoxystyrene or acetoxyvinylnaphthalene may be used in place of hydroxystyrene or hydroxyvinylnaphthalene; after the polymerization, the acetoxy group may be deprotected by the alkaline hydrolysis as described above to convert the acetoxystyrene or acetoxyvinylnaphthalene to hydroxystyrene or hydroxyvinylnaphthalene.

In the alkaline hydrolysis, a base is usable, such as ammonia water or triethylamine. The reaction temperature is preferably-20 to 100° C., more preferably 0 to 60° C. The reaction time is preferably 0.2 to 100 hours, more preferably 0.5 to 20 hours.

The base polymer has a weight-average molecular weight (Mw) in terms of polystyrene of preferably 1,000 to 500,000, more preferably 2,000 to 30,000, determined by gel permeation chromatography (GPC) using THE as an eluent. When the Mw is 1, 000 or more, the resist material is provided with excellent heat resistance. When the Mw is 500, 000 or less, alkali solubility is sufficient, and a footing phenomenon after pattern formation hardly occurs. Note that number-average molecular weight (Mn) can also be determined by the above-described GPC.

Furthermore, when the base polymer has a wide molecular weight distribution (Mw/Mn), low-molecular-weight and high-molecular-weight polymers are present, and therefore, there are risks of foreign matters appearing on the pattern after the exposure and the degradation of pattern profile. The finer the pattern rule, the stronger the influences of Mw and Mw/Mn.

Hence, in order to obtain a resist material suitably used for finer pattern dimensions, the base polymer preferably has a narrow dispersity Mw/Mn of 1.0 to 2.0, particularly preferably 1.0 to 1.5.

To achieve a narrow-dispersity polymer, it is possible to use, not only normal radical polymerization, but also living radical polymerization. Examples of living radical polymerization include living radical polymerization using nitroxide radicals (Nitroxide-Mediated radical Polymerization: NMP), atom transfer radical polymerization (ATRP), and reversible addition-fragmentation chain transfer (RAFT) polymerization.

The base polymer may include two or more polymers having different composition ratios, Mw, and Mw/Mn. Furthermore, a polymer containing a repeating unit-a and a polymer not containing a repeating unit-a may be blended.

### [Acid Generator]

In the present invention, as an acid generator, it is possible to incorporate an acid generator in the resist material instead of using a polymer incorporating an acid-generating moiety (polymer-bound acid generator) as described above, and these can also be combined. The manner of acid generation can be adjusted by an acid generator contained in addition to the base polymer (externally added acid generator), a polymer incorporating an acid-generating moiety that also functions as an acid generator (internally added acid generator), or a combination thereof.

When the resist material contains such an acid generator, i.e. externally added acid generator, internally added acid generator, or a combination thereof, a suitable acid-generating function in the resist material can be achieved.

The externally added acid generator is not particularly limited, and can be a substance that generates an acid in response to an external stimulus such as heat or light. Examples of the acid generator include compounds that generate acids in response to actinic light or radiation (photo-acid generator). The photo-acid generator component is not particularly limited, as long as the compound generates an acid upon high-energy beam irradiation. Preferably, the photo-acid generator generates a sulfonic acid, imide acid, or methide acid. Specific examples of suitable photo-acid generators include sulfonium salt, iodonium salt, sulfonyldiazomethane, N-sulfonyloxyimide, oxime-O-sulfonate type acid generators, etc. Specific examples of the acid generator include ones disclosed in paragraphs [0122] to [0142] of JP 2008-111103 A, JP 2018-5224 A, and JP 2018-25789 A. When the inventive resist material contains such an externally added acid generator, the contained amount is preferably 0 to 200 parts by mass, preferably 0.1 to 100 parts by mass based on 100 parts by mass of the base polymer.

### [Organic Solvent]

The inventive resist material may contain an organic solvent. This organic solvent is not particularly limited, as long as it is capable of dissolving the above-described components and components described below. Specific examples of the organic solvent include ones disclosed in paragraphs [0144] and [0145] of JP 2008-111103 A: ketones, such as cyclohexanone, cyclopentanone, methyl-2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; etc.

In the inventive resist material, the organic solvent is preferably contained in an amount of 100 to 10000 parts by mass, more preferably 200 to 8000 parts by mass based on 100 parts by mass of the base polymer. One kind of the organic solvent may be used, or two or more kinds thereof may be used in mixture.

### [Quencher]

The inventive resist material may contain a quencher. Note that a quencher means a compound that is capable of preventing, by trapping the acid, an acid that is generated from an acid generator in a resist material from diffusing to unexposed portions.

Examples of the quencher include conventional basic compounds. Specific examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, etc. Particularly preferable are primary, secondary, and tertiary amine compounds disclosed in paragraphs [0146] to [0164] of JP 2008-111103 A; especially amine compounds having a hydroxy group, an ether bond, an ester bond, a lactone ring, a cyano group, or a sulfonic acid ester bond; compounds having a carbamate bond disclosed in JP 3790649 B; etc. Adding such a basic compound can, for example, further suppress the acid diffusion rate in the resist film and correct the shape.

Other examples of the quencher include onium salts, such as sulfonium salts, iodonium salts, and ammonium salts of fluorinated alkoxides, carboxylic acids, or sulfonic acids which are not fluorinated at α position as disclosed in JP 2008-158339 A. While α-fluorinated sulfonic acid, imide acid, or methide acid is necessary to deprotect the acid-labile group of carboxylic acid ester, a fluorinated alcohol, carboxylic acid, or sulfonic acid not fluorinated at α position is released by salt exchange with the onium salt. Such fluorinated alcohol, carboxylic acid, and sulfonic acid not fluorinated at α position hardly induce a deprotection reaction, and thus function as quenchers.

Specific examples of such quenchers include a compound shown by the following formula (4) (onium salt of sulfonic acid not fluorinated at α position), a compound shown by the following formula (5) (onium salt of carboxylic acid), and a compound shown by the following formula (6) (onium salt of alkoxide).

R¹⁰¹—SO₃⁻Mq⁺ (4)

R¹⁰²—CO₂⁻Mq⁺ (5)

R¹⁰³—O⁻Mq⁺ (6)

In the formula (4), R¹⁰¹ represents a hydrogen atom or a hydrocarbyl group having 1 to 40 carbon atoms and optionally containing a heteroatom, but excludes groups in which a hydrogen atom bonded to the carbon atom at a position of the sulfo group is substituted with a fluorine atom or a fluoroalkyl group.

The hydrocarbyl group having 1 to 40 carbon atoms represented by R¹⁰¹ may be saturated or unsaturated, and may be linear, branched, or cyclic. Specific examples thereof include: alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; alkenyl groups having 2 to 40 carbon atoms, such as a vinyl group, an allyl group, a propenyl group, a butenyl group, and a hexenyl group; cyclic unsaturated aliphatic hydrocarbyl groups having 3 to 40 carbon atoms, such as a cyclohexenyl group; aryl groups having 6 to 40 carbon atoms, such as a phenyl group, a naphthyl group, alkylphenyl groups (such as a 2-methylphenyl group, a 3-methylphenyl group, a 4-methylphenyl group, a 4-ethylphenyl group, a 4-tert-butylphenyl group, and a 4-n-butylphenyl group), dialkylphenyl groups or trialkylphenyl groups (such as a 2,4-dimethylphenyl group and a 2, 4, 6-triisopropylphenyl group), alkylnaphthyl groups (such as a methylnaphthyl group and an ethylnaphthyl group), and dialkylnaphthyl groups (such as a dimethylnaphthyl group and a diethylnaphthyl group); aralkyl groups having 7 to 40 carbon atoms, such as a benzyl group, a 1-phenylethyl group, and a 2-phenylethyl group; etc.

Moreover, part or all of the hydrogen atoms of the hydrocarbyl groups may be substituted with a group containing a heteroatom, such as an oxygen atom, a sulfur atom, a nitrogen atom, or a halogen atom, and part of the —CH— of the hydrocarbyl groups may be substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester bond, a carbonate bond, a lactone ring, a sultone ring, carboxylic anhydride (—C(═O)—O—C(═O)—), a haloalkyl group, etc. Specific examples of the hydrocarbyl group containing a heteroatom include: heteroaryl groups, such as a thienyl group; alkoxyphenyl groups, such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups, such as a methoxynaphthyl group, an ethoxynaphthyl group, an n-propoxynaphthyl group, and an n-butoxynaphthyl group; dialkoxynaphthyl groups, such as a dimethoxynaphthyl group and a diethoxynaphthyl group; aryloxoalkyl groups, such as 2-aryl-2-oxoethyl groups including a 2-phenyl-2-oxoethyl group, a 2-(1-naphthyl)-2-oxoethyl group, and a 2-(2-naphthyl)-2-oxoethyl group; etc.

In the formula (5), R¹⁰² represents a hydrocarbyl group having 1 to 40 carbon atoms and optionally containing a heteroatom. Specific examples of the hydrocarbyl group represented by R¹⁰² include those exemplified as the hydrocarbyl group represented by R¹⁰¹. Other specific examples thereof include fluorinated alkyl groups, such as a trifluoromethyl group, a trifluoroethyl group, a 2, 2, 2-trifluoro-1-methyl-1-hydroxyethyl group, and a 2, 2, 2-trifluoro-1-(trifluoromethyl)-1-hydroxyethyl group; fluorinated aryl groups, such as a pentafluorophenyl group and a 4-trifluoromethylphenyl group; etc.

In the formula (6), R¹⁰³ represents a saturated hydrocarbyl group having 1 to 8 carbon atoms and having at least three fluorine atoms or represents an aryl group having 6 to 10 carbon atoms and having at least three fluorine atoms, and optionally contains a nitro group.

In the formulae (4), (5), and (6), Mq⁺ represents an onium cation. The onium cation is preferably a sulfonium cation, an iodonium cation, or an ammonium cation, more preferably a sulfonium cation. Specific examples of the sulfonium cation include those given as examples of the sulfonium cation represented by M⁺ in the description of the formulae (b2) to (b5).

A sulfonium salt of a carboxylic acid containing an iodized benzene ring shown by the following formula (7) can also be used suitably as the quencher.

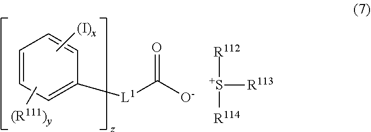

In the formula (7), “x” represents an integer of 1 to 5. “y” represents an integer of 0 to 3. “z” represents an integer of 1 to 3.

In the formula (7), R¹¹¹ represents a hydroxy group, a fluorine atom, a chlorine atom, a bromine atom, an amino group, a nitro group, a cyano group, —N(R^{111A})—C(═O)—R^{111B}, or —N(R^{111A})—C(═O)—O—R^{111B}; or a saturated hydrocarbyl group having 1 to 6 carbon atoms, a saturated hydrocarbyloxy group having 1 to 6 carbon atoms, a saturated hydrocarbylcarbonyloxy group having 2 to 6 carbon atoms, or a saturated hydrocarbylsulfonyloxy group having 1 to 4 carbon atoms, the groups optionally having part or all of hydrogen atoms substituted with a halogen atom. R^{111A} represents a hydrogen atom or a saturated hydrocarbyl group having 1 to 6 carbon atoms. R^{111B} represents a saturated hydrocarbyl group having 1 to 6 carbon atoms or an unsaturated aliphatic hydrocarbyl group having 2 to 8 carbon atoms. When “y” and/or “z” is 2 or more, the Rill's may be identical to or different from each other.

In the formula (7), L¹ represents a single bond or a linking group having a valency of z+1 and having 1 to 20 carbon atoms, and optionally contains at least one selected from an ether bond, a carbonyl group, an ester bond, an amide bond, a sultone ring, a lactam ring, a carbonate bond, a halogen atom, a hydroxy group, and a carboxy group. The saturated hydrocarbyl group, saturated hydrocarbyloxy group, saturated hydrocarbylcarbonyloxy group, and saturated hydrocarbylsulfonyloxy group may be linear, branched, or cyclic.

In the formula (7), R¹¹², R¹¹³, and R¹¹⁴ each independently represent a halogen atom or a hydrocarbyl group having 1 to 20 carbon atoms and optionally containing a heteroatom. The hydrocarbyl group may be saturated or unsaturated and may be linear, branched, or cyclic.

Specific examples of the compound represented by the formula (7) include ones disclosed in JP 2017-219836 A and JP 2021-91666 A.

Other examples of the quencher include polymer-type quenchers disclosed in JP 2008-239918 A. The quenchers enhance the rectangularity of a resist pattern by being oriented on the resist film surface. The polymer-type quencher also has effects of preventing rounding of a pattern top and film thickness loss of a pattern when a top coat for immersion exposure is applied.

Furthermore, it is also possible to use, as a quencher: betaine type sulfonium salts disclosed in JP 6848776 B2 and JP 2020-37544 A; methide acids containing no fluorine atoms disclosed in JP 2020-55797 A; sulfonium salts of sulfonamides disclosed in JP 5807552 B2; sulfonium salts of sulfonamides containing an iodine atom disclosed in JP 2019-211751 A; phenol; halogen; and acid generators that generate carbonic acid.

When the inventive resist material contains the quencher, the contained amount is preferably 0 to 5 parts by mass, more preferably 0 to 4 parts by mass based on 100 parts by mass of the base polymer. One kind of the quencher may be used, or two or more kinds thereof may be used in combination.

### [Other Components]

In addition to the above-described components, a surfactant, a dissolution inhibitor, a crosslinking agent, a water-repellency enhancer, an acetylene alcohol, etc. may be contained.

Specific examples of the surfactant include ones disclosed in paragraphs and of JP 2008-111103 A. Adding a surfactant can further enhance or control the coatability of the resist material. When the inventive resist material contains a surfactant, the contained amount is preferably 0.0001 to 10 parts by mass based on 100 parts by mass of the base polymer. One kind of the surfactant may be used, or two or more kinds thereof may be used in combination.

When the inventive resist material is a positive type, blending a dissolution inhibitor can further increase the difference in dissolution rate between exposed and unexposed areas, and further enhance the resolution. Specific examples of the dissolution inhibitor include a compound which contains two or more phenolic hydroxy groups per molecule, and in which 0 to 100 mol % of all the hydrogen atoms of the phenolic hydroxy groups are substituted with acid-labile groups; and a compound which contains a carboxy group in a molecule, and in which 50 to 100 mol % of all the hydrogen atoms of such carboxy groups are substituted with acid-labile groups on average. The compounds each have a molecular weight of preferably 100 to 1000, more preferably 150 to 800. Specific examples include compounds obtained by substituting acid-labile groups for hydrogen atoms of hydroxy groups or carboxy groups of bisphenol A, trisphenol, phenolphthalein, cresol novolak, naphthalenecarboxylic acid, adamantanecarboxylic acid, or cholic acid; etc. Examples of such compounds are disclosed in paragraphs [0155] to [0178] of JP 2008-122932 A.

When the inventive resist material is a positive type and contains the dissolution inhibitor, the contained amount is preferably 0 to 50 parts by mass, more preferably 5 to 40 parts by mass based on 100 parts by mass of the base polymer. One kind of the dissolution inhibitor can be used, or two or more kinds thereof can be used in combination.

On the other hand, when the inventive resist material is a negative type, a negative pattern can be obtained by reducing the dissolution rate in exposed portions by adding a crosslinking agent. Specific examples of the crosslinking agent include: epoxy compounds, melamine compounds, guanamine compounds, and glycoluril compounds, each substituted with at least one group selected from a methylol group, an alkoxymethyl group, and an acyloxymethyl group; and compounds including a double bond, such as urea compounds, isocyanate compounds, azide compounds, and alkenyloxy groups. These may be contained as an additive, but may also be introduced as a pendant group in a polymer side chain. A compound containing a hydroxy group can also be contained as a crosslinking agent.

Specific examples of the epoxy compounds include tris (2, 3-epoxypropyl) isocyanurate, trimethylolmethane triglycidyl ether, trimethylolpropane triglycidyl ether, and triethylolethane triglycidyl ether.

Specific examples of the melamine compounds include hexamethylolmelamine, hexamethoxymethylmelamine, compounds in which 1 to 6 methylol groups of hexamethylolmelamine have been methoxymethylated, mixtures thereof; hexamethoxyethylmelamine, hexaacyloxymethylmelamine, compounds in which 1 to 6 methylol groups of or hexamethylolmelamine have been acyloxymethylated, and mixtures thereof.

Specific examples of the guanamine compounds include: tetramethylolguanamine, tetramethoxymethylguanamine, compounds in which 1 to 4 methylol groups of tetramethylolguanamine have been methoxymethylated, and mixtures thereof; and tetramethoxyethylguanamine, tetraacyloxyguanamine, compounds in which 1 to 4 methylol groups of tetramethylolguanamine have been acyloxymethylated, and mixtures thereof.

Specific examples of the glycoluril compounds include: tetramethylolglycoluril, tetramethoxyglycoluril, tetramethoxymethylglycoluril, compounds in which 1 to 4 methylol groups of tetramethylolglycoluril have been methoxymethylated, and mixtures thereof; and compounds in which 1 to 4 methylol groups of tetramethylolglycoluril have been acyloxymethylated and mixtures thereof. Specific examples of the urea compounds include: tetramethylolurea, tetramethoxymethylurea, compounds in which 1 to 4 methylol groups of tetramethylolurea have been methoxymethylated, and mixtures thereof; and tetramethoxyethylurea.

Specific examples of the isocyanate compounds include tolylenediisocyanate, diphenylmethanediisocyanate, hexamethylenediisocyanate, and cyclohexanediisocyanate.

Specific examples of the azide compounds include 1,1′-biphenyl-4,4′-bisazide, 4,4′-methylidenebisazide, and 4,4′-oxybisazide.

Specific examples of the compounds containing an alkenyloxy group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylolpropane trivinyl ether.

When the inventive resist material is a negative type and contains the crosslinking agent, the contained amount is preferably 0.1 to 50 parts by mass, more preferably 1 to 40 parts by mass based on 100 parts by mass of the base polymer. One kind of the crosslinking agent may be used, or two or more kinds thereof may be used in combination.

The water-repellency enhancer improves the water-repellency of the resist film surface, and can be employed in immersion lithography with no top coat. The water-repellency enhancer is preferably a polymer containing a fluorinated alkyl group, a polymer containing a 1,1,1,3,3,3-hexafluoro-2-propanol residue with a particular structure, etc., preferably ones exemplified in JP 2007-297590 A, JP 2008-111103 A, etc. The water-repellency enhancer needs to be dissolved in an alkali developer or an organic solvent developer. The water-repellency enhancer having a particular 1,1,1,3,3,3-hexafluoro-2-propanol residue mentioned above has favorable solubility to developers. A polymer containing a repeating unit with an amino group or amine salt as a water-repellency enhancer exhibits high effects of preventing acid evaporation during PEB and opening failure of a hole pattern after development. When the inventive resist material contains the water-repellency enhancer, the contained amount is preferably 0 to 20 parts by mass, more preferably 0.5 to 10 parts by mass based on 100 parts by mass of the base polymer. One kind of the water-repellency enhancer may be used, or two or more kinds thereof may be used in combination.

Specific examples of the acetylene alcohol include ones disclosed in paragraphs [0179] to [0182] of JP 2008-122932 A. When the inventive resist material contains the acetylene alcohol, the contained amount is preferably 0 to 5 parts by mass based on 100 parts by mass of the base polymer. One kind of the acetylene alcohol may be used, or two or more kinds thereof may be used in combination.

When the inventive resist material is used for manufacturing various integrated circuits, known lithography techniques can be applied as necessary.

For example, the inventive resist material is applied onto a substrate (such as Si, SiO₂, SiN, SiON, TiN, WSi, BPSG, SOG, or organic antireflective film) for manufacturing an integrated circuit or a substrate (such as Cr, Cro, CrON, MoSi₂, or SiO₂) for manufacturing a mask circuit by an appropriate coating process such as spin coating, roll coating, flow coating, dip coating, spray coating, or doctor coating so that the coating film has a thickness of 0.01 to 2 μm. The resultant is prebaked on a hot plate preferably at 60 to 150° C. for 10 seconds to 30 minutes, more preferably at 80 to 120° C. for 30 seconds to 20 minutes. In this manner, a resist film can be formed.

In addition, when ultraviolet ray, deep ultraviolet ray, EUV, X-ray, soft X-ray, excimer laser beam, γ-ray, synchrotron radiation, or the like is employed as the high-energy beam, the irradiation is performed directly or while using a mask for forming a target pattern at an exposure dose of preferably about 1 to 200 mJ/cm², more preferably about 10 to 100 mJ/cm². When an EB is employed as the high-energy beam, the exposure dose is preferably about 0.1 to 300 μC/cm², more preferably about 0.5 to 200 μC/cm², and the writing is performed directly or while using a mask for forming a target pattern. As stated above, the inventive resist material is particularly suitable for fine patterning with a KrF excimer laser beam, an ArF excimer laser beam, an EB, EUV, X-ray, soft X-ray, γ-ray, or synchrotron radiation, among the high-energy beams, and is especially suitable for fine patterning with EB or EUV.

Specific examples include: patterning processes in which exposure is performed with an extreme ultraviolet ray having a wavelength of 3 to 15 nm; and patterning processes in which exposure is performed with an electron beam with an acceleration voltage of 1 to 150 kV.

The exposure may be followed by PEB on a hot plate or in an oven preferably at 30 to 150° C. for 10 seconds to 30 minutes, more preferably at 50 to 120° C. for 30 seconds to 20 minutes. The acid-labile groups having a phenolic group undergo deprotection due to a deprotection reaction during PEB, the deprotection component evaporates from within the film, and a polymer having a carboxy group is generated in the resist film.

As described above, dry etching is performed after the PEB and the exposed portions are etched to open space portions. For the dry etching, preferably used are gases containing oxygen, hydrogen, ammonia, etc. and containing nitrogen, helium, argon, carbon dioxide, or carbon monoxide for dilution. Furthermore, a fluorocarbon-, chlorine-, bromine-, or iodine-based gas can also be mixed in.

Regarding details of dry etching conditions, conditions disclosed in Patent Document 3 can be used.

After the development, a hole pattern or trench pattern can be shrunk by thermal flow, RELACS process, or DSA process. A shrink agent is applied onto the hole pattern, and the shrink agent undergoes crosslinking on the resist film surface by diffusion of the acid catalyst from the resist film during baking, so that the shrink agent is attached to sidewalls of the hole pattern. The baking temperature is preferably 70 to 180° C., more preferably 80 to 170° C. The baking time is preferably 10 to 300 seconds. The extra shrink agent is removed, and thus the hole pattern is shrunk.

The inventive patterning process has a characteristic in the fact that the patterning process combines: the use of a base polymer having one or both of the repeating units represented by the general formulae (a1) and (a2); and the formation of a pattern by development using dry etching.

In the present invention, a resist film is formed by using a resist material containing the above-described base polymer, in which a carboxy group bonded to a polymer main chain is protected with an acid-labile group, and the resist film is subjected to exposure and heating, and then to development by dry etching to form a pattern.

In the present invention, a resist material containing, as a base polymer, a polymer having a repeating unit in which a carboxy group is protected with an acid-labile group having a phenolic group is used. In this manner, unexposed portions have phenolic groups and exposed portions generate carboxy groups by deprotection, and when this is dry etched, the etching rate in the unexposed portions is decreased because radicals generated in the etching chamber are absorbed by phenol moieties and the etching rate in the exposed portions is increased along with decarboxylation and main-chain decomposition, thus increasing the selectivity of the etching rate between the exposed portions and the unexposed portions without relying on shrinkage of the film in the exposed portions and making it possible to form a fine pattern with a high aspect ratio.

In development by dry etching, pattern collapse due to stress that is generated during spin-drying in solvent development does not occur, and therefore, pattern formation with a higher aspect ratio and higher resolution is possible.

### EXAMPLES

Hereinafter, the present invention will be specifically described with reference to Synthesis Examples, Preparation Examples, Examples, and Comparative Examples, but the present invention is not limited to the following Examples.

### [Synthesis Example] Synthesis of Base Resins

A copolymerization reaction was performed in THE with a combination of the monomers, a crystal was precipitated in methanol, furthermore, washing with hexane was repeated, and then isolation and drying were performed to synthesize base resins (polymers 1 to 12 and comparative polymers 1 and 2) of the constitution shown below. The constitutions of the obtained base resins were confirmed by 1H-NMR and Mw and Mw/Mn were confirmed by GPC (eluent: THF, standard: polystyrene).

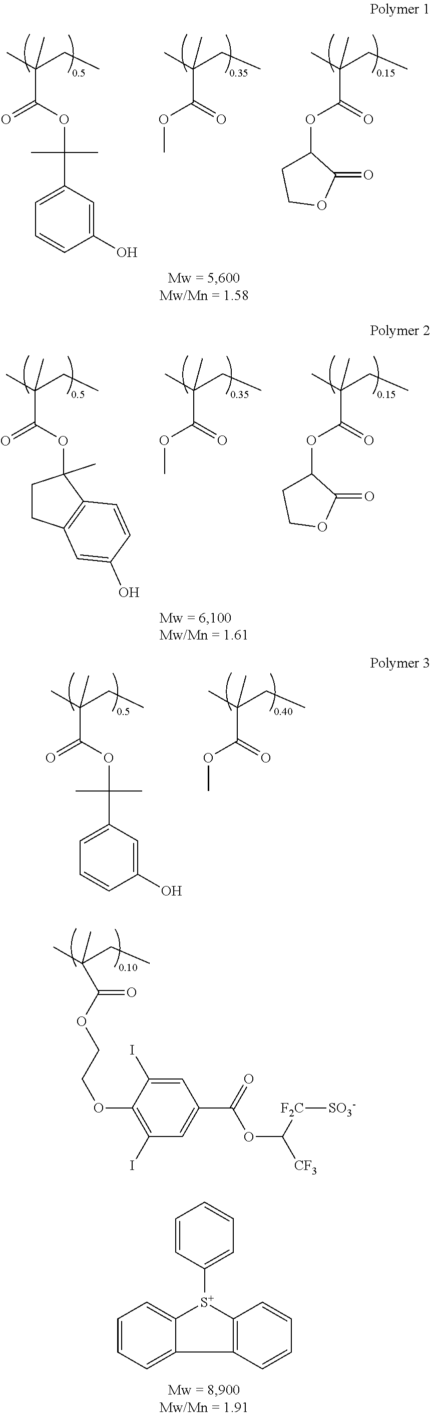

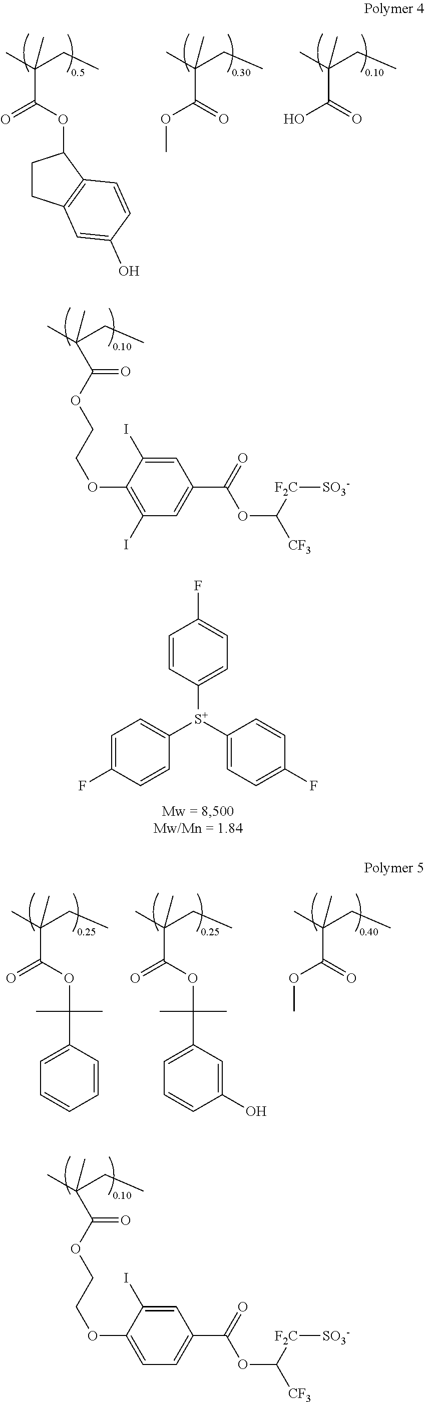

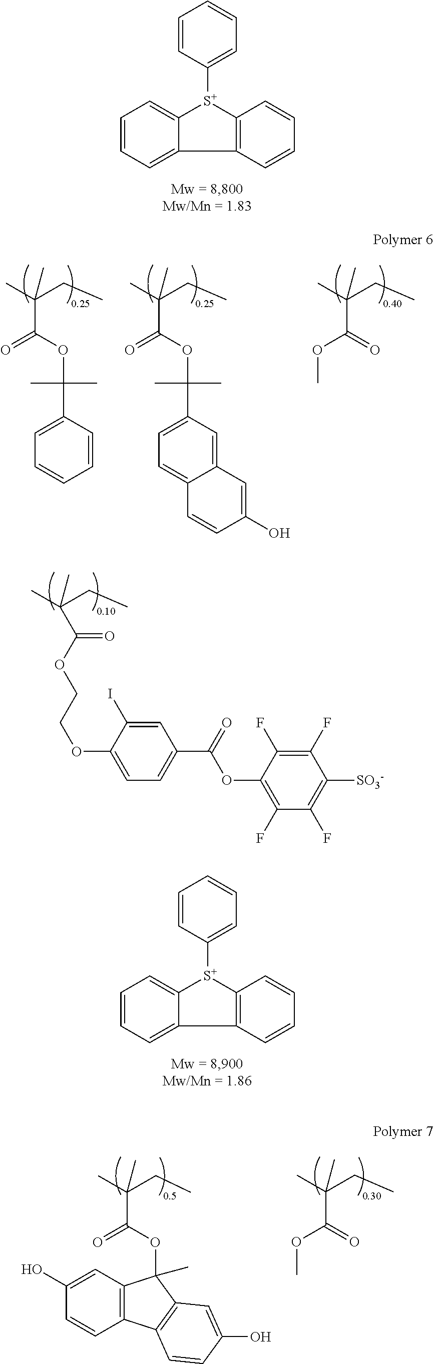

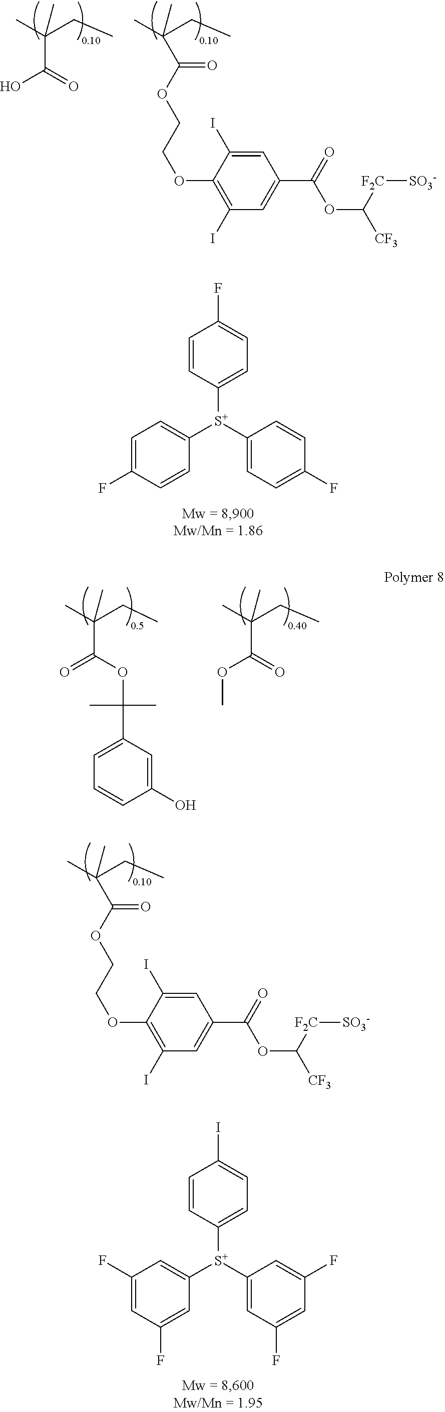

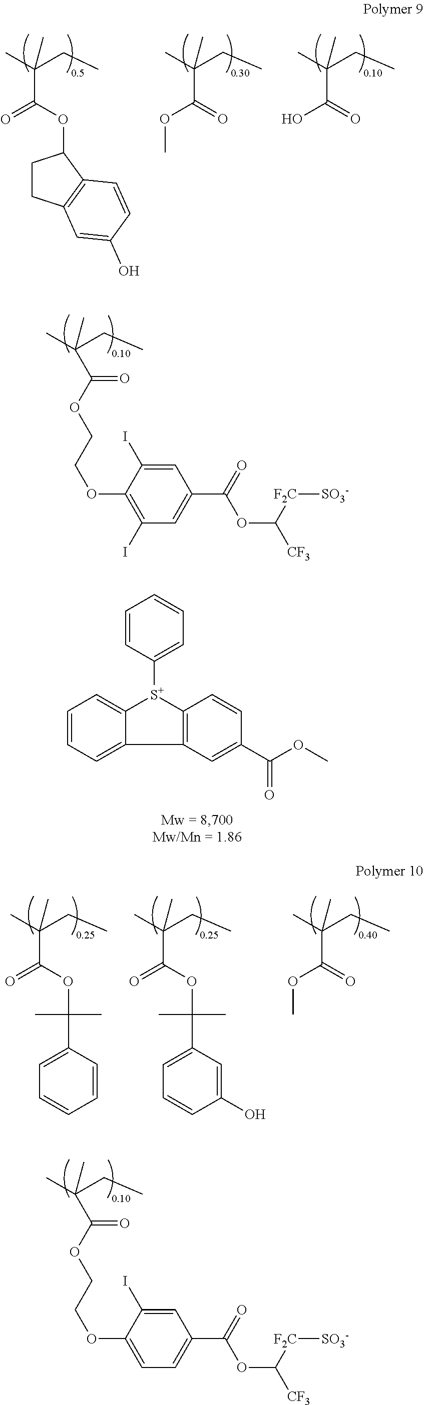

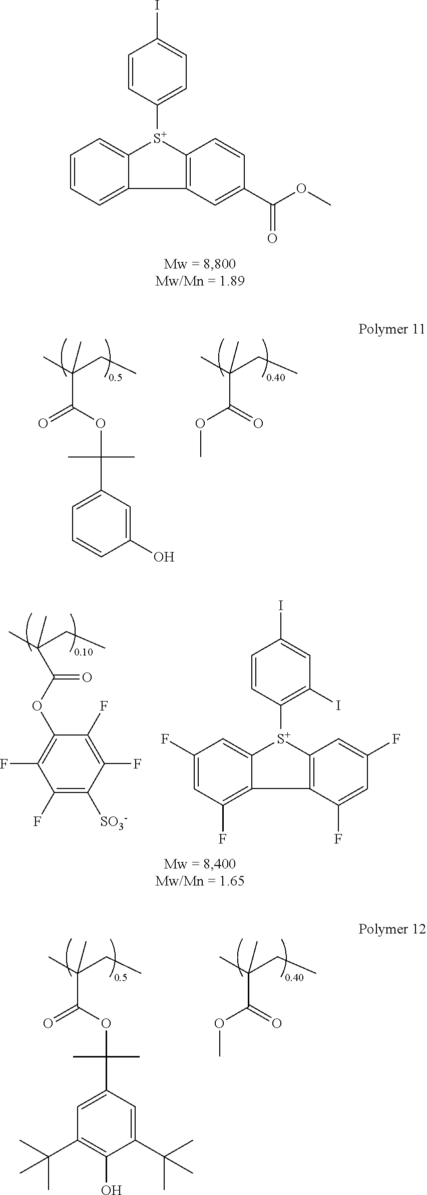

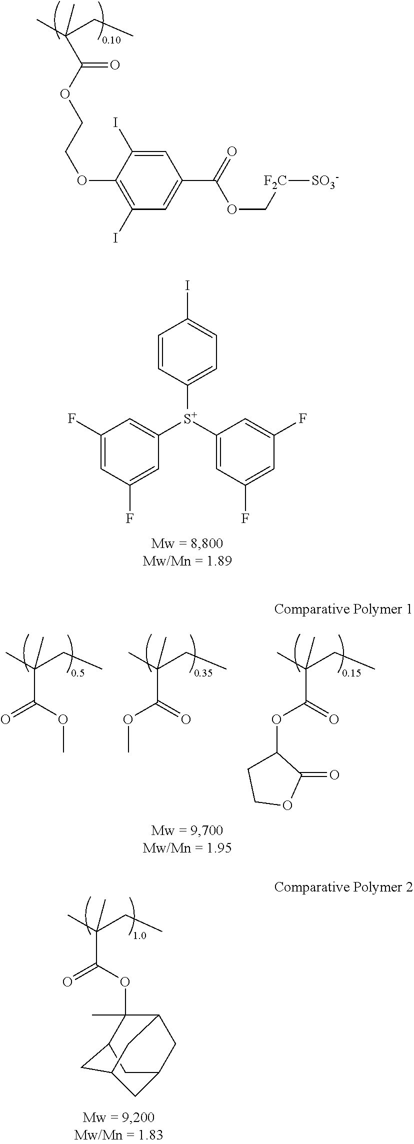

### [Preparation Examples 1 to 12 and Comparative Preparation Examples 1 and 2] Preparation of Resist Materials

According to the constitution shown in Table 1, components were dissolved in a solvent in which 50 ppm of a surfactant Polyfox636, manufactured by OMNOVA Solutions Inc., had been dissolved. The resulting solution was filtered through a filter having a pore size of 0.2 μm. In this manner, positive resist materials were prepared.

The components in Table 1 are as follows.
Acid generators: PAG-1 and PAG-2

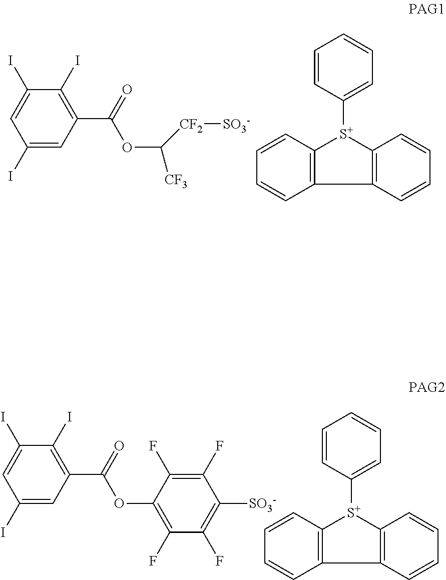

Quencher: quencher 1

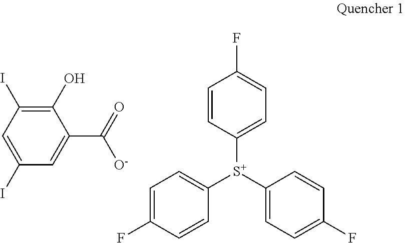 [SMILES: O=C([O-])c1cc(I)cc(I)c1O ; Fc1ccc([S+](c2ccc(F)cc2)c2ccc(F)cc2)cc1]

Organic solvents:
   PGMEA (propylene glycol monomethyl ether acetate)
   DAA (diacetone alcohol)

TABLE 1

| | | | Acid | | |
|---|---|---|---|---|---|
| | Resist | Polymer | generator | Quencher | Organic solvent |
| | material | (parts by mass) | (parts by mass) | (parts by mass) | (parts by mass) |
| Preparation | R-1 | Polymer 1 | PAG-1 | Quencher 1 | PGMEA (1,400) |
| Example 1 | | (100) | (20.0) | (6.0) | DAA (400) |
| Preparation | R-2 | Polymer 2 | PAG-2 | Quencher 1 | PGMEA (1,400) |
| Example 2 | | (100) | (20.0) | (6.0) | DAA (400) |
| Preparation | R-3 | Polymer 3 | — | Quencher 1 | PGMEA (1,400) |
| Example 3 | | (100) | | (6.0) | DAA (400) |
| Preparation | R-4 | Polymer 4 | — | Quencher 1 | PGMEA (1,400) |
| Example 4 | | (100) | | (6.0) | DAA (400) |
| Preparation | R-5 | Polymer 5 | — | Quencher 1 | PGMEA (1,400) |
| Example 5 | | (100) | | (6.0) | DAA (400) |
| Preparation | R-6 | Polymer 6 | — | Quencher 1 | PGMEA (1,400) |
| Example 6 | | (100) | | (6.0) | DAA (400) |
| Preparation | R-7 | Polymer 7 | — | Quencher 1 | PGMEA (1,400) |
| Example 7 | | (100) | | (6.0) | DAA (400) |
| Preparation | R-8 | Polymer 8 | — | Quencher 1 | PGMEA (1,400) |
| Example 8 | | (100) | | (6.0) | DAA (400) |
| Preparation | R-9 | Polymer 9 | — | Quencher 1 | PGMEA (1,400) |
| Example 9 | | (100) | | (6.0) | DAA (400) |
| Preparation | R-10 | Polymer 10 | — | Quencher 1 | PGMEA (1,400) |
| Example 10 | | (100) | | (6.0) | DAA (400) |
| Preparation | R-11 | Polymer 11 | — | Quencher 1 | PGMEA (1,400) |
| Example 11 | | (100) | | (6.0) | DAA (400) |
| Preparation | R-12 | Polymer 12 | — | Quencher 1 | PGMEA (1,400) |
| Example 12 | | (100) | | (6.0) | DAA (400) |
| Comparative | CR-1 | Comparative | — | Quencher 1 | PGMEA (1,400) |
| Preparation | | polymer 1 | | (6.0) | DAA (400) |
| Example 1 | | (100) | | | |
| Comparative | CR-2 | Comparative | — | Quencher 1 | Cyclopentanone |
| Preparation | | polymer 2 | | (6.0) | (2,000) |
| Example 2 | | (100) | | | |

### [Examples 1-1 to 1-12 and Comparative Examples 1-1 and 1-2] KrF Exposure, Dry Etching Evaluation

Each of the resist materials (R-1 to R-7, CR-1, and CR-2) was respectively applied by spin-coating onto a Si substrate on which an antireflective film DUV-42 manufactured by Nissan Chemical Corporation had been formed with a film thickness of 60 nm, and was prebaked by using a hot plate at 105° C. for 60 seconds to prepare a resist film with a film thickness of 140 nm. The resist film was exposed in a 90-nm line-and-space pattern by using a KrF excimer scanner (XT860N, NA: 0.8, dipole illumination, 6% halftone phase shift mask) manufactured by ASML, followed by PEB on the hot plate at the temperature shown in Table 2 for 60 seconds.

The wafers after the PEB were etched under the following conditions by using a dry etching apparatus Telius manufactured by Tokyo Electron Ltd.
Chamber pressure 12.0 Pa
RF-power 600 W
Bias power 50 W
Stage temperature 25° C.
O₂ gas flow rate 20 sccm
N₂ gas flow rate 400 sccm
Time 30 sec

The resist film and the antireflective film in the exposed portions were allowed to undergo film loss by dry etching, and the dry etching was performed until the surface of the Si substrate appeared.

Using a CD-SEM CG-6300 manufactured by Hitachi High-Technologies Corporation, the exposure dose at which 90-nm lines and spaces are formed at 1:1 was obtained as the sensitivity of the resist, the wafer was cut, and the cross section of the 90-nm line-and-space pattern was observed with an electron microscope S-4100 manufactured by Hitachi High-Technologies Corporation.

The results are shown together in Table 2.

TABLE 2

| | | PEB | | |
|---|---|---|---|---|
| | | temperature | Sensitivity | Cross-sectional |
| | Resist | (° C.) | (mJ/cm²) | profile |
| Example 1-1 | R-1 | 80 | 72 | Rectangular |
| Example 1-2 | R-2 | 85 | 80 | Rectangular |
| Example 1-3 | R-3 | 90 | 70 | Rectangular |
| Example 1-4 | R-4 | 90 | 69 | Rectangular |
| Example 1-5 | R-5 | 90 | 75 | Rectangular |
| Example 1-6 | R-6 | 95 | 79 | Rectangular |
| Example 1-7 | R-7 | 95 | 73 | Rectangular |
| Example 1-8 | R-8 | 85 | 75 | Rectangular |
| Example 1-9 | R-9 | 85 | 71 | Rectangular |
| Example 1-10 | R-10 | 90 | 69 | Rectangular |
| Example 1-11 | R-11 | 90 | 68 | Rectangular |
| Example 1-12 | R-12 | 90 | 62 | Rectangular |
| Comparative | CR-1 | 90 | — | Line pattern |
| Example 1-1 | | | | was lost |
| Comparative | CR-2 | 100 | 84 | Line pattern |
| Example 1-2 | | | | was triangular |

### [Examples 2-1 to 2-12 and Comparative Examples 2-1 and 2-2] KrF Exposure, Film Thickness Evaluation

Each of the resist materials (R-1 to R-7, CR-1, and CR-2) was respectively applied by spin-coating onto a Si substrate on which an antireflective film DUV-42 manufactured by Nissan Chemical Corporation had been formed with a film thickness of 60 nm, and was prebaked by using a hot plate at 105° C. for 60 seconds to prepare a resist film with a film thickness of 140 nm. The resist film was subjected to open-frame exposure by using a KrF excimer scanner (XT860N, NA: 0.8, normal illumination) manufactured by ASML, followed by PEB on the hot plate at the temperature shown in Table 3 for 60 seconds. Then, using an optical film thickness meter, the film thicknesses at an exposure dose of 0 mJ/cm² and an exposure dose of 100 mJ/cm² were measured, and the film thickness at the exposure dose of 100 mJ/cm² was divided by the film thickness at the exposure dose of 0 mJ/cm² to obtain the percentage of the shrink rate of the film.

The results are shown together in Table 3.

TABLE 3

| | | PEB | Film thickness at 100 |
|---|---|---|---|
| | | temperature | mJ/cm²/film thickness |
| | Resist | (° C.) | at 0 mJ/cm² * 100 (%) |
| Example 2-1 | R-1 | 80 | 72 |
| Example 2-2 | R-2 | 85 | 68 |
| Example 2-3 | R-3 | 90 | 67 |
| Example 2-4 | R-4 | 90 | 66 |
| Example 2-5 | R-5 | 90 | 78 |
| Example 2-6 | R-6 | 95 | 75 |
| Example 2-7 | R-7 | 95 | 64 |
| Example 2-8 | R-8 | 85 | 72 |
| Example 2-9 | R-9 | 85 | 70 |
| Example 2-10 | R-10 | 90 | 71 |
| Example 2-11 | R-11 | 90 | 72 |
| Example 2-12 | R-12 | 90 | 67 |
| Comparative | CR-1 | 90 | 82 |
| Example 2-1 | | | |
| Comparative | CR-2 | 90 | 43 |
| Example 2-2 | | | |

From the results shown in Tables 2 and 3, it was shown that, by using a resist material containing, as a base polymer, a polymer in which an acid-labile group having a phenolic hydroxy group is copolymerized, a pattern can be formed by the development of the present invention using dry etching. In the case of the resist material CR-1 of Comparative Example 1-1, where a polymer in which an acid-labile group not having a phenolic hydroxy group is copolymerized is contained as a base polymer, the shrinkage of the film was not large (Comparative Example 2-1). However, the film was lost not only in the exposed portions but also in the unexposed portions. In the case of the resist of Comparative Example 1-2, the shrinkage of the film in the space portions of the exposed portions after the PEB was large (Comparative Example 2-2). Therefore, the space portions opened after the dry etching, but pattern deformation due to the high shrinkage of the film during the PEB occurred, and the cross-sectional profile became triangular. In development by dry etching, pattern collapse due to stress that is generated during spin-drying in solvent development does not occur, and therefore, pattern formation with a higher aspect ratio and higher resolution is possible.

The present description includes the following embodiments.
[1]: A patterning process comprising:
providing a resist material containing a polymer in which a carboxy group bonded to a polymer main chain is protected with an acid-labile group;
forming a resist film by using the resist material; and
subjecting the resist film to exposure and heating, and then to development by dry etching to form a pattern,
wherein the polymer has one or both of repeating units represented by the following general formulae (a1) and (a2),

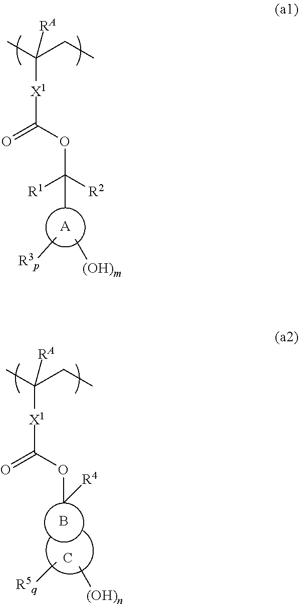

wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.
[2]: The patterning process of [1], wherein the resist material further contains an acid generator.
[3]: The patterning process of [1] or [2], wherein a resist material containing a polymer having a repeating unit-b having an acid-generating moiety in addition to the one or both of the repeating units is used.
[4]: The patterning process of [3], wherein the repeating unit-b having the acid-generating moiety is at least one of repeating units selected from repeating units represented by the following formulae (b1) to (b5),

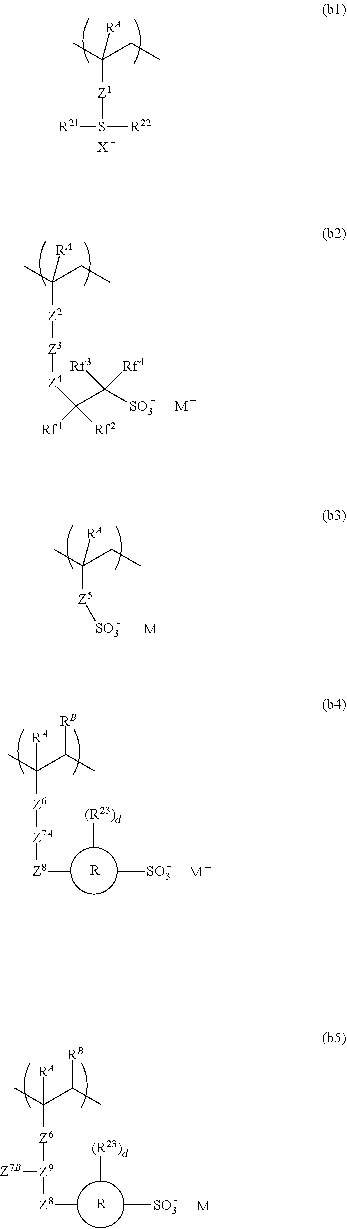

wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, ZA optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.
[5]: The patterning process of [4], wherein the repeating unit-b having the acid-generating moiety is at least one repeating unit selected from repeating units represented by the formulae (b2) to (b5) in which the Z³, the Z^{7A}, the Z^{7B}, or the M⁺ in the formula contains one or more iodine atoms.
[6]: The patterning process of any one of [1] to [5], wherein the exposure is performed with an extreme ultraviolet ray having a wavelength of 3 to 15 nm.
[7]: The patterning process of any one of [1] to [5], wherein the exposure is performed with an electron beam with an acceleration voltage of 1 to 150 kV.
[8]: A resist material for patterning by dry etching, the resist material comprising a polymer having one or both of repeating units represented by the following general formulae (a1) and (a2),

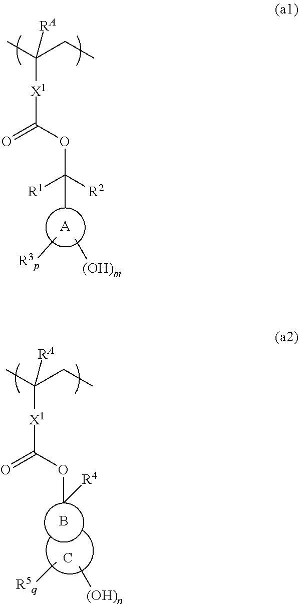

wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A patterning process comprising:
providing a resist material containing a polymer in which a carboxy group bonded to a polymer main chain is protected with an acid-labile group;
forming a resist film by using the resist material; and
subjecting the resist film to exposure and heating, and then to development by dry etching to form a pattern,
wherein the polymer has one or both of repeating units represented by the following general formulae (a1) and (a2), 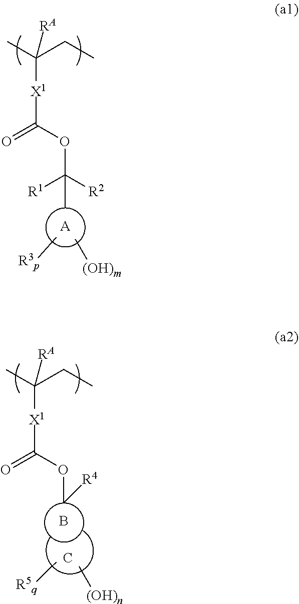
wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.

2. The patterning process according to claim 1, wherein the resist material further contains an acid generator.

3. The patterning process according to claim 1, wherein a resist material containing a polymer having a repeating unit-b having an acid-generating moiety in addition to the one or both of the repeating units is used.

4. The patterning process according to claim 3, wherein the repeating unit-b having the acid-generating moiety is at least one of repeating units selected from repeating units represented by the following formulae (b1) to (b5), 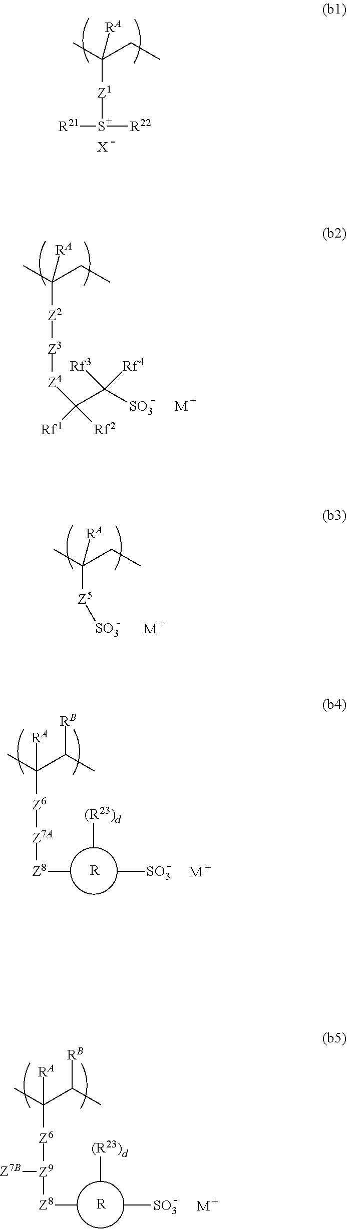
wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z° represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

5. The patterning process according to claim 4, wherein the repeating unit-b having the acid-generating moiety is at least one repeating unit selected from repeating units represented by the formulae (b2) to (b5) in which the Z³, the Z^{7A}, the Z⁷⁸, or the M⁺ in the formula contains one or more iodine atoms.

6. The patterning process according to claim 1, wherein the exposure is performed with an extreme ultraviolet ray having a wavelength of 3 to 15 nm.

7. The patterning process according to claim 1, wherein the exposure is performed with an electron beam with an acceleration voltage of 1 to 150 kV.

8. A resist material for patterning by dry etching, the resist material comprising a polymer having one or both of repeating units represented by the following general formulae (a1) and (a2), 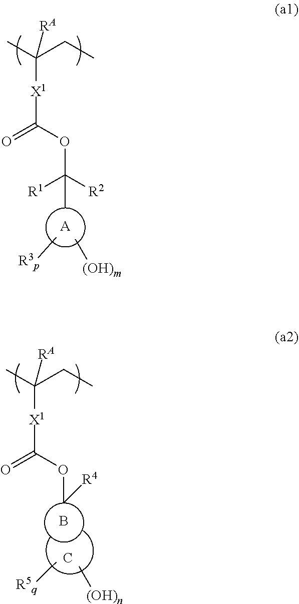
wherein each R^{A} independently represents a hydrogen atom or a methyl group, R¹ and R² each independently represent a linear, branched, or cyclic aliphatic hydrocarbon group having 1 to 14 carbon atoms and optionally having a double bond or a triple bond or represent an aryl group having 6 to 10 carbon atoms, R¹ and R² optionally being bonded to form a ring, R⁴ represents a hydrogen atom or a linear, branched, or cyclic aliphatic hydrocarbon group having 1 to 14 carbon atoms and optionally having a double bond or a triple bond, R³ and R⁵ each independently represent a linear, branched, or cyclic alkyl group having 1 to 6 carbon atoms, a linear, branched, or cyclic alkoxy group having 1 to 6 carbon atoms, a linear, branched, or cyclic alkoxycarbonyl group having 1 to 6 carbon atoms, a linear, branched, or cyclic alkanoyl group having 1 to 6 carbon atoms, a halogen atom, a cyano group, a trifluoromethyl group, a trifluoromethoxy group, or a nitro group, ring A represents an aryl group having 6 to 16 carbon atoms, ring B represents a 4- to 8-membered ring and optionally has a double bond, ring C represents an aryl group having 6 to 16 carbon atoms, “m” and “n” each represent an integer of 1 to 3, “p” and “q” each represent an integer of 0 to 6, and X¹ represents a single bond or a linking group having 1 to 12 carbon atoms and containing at least one selected from an ester bond, a lactone ring, a phenylene group, and a naphthylene group.
